(19) United States
(12) Patent Application Publication
(10) Pub. No.: US 2024/0261994 A1
(43) Pub. Date: Aug. 8, 2024

(54) CRYSTAL CUTTING METHOD, METHOD OF MANUFACTURING SiC SEMICONDUCTOR DEVICE, AND SiC SEMICONDUCTOR DEVICE

(71) Applicant: ROHM CO., LTD., Kyoto-shi (JP)

(72) Inventors: Kazunori FUJI, Kyoto-shi (JP); Hironobu KAWAUCHI, Kyoto-shI (JP)

(73) Assignee: ROHM CO., LTD., Kyoto-shi (JP)

(21) Appl. No.: 18/442,416

(22) Filed: Feb. 15, 2024

Related U.S. Application Data
(63) Continuation of application No. 17/041,269, filed on Sep. 24, 2020.

(30) Foreign Application Priority Data
Apr. 27, 2018 (JP) 2018-086472

(51) Int. Cl. B26D 1/00; B23K 26/06; B23K 101/40; H01L 21/78

(52) U.S. Cl. CPC B26D 1/0006; B23K 26/0626; H01L 21/78; B23K 2101/40

(57) ABSTRACT

A crystal cutting method includes a step of preparing a crystal structure body constituted of a hexagonal crystal, a first cutting step of cutting the crystal structure body along a [1-100] direction of the hexagonal crystal and forming a first cut portion in the crystal structure body and a second cutting step of cutting the crystal structure body along a [11-20] direction of the hexagonal crystal and forming a second cut portion crossing the first cut portion in the crystal structure body.

### CROSS-REFERENCE TO RELATED APPLICATIONS

The present application is a continuation application of U.S. application Ser. No. 17/041,269, filed on Sep. 24, 2020, which is based on PCT filing PCT/JP2019/018110, filed on Apr. 26, 2019, which claims the benefit of priority from Japanese Patent Application No. 2018-086472, filed on Apr. 27, 2018. The disclosure of each are incorporated by reference herein in their entirety.

### TECHNICAL FIELD

The present invention relates to a crystal cutting method, a method for manufacturing an SiC semiconductor device, and an SiC semiconductor device.

### BACKGROUND ART

Patent Document 1 discloses a wafer processing method of cutting out a plurality of devices from a single wafer. The wafer is constituted of silicon carbide (SiC), gallium nitride (GaN), lithium tantalate (LT), lithium niobate (LN), etc.

### CITATION LIST

### Patent Literature

Patent Literature 1: Japanese Patent Application Publication No. 2017-100255

### SUMMARY OF INVENTION

### Technical Problem

A crystal structure body constituted of a hexagonal crystal has different physical properties according to crystal plane and crystal direction. For example, a crystal structure body constituted of a hexagonal crystal has physical properties of cracking easily along a direction of arrangement of nearest neighboring atoms (hereinafter referred to simply as the “nearest neighbor direction”) and being difficult to crack along an intersecting direction intersecting the nearest neighbor direction (hereinafter referred to simply as the “nearest neighbor direction intersecting direction”).

The present inventors diligently examined steps of cutting a crystal structure body along a nearest neighbor direction and thereafter cutting the crystal structure body along a nearest neighbor direction intersecting direction. As a result, it was discovered that in the second cutting step, a bulging portion bulging along the nearest neighbor direction is formed at a cut portion of the crystal structure body.

In particular, the bulging portion has a tendency of forming with a connection portion of a cut portion formed in the first cutting step and a cut portion formed in the second connection step as a starting point. In the second cutting step, the crystal structure body is cut in a direction in which the atomic arrangement is discontinuous with respect to the nearest neighbor direction. It is therefore considered that a force that holds the atomic arrangement acts in the crystal structure body to form the bulging portion oriented along the nearest neighbor direction at the cut portion.

A preferred embodiment of the present invention provides a crystal cutting method and a method for manufacturing an SiC semiconductor device that enable a crystal structure body constituted of a hexagonal crystal to be cut appropriately from two different directions, and an SiC semiconductor device, manufactured using such a method for manufacturing an SiC semiconductor device.

### Solution to Problem

A preferred embodiment of the present invention provides a crystal cutting method including a step of preparing a crystal structure body constituted of a hexagonal crystal, a first cutting step of cutting the crystal structure body along a [1-100] direction of the hexagonal crystal and forming a first cut portion in the crystal structure body and a second cutting step of cutting the crystal structure body along a [11-20] direction of the hexagonal crystal and forming a second cut portion crossing the first cut portion in the crystal structure body.

According to this crystal cutting method, the crystal structure body is cut along the [1-100] direction which is a nearest neighbor direction intersecting direction in the first cutting step. The crystal structure body is cut along the [11-20] direction which is a nearest neighbor direction in the second cutting step.

In the first cutting step, the uncut crystal structure body is cut and therefore stress to the crystal structure body does not become discontinuous. Forming of a bulging portion in the first cut portion can thereby be suppressed. On the other hand, in the second cutting step, stress to the crystal structure body becomes discontinuous because the crystal structure body has been cut in the nearest neighbor direction intersecting direction. However, in the second cutting step, stress is applied to the crystal structure body along the nearest neighbor direction and the crystal structure body is cut along the nearest neighbor direction.

Forming of a bulging portion in the second cut portion can thereby be suppressed and flatness of the first cut portion and the second cut portion can thus be improved. A crystal cutting method that enables a crystal structure body constituted of a hexagonal crystal to be cut appropriately from two different directions can thus be provided.

A preferred embodiment of the present invention provides a crystal cutting method including a step of preparing a SiC crystal structure body constituted of a hexagonal crystal, a first cutting step of cutting the SiC crystal structure body along a [1-100] direction of the hexagonal crystal and forming a first cut portion in the SiC crystal structure body and a second cutting step of cutting the SiC crystal structure body along a [11-20] direction of the hexagonal crystal and forming a second cut portion crossing the first cut portion in the SiC crystal structure body.

According to this crystal cutting method, the SiC crystal structure body is cut along the [1-100] direction which is a nearest neighbor direction intersecting direction in the first cutting step. The SiC crystal structure body is cut along the [11-20] direction which is a nearest neighbor direction in the second cutting step.

In the first cutting step, the uncut SiC crystal structure body is cut and therefore stress to the SiC crystal structure body does not become discontinuous. Forming of a bulging portion in the first cut portion can thereby be suppressed. On the other hand, in the second cutting step, stress to the SiC crystal structure body becomes discontinuous because the SiC crystal structure body has been cut in the nearest neighbor direction intersecting direction. However, in the second cutting step, stress is applied to the SiC crystal structure body along the nearest neighbor direction and the SiC crystal structure body is cut along the nearest neighbor direction.

Forming of a bulging portion in the second cut portion can thereby be suppressed and flatness of the first cut portion and the second cut portion can thus be improved. A crystal cutting method that enables an SiC crystal structure body constituted of a hexagonal crystal to be cut appropriately from two different directions can thus be provided.

A preferred embodiment of the present invention provides a method for manufacturing an SiC semiconductor device comprising, a step of preparing an SiC crystal structure body constituted of a hexagonal crystal, a step of setting a device region of quadrilateral shape having a [1-100] direction side oriented along a [1-100] direction of the hexagonal crystal, and a [11-20] direction side oriented along a [11-20] direction of the hexagonal crystal in the SiC crystal structure body, and forming a functional device in the device region, a first cutting step of cutting the SiC crystal structure body along the [1-100] direction side of the device region and forming a first cut portion in the SiC crystal structure body, and a second cutting step of cutting the SiC crystal structure body along the [11-20] direction side of the device region and forming a second cut portion crossing the first cut portion in the SiC crystal structure body.

According to this method for manufacturing the SiC semiconductor device, the SiC crystal structure body is cut along the [1-100] direction which is a nearest neighbor direction intersecting direction in the first cutting step. The SiC crystal structure body is cut along the [11-20] direction which is a nearest neighbor direction in the second cutting step.

In the first cutting step, the uncut SiC crystal structure body is cut and therefore stress to the SiC crystal structure body does not become discontinuous. Forming of a bulging portion in the first cut portion can thereby be suppressed. On the other hand, in the second cutting step, stress to the SiC crystal structure body becomes discontinuous because the SiC crystal structure body has been cut in the nearest neighbor direction intersecting direction. However, in the second cutting step, stress is applied to the SiC crystal structure body along the nearest neighbor direction and the SiC crystal structure body is cut along the nearest neighbor direction.

Forming of a bulging portion in the second cut portion can thereby be suppressed and flatness of the first cut portion and the second cut portion can thus be improved. A method for manufacturing an SiC semiconductor device that enables an SiC crystal structure body constituted of a hexagonal crystal to be cut appropriately from two different directions can thus be provided.

A preferred embodiment of the present invention provides an SiC semiconductor device including an SiC semiconductor layer that is constituted of a hexagonal crystal and includes a first main surface at one side, a second main surface at another side, a first side surface connecting the first main surface and the second main surface and extending along a [11-20] direction of the hexagonal crystal, and a second side surface connecting the first main surface and the second main surface and extending along a [1-100] direction of the hexagonal crystal, and being not more than 20 μm in an in-plane variation along the [11-20] direction of the hexagonal crystal.

The aforementioned as well as other objects, features, and effects of the present invention will be made clear by the following description of the preferred embodiments, with reference to the accompanying drawings.

### BRIEF DESCRIPTION OF DRAWINGS

FIG. 1 is a diagram of a unit cell of a 4H—SiC monocrystal applied to preferred embodiments of the present invention.

FIG. 2 is a plan view of a silicon plane of the unit cell of the 4H—SiC monocrystal shown in FIG. 1.

FIG. 3 is a perspective view of a 4H—SiC crystal structure body that includes a 4H—SiC monocrystal.

FIG. 4 is a plan view of a splitting mode of the 4H—SiC crystal structure body.

FIG. 5A is a sectional perspective view of a partial region of the 4H—SiC crystal structure body shown in FIG. 3 and is for describing an SiC processing method according to a first preferred embodiment of the present invention.

FIG. 5B is a sectional perspective view of a step subsequent to that of FIG. 5A.

FIG. 5C is a sectional perspective view of a step subsequent to that of FIG. 5B.

FIG. 5D is a sectional perspective view of a step subsequent to that of FIG. 5C.

FIG. 6 is a sectional view of a modified layer formed in the step of FIG. 5B.

FIG. 7 is a graph of components of the 4H—SiC crystal structure body.

FIG. 8A is a sectional perspective view of a partial region of the 4H—SiC crystal structure body shown in FIG. 3 and is for describing an SiC processing method according to a second preferred embodiment of the present invention.

FIG. 8B is a sectional perspective view of a step subsequent to that of FIG. 8A.

FIG. 8C is a sectional perspective view of a step subsequent to that of FIG. 8B.

FIG. 8D is a sectional perspective view of a step subsequent to that of FIG. 8C.

FIG. 9A is a sectional perspective view of a partial region of the 4H—SiC crystal structure body shown in FIG. 3 and is for describing an SiC processing method according to a third preferred embodiment of the present invention.

FIG. 9B is a sectional perspective view of a step subsequent to that of FIG. 9A.

FIG. 9C is a sectional perspective view of a step subsequent to that of FIG. 9B.

FIG. 9D is a sectional perspective view of a step subsequent to that of FIG. 9C.

FIG. 10A is a sectional perspective view of a partial region of the 4H—SiC crystal structure body shown in FIG. 3 and is for describing an SiC processing method according to a fourth preferred embodiment of the present invention.

FIG. 10B is a sectional perspective view of a step subsequent to that of FIG. 10A.

FIG. 10C is a sectional perspective view of a step subsequent to that of FIG. 10B.

FIG. 10D is a sectional perspective view of a step subsequent to that of FIG. 10C.

FIG. 11A is a sectional perspective view of a partial region of the 4H—SiC crystal structure body shown in FIG. 3 and is for describing an SiC processing method according to a fifth preferred embodiment of the present invention.

FIG. 11B is a sectional perspective view of a step subsequent to that of FIG. 11A.

FIG. 11C is a sectional perspective view of a step subsequent to that of FIG. 11B.

FIG. 11D is a sectional perspective view of a step subsequent to that of FIG. 11C.

FIG. 12A is a sectional perspective view of a partial region of the 4H—SiC crystal structure body shown in FIG. 3 and is for describing an SiC processing method according to a sixth preferred embodiment of the present invention.

FIG. 12B is a sectional perspective view of a step subsequent to that of FIG. 12A.

FIG. 12C is a sectional perspective view of a step subsequent to that of FIG. 12B.

FIG. 12D is a sectional perspective view of a step subsequent to that of FIG. 12C.

FIG. 13A is a sectional perspective view of a partial region of the 4H—SiC crystal structure body shown in FIG. 3 and is for describing an SiC processing method according to a seventh preferred embodiment of the present invention.

FIG. 13B is a sectional perspective view of a step subsequent to that of FIG. 13A.

FIG. 13C is a sectional perspective view of a step subsequent to that of FIG. 13B.

FIG. 13D is a sectional perspective view of a step subsequent to that of FIG. 13C.

FIG. 14A is a sectional perspective view of a partial region of the 4H—SiC crystal structure body shown in FIG. 3 and is for describing an SiC processing method according to an eighth preferred embodiment of the present invention.

FIG. 14B is a sectional perspective view of a step subsequent to that of FIG. 14A.

FIG. 14C is a sectional perspective view of a step subsequent to that of FIG. 14B.

FIG. 14D is a sectional perspective view of a step subsequent to that of FIG. 14C.

FIG. 15A is a sectional perspective view of a partial region of the 4H—SiC crystal structure body shown in FIG. 3 and is for describing an SiC processing method according to a ninth preferred embodiment of the present invention.

FIG. 15B is a sectional perspective view of a step subsequent to that of FIG. 15A.

FIG. 15C is a sectional perspective view of a step subsequent to that of FIG. 15B.

FIG. 15D is a sectional perspective view of a step subsequent to that of FIG. 15C.

FIG. 16A is a sectional perspective view of a partial region of the 4H—SiC crystal structure body shown in FIG. 3 and is for describing an SiC processing method according to a tenth preferred embodiment of the present invention.

FIG. 16B is a sectional perspective view of a step subsequent to that of FIG. 16A.

FIG. 16C is a sectional perspective view of a step subsequent to that of FIG. 16B.

FIG. 16D is a sectional perspective view of a step subsequent to that of FIG. 16C.

FIG. 17 is a perspective view of the general arrangement of an SiC semiconductor device according to an eleventh preferred embodiment of the present invention.

FIG. 18 is a plan view of the SiC semiconductor device shown in FIG. 17.

FIG. 19 is a sectional view taken along line XIX-XIX shown in FIG. 18.

FIG. 20 is an enlarged view of a region XX shown in FIG. 19.

FIG. 21 is an enlarged view of a region XXI shown in FIG. 17.

FIG. 22 is a graph of components of the SiC semiconductor layer shown in FIG. 21.

FIG. 23 is a perspective view of a 4H—SiC crystal structure body used in manufacturing the SiC semiconductor device shown in FIG. 17.

FIG. 24A is a sectional perspective view of a partial region of the 4H—SiC crystal structure body shown in FIG. 23 and is for describing an example of a method for manufacturing the SiC semiconductor device shown in FIG. 17.

FIG. 24B is a sectional perspective view of a step subsequent to that of FIG. 24A.

FIG. 24C is a sectional perspective view of a step subsequent to that of FIG. 24B.

FIG. 24D is a sectional perspective view of a step subsequent to that of FIG. 24C.

FIG. 24E is a sectional perspective view of a step subsequent to that of FIG. 24D.

FIG. 24F is a sectional perspective view of a step subsequent to that of FIG. 24E.

FIG. 24G is a sectional perspective view of a step subsequent to that of FIG. 24F.

FIG. 24H is a sectional perspective view of a step subsequent to that of FIG. 24G.

FIG. 24I is a sectional perspective view of a step subsequent to that of FIG. 24H.

FIG. 24J is a sectional perspective view of a step subsequent to that of FIG. 24I.

FIG. 24K is a sectional perspective view of a step subsequent to that of FIG. 24J.

FIG. 24L is a sectional perspective view of a step subsequent to that of FIG. 24K.

FIG. 25A is a perspective view of the 4H—SiC crystal structure body shown in FIG. 23 and is a perspective view for describing an example of a cleaving step of FIG. 24K.

FIG. 25B is a perspective view of a step subsequent to that of FIG. 25A.

FIG. 25C is a perspective view of a step subsequent to that of FIG. 25B.

FIG. 25D is a perspective view of a step subsequent to that of FIG. 25C.

FIG. 26 is a plan view for describing planar shapes of SiC semiconductor devices diced through a method for manufacturing the SiC semiconductor devices according to a reference example.

FIG. 27 is a plan view for describing planar shapes of the SiC semiconductor devices, shown in FIG. 17 and diced through the manufacturing method of FIG. 24A to FIG. 24L.

FIG. 28 is a sectional view of a region corresponding to FIG. 19 and is a sectional view of the general arrangement of an SiC semiconductor device according to a twelfth preferred embodiment of the present invention.

FIG. 29 is a sectional view of a region corresponding to FIG. 19 and is a sectional view of the general arrangement of an SiC semiconductor device according to a thirteenth preferred embodiment of the present invention.

FIG. 30 is a sectional view of a region corresponding to FIG. 19 and is a sectional view of the general arrangement of an SiC semiconductor device according to a fourteenth preferred embodiment of the present invention.

FIG. 31 is a sectional view of a region corresponding to FIG. 19 and is a sectional view of the general arrangement of an SiC semiconductor device according to a fifteenth preferred embodiment of the present invention.

FIG. 32 is a sectional view of a region corresponding to FIG. 19 and is a sectional view of the general arrangement of an SiC semiconductor device according to a sixteenth preferred embodiment of the present invention.

FIG. 33 is a sectional view of a region corresponding to FIG. 19 and is a sectional view of the general arrangement of an SiC semiconductor device according to a seventeenth preferred embodiment of the present invention.

FIG. 34 is a sectional view of a region corresponding to FIG. 19 and is a sectional view of the general arrangement of an SiC semiconductor device according to an eighteenth preferred embodiment of the present invention.

FIG. 35 is a sectional view of a region corresponding to FIG. 19 and is a sectional view of the general arrangement of an SiC semiconductor device according to a nineteenth preferred embodiment of the present invention.

FIG. 36 is a top view of an SiC semiconductor device according to a twentieth preferred embodiment of the present invention.

FIG. 37 is a top view of the SiC semiconductor device shown in FIG. 36 and is a top view with a resin layer being removed.

FIG. 38 is an enlarged view of a region XXXVIII shown in FIG. 37 and is a diagram for describing the structure of a first main surface of an SiC semiconductor layer.

FIG. 39 is a sectional view taken along line XXXIX-XXXIX shown in FIG. 38.

FIG. 40 is a sectional view taken along line XL-XL shown in FIG. 39.

FIG. 41 is an enlarged view of a region XLI shown in FIG. 39.

FIG. 42 is a sectional view taken along line XLII-XLII shown in FIG. 37.

FIG. 43 is an enlarged view of a region XLIII shown in FIG. 42.

FIG. 44 is an enlarged view of a region XLIV shown in FIG. 42.

FIG. 45 is an enlarged view of a region corresponding to FIG. 44 and is an enlarged view of an SiC semiconductor device according to a twenty-first preferred embodiment of the present invention.

FIG. 46 is an enlarged view of a region corresponding to FIG. 44 and is an enlarged view of an SiC semiconductor device according to a twenty-second preferred embodiment of the present invention.

FIG. 47 is an enlarged view of a region corresponding to FIG. 44 and is an enlarged view of an SiC semiconductor device according to a twenty-third preferred embodiment of the present invention.

FIG. 48 is an enlarged view of a region corresponding to FIG. 44 and is an enlarged view of an SiC semiconductor device according to a twenty-fourth preferred embodiment of the present invention.

FIG. 49 is an enlarged view of a region corresponding to FIG. 44 and is an enlarged view of an SiC semiconductor device according to a twenty-fifth preferred embodiment of the present invention.

FIG. 50 is an enlarged view of a region corresponding to FIG. 44 and is an enlarged view of an SiC semiconductor device according to a twenty-sixth preferred embodiment of the present invention.

FIG. 51 is an enlarged view of a region corresponding to FIG. 44 and is an enlarged view of an SiC semiconductor device according to a twenty-seventh preferred embodiment of the present invention.

FIG. 52 is a sectional view of a region corresponding to FIG. 44 and is a sectional view of an SiC semiconductor device according to a twenty-eighth preferred embodiment of the present invention.

FIG. 53 is a sectional view of a region corresponding to FIG. 44 and is a sectional view of an SiC semiconductor device according to a twenty-ninth preferred embodiment of the present invention.

FIG. 54 is a sectional view of a region corresponding to FIG. 44 and is a sectional view of an SiC semiconductor device according to a thirtieth preferred embodiment of the present invention.

FIG. 55 is a sectional view of a region corresponding to FIG. 42 and is a sectional view of an SiC semiconductor device according to a thirty-first preferred embodiment of the present invention.

FIG. 56 is a sectional view of a region corresponding to FIG. 42 and is a sectional view of an SiC semiconductor device according to a thirty-second preferred embodiment of the present invention.

FIG. 57 is a sectional view of a region corresponding to FIG. 42 and is a sectional view of an SiC semiconductor device according to a thirty-third preferred embodiment of the present invention.

FIG. 58 is an enlarged view of a region corresponding to FIG. 38 and is an enlarged view of an SiC semiconductor device according to a thirty-fourth preferred embodiment of the present invention.

FIG. 59 is a sectional view taken along line LIX-LIX shown in FIG. 58.

FIG. 60 is an enlarged view of a region corresponding to FIG. 38 and is an enlarged view of an SiC semiconductor device according to a thirty-fifth preferred embodiment of the present invention.

### DESCRIPTION OF EMBODIMENTS

A crystal structure body constituted of a hexagonal crystal is applied in the preferred embodiments of the present invention. The crystal structure body constituted of the hexagonal crystal may include a material type with a thermal conductivity of not less than 0.35 W/cmK and not more than 25 W/cmK. The crystal structure body constituted of the hexagonal crystal may include a material type with a thermal conductivity exceeding 2.5 W/cmK.

As the crystal structure body constituted of the hexagonal crystal, any of various material types that constitute a hexagonal crystal, such as sapphire (Al₂O₃), gallium nitride (GaN), silicon carbide (SiC), diamond (C), etc., is applied.

The thermal conductivity increases in the order of sapphire (Al₂O₃), gallium nitride (GaN), silicon carbide (SiC), and diamond (C). The thermal conductivity of sapphire (Al₂O₃) is not less than 0.35 W/cmK and not more than 0.45 W/cmK (more specifically, approximately 0.4 W/cmK). That of gallium nitride (GaN) is not less than 1.5 W/cmK and not more than 2.5 W/cmK (more specifically, approximately 2.0 W/cmK).

The thermal conductivity of silicon carbide (SiC) is not less than 4.5 W/cmK and not more than 5.5 W/cmK (more specifically, approximately 4.9 W/cmK). The thermal conductivity of diamond (C) is not less than 10 W/cmK and not more than 25 W/cmK (more specifically, approximately 22 W/cmK).

With the preferred embodiments of the present invention, examples where an SiC crystal structure body constituted of a hexagonal crystal is applied as an example of the crystal structure body constituted of the hexagonal crystal shall be described. The SiC crystal structure body constituted of the hexagonal crystal has a plurality of polytypes including a 2H (hexagonal)-SiC monocrystal, a 4H—SiC monocrystal, and a 6H—SiC monocrystal in accordance with cycle of atomic arrangement. Although, with the preferred embodiments of the present invention, examples where a 4H—SiC monocrystal is applied shall be described, this does not exclude other polytypes and other material types that constitute a hexagonal crystal from the present invention.

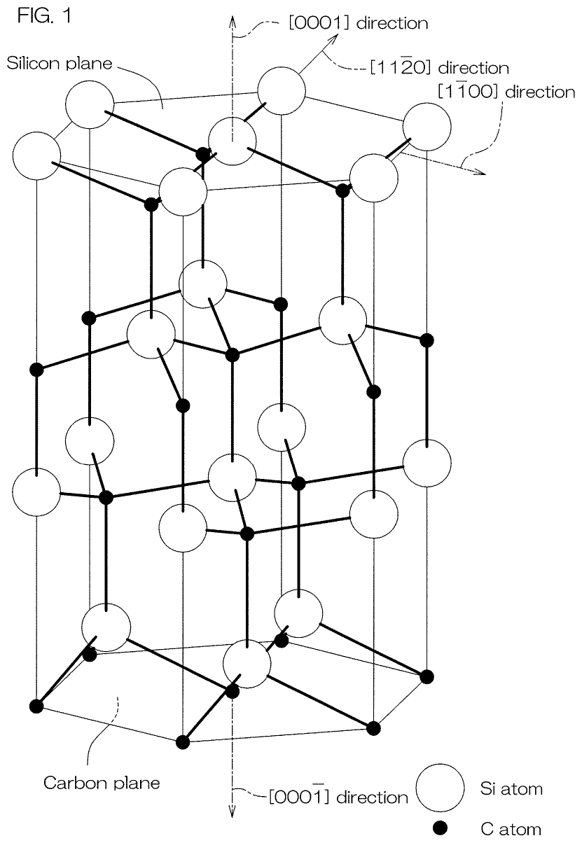

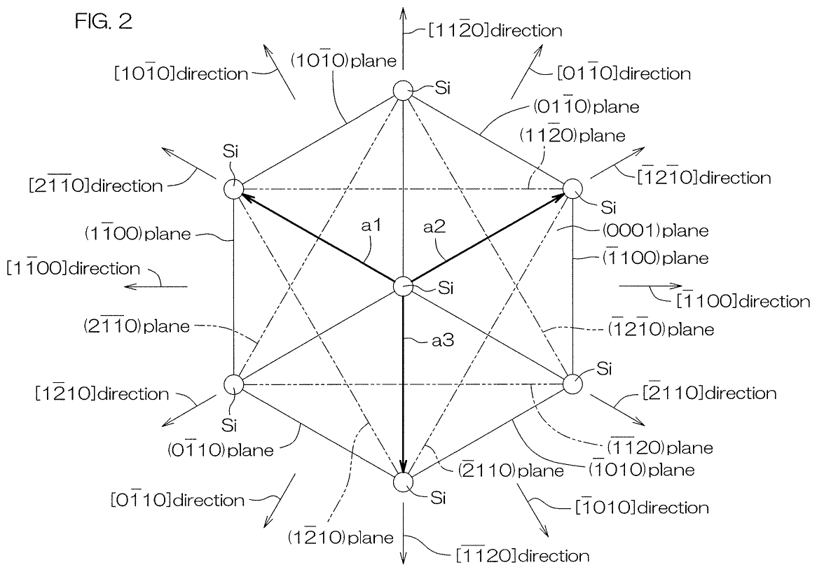

The crystal structure body of the 4H—SiC monocrystal shall now be described with reference to FIG. 1 and FIG. 2. FIG. 1 is a diagram of a unit cell of the 4H—SiC monocrystal applied to the preferred embodiments of the present invention (hereinafter referred to simply as the “unit cell”). FIG. 2 is a plan view of a silicon plane of the unit cell shown in FIG. 1.

Referring to FIG. 1 and FIG. 2, the unit cell includes tetrahedral structures, in each of which four C atoms are bonded to a single Si atom in a tetrahedral arrangement (regular tetrahedral arrangement) relationship. The unit cell has an atomic arrangement in which the tetrahedral structures are layered in a four-layer cycle. The unit cell has a hexagonal prism structure having a regular hexagonal silicon plane, a regular hexagonal carbon plane, and six side planes connecting the silicon plane and the carbon plane.

The silicon plane is an end plane terminated by Si atoms. At the silicon plane, a single Si atom is positioned at each of the six vertices of a regular hexagon and a single Si atom is positioned at a center of the regular hexagon.

The carbon plane is an end plane terminated by C atoms. At the carbon plane, a single C atom is positioned at each of the six vertices of a regular hexagon and a single C atom is positioned at a center of the regular hexagon.

The crystal planes of the unit cell are defined by four coordinate axes (a1, a2, a3, and c) including an a1 axis, an a2 axis, an a3 axis, and a c axis. Of the four coordinate axes, a value of a3 takes on a value of −(a1+a2). The crystal planes of the 4H—SiC monocrystal shall be described below based on the silicon plane as an example of an end plane of a hexagonal crystal.

In a plan view of viewing the silicon plane from the c axis, the a1 axis, the a2 axis, and the a3 axis are respectively set along directions of arrangement of the nearest neighboring Si atoms (hereinafter referred to simply as the “nearest neighbor directions”) based on the Si atom positioned at the center. The a1 axis, the a2 axis, and the a3 axis are set to be shifted by 1200 each in conformance to the arrangement of the Si atoms.

The c axis is set in a direction normal to the silicon plane based on the Si atom positioned at the center. The silicon plane is the (0001) plane. The carbon plane is the (000-1) plane. The side planes of the hexagonal prism include six crystal planes oriented along the nearest neighbor directions in the plan view of viewing the silicon plane from the c axis. More specifically, the side planes of the hexagonal prism include the six crystal planes formed by the nearest neighboring Si atoms.

In the plan view of viewing the silicon plane from the c axis, the side planes of the hexagonal prism include a (10-10) plane, a (01-10) plane, a (−1100) plane, a (−1010) plane, a (0-110) plane, and a (1-100) plane in clockwise order from a tip of the a1 axis.

Diagonals of the hexagonal prism not passing through the center include six crystal planes oriented along intersecting directions intersecting the nearest neighbor directions in the plan view of viewing the silicon plane from the c axis (hereinafter referred to simply as the “nearest neighbor direction intersecting directions”). When viewed on a basis of the Si atom positioned at the center, the nearest neighbor direction intersecting directions are orthogonal directions orthogonal to the nearest neighbor directions. More specifically, the diagonals of the hexagonal prism not passing through the center include the six crystal planes formed by Si atoms that are not nearest neighbors.

In the plan view of viewing the silicon plane from the c axis, the diagonals of the hexagonal prism not passing through the center include a (11-20) plane, a (−2110) plane, a (1-2-10) plane, a (−1-120) plane, a (2-1-10) plane, and a (−12-10) plane.

The crystal directions of the unit cell are defined by directions normal to the crystal planes. A direction normal to the (10-10) plane is a [10-10] direction. A direction normal to the (01-10) plane is a [01-10] direction. A direction normal to the (−1100) plane is a [−1100] direction. A direction normal to the (−1010) plane is a [−1010] direction. A direction normal to the (0-110) plane is a [0-110] direction. A direction normal to the (1-100) plane is a [1-100] direction.

A direction normal to the (11-20) plane is a [11-20] direction. A direction normal to the (−2110) plane is a [−2110] direction. A direction normal to the (1-2-10) plane is a [1-2-10] direction. A direction normal to the (−1-120) plane is a [−1-120] direction. A direction normal to the (2-1-10) plane is a [2-1-10] direction. A direction normal to the (−12-10) plane is a [−12-10] direction.

The hexagonal crystal is six-fold symmetrical and equivalent crystal planes and equivalent crystal directions are present every 60°. For example, the (10-10) plane, the (01-10) plane, the (−1100) plane, the (−1010) plane, the (0-110) plane, and the (1-100) plane form equivalent crystal planes.

Also, the [01-10] direction, the [−1100] direction, the [−1010] direction, the [0-110] direction, the [1-100] direction, and the [10-10] direction form equivalent crystal directions. Also, the [11-20] direction, the [−12-10] direction, the [−2110] direction, the [−1-120] direction, the [1-210] direction, and the [2-1-10] direction form equivalent crystal directions.

The c axis is a [0001] direction ([000-1] direction). The a1 axis is the [2-1-10] direction ([−2110] direction). The a2 axis is the [−12-10] direction ([1-210] direction). The a3 axis is the [−1-120] direction ([11-20] direction).

The [0001] direction and the [000-1] direction are referred to at times simply as the c axis. The (0001) plane and the (000-1) plane are referred to at times simply as c planes. The [11-20] direction and the [−1-120] direction are referred to at times simply as the a axis. The (11-20) plane and the (−1-120) plane are referred to at times simply as a planes. The [1-100] direction and the [−1100] direction are referred to at times simply as the m axis. The (1-100) plane and the (−1100) plane are referred to at times simply as m planes.

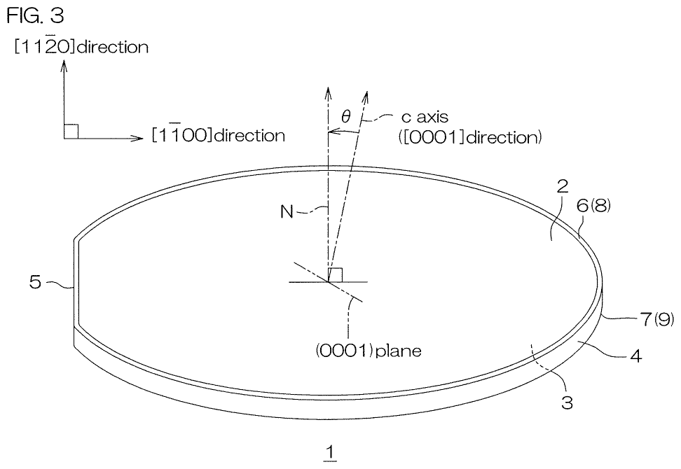

FIG. 3 is a perspective view of a 4H—SiC crystal structure body 1 that includes a 4H—SiC monocrystal.

In this embodiment, the 4H—SiC crystal structure body 1 is formed in a plate shape or discoid shape. The 4H—SiC crystal structure body 1 may be formed in a circular shape (disk shape).

A thickness of the 4H—SiC crystal structure body 1 may be not less than 1 μm and not more than 1000 μm. The thickness of the 4H—SiC crystal structure body 1 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The 4H—SiC crystal structure body 1 has a first main surface 2 at one side, a second main surface 3 at another side, and a side surface 4 connecting the first main surface 2 and the second main surface 3. The first main surface 2 and the second main surface 3 of the 4H—SiC crystal structure body 1 may have an off angle θ inclined at an angle of not more than 10° in the [11-20] direction with respect to the (0001) plane. The off angle θ is also an angle between a normal direction N of the first main surface 2 and the second main surface 3 and the c axis of the 4H—SiC crystal structure body 1.

The off angle θ may be not less than 0° and not more than 4°. A state in which the off angle θ is 0° is that in which the normal direction N and the c axis are matched. The off angle θ may exceed 0° and be less than 4°. The off angle θ is typically 2° or 4° and more specifically is set in a range of 2°±10% or a range of 4°±10%.

An orientation flat 5 which is an example of a marker indicating a crystal orientation is formed on the side surface 4 of the 4H—SiC crystal structure body 1. The orientation flat 5 is a notched portion formed on the side surface 4 of the 4H—SiC crystal structure body 1. In this embodiment, the orientation flat 5 extends rectilinearly along the [11-20] direction.

A plurality (for example, two) of orientation flats indicating the crystal orientation may be formed on the side surface 4 of the 4H—SiC crystal structure body 1. In this case, a first orientation flat and a second orientation flat may be formed on the side surface 4 of the 4H—SiC crystal structure body 1. The first orientation flat may be a notched portion extending rectilinearly along the [11-20] direction. The second orientation flat may be a notched portion extending rectilinearly along the [1-100] direction.

An orientation notch constituted of a notched portion recessed toward a central portion of the 4H—SiC crystal structure body 1 may be formed on the side surface 4 of the 4H—SiC crystal structure body 1 in place of the orientation flat 5.

The 4H—SiC crystal structure body 1 includes a first corner portion 6 connecting the first main surface 2 and the side surface 4, and a second corner portion 7 connecting the second main surface 3 and the side surface 4. The first corner portion 6 has a first chamfered portion 8 that is inclined downward from the first main surface 2 toward the side surface 4. The second corner portion 7 has a second chamfered portion 9 that is inclined downward from the second main surface 3 toward the side surface 4.

The first chamfered portion 8 may be formed in a convexly curved shape. The second chamfered portion 9 may be formed in a convexly curved shape. The first chamfered portion 8 and the second chamfered portion 9 suppress cracking of the 4H—SiC crystal structure body 1.

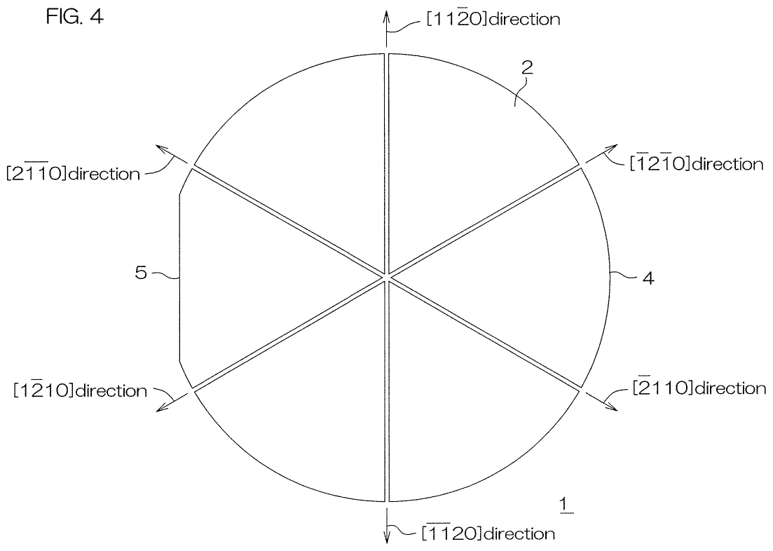

FIG. 4 is a plan view of a splitting mode of the 4H—SiC crystal structure body 1.

The 4H—SiC crystal structure body 1 has different physical properties according to crystal plane and crystal direction. For example, the 4H—SiC crystal structure body 1 has physical properties of cracking easily along the nearest neighbor directions and being difficult to crack along the nearest neighbor direction intersecting directions. The nearest neighbor direction intersecting directions are, more specifically, orthogonal directions orthogonal to the nearest neighbor directions.

Referring to FIG. 4, when, for example, the 4H—SiC crystal structure body 1 is split by applying an external force to a center of the 4H—SiC crystal structure body 1, the 4H—SiC crystal structure body 1 is split along six directions based on a center of the first main surface 2 of the 4H—SiC crystal structure body 1.

More specifically, the 4H—SiC crystal structure body 1 is split along the [11-20] direction, the [−12-10] direction, and the [−2110] direction. The [11-20] direction, the [−12-10] direction, and the [−2110] direction are all nearest neighbor directions.

The 4H—SiC crystal structure body 1 is difficult to split along a direction orthogonal to the [11-20] direction, a direction orthogonal to the [−12-10] direction, and a direction orthogonal to the [−2110] direction. That is, the 4H—SiC crystal structure body 1 is difficult to split along the [−1100] direction, the [10-10] direction, and the [01-10]direction. The [−1100] direction, the [10-10] direction, and the [01-10] direction are all nearest neighbor direction intersecting directions.

Processing methods implemented on the 4H—SiC crystal structure body 1 shall now be described. The following processing methods can also be applied to a method for manufacturing an SiC semiconductor device.

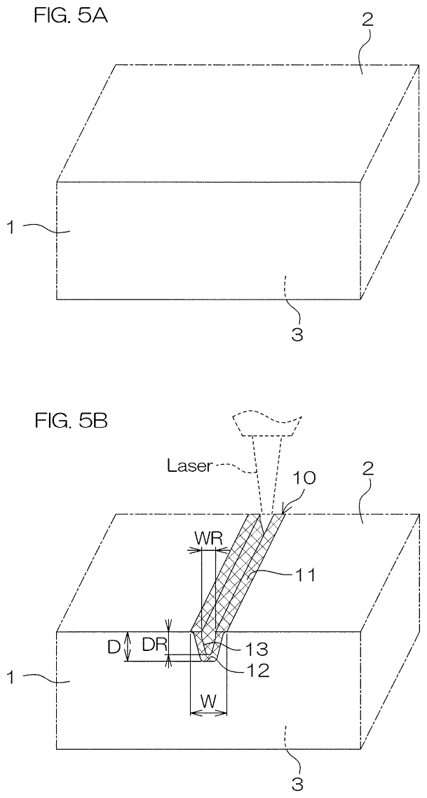

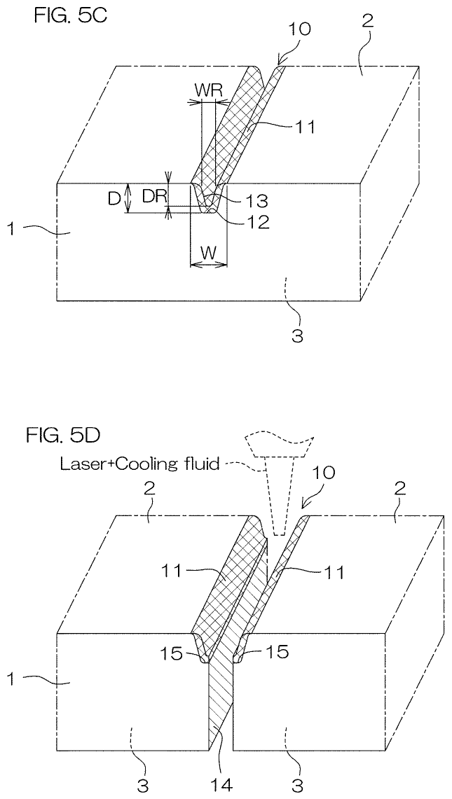

FIG. 5A to FIG. 5D are sectional perspective views of a partial region of the 4H—SiC crystal structure body 1 shown in FIG. 3 and are for describing an SiC processing method according to a first preferred embodiment of the present invention.

First, referring to FIG. 5A, the 4H—SiC crystal structure body 1 is prepared as an example of an SiC processing object.

Next, referring to FIG. 5B, a processed region 10 selectively set in the first main surface 2 of the 4H—SiC crystal structure body 1 is heated and a modified layer 11 in which the SiC is modified to a different property is formed. In this step, the modified layer 11 is formed as a band extending along an arbitrary direction.

The heating of the processed region 10 may be performed by a method of ablation processing by laser irradiation. In the ablation processing method, an ultraviolet laser may be used. Laser energy, laser pulse duty ratio and laser irradiation speed are respectively set to arbitrary values in accordance with size, shape, thickness, etc., of the modified layer 11 to be formed.

In the ablation processing method, a depression 12 recessed from the first main surface 2 toward the second main surface 3 is formed in a surface layer portion of the first main surface 2. The depression 12 includes a bottom portion and a side portion. The depression 12 may be formed in a convergent shape that narrows in opening width from the first main surface 2 toward the bottom portion. The bottom portion of the depression 12 may be formed in a shape curved toward the second main surface 3.

The depression 12 includes an opening side corner portion and a bottom portion side corner portion. The opening side corner portion of the depression 12 connects the first main surface 2 and the side portion of the depression 12. The bottom portion side corner portion of the depression 12 connects the bottom portion and the side portion of the depression 12.

A width W of the depression 12 may exceed 0 μm and be not more than 10 μm. The width W of the depression 12 is a width in a direction orthogonal to the direction in which the depression 12 extends. The width W of the depression 12 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the 4H—SiC crystal structure body 1 is not more than 150 μm, the width W of the depression 12 preferably exceeds 0 μm and is not more than 5 μm.

A depth D of the depression 12 may exceed 0 μm and be not more than 30 μm. The depth D of the depression 12 is a distance in the normal direction N from the first main surface 2 to a lowermost portion of the depression 12. The depth D of the depression 12 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the 4H—SiC crystal structure body 1 is not more than 150 μm, the depth D of the depression 12 preferably exceeds 0 μm and is not more than 15 μm.

The modified layer 11 is formed as a film along an inner wall of the depression 12. A thickness of a portion of the modified layer 11 covering a bottom wall of the depression 12 may be greater than a thickness of portions of the modified layer 11 covering a side wall of the depression 12. The modified layer 11 may be formed in a uniform thickness along the inner wall of the depression 12.

Inside the depression 12, the modified layer 11 defines a recess 13. More specifically, the recess 13 is defined by an outer surface of the modified layer 11. The recess 13 includes a bottom portion and a side portion. The recess 13 may be formed in a convergent shape that narrows in opening width from the first main surface 2 toward the bottom portion. The bottom portion of the recess 13 may be formed in a shape curved toward the second main surface 3.

The recess 13 includes an opening side corner portion and a bottom portion side corner portion. The opening side corner portion of the recess 13 connects the first main surface 2 of the 4H—SiC crystal structure body 1 and the side portion of the recess 13. The bottom portion side corner portion of the recess 13 connects the bottom portion and the side portion of the recess 13.

A width WR of the recess 13 is less than the width W of the depression 12. The width WR of the recess 13 may exceed 0 μm and be less than 10 μm. The width WR of the recess 13 may exceed 0 μm and be not more than 2.5 μm, be not less than 2.5 μm and not more than 5 μm, be not less than 5 μm and not more than 7.5 μm, or be not less than 7.5 μm and less than 10 μm. If the thickness of the 4H—SiC crystal structure body 1 is not more than 150 μm, the width WR of the recess 13 preferably exceeds 0 μm and is less than 5 μm.

A depth DR of the recess 13 is less than the depth D of the depression 12. The depth DR of the recess 13 may exceed 0 μm and be less than 30 μm. The depth DR of the recess 13 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and less than 30 μm. If the thickness of the 4H—SiC crystal structure body 1 is not more than 150 μm, the depth DR of the recess 13 preferably exceeds 0 μm and is not more than 15 μm.

Next, referring to FIG. 5C, corners of the modified layer 11 are rounded. More specifically, the outer surface of the modified layer 11 is flattened by removing an unevenness from the outer surface of the modified layer 11. A portion of the modified layer 11 may be removed by an etching method. The etching method may be a dry etching method or may be a wet etching method. Here, a portion of the modified layer 11 is removed by a plasma etching method as an example of a dry etching method.

The modified layer 11 has a component differing from that of the 4H—SiC crystal structure body 1. An etching rate (etching selectivity) with respect to the modified layer 11 differs from an etching rate (etching selectivity) with respect to SiC. A portion of the modified layer 11 can thus be removed appropriately while letting the 4H—SiC crystal structure body 1 remain. The opening side corner portion of the recess 13 is thereby rounded to shapes curved toward an inner side of the recess 13. Also, the bottom portion side corner portion of the recess 13 is rounded to shapes curved toward an outer side of the recess 13.

By the recess 13 that is rounded at the opening side corner portion, concentration of stress on the modified layer 11 can be relaxed at the opening side corner portion. Also, by the recess 13 that is rounded at the bottom portion side corner portion, concentration of stress on the modified layer 11 can be relaxed at the bottom portion side corner portion. Undesirable cracks due to stress on the modified layer 11 can thereby be suppressed.

Next, referring to FIG. 5D, the 4H—SiC crystal structure body 1 may be cleaved with the processed region 10 as a starting point. More specifically, the 4H—SiC crystal structure body 1 may be cleaved with the depression 12 as the starting point. The 4H—SiC crystal structure body 1 may be cleaved by applying stress to the depression 12. In this step, a step of applying thermal stress to the depression 12 by heating and cooling is performed.

A depression 12 heating step may be performed by a laser irradiation method. The laser irradiation method may be performed by an infrared laser (for example, a CO₂ laser). By the depression 12 heating step, a compressive stress, with the depression 12 as a starting point, is thermally induced. Laser energy, laser pulse duty ratio and laser irradiation speed are respectively set to arbitrary values in accordance with a magnitude of the stress to be applied to the depression 12.

A depression 12 cooling step may include a step of supplying a cooling fluid to the depression 12. The cooling fluid may include water or air or a mixture of water and air (aerosol). By the depression 12 cooling step, a tensile stress, with the depression 12 as a starting point, is thermally induced.

The cooling fluid supplying step may include a cooling fluid emission (jetting) step by a coolant jetting method or a cooling gas supplying method. The depression 12 cooling step may be performed after the depression 12 heating step or may be performed at the same time as the depression 12 heating step. The 4H—SiC crystal structure body 1 is cleaved along the depression 12 by the compressive stress generated in the depression 12 heating step and the tensile stress generated in the depression 12 cooling step.

The cleaved 4H—SiC crystal structure body 1 has cleavage surfaces 14. The cleavage surfaces 14 are continuous to inclining portions 15 constituted of residual portions of the depression 12. Portions of the modified layer 11 are exposed at corner portions connecting the first main surface 2 of the 4H—SiC crystal structure body 1 and the cleavage surfaces 14. The modified layer 11 is formed along the inclining portions 15.

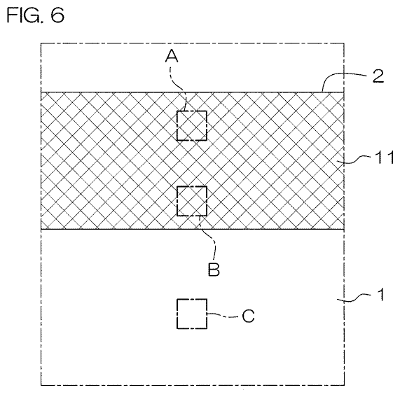

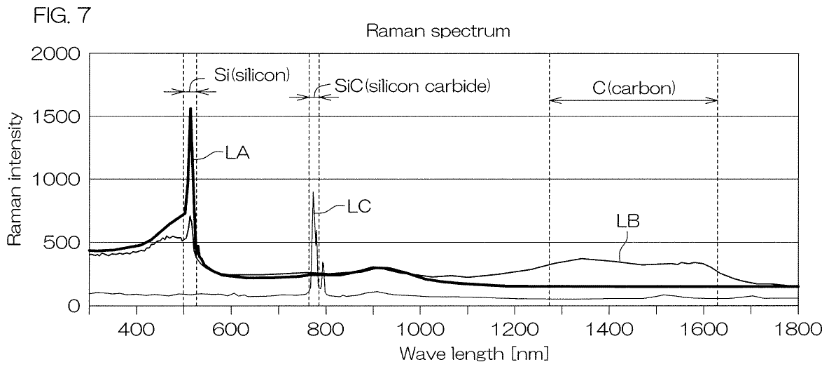

FIG. 6 is a sectional view of the modified layer 11 formed in the step of FIG. 5B. FIG. 7 is a graph of constituents of the modified layer 11. FIG. 7 shows results of examining the components of the 4H—SiC crystal structure body 1 by a Raman spectroscopy method.

A first region A, a second region B, and a third region C are shown in FIG. 6. The first region A represents a surface layer portion of the modified layer 11. The surface layer portion of the modified layer 11 is a region positioned at the first main surface 2 side of the 4H—SiC crystal structure body 1. The second region B represents a bottom portion of the modified layer 11. The bottom portion of the modified layer 11 is a region positioned at the second main surface 3 side of the 4H—SiC crystal structure body 1 with respect to the surface layer portion of the modified layer 11. The third region C represents a region of the 4H—SiC crystal structure body 1 outside the modified layer 11.

A first curve LA, a second curve LB, and a third curve LC are shown in FIG. 7. The first curve LA represents components of the first region A shown in FIG. 6. The second curve LB represents components of the second region B shown in FIG. 6. The third curve LC represents components of the third region C shown in FIG. 6.

The first curve LA has a peak value derived from Si (silicon) in a wavelength range of not less than 500 nm and not more than 550 nm. The second curve LB has a peak value derived from Si (silicon) in the wavelength range of not less than 500 nm and not more than 550 nm and a peak value derived from C (carbon) in a wavelength range of not less than 1300 nm and not more than 1700 nm.

The third curve LC has a peak value derived from SiC (silicon carbide) in a wavelength range of not less than 750 nm and not more than 850 nm. Therefore in the third region C, the modified layer 11 is not formed and just the 4H—SiC monocrystal is present.

Referring to the first curve LA, a silicon density of the surface layer portion (first region A) of the modified layer 11 is higher than a carbon density of the surface layer portion of the modified layer 11. That is, the surface layer portion of the modified layer 11 includes an Si modified layer, in which the SiC of the 4H—SiC crystal structure body 1 is modified to Si. The Si modified layer may include an Si polycrystal. The Si modified layer may include amorphous Si. The Si modified layer may include an Si polycrystal and amorphous Si. The Si modified layer may include an Si amorphous layer as a main constituent.

Referring to the second curve LB, a silicon density of the bottom portion (second region B) of the modified layer 11 is higher than a carbon density of the bottom portion of the modified layer 11. The bottom portion of the modified layer 11 includes an Si modified layer, in which the SiC of the 4H—SiC crystal structure body 1 is modified to Si. The Si modified layer may include an Si polycrystal. The Si modified layer may include amorphous Si. The Si modified layer may include an Si polycrystal and amorphous Si. The Si modified layer may include an Si amorphous layer as a main constituent.

Referring to the first curve LA and the second curve LB, the modified layer 11 has mutually different components in the surface layer portion (first region A) and the bottom portion (second region B). More specifically, the modified layer 11 has a silicon density that differs along a thickness direction. The silicon density of the bottom portion of the modified layer 11 is lower than the silicon density of the surface layer portion of the modified layer 11. Also, the modified layer 11 has a carbon density that differs along the thickness direction. The carbon density of the bottom portion of the modified layer 11 is higher than the carbon density of the surface layer portion of the modified layer 11.

From the results of the first curve LA to the third curve LC, it can be understood that the modified layer 11 forming step includes a step of heating the processed region 10 to a temperature at which a C atom is eliminated or sublimated from the SiC. The modified layer 11 is thereby formed in the first main surface 2 of the 4H—SiC crystal structure body 1.

As described above, by the present SiC processing method, an outer surface of the 4H—SiC crystal structure body 1 can be processed by the modified layer 11 forming step and the modified layer 11 removing step. In addition, the 4H—SiC crystal structure body 1 can also be cleaved using the depression 12 of the modified layer 11.

In particular, by the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

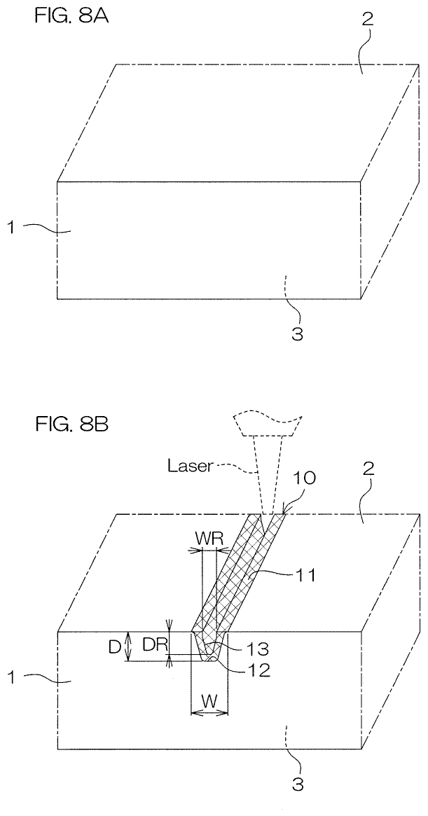

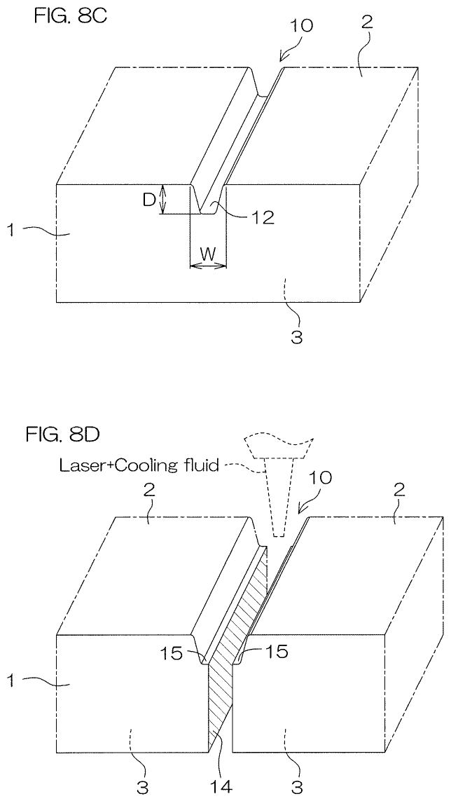

FIG. 8A to FIG. 8D are sectional perspective views of a partial region of the 4H—SiC crystal structure body 1 shown in FIG. 3 and are for describing an SiC processing method according to a second preferred embodiment of the present invention. In the following, description of structures and manufacturing steps corresponding to structures and manufacturing steps described with FIG. 5A to FIG. 5D shall be omitted.

First, referring to FIG. 8A, the 4H—SiC crystal structure body 1 is prepared as an example of the SiC processing object.

Next, referring to FIG. 8B, the modified layer 11, the depression 12 and the recess 13 are formed in the processed region 10 selectively set in the first main surface 2. The modified layer 11, the depression 12 and the recess 13 are formed through the same step as in FIG. 5B described above.

Next, referring to FIG. 8C, an entirety of the modified layer 11 is removed while letting the 4H—SiC crystal structure body 1 remain. The modified layer 11 is removed through the same step as in FIG. 5C described above. The depression 12 defined by the 4H—SiC crystal structure body 1 thereby remains in the first main surface 2.

In this step, the opening side corner portion of the depression 12 is rounded to shapes curved toward an inner side of the depression 12. Also, the bottom portion side corner portion of the depression 12 is rounded to shapes curved toward an outer side of the depression 12. By the depression 12 that is rounded at the opening side corner portion, concentration of stress on the depression 12 can be relaxed at the opening side corner portion. Also, by the depression 12 that is rounded at the bottom portion side corner portion, concentration of stress on the depression 12 can be relaxed at the bottom portion side corner portion. Undesirable cracks due to stress on the depression 12 can thereby be suppressed.

Next, referring to FIG. 8D, the 4H—SiC crystal structure body 1 may be cleaved with the depression 12 as the starting point. The 4H—SiC crystal structure body 1 may be cleaved through the same step as in FIG. 5D described above. The cleaved 4H—SiC crystal structure body 1 has the cleavage surfaces 14. The cleavage surfaces 14 are continuous to the inclining portions 15 constituted of the residual portions of the depression 12.

As described above, by the present SiC processing method, the outer surface of the 4H—SiC crystal structure body 1 can be processed by the modified layer 11 forming step and the modified layer 11 removing step. In addition, the 4H—SiC crystal structure body 1 can also be cleaved using the depression 12 formed in the outer surface of the 4H—SiC crystal structure body 1 through the modified layer 11 removing step.

In particular, by the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

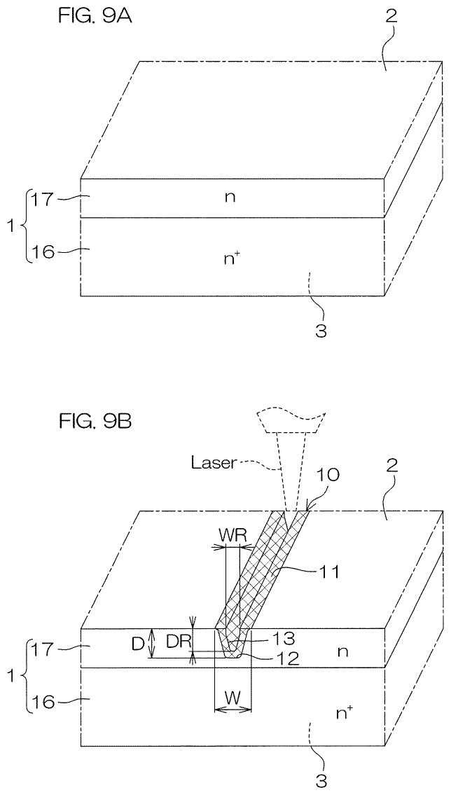

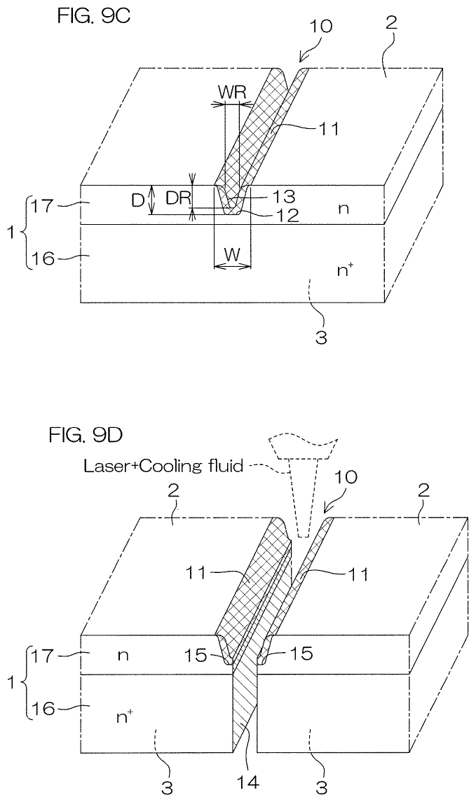

FIG. 9A to FIG. 9D are sectional perspective views of a partial region of the 4H—SiC crystal structure body 1 shown in FIG. 3 and are for describing an SiC processing method according to a third preferred embodiment of the present invention. In the following, description of structures and manufacturing steps corresponding to structures and manufacturing steps described with FIG. 5A to FIG. 5D shall be omitted.

First, referring to FIG. 9A, the 4H—SiC crystal structure body 1 is prepared as an example of the SiC processing object. In this embodiment, the 4H—SiC crystal structure body 1 has a laminated structure that includes an SiC semiconductor wafer 16 and an SiC epitaxial layer 17. The SiC epitaxial layer 17 may have an impurity concentration (for example, an n type impurity concentration) less than an impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The SiC epitaxial layer 17 is formed by epitaxially growing SiC from the SiC semiconductor wafer 16. A thickness of the SiC epitaxial layer 17 is less than a thickness of the SiC semiconductor wafer 16.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

Next, referring to FIG. 9B, the modified layer 11, the depression 12 and the recess 13 are formed in the processed region 10 selectively set in the first main surface 2 of the 4H—SiC crystal structure body 1. The modified layer 11, the depression 12 and the recess 13 are formed in the SiC epitaxial layer 17. The modified layer 11, the depression 12 and the recess 13 are formed through the same step as in FIG. 5B described above.

Next, referring to FIG. 9C, the modified layer 11 is removed partially and the outer surface of the modified layer 11 is flattened while letting the 4H—SiC crystal structure body 1 remain. The modified layer 11 is removed through the same step as in FIG. 5C described above. The opening side corner portion of the recess 13 is thereby rounded to shapes curved toward the inner side of the recess 13. Also, the bottom portion side corner portion of the recess 13 is rounded to shapes curved toward the outer side of the recess 13.

By the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

Next, referring to FIG. 9D, the 4H—SiC crystal structure body 1 may be cleaved with the depression 12 as the starting point. The 4H—SiC crystal structure body 1 may be cleaved through the same step as in FIG. 5D described above. If the impurity concentration of the SiC semiconductor wafer 16 is higher than the impurity concentration of the SiC epitaxial layer 17, a damping rate of laser light with respect to the SiC semiconductor wafer 16 is higher than a damping rate of laser light with respect to the SiC epitaxial layer 17.

Therefore by irradiating the laser light such that it reaches the SiC semiconductor wafer 16, the SiC semiconductor wafer 16 can be heated efficiently. The compressive stress generated in the depression 12 heating step and the tensile stress generated in the depression 12 cooling step can thereby be increased. A cleaving force applied to the 4H—SiC crystal structure body 1 can thus be increased.

The cleaved 4H—SiC crystal structure body 1 has the cleavage surfaces 14. The cleavage surfaces 14 are continuous to the inclining portions 15 constituted of the residual portions of the depression 12. Portions of the modified layer 11 are exposed at the corner portions connecting the first main surface 2 of the 4H—SiC crystal structure body 1 and the cleavage surfaces 14. The modified layer 11 is formed along the inclining portions 15.

As described above, by the present SiC processing method, an outer surface of the SiC epitaxial layer 17 can be processed by the modified layer 11 forming step and the modified layer 11 removing step. In addition, the 4H—SiC crystal structure body 1 can also be cleaved using the depression 12.

In particular, by the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

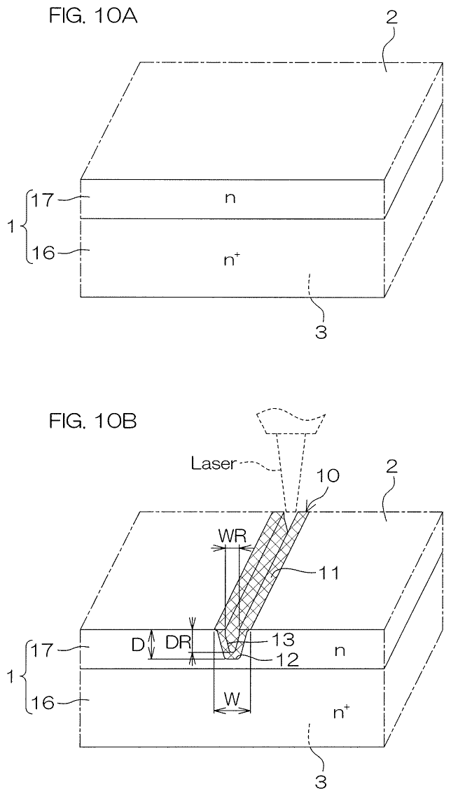

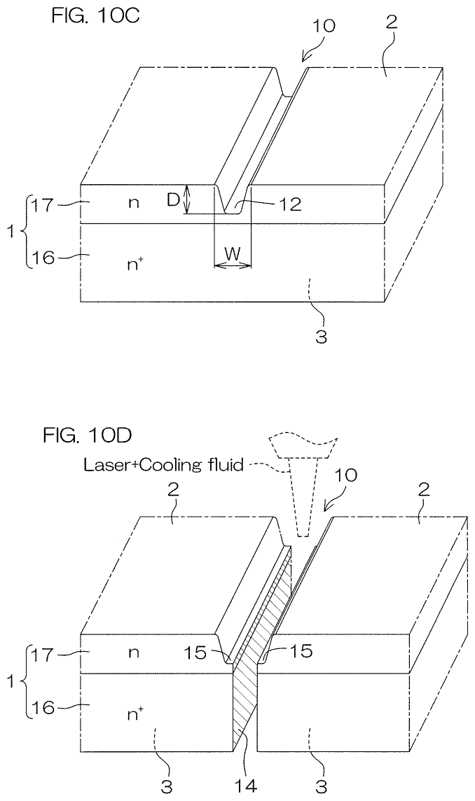

FIG. 10A to FIG. 10D are sectional perspective views of a partial region of the 4H—SiC crystal structure body 1 shown in FIG. 3 and are for describing an SiC processing method according to a fourth preferred embodiment of the present invention. In the following, description of structures and manufacturing steps corresponding to structures and manufacturing steps described with FIG. 5A to FIG. 5D shall be omitted.

First, referring to FIG. 10A, the 4H—SiC crystal structure body 1 is prepared as an example of the SiC processing object. In this embodiment, the 4H—SiC crystal structure body 1 has the laminated structure that includes the SiC semiconductor wafer 16 and the SiC epitaxial layer 17. The SiC epitaxial layer 17 may have an impurity concentration (for example, an n type impurity concentration) less than the impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The SiC epitaxial layer 17 is formed by epitaxially growing SiC from the SiC semiconductor wafer 16. The thickness of the SiC epitaxial layer 17 is less than the thickness of the SiC semiconductor wafer 16.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

Next, referring to FIG. 10B, the modified layer 11, the depression 12 and the recess 13 are formed in the processed region 10, selectively set in the first main surface 2 of the 4H—SiC crystal structure body 1. The modified layer 11, the depression 12 and the recess 13 are formed in the SiC epitaxial layer 17. The modified layer 11, the depression 12 and the recess 13 are formed through the same step as in FIG. 5B described above.

Next, referring to FIG. 10C, the entirety of the modified layer 11 is removed while letting the 4H—SiC crystal structure body 1 remain. The modified layer 11 is removed through the same step as in FIG. 5C described above. The depression 12, defined by the 4H—SiC crystal structure body 1, thereby remains in the first main surface 2. In this step, the opening side corner portion of the depression 12 is rounded to shapes curved toward the inner side of the depression 12. Also, the bottom portion side corner portion of the depression 12 is rounded to shapes curved toward the outer side of the depression 12.

By the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

Next, referring to FIG. 10D, the 4H—SiC crystal structure body 1 may be cleaved with the depression 12 as the starting point. The 4H—SiC crystal structure body 1 may be cleaved through the same step as in FIG. 5D described above. If the impurity concentration of the SiC semiconductor wafer 16 is higher than the impurity concentration of the SiC epitaxial layer 17, the damping rate of laser light with respect to the SiC semiconductor wafer 16 is higher than the damping rate of laser light with respect to the SiC epitaxial layer 17.

Therefore by irradiating the laser light such that it reaches the SiC semiconductor wafer 16, the SiC semiconductor wafer 16 can be heated efficiently. The compressive stress generated in the depression 12 heating step and the tensile stress generated in the depression 12 cooling step can thereby be increased.

The cleaving force applied to the 4H—SiC crystal structure body 1 can thus be increased. The cleaved 4H—SiC crystal structure body 1 has the cleavage surfaces 14. The cleavage surfaces 14 are continuous to the inclining portions 15 constituted of the residual portions of the depression 12.

As described above, by the present SiC processing method, the outer surface of the SiC epitaxial layer 17 can be processed by the modified layer 11 forming step and the modified layer 11 removing step. In addition, the 4H—SiC crystal structure body 1 can also be cleaved using the depression 12.

In particular, by the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

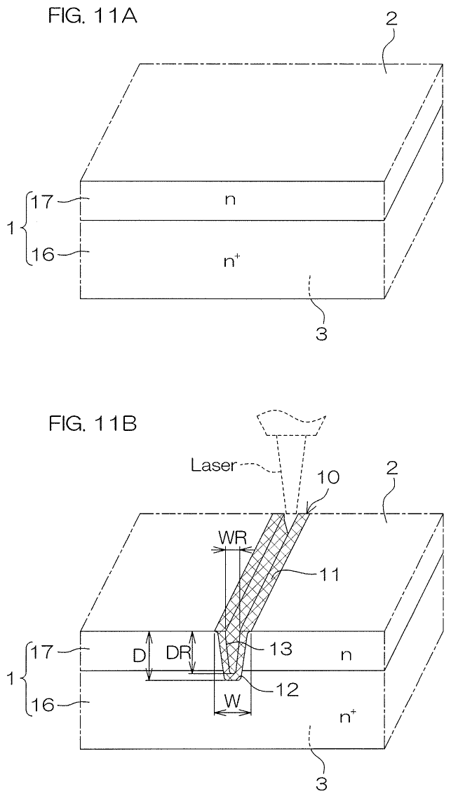

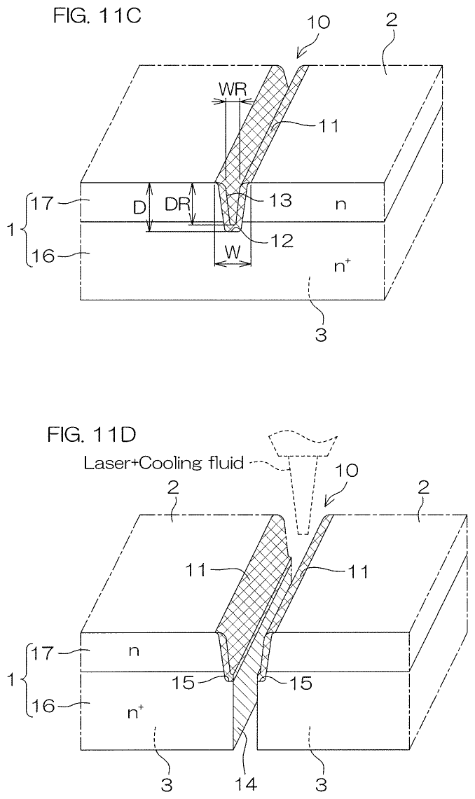

FIG. 11A to FIG. 11D are sectional perspective views of a partial region of the 4H—SiC crystal structure body 1 shown in FIG. 3 and are for describing an SiC processing method according to a fifth preferred embodiment of the present invention. In the following, description of structures and manufacturing steps corresponding to structures and manufacturing steps described with FIG. 5A to FIG. 5D shall be omitted.

First, referring to FIG. 11A, the 4H—SiC crystal structure body 1 is prepared as an example of the SiC processing object. In this embodiment, the 4H—SiC crystal structure body 1 has the laminated structure that includes the SiC semiconductor wafer 16 and the SiC epitaxial layer 17. The SiC epitaxial layer 17 may have an impurity concentration (for example, an n type impurity concentration) less than the impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The SiC epitaxial layer 17 is formed by epitaxially growing SiC from the SiC semiconductor wafer 16. The thickness of the SiC epitaxial layer 17 is less than the thickness of the SiC semiconductor wafer 16.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

Next, referring to FIG. 11B, the modified layer 11, the depression 12 and the recess 13 are formed in the processed region 10, selectively set in the first main surface 2 of the 4H—SiC crystal structure body 1. The modified layer 11, the depression 12 and the recess 13 are formed through the same step as in FIG. 5B described above.

The modified layer 11, the depression 12 and the recess 13 are formed in the SiC epitaxial layer 17. More specifically, the modified layer 11, the depression 12 and the recess 13 cross a boundary between the SiC semiconductor wafer 16 and the SiC epitaxial layer 17 from the SiC epitaxial layer 17 and are formed in the SiC semiconductor wafer 16 as well.

Next, referring to FIG. 11C, the modified layer 11 is removed partially and the outer surface of the modified layer 11 is flattened while letting the 4H—SiC crystal structure body 1 remain. The modified layer 11 is removed through the same step as in FIG. 5C described above. The opening side corner portion of the recess 13 is thereby rounded to shapes curved toward the inner side of the recess 13. Also, the bottom portion side corner portion of the recess 13 is rounded to shapes curved toward the outer side of the recess 13.

By the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

Next, referring to FIG. 11D, the 4H—SiC crystal structure body 1 may be cleaved with the depression 12 as the starting point. The 4H—SiC crystal structure body 1 may be cleaved through the same step as in FIG. 5D described above. If the impurity concentration of the SiC semiconductor wafer 16 is higher than the impurity concentration of the SiC epitaxial layer 17, the damping rate of laser light with respect to the SiC semiconductor wafer 16 is higher than the damping rate of laser light with respect to the SiC epitaxial layer 17.

Therefore by irradiating the laser light such that it reaches the SiC semiconductor wafer 16, the SiC semiconductor wafer 16 can be heated efficiently. In particular in this step, the SiC semiconductor wafer 16 can be heated via the modified layer 11 formed inside the SiC semiconductor wafer 16.

The compressive stress generated in the depression 12 heating step and the tensile stress generated in the depression 12 cooling step can thereby be increased efficiently. The cleaving force applied to the 4H—SiC crystal structure body 1 can thus be increased efficiently.

The cleaved 4H—SiC crystal structure body 1 has the cleavage surfaces 14. The cleavage surfaces 14 are continuous to the inclining portions 15 constituted of the residual portions of the depression 12. Portions of the modified layer 11 are exposed at the corner portions connecting the first main surface 2 of the 4H—SiC crystal structure body 1 and the cleavage surfaces 14. The modified layer 11 is formed along the inclining portions 15.

As described above, by the present SiC processing method, the outer surface of the SiC epitaxial layer 17 can be processed by the modified layer 11 forming step and the modified layer 11 removing step. In addition, the 4H—SiC crystal structure body 1 can also be cleaved using the depression 12.

In particular, by the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

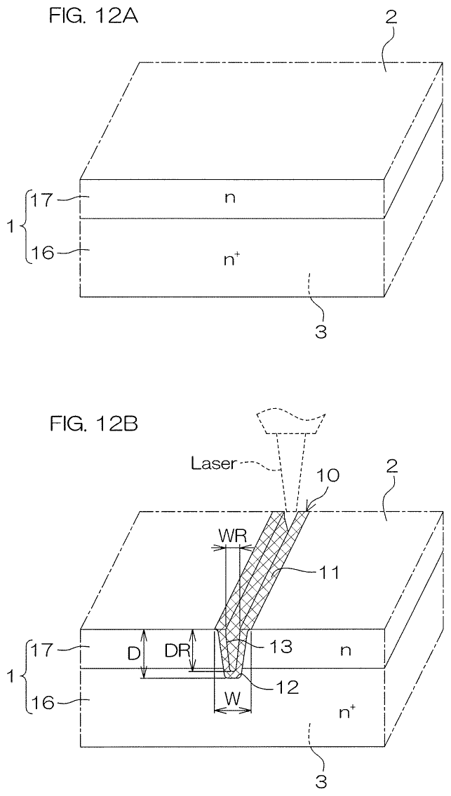

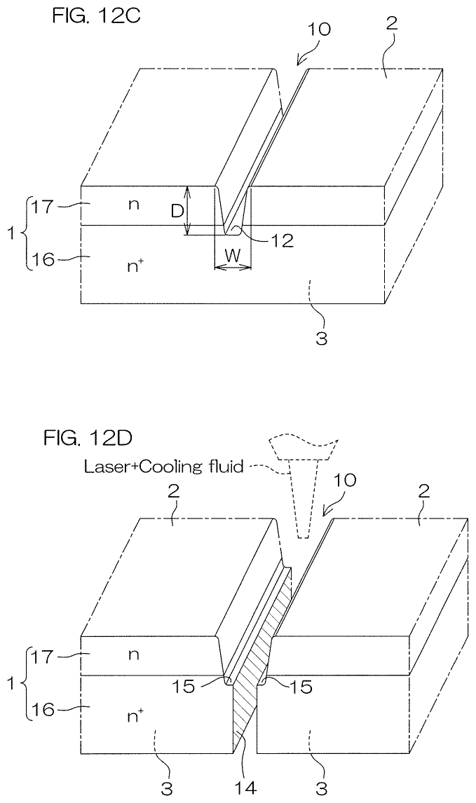

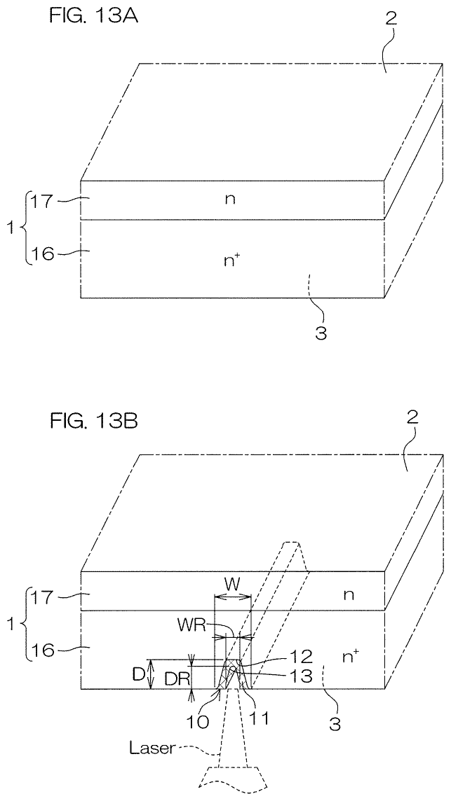

FIG. 12A to FIG. 12D are sectional perspective views of a partial region of the 4H—SiC crystal structure body 1 shown in FIG. 3 and are for describing an SiC processing method according to a sixth preferred embodiment of the present invention. In the following, description of structures and manufacturing steps corresponding to structures and manufacturing steps described with FIG. 5A to FIG. 5D shall be omitted.

First, referring to FIG. 12A, the 4H—SiC crystal structure body 1 is prepared as an example of the SiC processing object. In this embodiment, the 4H—SiC crystal structure body 1 has the laminated structure that includes the SiC semiconductor wafer 16 and the SiC epitaxial layer 17. The SiC epitaxial layer 17 may have an impurity concentration (for example, an n type impurity concentration) less than the impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The SiC epitaxial layer 17 is formed by epitaxially growing SiC from the SiC semiconductor wafer 16. The thickness of the SiC epitaxial layer 17 is less than the thickness of the SiC semiconductor wafer 16.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

Next, referring to FIG. 12B, the modified layer 11, the depression 12 and the recess 13 are formed in the processed region 10, selectively set in the first main surface 2 of the 4H—SiC crystal structure body 1. The modified layer 11, the depression 12 and the recess 13 are formed through the same step as in FIG. 5B described above.

The modified layer 11, the depression 12 and the recess 13 are formed in the SiC epitaxial layer 17. More specifically, the modified layer 11, the depression 12 and the recess 13 cross the boundary between the SiC semiconductor wafer 16 and the SiC epitaxial layer 17 from the SiC epitaxial layer 17 and are formed in the SiC semiconductor wafer 16 as well.

Next, referring to FIG. 12C, the entirety of the modified layer 11 is removed while letting the 4H—SiC crystal structure body 1 remain. The modified layer 11 is removed through the same step as in FIG. 5C described above. The depression 12, defined by the SiC semiconductor wafer 16 and the SiC epitaxial layer 17, thereby remains in the first main surface 2.

In this step, the opening side corner portion of the depression 12 is rounded to shapes curved toward the inner side of the depression 12. Also, the bottom portion side corner portion of the depression 12 is rounded to shapes curved toward the outer side of the depression 12. By the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

Next, referring to FIG. 12D, the 4H—SiC crystal structure body 1 may be cleaved with the depression 12 as the starting point. The 4H—SiC crystal structure body 1 may be cleaved through the same step as in FIG. 5D described above. If the impurity concentration of the SiC semiconductor wafer 16 is higher than the impurity concentration of the SiC epitaxial layer 17, the damping rate of laser light with respect to the SiC semiconductor wafer 16 is higher than the damping rate of laser light with respect to the SiC epitaxial layer 17.

Therefore by irradiating the laser light such that it reaches the SiC semiconductor wafer 16, the SiC semiconductor wafer 16 can be heated efficiently. In particular in this step, the SiC semiconductor wafer 16 exposed from the bottom portion of the depression 12 can be heated directly by the laser light.

The compressive stress generated in the depression 12 heating step and the tensile stress generated in the depression 12 cooling step can thereby be increased efficiently. The cleaving force applied to the 4H—SiC crystal structure body 1 can thus be increased efficiently. The cleaved 4H—SiC crystal structure body 1 has the cleavage surfaces 14. The cleavage surfaces 14 are continuous to the inclining portions 15 constituted of the residual portions of the depression 12.

As described above, by the present SiC processing method, the outer surface of the SiC epitaxial layer 17 can be processed by the modified layer 11 forming step and the modified layer 11 removing step. In addition, the 4H—SiC crystal structure body 1 can also be cleaved using the depression 12 formed in the SiC epitaxial layer 17 through the modified layer 11 removing step.

In particular, by the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

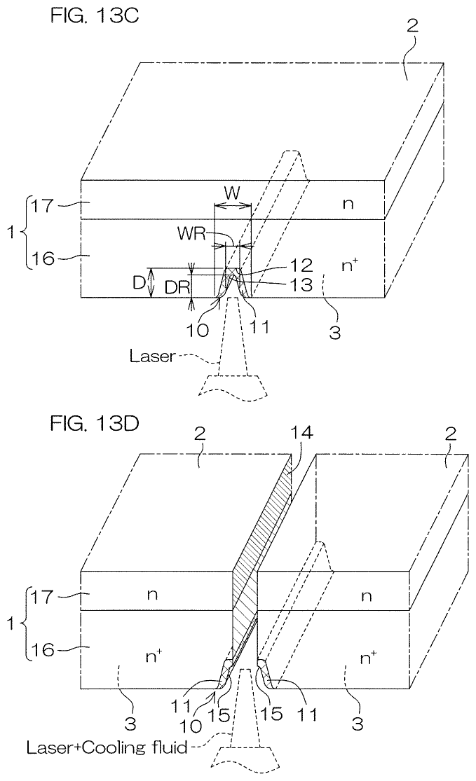

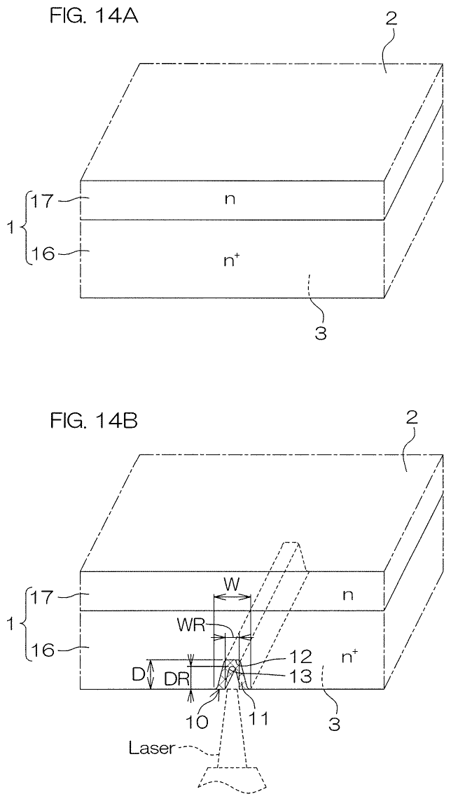

FIG. 13A to FIG. 13D are sectional perspective views of a partial region of the 4H—SiC crystal structure body 1 shown in FIG. 3 and are for describing an SiC processing method according to a seventh preferred embodiment of the present invention. In the following, description of structures and manufacturing steps corresponding to structures and manufacturing steps described with FIG. 5A to FIG. 5D shall be omitted.

First, referring to FIG. 13A, the 4H—SiC crystal structure body 1 is prepared as an example of the SiC processing object. In this embodiment, the 4H—SiC crystal structure body 1 has the laminated structure that includes the SiC semiconductor wafer 16 and the SiC epitaxial layer 17. The SiC epitaxial layer 17 may have an impurity concentration (for example, an n type impurity concentration) less than the impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

Next, referring to FIG. 13B, the modified layer 11, the depression 12 and the recess 13 are formed in the processed region 10, selectively set in the second main surface 3 of the 4H—SiC crystal structure body 1 instead of the first main surface 2 of the 4H—SiC crystal structure body 1. The modified layer 11, the depression 12 and the recess 13 are formed in the SiC semiconductor wafer 16. The modified layer 11, the depression 12 and the recess 13 are formed in the second main surface 3 through the same step as in FIG. 5B described above.

The depression 12 includes the bottom portion and the side portion. The depression 12 may be formed in a convergent shape that narrows in opening width from the second main surface 3 toward the bottom portion. The bottom portion of the depression 12 may be formed in a shape curved toward the first main surface 2. The depression 12 includes the opening side corner portion and the bottom portion side corner portion. The opening side corner portion of the depression 12 connects the second main surface 3 and the side portion of the depression 12. The bottom portion side corner portion of the depression 12 connects the bottom portion and the side portion of the depression 12.

The width W of the depression 12 may exceed 0 μm and be not more than 10 μm. The width W of the depression 12 is the width in the direction orthogonal to the direction in which the depression 12 extends. The width W of the depression 12 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the 4H—SiC crystal structure body 1 is not more than 150 μm, the width W of the depression 12 preferably exceeds 0 μm and is not more than 5 μm.

The depth D of the depression 12 may exceed 0 μm and be not more than 30 μm. The depth D of the depression 12 is the distance in the normal direction N from the second main surface 3 to the lowermost portion of the depression 12. The depth D of the depression 12 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the 4H—SiC crystal structure body 1 is not more than 150 μm, the depth D of the depression 12 preferably exceeds 0 μm and is not more than 15 μm.

The modified layer 11 is formed as a film along the inner wall of the depression 12. The thickness of the portion of the modified layer 11 covering the bottom wall of the depression 12 may be greater than the thickness of the portions of the modified layer 11 covering the side wall of the depression 12. The modified layer 11 may be formed in a uniform thickness along the inner wall of the depression 12.

Inside the depression 12, the modified layer 11 defines the recess 13. More specifically, the recess 13 is defined by the outer surface of the modified layer 11. The recess 13 includes the bottom portion and the side portion. The recess 13 may be formed in a convergent shape that narrows in opening width from the second main surface 3 toward the first main surface 2. The bottom portion of the recess 13 may be formed in a shape curved toward the first main surface 2.

The recess 13 includes the opening side corner portion and the bottom portion side corner portion. The opening side corner portion of the recess 13 connects the second main surface 3 and the side portion of the recess 13. The bottom portion side corner portion of the recess 13 connects the bottom portion and the side portion of the recess 13.

The width WR of the recess 13 is less than the width W of the depression 12. The width WR of the recess 13 may exceed 0 μm and be less than 10 μm. The width WR of the recess 13 may exceed 0 μm and be not more than 2.5 μm, be not less than 2.5 μm and not more than 5 μm, be not less than 5 μm and not more than 7.5 μm, or be not less than 7.5 μm and less than 10 μm. If the thickness of the 4H—SiC crystal structure body 1 is not more than 150 μm, the width WR of the recess 13 preferably exceeds 0 μm and is less than 5 μm.

The depth DR of the recess 13 is less than the depth D of the depression 12. The depth DR of the recess 13 may exceed 0 μm and be less than 30 μm. The depth DR of the recess 13 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and less than 30 μm. If the thickness of the 4H—SiC crystal structure body 1 is not more than 150 μm, the depth DR of the recess 13 preferably exceeds 0 μm and is not more than 15 μm.

Next, referring to FIG. 13C, the modified layer 11 is removed partially and the outer surface of the modified layer 11 is flattened while letting the 4H—SiC crystal structure body 1 remain. The modified layer 11 is removed through the same step as in FIG. 5C described above. The opening side corner portion of the recess 13 is thereby rounded to shapes curved toward the inner side of the recess 13. Also, the bottom portion side corner portion of the recess 13 is rounded to shapes curved toward the outer side of the recess 13.

By the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

Next, referring to FIG. 13D, the 4H—SiC crystal structure body 1 may be cleaved with the depression 12 as the starting point. The 4H—SiC crystal structure body 1 may be cleaved through the same step as in FIG. 5D described above. If the impurity concentration of the SiC semiconductor wafer 16 is higher than the impurity concentration of the SiC epitaxial layer 17, the damping rate of laser light with respect to the SiC semiconductor wafer 16 is higher than the damping rate of laser light with respect to the SiC epitaxial layer 17.

Therefore by irradiating the laser light such that it reaches the SiC semiconductor wafer 16, the SiC semiconductor wafer 16 can be heated efficiently. In particular in this step, the SiC semiconductor wafer 16 can be heated by the laser light via the modified layer 11. The compressive stress generated in the depression 12 heating step and the tensile stress generated in the depression 12 cooling step can thereby be increased efficiently. The cleaving force applied to the 4H—SiC crystal structure body 1 can thus be increased efficiently.

The cleaved 4H—SiC crystal structure body 1 has the cleavage surfaces 14. The cleavage surfaces 14 are continuous to the inclining portions 15 constituted of the residual portions of the depression 12. Portions of the modified layer 11 are exposed at the corner portions connecting the first main surface 2 of the 4H—SiC crystal structure body 1 and the cleavage surfaces 14. The modified layer 11 is formed along the inclining portions 15.

As described above, by the present SiC processing method, the outer surface of the SiC semiconductor wafer 16 can be processed by the modified layer 11 forming step and the modified layer 11 removing step. In addition, the 4H—SiC crystal structure body 1 can also be cleaved using the depression 12.

In particular, by the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

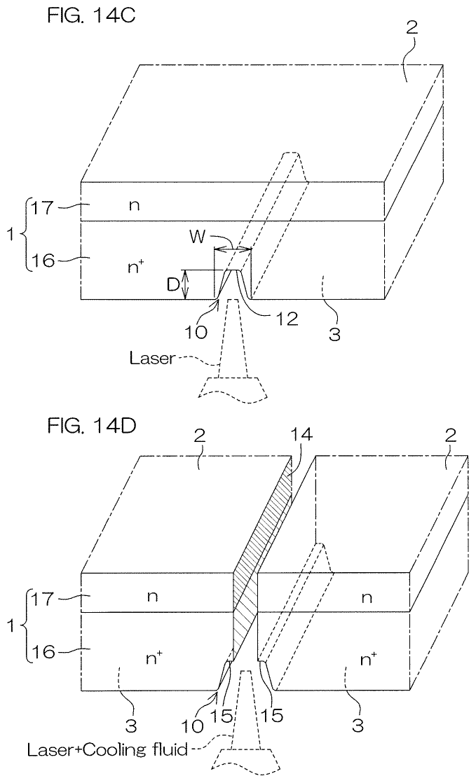

FIG. 14A to FIG. 14D are sectional perspective views of a partial region of the 4H—SiC crystal structure body 1 shown in FIG. 3 and are for describing an SiC processing method according to an eighth preferred embodiment of the present invention. In the following, description of structures and manufacturing steps corresponding to structures and manufacturing steps described with FIG. 5A to FIG. 5D shall be omitted.

First, referring to FIG. 14A, the 4H—SiC crystal structure body 1 is prepared as an example of the SiC processing object. In this embodiment, the 4H—SiC crystal structure body 1 has the laminated structure that includes the SiC semiconductor wafer 16 and the SiC epitaxial layer 17. The SiC epitaxial layer 17 may have an impurity concentration (for example, an n type impurity concentration) less than the impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The SiC epitaxial layer 17 is formed by epitaxially growing SiC from the SiC semiconductor wafer 16. The thickness of the SiC epitaxial layer 17 is less than the thickness of the SiC semiconductor wafer 16.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

Next, referring to FIG. 14B, the modified layer 11, the depression 12 and the recess 13 are formed in the processed region 10, selectively set in the second main surface 3 of the 4H—SiC crystal structure body 1 instead of the first main surface 2 of the 4H—SiC crystal structure body 1. The modified layer 11, the depression 12 and the recess 13 are formed in the SiC semiconductor wafer 16. The modified layer 11, the depression 12 and the recess 13 are formed in the second main surface 3 through the same step as in FIG. 5B described above.

The depression 12 includes the bottom portion and the side portion. The depression 12 may be formed in a convergent shape that narrows in opening width from the second main surface 3 toward the bottom portion. The bottom portion of the depression 12 may be formed in a shape curved toward the first main surface 2. The depression 12 includes the opening side corner portion and the bottom portion side corner portion. The opening side corner portion of the depression 12 connects the second main surface 3 and the side portion of the depression 12. The bottom portion side corner portion of the depression 12 connects the bottom portion and the side portion of the depression 12.

The width W of the depression 12 may exceed 0 μm and be not more than 10 μm. The width W of the depression 12 is the width in the direction orthogonal to the direction in which the depression 12 extends. The width W of the depression 12 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the 4H—SiC crystal structure body 1 is not more than 150 μm, the width W of the depression 12 preferably exceeds 0 μm and is not more than 5 μm.

The depth D of the depression 12 may exceed 0 μm and be not more than 30 μm. The depth D of the depression 12 is the distance in the normal direction N from the second main surface 3 to the lowermost portion of the depression 12. The depth D of the depression 12 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the 4H—SiC crystal structure body 1 is not more than 150 μm, the depth D of the depression 12 preferably exceeds 0 μm and is not more than 15 μm.

The modified layer 11 is formed as a film along the inner wall of the depression 12. The thickness of the portion of the modified layer 11 covering the bottom wall of the depression 12 may be greater than the thickness of the portions of the modified layer 11 covering the side wall of the depression 12. The modified layer 11 may be formed in a uniform thickness along the inner wall of the depression 12.

Inside the depression 12, the modified layer 11 defines the recess 13. More specifically, the recess 13 is defined by the outer surface of the modified layer 11. The recess 13 includes the bottom portion and the side portion. The recess 13 may be formed in a convergent shape that narrows in opening width from the second main surface 3 toward the first main surface 2. The bottom portion of the recess 13 may be formed in a shape curved toward the first main surface 2.

The recess 13 includes the opening side corner portion and the bottom portion side corner portion. The opening side corner portion of the recess 13 connects the second main surface 3 and the side portion of the recess 13. The bottom portion side corner portion of the recess 13 connects the bottom portion and the side portion of the recess 13.

The width WR of the recess 13 is less than the width W of the depression 12. The width WR of the recess 13 may exceed 0 μm and be less than 10 μm. The width WR of the recess 13 may exceed 0 μm and be not more than 2.5 μm, be not less than 2.5 μm and not more than 5 μm, be not less than 5 μm and not more than 7.5 μm, or be not less than 7.5 μm and less than 10 μm. If the thickness of the 4H—SiC crystal structure body 1 is not more than 150 μm, the width WR of the recess 13 preferably exceeds 0 μm and is less than 5 μm.

The depth DR of the recess 13 is less than the depth D of the depression 12. The depth DR of the recess 13 may exceed 0 μm and be less than 30 μm. The depth DR of the recess 13 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and less than 30 μm. If the thickness of the 4H—SiC crystal structure body 1 is not more than 150 μm, the depth DR of the recess 13 preferably exceeds 0 μm and is not more than 15 μm.

Next, referring to FIG. 14C, the entirety of the modified layer 11 is removed while letting the 4H—SiC crystal structure body 1 remain. The modified layer 11 is removed through the same step as in FIG. 5C described above. The depression 12, defined by the SiC semiconductor wafer 16, thereby remains in the second main surface 3. In this step, the opening side corner portion of the depression 12 is rounded to shapes curved toward the inner side of the depression 12. Also, the bottom portion side corner portion of the depression 12 is rounded to shapes curved toward the outer side of the depression 12.

By the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

Next, referring to FIG. 14D, the 4H—SiC crystal structure body 1 may be cleaved with the depression 12 as the starting point. The 4H—SiC crystal structure body 1 may be cleaved through the same step as in FIG. 5D described above. If the impurity concentration of the SiC semiconductor wafer 16 is higher than the impurity concentration of the SiC epitaxial layer 17, the damping rate of laser light with respect to the SiC semiconductor wafer 16 is higher than the damping rate of laser light with respect to the SiC epitaxial layer 17.

Therefore by irradiating the laser light such that it reaches the SiC semiconductor wafer 16, the SiC semiconductor wafer 16 can be heated efficiently. In particular in this step, a portion of the SiC semiconductor wafer 16 exposed from the bottom portion of the depression 12 can be heated directly by the laser light.

The compressive stress generated in the depression 12 heating step and the tensile stress generated in the depression 12 cooling step can thereby be increased efficiently. The cleaving force applied to the 4H—SiC crystal structure body 1 can thus be increased efficiently. The cleaved 4H—SiC crystal structure body 1 has the cleavage surfaces 14. The cleavage surfaces 14 are continuous to the inclining portions 15 constituted of the residual portions of the depression 12.

As described above, by the present SiC processing method, the outer surface of the SiC semiconductor wafer 16 can be processed by the modified layer 11 forming step and the modified layer 11 removing step. In addition, the 4H—SiC crystal structure body 1 can also be cleaved using the depression 12.

In particular, by the depression 12 that is rounded at the opening side corner portion, the concentration of stress on the depression 12 can be relaxed at the opening side corner portion. Also, by the depression 12 that is rounded at the bottom portion side corner portion, the concentration of stress on the depression 12 can be relaxed at the bottom portion side corner portion. Undesirable cracks due to the stress on the depression 12 can thereby be suppressed.

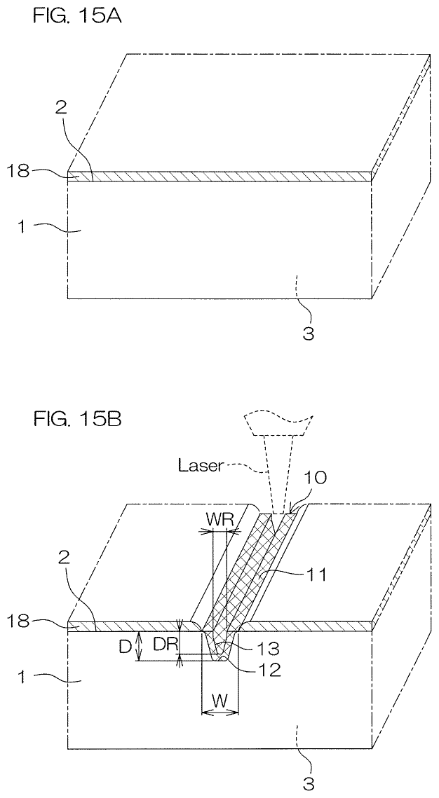

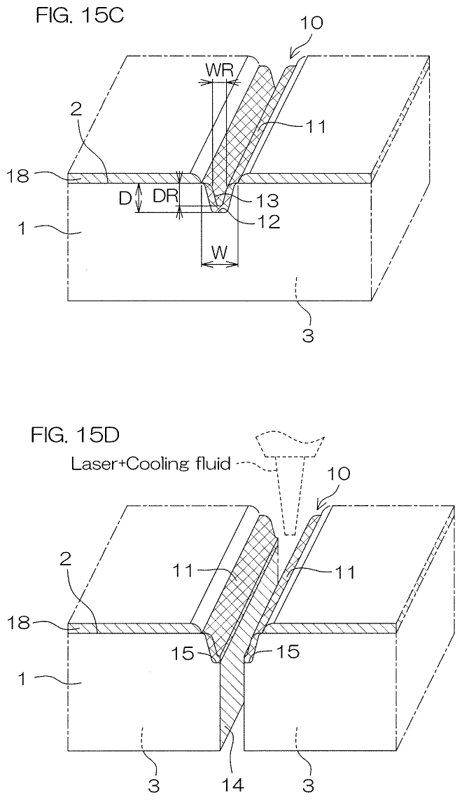

FIG. 15A to FIG. 15D are sectional perspective views of a partial region of the 4H—SiC crystal structure body 1 shown in FIG. 3 and are for describing an SiC processing method according to a ninth preferred embodiment of the present invention. In the following, description of structures and manufacturing steps corresponding to structures and manufacturing steps described with FIG. 5A to FIG. 5D shall be omitted.

First, referring to FIG. 15A, the 4H—SiC crystal structure body 1 is prepared as an example of the SiC processing object. In this embodiment, a covering layer 18 covering the first main surface 2 of the 4H—SiC crystal structure body 1 is formed on the first main surface 2. The covering layer 18 may have a single layer structure constituted of a metal layer or an insulating layer. The covering layer 18 may have a laminated structure that includes a metal layer and an insulating layer.

As examples of an insulating material of the covering layer 18, silicon oxide or silicon nitride can be cited. As examples of a metal material of the covering layer 18, aluminum, copper, gold, titanium, titanium nitride, etc., can be cited. The covering layer 18 may be formed by at least one method among an oxidation processing method, a CVD method, a sputtering method, a vapor deposition method and a plating method.

Next, referring to FIG. 15B, the modified layer 11, the depression 12 and the recess 13 are formed in the processed region 10 selectively set in the first main surface 2 of the 4H—SiC crystal structure body 1. The modified layer 11, the depression 12 and the recess 13 are formed in the first main surface 2 through the same step as in FIG. 5B described above.

In this step, the laser light is irradiated onto the first main surface 2 via the covering layer 18. The covering layer 18 is melted or sublimated by the irradiation of the laser light. The first main surface 2 is thereby exposed from the covering layer 18. Also, the laser light is continuously irradiated onto a portion of the first main surface 2 exposed from the covering layer 18.

The modified layer 11, the depression 12 and the recess 13 are thereby formed in the first main surface 2. The depression 12 may be in communication with a portion from which the covering layer 18 was removed. The modified layer 11 may cover the covering layer 18. The modified layer 11 may cover the portion from which the covering layer 18 was removed.

Here, an example where the step of irradiating the laser light onto the 4H—SiC crystal structure body 1 is performed at the same time as the step of irradiating the laser light onto covering layer 18 was described. However, the step of irradiating the laser light onto the 4H—SiC crystal structure body 1 may be performed, upon changing an irradiation condition, etc., after the step of irradiating the laser light onto the covering layer 18.

A damping rate of the laser light with respect to the covering layer 18 is preferably not less than a damping rate of the laser light with respect to the 4H—SiC crystal structure body 1. The covering layer 18 can thereby be melted or sublimated efficiently by the laser energy for the 4H—SiC crystal structure body 1.

Next, referring to FIG. 15C, the modified layer 11 is removed partially and the outer surface of the modified layer 11 is flattened while letting the 4H—SiC crystal structure body 1 and the covering layer 18 remain. The modified layer 11 is removed through the same step as in FIG. 5C described above.

The modified layer 11 has a component differing from that of the covering layer 18. The etching rate (etching selectivity) with respect to the modified layer 11 differs from an etching rate (etching selectivity) with respect to the covering layer 18. A portion of the modified layer 11 can thus be removed while letting the 4H—SiC crystal structure body 1 and the covering layer 18 remain. The opening side corner portion of the recess 13 is thereby rounded to shapes curved toward the inner side of the recess 13. Also, the bottom portion side corner portion of the recess 13 is rounded to shapes curved toward the outer side of the recess 13.

By the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

Next, referring to FIG. 15D, the 4H—SiC crystal structure body 1 may be cleaved with the depression 12 as the starting point. The 4H—SiC crystal structure body 1 may be cleaved through the same step as in FIG. 5D described above. The cleaved 4H—SiC crystal structure body 1 has the cleavage surfaces 14. The cleavage surfaces 14 are continuous to the inclining portions 15 constituted of the residual portions of the depression 12. Also, the inclining portions 15 are exposed from the covering layer 18.

As described above, by the present SiC processing method, the outer surface of the 4H—SiC crystal structure body 1 can be processed by the modified layer 11 forming step and the modified layer 11 removing step. In addition, the 4H—SiC crystal structure body 1 can also be cleaved using the depression 12 formed in the outer surface of the 4H—SiC crystal structure body 1 through the modified layer 11 removing step.

In particular, by the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

With the present preferred embodiment, an example where a portion of the modified layer 11 is removed from the first main surface 2 of the 4H—SiC crystal structure body 1 in the step of FIG. 15C was described. However, in the step of FIG. 15C, the entirety of the modified layer 11 may be removed. The manufacturing method with which the covering layer 18 is formed is also applicable to the first preferred embodiment to the eighth preferred embodiment described above.

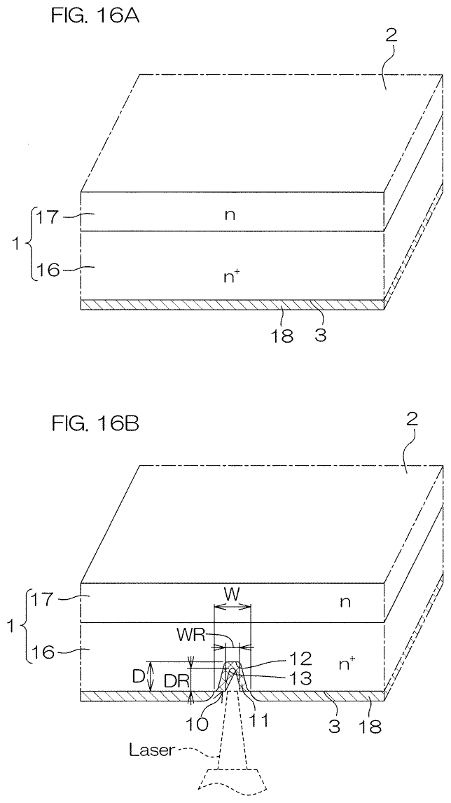

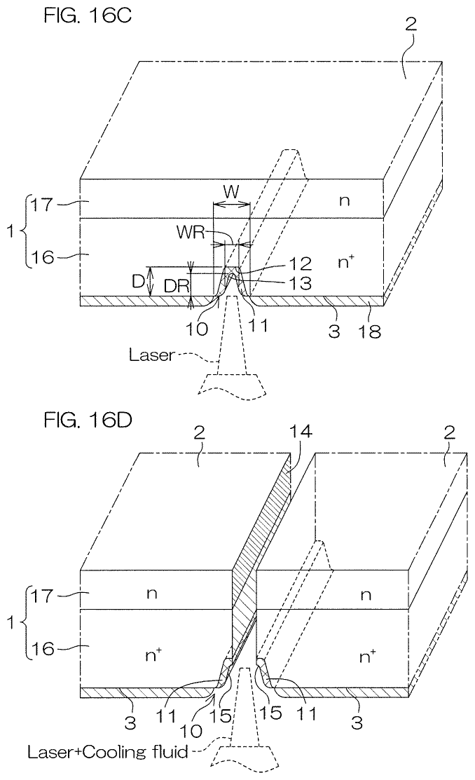

FIG. 16A to FIG. 16D are sectional perspective views of a partial region of the 4H—SiC crystal structure body 1 shown in FIG. 3 and are for describing an SiC processing method according to a tenth preferred embodiment of the present invention. In the following, description of structures and manufacturing steps corresponding to structures and manufacturing steps described with FIG. 5A to FIG. 5D shall be omitted.

First, referring to FIG. 16A, the 4H—SiC crystal structure body 1 is prepared as an example of the SiC processing object. In this embodiment, the 4H—SiC crystal structure body 1 has the laminated structure that includes the SiC semiconductor wafer 16 and the SiC epitaxial layer 17. The SiC epitaxial layer 17 may have an impurity concentration (for example, an n type impurity concentration) less than the impurity concentration (for example, an n type impurity concentration) of the SiC semiconductor wafer 16.

The first main surface 2 of the 4H—SiC crystal structure body 1 is formed by the SiC epitaxial layer 17. The second main surface 3 of the 4H—SiC crystal structure body 1 is formed by the SiC semiconductor wafer 16. The side surface 4 of the 4H—SiC crystal structure body 1 is formed by the SiC semiconductor wafer 16 and the SiC epitaxial layer 17.

The SiC epitaxial layer 17 is formed by epitaxially growing SiC from the SiC semiconductor wafer 16. The thickness of the SiC epitaxial layer 17 is less than the thickness of the SiC semiconductor wafer 16.

The thickness of the SiC semiconductor wafer 16 may be not less than 1 μm and less than 1000 μm. The thickness of the SiC semiconductor wafer 16 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC epitaxial layer 17 may be not less than 1 μm and not more than 100 μm. The thickness of the SiC epitaxial layer 17 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm.

In this embodiment, the covering layer 18 covering the second main surface 3 of the 4H—SiC crystal structure body 1 is formed on the second main surface 3. The covering layer 18 may have a single layer structure constituted of a metal layer or an insulating layer. The covering layer 18 may have a laminated structure that includes a metal layer and an insulating layer.

As examples of the insulating material of the covering layer 18, silicon oxide or silicon nitride can be cited. As examples of the metal material of the covering layer 18, aluminum, copper, gold, titanium, titanium nitride, etc., can be cited. The covering layer 18 may be formed by at least one method among the oxidation processing method, the CVD method, the sputtering method, the vapor deposition method, and the plating method.

Next, referring to FIG. 16B, the modified layer 11, the depression 12 and the recess 13 are formed in the processed region 10, selectively set in the second main surface 3 of the 4H—SiC crystal structure body 1 instead of the first main surface 2 of the 4H—SiC crystal structure body 1. The modified layer 11, the depression 12 and the recess 13 are formed in the second main surface 3 through the same step as in FIG. 5B described above.

In this step, the laser light is irradiated onto the second main surface 3 via the covering layer 18. The covering layer 18 is melted or sublimated by the irradiation of the laser light. The second main surface 3 is thereby exposed from the covering layer 18. Also, the laser light is continuously irradiated onto a portion of the second main surface 3 exposed from the covering layer 18. The modified layer 11, the depression 12 and the recess 13 are thereby formed in the second main surface 3.

Here, an example where the step of irradiating the laser light onto the 4H—SiC crystal structure body 1 is performed at the same time as the step of irradiating the laser light onto covering layer 18 was described. However, the step of irradiating the laser light onto the 4H—SiC crystal structure body 1 may be performed, upon changing an irradiation condition, etc., after the step of irradiating the laser light onto the covering layer 18.

The damping rate of the laser light with respect to the covering layer 18 is preferably not less than the damping rate of the laser light with respect to the 4H—SiC crystal structure body 1. The covering layer 18 can thereby be melted or sublimated efficiently by the laser energy for the 4H—SiC crystal structure body 1.

The depression 12 includes the bottom portion and the side portion. The depression 12 may be formed in a convergent shape that narrows in opening width from the second main surface 3 toward the bottom portion. The bottom portion of the depression 12 may be formed in a shape curved toward the first main surface 2. The depression 12 includes the opening side corner portion and the bottom portion side corner portion. The opening side corner portion of the depression 12 connects the second main surface 3 and the side portion of the depression 12. The bottom portion side corner portion of the depression 12 connects the bottom portion and the side portion of the depression 12. The depression 12 may be in communication with the portion from which the covering layer 18 was removed.

The width W of the depression 12 may exceed 0 μm and be not more than 10 μm. The width W of the depression 12 is the width in the direction orthogonal to the direction in which the depression 12 extends. The width W of the depression 12 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the 4H—SiC crystal structure body 1 is not more than 150 μm, the width W of the depression 12 preferably exceeds 0 μm and is not more than 5 μm.

The depth D of the depression 12 may exceed 0 μm and be not more than 30 μm. The depth D of the depression 12 is the distance in the normal direction N from the second main surface 3 to the lowermost portion of the depression 12. The depth D of the depression 12 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the 4H—SiC crystal structure body 1 is not more than 150 μm, the depth D of the depression 12 preferably exceeds 0 μm and is not more than 15 μm.

The modified layer 11 is formed as a film along the inner wall of the depression 12. The thickness of a portion of the modified layer 11 covering a bottom surface of the depression 12 may be greater than the thickness of the portions of the modified layer 11 covering the side wall of the depression 12. The modified layer 11 may be formed in a uniform thickness along the inner wall of the depression 12. The modified layer 11 may cover the covering layer 18. The modified layer 11 may cover the portion from which the covering layer 18 was removed.

Inside the depression 12, the modified layer 11 defines the recess 13. More specifically, the recess 13 is defined by the outer surface of the modified layer 11. The recess 13 includes the bottom portion and the side portion. The recess 13 may be formed in a convergent shape that narrows in opening width from the second main surface 3 toward the first main surface 2. The bottom portion of the recess 13 may be formed in a shape curved toward the first main surface 2.

The recess 13 includes the opening side corner portion and the bottom portion side corner portion. The opening side corner portion of the recess 13 connects the second main surface 3 and the side portion of the recess 13. The bottom portion side corner portion of the recess 13 connects the bottom portion and the side portion of the recess 13.

The width WR of the recess 13 is less than the width W of the depression 12. The width WR of the recess 13 may exceed 0 μm and be less than 10 μm. The width WR of the recess 13 may exceed 0 μm and be not more than 2.5 μm, be not less than 2.5 μm and not more than 5 μm, be not less than 5 μm and not more than 7.5 μm, or be not less than 7.5 μm and less than 10 μm. If the thickness of the 4H—SiC crystal structure body 1 is not more than 150 μm, the width WR of the recess 13 preferably exceeds 0 μm and is less than 5 μm.

The depth DR of the recess 13 is less than the depth D of the depression 12. The depth DR of the recess 13 may exceed 0 μm and be less than 30 μm. The depth DR of the recess 13 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and less than 30 μm. If the thickness of the 4H—SiC crystal structure body 1 is not more than 150 μm, the depth DR of the recess 13 preferably exceeds 0 μm and is not more than 15 μm.

Next, referring to FIG. 16C, the modified layer 11 is removed partially and the outer surface of the modified layer 11 is flattened while letting the 4H—SiC crystal structure body 1 and the covering layer 18 remain. The modified layer 11 is removed through the same step as in FIG. 5C described above.

The modified layer 11 has a component differing from that of the covering layer 18. The etching rate (etching selectivity) with respect to the modified layer 11 differs from the etching rate (etching selectivity) with respect to the covering layer 18. A portion of the modified layer 11 can thus be removed while letting the 4H—SiC crystal structure body 1 and the covering layer 18 remain. The opening side corner portion of the recess 13 is thereby rounded to shapes curved toward the inner side of the recess 13. Also, the bottom portion side corner portion of the recess 13 is rounded to shapes curved toward the outer side of the recess 13.

By the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

Next, referring to FIG. 16D, the 4H—SiC crystal structure body 1 may be cleaved with the depression 12 as the starting point. The 4H—SiC crystal structure body 1 may be cleaved through the same step as in FIG. 5D described above. The cleaved 4H—SiC crystal structure body 1 has the cleavage surfaces 14. The cleavage surfaces 14 are continuous to the inclining portions 15 constituted of the residual portions of the depression 12. Also, the inclining portions 15 are exposed from the covering layer 18.

As described above, by the present SiC processing method, the outer surface of the 4H—SiC crystal structure body 1 can be processed by the modified layer 11 forming step and the modified layer 11 removing step. In addition, the 4H—SiC crystal structure body 1 can also be cleaved using the depression 12 formed in the outer surface of the 4H—SiC crystal structure body 1 through the modified layer 11 removing step.

In particular, by the recess 13 that is rounded at the opening side corner portion, the concentration of stress on the modified layer 11 can be relaxed at the opening side corner portion. Also, by the recess 13 that is rounded at the bottom portion side corner portion, the concentration of stress on the modified layer 11 can be relaxed at the bottom portion side corner portion. Undesirable cracks due to the stress on the modified layer 11 can thereby be suppressed.

With the present preferred embodiment, an example where a portion of the modified layer 11 is removed in the step of FIG. 16C was described. However, in the step of FIG. 16C, the entirety of the modified layer 11 may be removed. The manufacturing method with which the covering layer 18 is formed is also applicable to the first preferred embodiment to the eighth preferred embodiment described above.

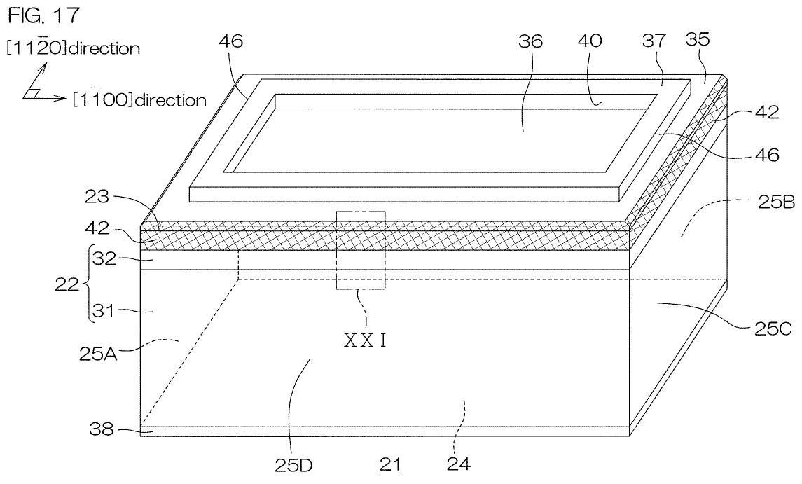

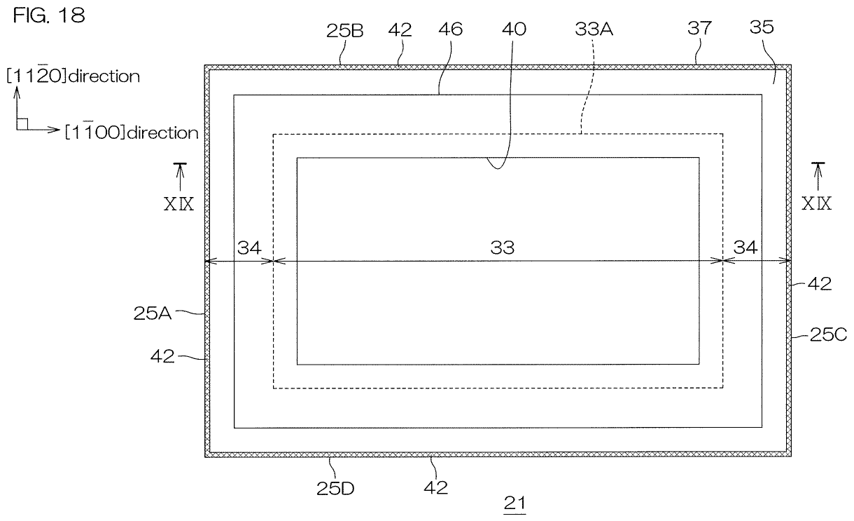

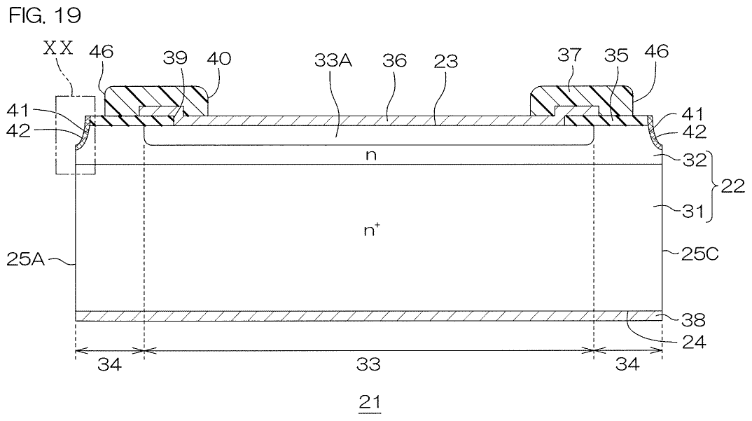

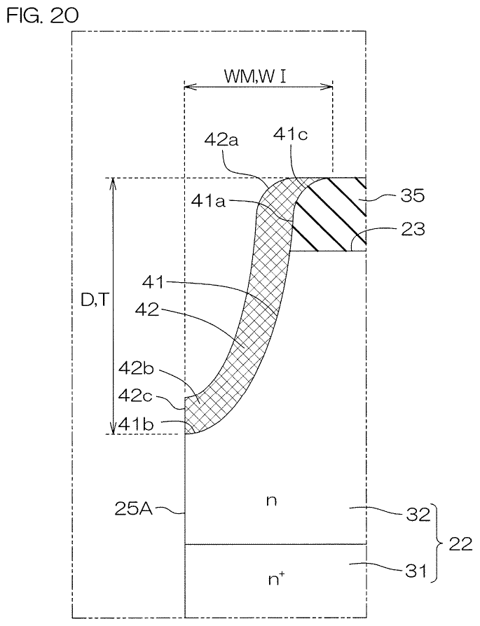

FIG. 17 is a perspective view of the general arrangement of an SiC semiconductor device 21 according to an eleventh preferred embodiment of the present invention. FIG. 18 is a plan view of the SiC semiconductor device 21 shown in FIG. 17. FIG. 19 is a sectional view taken along line XIX-XIX shown in FIG. 18. FIG. 20 is an enlarged view of a region XX shown in FIG. 19. The SiC semiconductor device 21 is a device manufactured using the 4H—SiC crystal structure body 1 described above.

Referring to FIG. 17 to FIG. 20, the SiC semiconductor device 21 includes an SiC semiconductor layer 22. A thickness of the SiC semiconductor layer 22 may be not less than 1 μm and less than 1000 μm. The thickness of the SiC semiconductor layer 22 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The SiC semiconductor layer 22 has a first main surface 23 at one side, a second main surface 24 at another side, and side surfaces 25A, 25B, 25C and 25D connecting the first main surface 23 and the second main surface 24. In this embodiment, the side surfaces 25A to 25D are all constituted of cut surfaces. More specifically, the side surfaces 25A to 25D are constituted of cleavage surfaces.

The first main surface 23 and the second main surface 24 are formed in quadrilateral shapes (rectangular shapes in this embodiment) in a plan view as viewed in a normal direction N to the surfaces (hereinafter referred to simply as “plan view”). The side surface 25A opposes the side surface 25C. The side surface 25B opposes the side surface 25D.

The SiC semiconductor layer 22 includes a 4H—SiC monocrystal. The first main surface 23 and the second main surface 24 face the c planes of the 4H—SiC monocrystal. The first main surface 23 faces the (0001) plane and the second main surface 24 faces the (000-1) plane.

The first main surface 23 and the second main surface 24 have an off angle θ inclined at an angle of not more than 100 in the [11-20] direction with respect to the (0001) plane. The off angle θ may be not less than 0° and not more than 2°, not less than 2° and not more than 4°, not less than 4° and not more than 6°, not less than 6° and not more than 8°, or not less than 8° and not more than 10°. The off angle θ is preferably not less than 0° and not more than 4°.

A state where the off angle θ is 0° is that in which the normal direction N and the c axis are matched. The off angle θ may exceed 0° and be less than 4°. The off angle θ is typically 2° or 4° and more specifically is set in a range of 2°±10% or a range of 4°±10%.

The side surfaces 25A to 25D respectively extend as planes along the normal direction N. A length of each of the side surfaces 25A to 25D may be not less than 1 mm and not more than 10 mm. The length of the side surfaces 25A to 25D may be not less than 1 mm and not more than 2.5 mm, not less than 2.5 mm and not more than 5 mm, not less than 5 mm and not more than 7.5 mm, or not less than 7.5 mm and not more than 10 mm. The length of the side surfaces 25A to 25D is preferably not less than 2 mm and not more than 5 mm.

The side surfaces 25A to 25D extend in a nearest neighbor direction and a nearest neighbor direction intersecting direction. More specifically, the nearest neighbor direction intersecting direction is an orthogonal direction orthogonal to the nearest neighbor direction. In this embodiment, the side surfaces 25A to 25D extend in the [11-20] direction and the [1-100] direction.

The side surface 25A and the side surface 25C are formed along the [11-20] direction. The side surface 25B and the side surface 25D are formed along the [1-100] direction. The side surface 25A and the side surface 25C may be formed along the [1-100] direction and the side surface 25B and the side surface 25D may be formed along the [11-20] direction instead.

In-plane variations of the side surfaces 25A to 25D are not more than 20 μm. The in-plane variations along the [11-20] direction of the side surfaces 25B and 25D that extend along the [1-100] direction are not more than 20 μm. More specifically the in-plane variations of the side surfaces 25B and 25D are not more than 10 μm.

The in-plane variations along the [1-100] direction of the side surfaces 25A and 25C that extend along the [11-20] direction are not more than 20 μm. More specifically, the in-plane variations of the side surfaces 25A and 25C are not more than 10 μm.

An in-plane variation is defined by a maximum value of distances between a reference virtual line and measurement virtual lines set in one of the side surfaces 25A to 25D selected from the side surfaces 25A to 25D. The reference virtual line is a straight line joining two corner portions of the SiC semiconductor 22 in plan view and is set in the selected one of the side surfaces 25A to 25D. A measurement virtual line is a straight line extending in parallel to the reference virtual line in plan view and is set to be tangent to a top portion or a base portion of a bulge (tortuosity) present on the selected one of the side surfaces 25A to 25D.

For example, the distance between the reference virtual line and the measurement virtual line tangent to the top portion of a bulge (tortuosity) and the distance between the reference virtual line and the measurement virtual line tangent to the base portion of the bulge (tortuosity) are measured. The in-plane variation of the selected one of the side surfaces 25A to 25D is defined by the maximum value of the measured distances between the reference virtual line and the measured virtual lines.

In this embodiment, the SiC semiconductor layer 22 has a laminated structure that includes an n⁺ type SiC semiconductor substrate 31 and an n type SiC epitaxial layer 32. The second main surface 24 of the SiC semiconductor layer 22 is formed by the SiC semiconductor substrate 31. The first main surface 23 of the SiC semiconductor layer 22 is formed by the SiC epitaxial layer 32. The side surfaces 25A to 25D of the SiC semiconductor layer 22 are formed by the SiC semiconductor substrate 31 and the SiC epitaxial layer 32.

A thickness of the SiC semiconductor substrate 31 may be not less than 1 μm and less than 1000 μm. The thickness of the SiC semiconductor substrate 31 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm. The thickness of the SiC semiconductor substrate 31 is preferably not less than 50 μm and not more than 150 μm. By making the thickness of the SiC semiconductor substrate 31 small, reduction of resistance value can be achieved by shortening of a current path.

The SiC epitaxial layer 32 has a thickness less than the thickness of the SiC semiconductor substrate 31. The thickness of the SiC epitaxial layer 32 may be not less than 1 μm and not more than 100 μm. The thickness of the SiC epitaxial layer 32 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm. The thickness of the SiC epitaxial layer 32 is preferably not less than 5 μm and not more than 20 μm.

An n type impurity concentration of the SiC epitaxial layer 32 is not more than an n type impurity concentration of the SiC semiconductor substrate 31. The n type impurity concentration of the SiC semiconductor substrate 31 may be not less than 1.0×10¹⁸ cm⁻³ and not more than 1.0×10²¹ cm⁻³. The n type impurity concentration of the SiC epitaxial layer 32 may be not less than 1.0×10¹⁵ cm⁻³ and not more than 1.0×10¹⁸ cm⁻³.

The SiC semiconductor layer 22 includes an active region 33 and an outer region 34. The active region 33 includes an impurity region 33A having an n type impurity and/or a p type impurity. The active region 33 is a region in which a semiconductor functional device is formed by the impurity region 33A. The semiconductor functional device may include a diode. The semiconductor functional device may include a transistor. The semiconductor functional device may include a field effect transistor.

In plan view, the active region 33 may be set in a central portion of the SiC semiconductor layer 22 at intervals toward an inner region from the side surfaces 25A to 25D. In plan view, the active region 33 may be set to a quadrilateral shape having four sides parallel to the four side surfaces 25A to 25D.

The outer region 34 is a region at an outer side of the active region 33. The outer region 34 may be set in a region between the side surfaces 25A to 25D and peripheral edges of the active region 33. In plan view, the outer region 34 may be set to an annular shape (for example, an endless shape) surrounding the active region 33.

The SiC semiconductor device 21 includes an insulating layer 35 formed on the first main surface 23. The insulating layer 35 selectively covers the first main surface 23. The insulating layer 35 may include silicon oxide or silicon nitride. A peripheral edge portion of the insulating layer 35 is continuous to the side surfaces 25A to 25D. An opening 39 selectively exposing the active region 33 is formed in the insulating layer 35.

The SiC semiconductor device 21 includes a first electrode layer 36 formed on the first main surface 23. More specifically, the first electrode layer 36 is formed on the insulating layer 35. The first electrode layer 36 may include a conductive polysilicon or a metal. The first electrode layer 36 enters into the opening 39 from above the insulating layer 35. Inside the opening 39, the first electrode layer 36 is electrically connected to the active region 33.

The SiC semiconductor device 21 includes a resin layer 37 formed on the first main surface 23. More specifically, the resin layer 37 is formed on the insulating layer 35. The resin layer 37 selectively covers the first electrode layer 36. A peripheral edge portion 46 of the resin layer 37 described above is formed at intervals toward an inner region from the side surfaces 25A to 25D. The resin layer 37 thereby exposes a peripheral edge portion of the SiC semiconductor layer 22 in plan view.

The resin layer 37 may include a negative type or positive type photosensitive resin. In this embodiment, the resin layer 37 includes a polybenzoxazole as an example of a positive type photosensitive resin. The resin layer 37 may include a polyimide as an example of a negative type photosensitive resin instead. An opening 40 exposing the first electrode layer 36 is formed in the resin layer 37.

The SiC semiconductor device 21 includes a second electrode layer 38 formed on the second main surface 24. The second electrode layer 38 covers the second main surface 24. The second electrode layer 38 is electrically connected to the second main surface 24. The second electrode layer 38 may include a conductive polysilicon or a metal.

An inclining portion 41 that inclines downwardly from the first main surface 23 of the SiC semiconductor layer 22 toward the side surfaces 25A to 25D is formed at corner portions connecting the first main surface 23 and the side surfaces 25A to 25D. The corner portions of the SiC semiconductor layer 22 include corner portions connecting the first main surface 23 and the side surfaces 25A and 25C and extending along the [11-20] direction. The corner portions of the SiC semiconductor layer 22 include corner portions connecting the first main surface 23 and the side surfaces 25B and 25D and extending along the [1-100] direction.

More specifically, the inclining portion 41 is formed in the SiC epitaxial layer 32. The inclining portion 41 is formed in a region at the first main surface 23 side with respect to a boundary region between the SiC semiconductor substrate 31 and the SiC epitaxial layer 32. The SiC epitaxial layer 32 is thus exposed from the inclining portion 41.

The inclining portion 41 is formed by an inner wall of a depression recessed from the first main surface 23 toward the second main surface 24. The inclining portion 41 has an upper side end portion 41a and a lower side end portion 41b. The upper side end portion 41a of the inclining portion 41 is positioned at the first main surface 23 side. The lower side end portion 41b of the inclining portion 41 is positioned at the second main surface 24 side.

The upper side end portion 41a of the inclining portion 41 extends from the SiC epitaxial layer 32 toward the insulating layer 35 and is continuous to the insulating layer 35. That is, the SiC epitaxial layer 32 and the insulating layer 35 are exposed from the inclining portion 41. Also, the peripheral edge portion of the insulating layer 35 is formed at an inner region of the SiC semiconductor layer 22 with respect to the side surfaces 25A to 25D.

The upper side end portion 41a of the inclining portion 41 is connected to an upper surface of the insulating layer 35. An upper side connection portion 41c of the inclining portion 41 that connects the upper side end portion 41a of the inclining portion 41 and the upper surface of the insulating layer 35 may be formed in a shape curved toward an outer side of the SiC semiconductor layer 22. The lower side end portion 41b of the inclining portion 41 is connected to the side surfaces 25A to 25D. The lower side end portion 41b of the inclining portion 41 may be formed in a shape curved toward the second main surface 24.

A width WI of the inclining portion 41 may be not more than the in-plane variations of the side surfaces 25A to 25D. The width WI of the inclining portion 41 may be less than the in-plane variations of the side surfaces 25A to 25D. The width WI of the inclining portion 41 is a width in a direction orthogonal to a direction in which the inclining portion 41 extends in plan view.

The width WI of the inclining portion 41 may exceed 0 μm and be not more than 10 μm. The width WI of the inclining portion 41 may exceed 0 μm and be not more than 2 μm, be not less than 2 μm and not more than 4 μm, be not less than 4 μm and not more than 6 μm, be not less than 6 μm and not more than 8 μm, or be not less than 8 μm and not more than 10 μm. If the thickness of the SiC semiconductor layer 22 is not more than 150 μm, the width WI of the inclining portion 41 preferably exceeds 0 μm and is not more than 5 μm. More preferably, the width WI of the inclining portion 41 exceeds 0 μm and is not more than 2.5 μm.

A depth D of the inclining portion 41 may exceed 0 μm and be not more than 30 μm. The depth D of the inclining portion 41 is a distance in the normal direction N from the first main surface 23 to the lower side end portion of the inclining portion 41. The depth D of the inclining portion 41 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 22 is not more than 150 μm, the depth D of the inclining portion 41 preferably exceeds 0 μm and is not more than 15 μm.

The SiC semiconductor device 21 includes a modified layer 42 which is formed in regions of the side surfaces 25A to 25D at the first main surface 23 side and in which the SiC is modified to a different property. In this embodiment, the modified layer is formed in the SiC epitaxial layer 32. More specifically, the modified layer 42 is formed in a region at the first main surface 23 side with respect to the boundary region between the SiC semiconductor substrate 31 and the SiC epitaxial layer 32.

The modified layer 42 is formed along the corner portions connecting the first main surface 23 and the side surfaces 25A to 25D. More specifically, the modified layer 42 is formed at the corner portions connecting the first main surface 23 and the side surfaces 25A and 25C and extending along the [11-20] direction. Also, the modified layer 42 is formed at the corner portions connecting the first main surface 23 and the side surfaces 25B and 25D and extending along the [1-100] direction.

The modified layer 42 extends as a band on the side surfaces 25A to 25D along directions parallel to the first main surface 23. That is, the modified layer 42 extends as a band along the [1-100] direction and the [11-20] direction. At the side surfaces 25A to 25D, the modified layer 42 is formed in an annular shape (for example, an endless shape) surrounding the active region 33.

The modified layer 42 is formed as a film along the inclining portion 41 of the SiC semiconductor layer 22. A thickness of a portion of the modified layer 42 covering a bottom wall of the inclining portion 41 may be greater than a thickness of a portion of the modified layer 42 covering a side wall of the inclining portion 41. The modified layer 42 may be formed in a uniform thickness along inner wall of the inclining portion 41.

The modified layer 42 includes an upper side covering portion 42a and a lower side covering portion 42b. The upper side covering portion 42a of the modified layer 42 covers the upper side end portion 41a of the inclining portion 41. The upper side covering portion 42a of the modified layer 42 covers the SiC epitaxial layer 32. The upper side covering portion 42a of the modified layer 42 extends from the SiC epitaxial layer 32 toward the insulating layer 35 and covers the insulating layer 35. The upper side covering portion 42a of the modified layer 42 may be formed in a shape curved toward the outer side of the SiC semiconductor layer 22.

The lower side covering portion 42b of the modified layer 42 covers the lower side end portion 41b of the inclining portion 41. The lower side covering portion 42b of the modified layer 42 covers the SiC epitaxial layer 32. The lower side covering portion 42b of the modified layer 42 includes a connection portion 42c connected to the side surfaces 25A to 25D. The connection portion 42c of the modified layer 42 may be a cleavage portion of the modified layer 42. The connection portion 42c of the modified layer 42 may be formed flush with the side surfaces 25A to 25D.

The modified layer 42 is exposed from the peripheral edge portion 46 of the resin layer 37. The peripheral edge portion 46 of the resin layer 37 is a portion in which dicing streets were formed in a process of cutting out the SiC semiconductor device 21 from the 4H—SiC crystal structure body 1. By exposing the modified layer 42 from the resin layer 37, it becomes unnecessary to physically cut the resin layer 37. The SiC semiconductor device 21 can thus be cut out smoothly from the 4H—SiC crystal structure body 1 while achieving appropriate protection of the active region 33 by the resin layer 37.

A width WM of the modified layer 42 may be not more than the in-plane variations of the side surfaces 25A to 25D. The width WM of the modified layer 42 may be less than the in-plane variations of the side surfaces 25A to 25D. The width WM of the modified layer 42 is a width in a direction orthogonal to a direction in which the modified layer 42 extends in plan view.

The width WM of the modified layer 42 may exceed 0 μm and be not more than 10 μm. The width WM of the modified layer 42 may exceed 0 μm and be not more than 2 μm, be not less than 2 μm and not more than 4 μm, be not less than 4 μm and not more than 6 μm, be not less than 6 μm and not more than 8 μm, or be not less than 8 μm and not more than 10 μm. If the thickness of the SiC semiconductor layer 22 is not more than 150 μm, the width WM of the modified layer 42 preferably exceeds 0 μm and is not more than 5 μm. More preferably, the width WM of the modified layer 42 exceeds 0 μm and is not more than 2.5 μm.

A thickness T of the modified layer 42 may exceed 0 μm and be not more than 30 μm. The thickness T of the modified layer 42 is a thickness of the modified layer 42 along the normal direction N. The thickness T of the modified layer 42 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 22 is not more than 150 μm, the thickness T of the modified layer 42 preferably exceeds 0 μm and is not more than 15 μm.

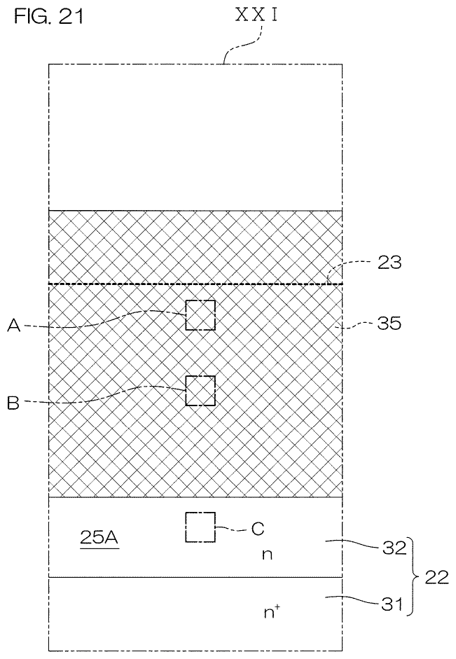

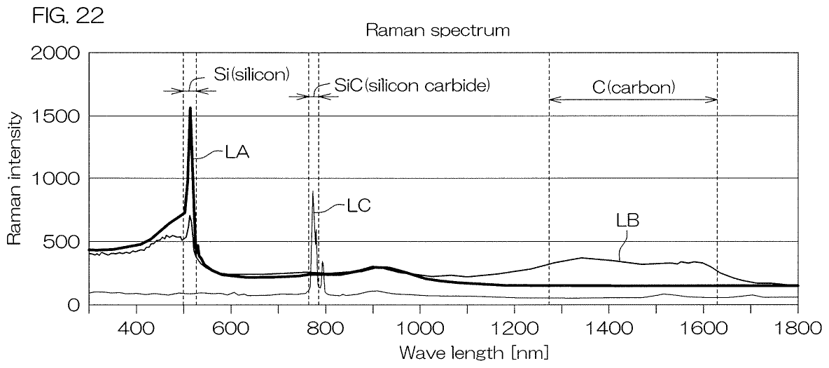

FIG. 21 is an enlarged view of a region XXI shown in FIG. 17. FIG. 22 is a graph of constituents of the modified layer 42. FIG. 22 shows results of examining the components of the SiC semiconductor layer 22 by the Raman spectroscopy method.

A first region A, a second region B, and a third region C are shown in FIG. 21. The first region A represents a surface layer portion of the modified layer 42. The surface layer portion of the modified layer 42 is a region of the modified layer 42 positioned at the first main surface 23 side of the SiC semiconductor layer 22 (here, the upper side covering portion 42a).

The second region B represents a bottom portion of the modified layer 42. The bottom portion of the modified layer 42 is a region of the modified layer 42 positioned at the second main surface 24 side with respect to the surface layer portion of the modified layer 42 (here, the lower side covering portion 42b). The third region C represents a region of the SiC semiconductor layer 22 outside the modified layer 42 (here, the SiC epitaxial layer 32).

A first curve LA, a second curve LB, and a third curve LC are shown in FIG. 22. The first curve LA represents components of the first region A shown in FIG. 21. The second curve LB represents components of the second region B shown in FIG. 21. The third curve LC represents components of the third region C shown in FIG. 21.

The first curve LA has a peak value derived from Si (silicon) in a wavelength range of not less than 500 nm and not more than 550 nm. The second curve LB has a peak value derived from Si (silicon) in the wavelength range of not less than 500 nm and not more than 550 nm and a peak value derived from C (carbon) in a wavelength range of not less than 1300 nm and not more than 1700 nm.

The third curve LC has a peak value derived from SiC (silicon carbide) in a wavelength range of not less than 750 nm and not more than 850 nm. Therefore in the third region C, the modified layer 42 is not formed and just the 4H—SiC monocrystal is present.

Referring to the first curve LA, a silicon density of the surface layer portion (first region A) of the modified layer 42 is higher than a carbon density of the surface layer portion of the modified layer 42. That is, the surface layer portion of the modified layer 42 includes an Si modified layer, in which the SiC of the 4H—SiC crystal structure body 1 is modified to Si. The Si modified layer may include an Si polycrystal. The Si modified layer may include amorphous Si. The Si modified layer may include an Si polycrystal and amorphous Si. The Si modified layer may include an Si amorphous layer as a main constituent.

Referring to the second curve LB, a silicon density of the bottom portion (second region B) of the modified layer 42 is higher than a carbon density of the bottom portion of the modified layer 42. The bottom portion of the modified layer 42 includes an Si modified layer, in which the SiC of the 4H—SiC crystal structure body 1 is modified to Si. The Si modified layer may include an Si polycrystal. The Si modified layer may include amorphous Si. The Si modified layer may include an Si polycrystal and amorphous Si. The Si modified layer may include an Si amorphous layer as a main constituent.

Referring to the first curve LA and the second curve LB, the modified layer 42 has mutually different components in the surface layer portion (first region A) and the bottom portion (second region B). More specifically, the modified layer 42 has a silicon density that differs along a thickness direction. The silicon density of the bottom portion of the modified layer 42 is lower than the silicon density of the surface layer portion of the modified layer 42. Also, the modified layer 42 has a carbon density that differs along the thickness direction. The carbon density of the bottom portion of the modified layer 42 is higher than the carbon density of the surface layer portion of the modified layer 42.

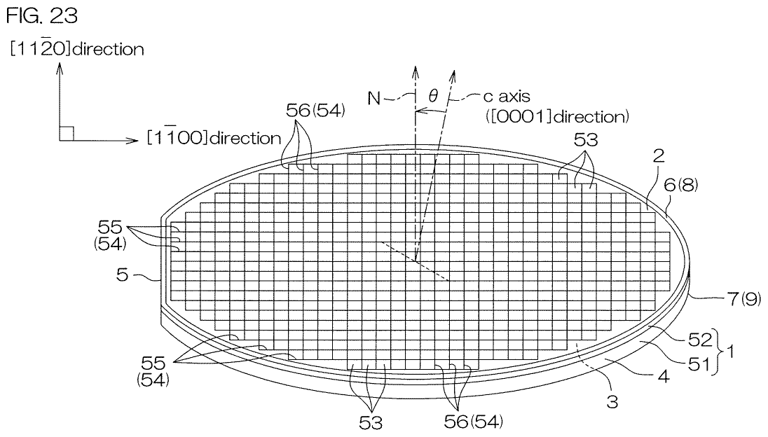

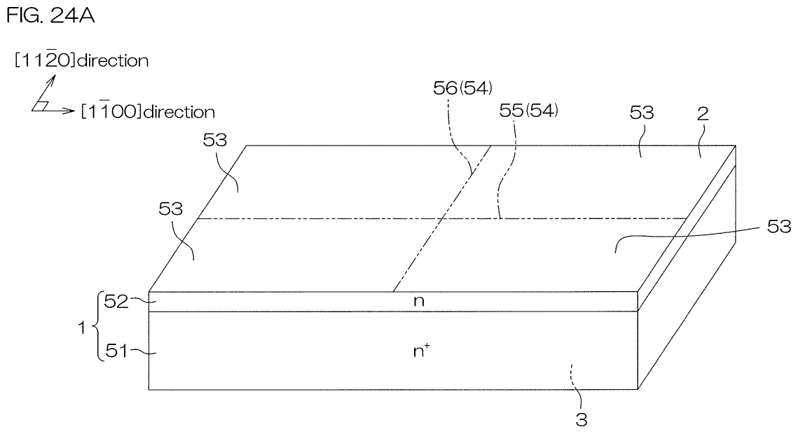

FIG. 23 is a perspective view of the 4H—SiC crystal structure body 1 used in manufacturing the SiC semiconductor device 21 shown in FIG. 17.

Referring to FIG. 23, in a method for manufacturing the SiC semiconductor device 21, the 4H—SiC crystal structure body 1 that has a laminated structure including an SiC semiconductor wafer 51 and an SiC epitaxial layer 52 is used. The SiC semiconductor wafer 51 is a base of the SiC semiconductor substrate 31. The SiC epitaxial layer 52 is a base of the SiC epitaxial layer 32. The SiC epitaxial layer 52 is formed by epitaxially growing SiC from the SiC semiconductor wafer 51.

The first main surface 2 of the 4H—SiC crystal structure body 1 is formed by the SiC epitaxial layer 52. The second main surface 3 of the 4H—SiC crystal structure body 1 is formed by the SiC semiconductor wafer 51. The side surface 4 of the 4H—SiC crystal structure body 1 is formed by the SiC semiconductor wafer 51 and the SiC epitaxial layer 52.

In the method for manufacturing the SiC semiconductor device 21, a plurality of device regions 53 corresponding to the SiC semiconductor devices 21 are set in the first main surface 2 of the 4H—SiC crystal structure body 1. The plurality of device regions 53 are set in a matrix array at intervals in the [1-100] direction and the [11-20] direction. Each of the device regions 53 has sides oriented along the [1-100] direction and sides oriented along the [11-20] direction.

The plurality of device regions 53 are defined by lattice-shaped intended cutting lines 54 extending along the [1-100] direction and the [11-20] direction. More specifically, the intended cutting lines 54 include a plurality of first intended cutting lines 55 and a plurality of second intended cutting lines 56. The plurality of first intended cutting lines 55 respectively extend along the [1-100] direction. The plurality of second intended cutting lines 56 respectively extend along the [11-20] direction.

After predetermined structures are formed in the 4H—SiC crystal structure body 1, the plurality of SiC semiconductor devices 21 are cut out by cutting the 4H—SiC crystal structure body 1 along the intended cutting lines 54.

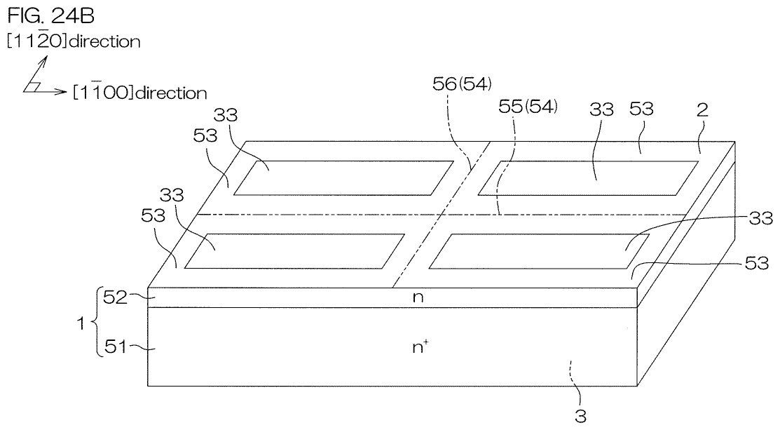

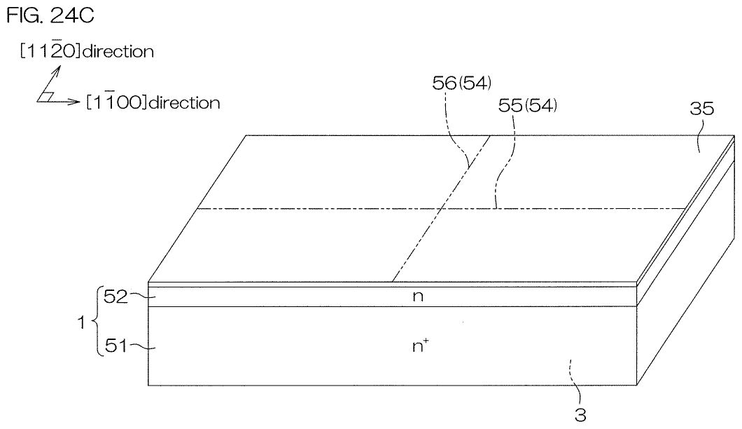

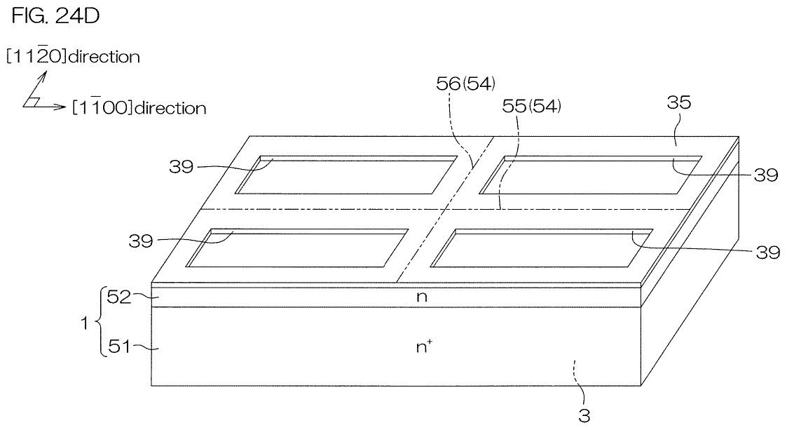

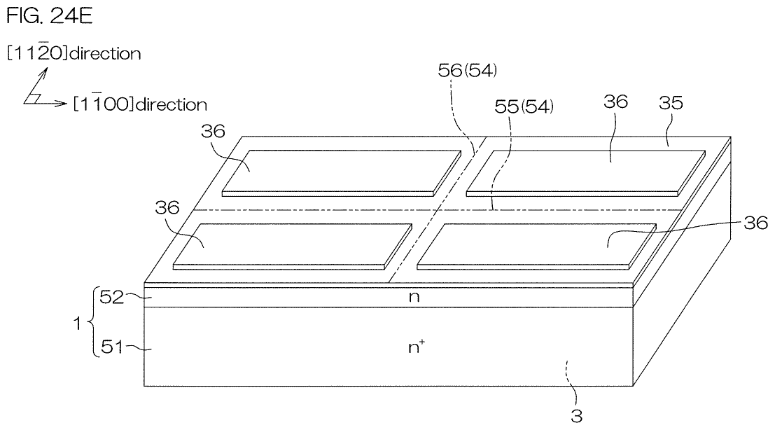

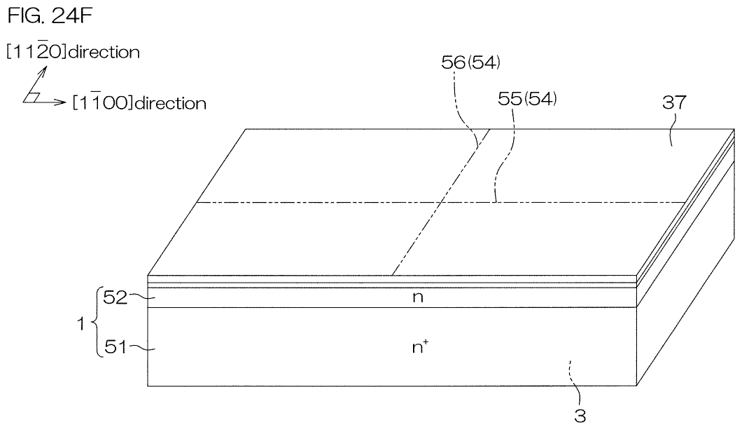

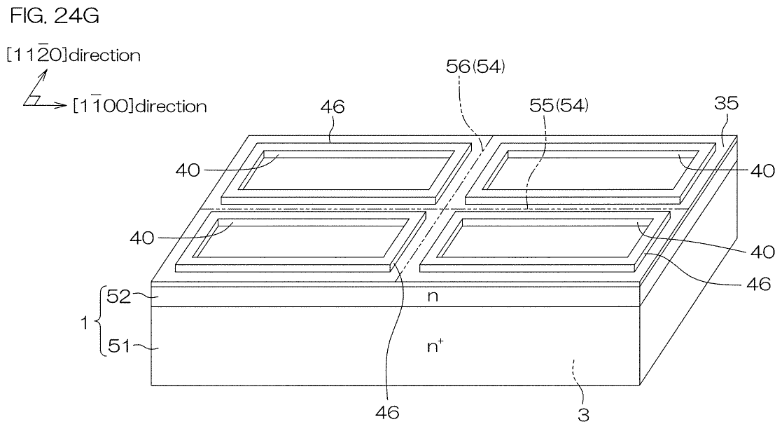

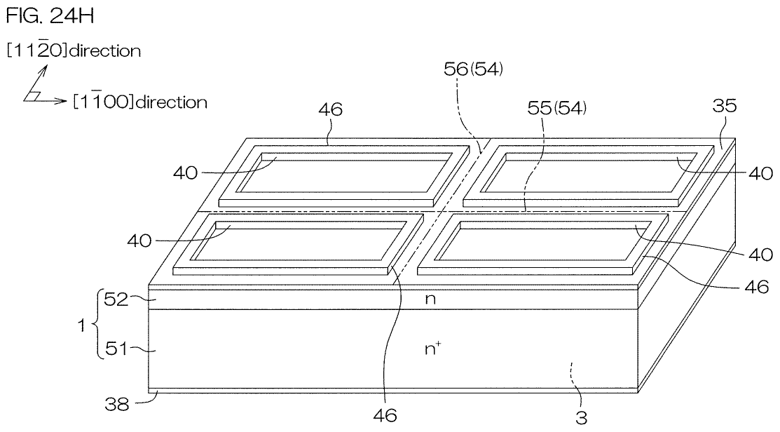

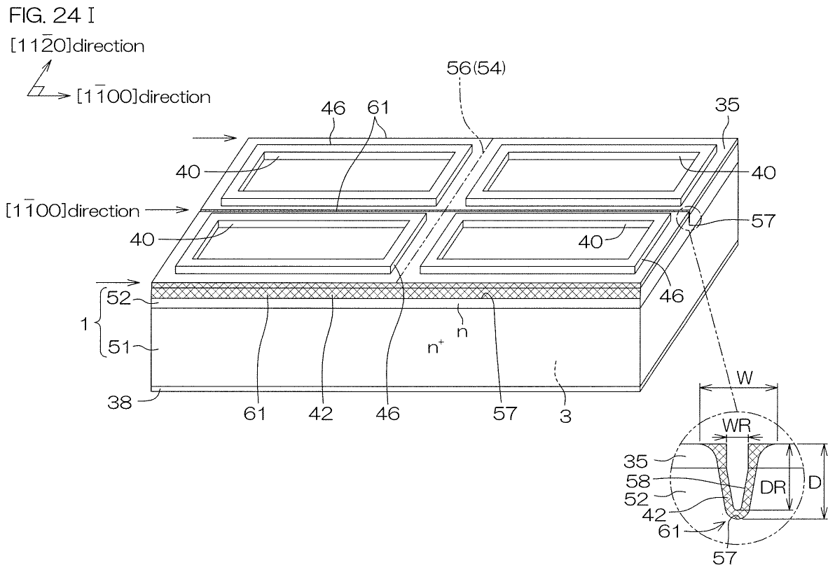

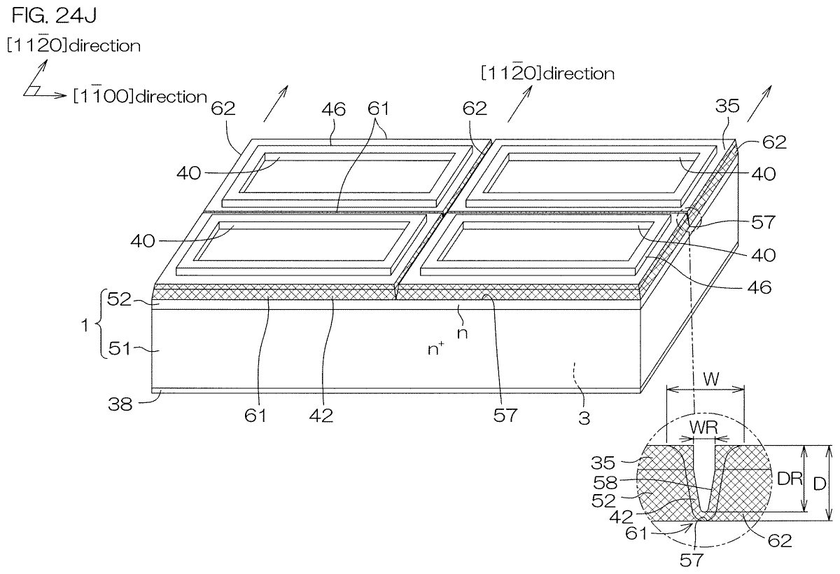

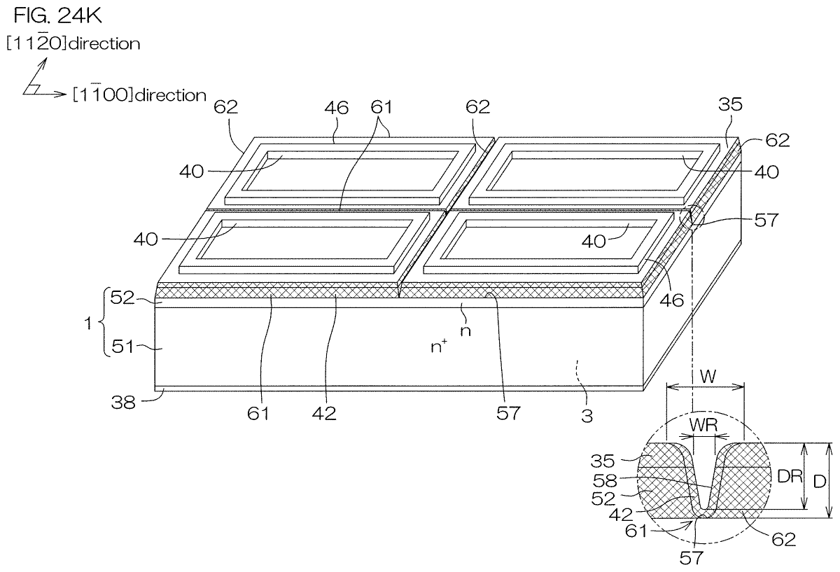

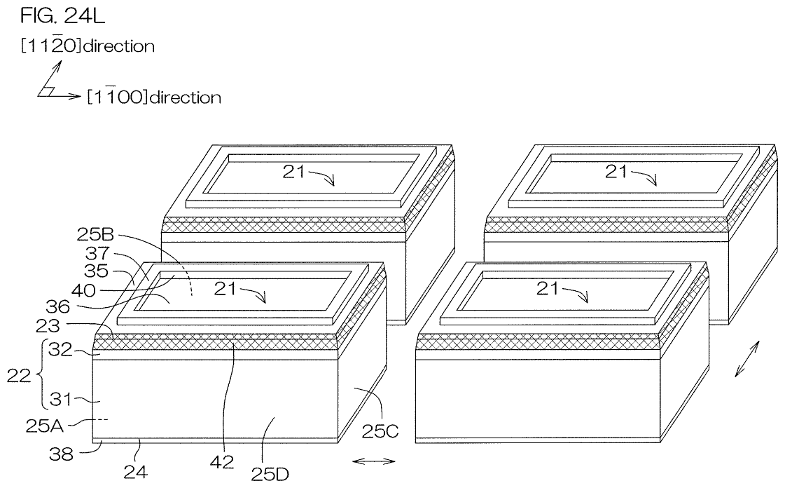

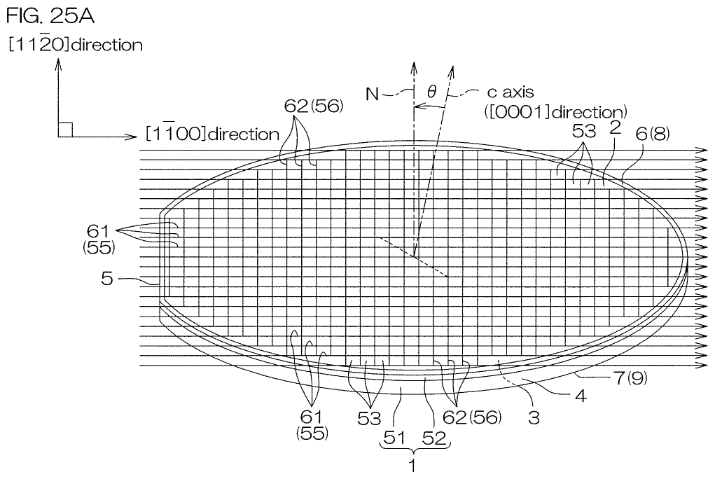

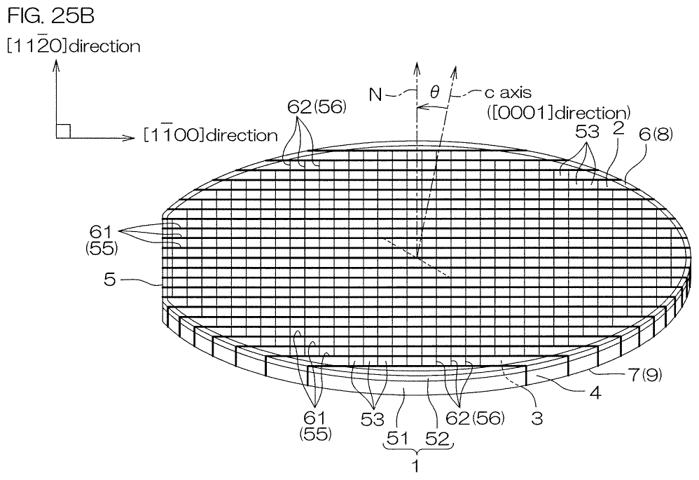

FIG. 24A to FIG. 24L are sectional perspective views of a partial region of the 4H—SiC crystal structure body 1 shown in FIG. 23 and are for describing an example of a method for manufacturing the SiC semiconductor device 21 shown in FIG. 17.

In FIG. 24A to 24L, four device regions 53 are indicated as a portion of regions of the 4H—SiC crystal structure body 1. Also, an enlarged end face diagram of a partial region of the device regions 53 as viewed from the [1-100] direction is shown in FIG. 24I to FIG. 24K. The technical ideas described with FIG. 9A to FIG. 9D above are incorporated in FIG. 24A to FIG. 24L.

First, referring to FIG. 24A, the 4H—SiC crystal structure body 1 shown in FIG. 23 is prepared.

Next, referring to FIG. 24B, a plurality of the active regions 33 are respectively formed in the plurality of device regions 53. The plurality of active regions 33 are respectively formed by introducing a p type impurity and/or an n type impurity into the plurality of device regions 53.

Next, referring to FIG. 24C, the insulating layer 35 is formed on the first main surface 2 of the 4H—SiC crystal structure body 1. The insulating layer 35 includes silicon oxide. The insulating layer 35 may be formed by a CVD method or a thermal oxidation processing method. In this embodiment, the insulating layer 35 is formed by thermal oxidation processing of the first main surface 2.

Next, referring to FIG. 24D, unnecessary portions of the insulating layer 35 are removed. A plurality of the openings 39 are thereby formed in the insulating layer 35. The respective openings 39 expose the active regions 33 of the respective device regions 53. The unnecessary portions of the insulating layer 35 may be removed by an etching method via a mask (not shown).

Next, referring to FIG. 24E, the first electrode layer 36 is formed on the insulating layer 35. In the first electrode layer 36 forming step, first, a conductive material is deposited by a sputtering method or a CVD method on the insulating layer 35. Next, unnecessary portions of the conductive material are removed by an etching method via a mask (not shown). The respective first electrode layers 36 are thereby formed in the respective device regions 53.

Next, referring to FIG. 24F, a resin is coated onto the insulating layer 35 to form the resin layer 37 that covers the first electrode layers 36.

Next, referring to FIG. 24G, the resin layer 37 is selectively exposed and thereafter developed. The resin layers 37 having the openings 40 that expose the respective first electrode layers 36 and the peripheral edge portions 46 that expose the intended cutting lines 54 are formed on the insulating layer 35. The peripheral edge portions 46 of the resin layer 37 define the dicing streets.

Next, referring to FIG. 24H, the second electrode layer 38 is formed on the second main surface 3 of the 4H—SiC crystal structure body 1. The second electrode layer 38 is formed by depositing a conductive material on the second main surface 3 by a sputtering method or a CVD method.

Next, referring to FIG. 24I, the intended cutting lines 54 are heated to form the modified layers 42 (first modified layers) in which the SiC is modified to a different property. Here, an example where the first intended cutting lines 55 along the [1-100] direction is heated first is illustrated.

More specifically, the modified layer 42 forming step includes a step of heating the intended cutting lines 54 to a temperature at which a C atom is eliminated or sublimated from the SiC. The modified layers 42 are thereby formed in the first main surface 2 of the 4H—SiC crystal structure body 1.

The heating of the intended cutting lines 54 may be performed by the method of ablation processing by laser irradiation. In the ablation processing method, an ultraviolet laser may be used. The laser energy, laser pulse duty ratio and laser irradiation speed are respectively set to arbitrary values in accordance with size, shape, thickness, etc., of the modified layers 42 to be formed.

In the ablation processing method, the laser light is irradiated onto the first main surface 2 via the insulating layer 35. The insulating layer 35 is melted or sublimated by the irradiation of the laser light. The first main surface 2 is thereby exposed from the insulating layer 35. Also, the laser light is continuously irradiated onto a portion of the first main surface 2 exposed from the insulating layer 35. The modified layers 42 are thereby formed in the first main surface 2.

Also in this step, depressions 57 penetrating through the insulating layer 35 and recessed from the first main surface 2 toward the second main surface 3 are formed. Each depression 57 includes a bottom portion and side portion. The depression 57 may be formed in a convergent shape that narrows in opening width from the first main surface 2 toward the bottom portion. The bottom portion of the depression 57 may be formed in a shape curved toward the second main surface 3.

A width W of the depression 57 may exceed 0 μm and be not more than 10 μm. The width W of the depression 57 may exceed 0 μm and be not more than 10 μm. The width W of the depression 57 is a width in a direction orthogonal to the direction in which the depression 57 extends. The width W of the depression 57 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the 4H—SiC crystal structure body 1 is not more than 150 μm, the width W of the depression 57 preferably exceeds 0 μm and is not more than 5 μm.

Each modified layer 42 is formed as a film along inner wall of a depression 57. A thickness of a portion of the modified layer 42 covering a bottom wall of the depression 57 may be greater than a thickness of portions of the modified layer 42 covering side wall of the depression 57. The modified layer 42 may be formed in a uniform thickness along the inner wall of the depression 57.

Inside the depression 57, the modified layer 42 is formed on the insulating layer 35 as well. That is, inside the depression 57, the modified layer 42 is formed such as to cover the insulating layer 35. Inside the depression 57, the modified layer 42 defines a recess 58. More specifically, the recess 58 is defined by an outer surface of the modified layer 42.

The recess 58 includes a bottom portion and side portion. The recess 58 may be formed in a convergent shape that narrows in opening width from the first main surface 2 toward the bottom portion. The bottom portion of the recess 58 may be formed in a shape curved toward the second main surface 3. The recess 58 includes opening side corner portion and bottom portion side corner portion. The opening side corner portion of the recess 58 connects the upper surface of the insulating layer 35 and the side portion of the recess 58. The bottom portion side corner portion of the recess 58 connects the bottom portion of the recess 58 and the side portion of the recess 58.

A width WR of the recess 58 is less than the width W of the depression 57. The width WR of the recess 58 may exceed 0 μm and be less than 10 μm. The width WR of the recess 58 may exceed 0 μm and be not more than 2.5 μm, be not less than 2.5 μm and not more than 5 μm, be not less than 5 μm and not more than 7.5 μm, or be not less than 7.5 μm and less than 10 μm. If the thickness of the 4H—SiC crystal structure body 1 is not more than 150 μm, the width WR of the recess 58 preferably exceeds 0 μm and is less than 5 μm.

A depth DR of the recess 58 is less than a depth D of the depression 57. The depth DR of the recess 58 may exceed 0 μm and be less than 30 μm. The depth DR of the recess 58 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and less than 30 μm. If the thickness of the 4H—SiC crystal structure body 1 is not more than 150 μm, the depth DR of the recess 58 preferably exceeds 0 μm and is not more than 15 μm.

Next, referring to FIG. 24J, the second intended cutting lines 56 along the [11-20] direction are heated with the details being the same as in FIG. 24I. The modified layers 42 (second modified layers), the depressions 57 and the recesses 58 are thereby formed in the second intended cutting lines 56.

The modified layers 42, the depressions 57 and the recesses 58 along the first intended cutting lines 55 form first cleavage lines 61 for cleaving the 4H—SiC crystal structure body 1 along the [1-100] direction. The modified layers 42, the depressions 57 and the recesses 58 along the second intended cutting lines 56 form second cleavage lines 62 for cleaving the 4H—SiC crystal structure body 1 along the [11-20] direction.

With this step, a step of forming the first cleavage lines 61 and thereafter forming the second cleavage lines 62 was described. However, an order of forming the first cleavage lines 61 and the second cleavage lines 62 is arbitrary and is not restricted to the order described above. For example, the first cleavage lines 61 may be formed after forming the second cleavage lines 62. Also, an arbitrary first intended cutting line 55 and an arbitrary second intended cutting line 56 may be selected and the first cleavage line 61 and the second cleavage line 62 may be formed alternately.

Next, referring to FIG. 24K, after the modified layer 42 forming step, corners of the modified layers 42 may be rounded. More specifically, an outer surface of each modified layer 42 may be flattened by removing an unevenness from the outer surface of the modified layer 42. The modified layer 42 may be removed by an etching method. The etching method may be a dry etching method or may be a wet etching method. The modified layer 42 may be removed by a plasma etching method as an example of a dry etching method.

The modified layer 42 has a component differing from that of the 4H—SiC crystal structure body 1. An etching rate (etching selectivity) with respect to the modified layer 42 differs from the etching rate (etching selectivity) with respect to SiC. Also, the modified layer 42 has a component differing from that of the insulating layer 35. An etching rate (etching selectivity) with respect to the modified layer 42 differs from an etching rate (etching selectivity) with respect to the insulating layer 35.

A portion of the modified layer 42 can thus be removed while letting the 4H—SiC crystal structure body 1 and the insulating layer 35 remain. The opening side corner portion of each recess 58 is thereby rounded to shapes curved toward an inner side of the recess 58. Also, the bottom portion side corner portion of the recess 58 is rounded to shapes curved toward an outer side of the recess 58.

By the recess 58 that is rounded at the opening side corner portion, concentration of stress on the modified layer 42 can be relaxed at the opening side corner portion. Also, by the recess 58 that is rounded at the bottom portion side corner portion, concentration of stress on the modified layer 42 can be relaxed at the bottom portion side corner portion. Undesirable cracks due to stress on the modified layer 42 can thereby be suppressed. The technical ideas of FIG. 8A to FIG. 8D may be incorporated in the step of FIG. 24K and an entirety of the modified layer 42 may be removed.

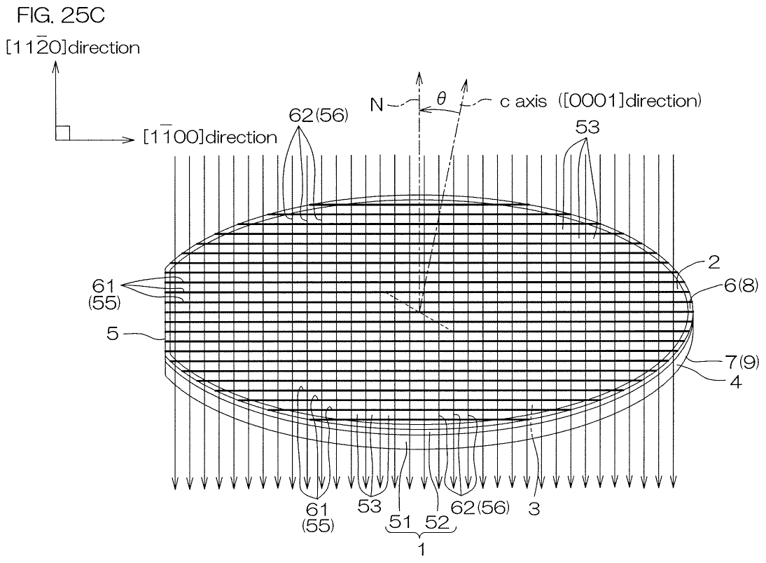

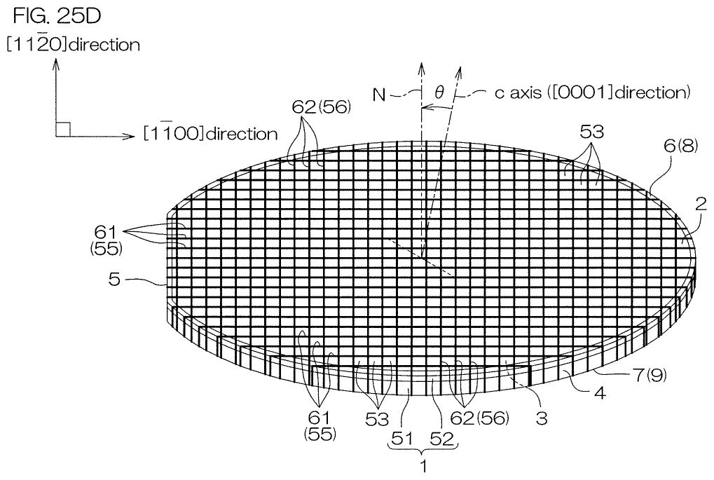

Next, referring to FIG. 24L, the 4H—SiC crystal structure body 1 is cleaved along the first cleavage lines 61 ([1-100] direction) and the second cleavage lines 62 ([11-20] direction). A 4H—SiC crystal structure body 1 cleaving step shall now be described specifically with reference to FIG. 25A to FIG. 25D.

FIG. 25A to FIG. 25D are perspective views of the 4H—SiC crystal structure body 1 shown in FIG. 23 and are perspective views for describing an example of the cleaving step of FIG. 24L.

Referring to FIG. 25A, in this step, first, the 4H—SiC crystal structure body 1 is cleaved along a nearest neighbor direction intersecting direction. That is, the 4H—SiC crystal structure body 1 is cleaved along the first cleavage lines 61 ([1-100] direction). More specifically, the 4H—SiC crystal structure body 1 is cleaved in order along arbitrary first cleavage lines 61 selected from the plurality of first cleavage lines 61.

The 4H—SiC crystal structure body 1 may be cleaved by applying stress to each first cleavage line 61. In this step, a step of applying thermal stress to the first cleavage line 61 by heating and cooling is performed.

A first cleavage line 61 heating step may be performed by the laser irradiation method. The laser irradiation method may be performed by an infrared laser (for example, a CO₂ laser). By the first cleavage line 61 heating step, a compressive stress with the first cleavage line 61 as a starting point is thermally induced. The laser energy, laser pulse duty ratio and laser irradiation speed are respectively set to arbitrary values in accordance with a magnitude of the stress to be applied to the first cleavage line 61.

A first cleavage line 61 cooling step may include a step of supplying a cooling fluid to the first cleavage line 61. The cooling fluid may include water or air or a mixture of water and air (aerosol). By the first cleavage line 61 cooling step, a tensile stress with the first cleavage line 61 as a starting point is thermally induced.

The cooling fluid supplying step may include the cooling fluid emission (jetting) step by the coolant jetting method or the cooling gas supplying method. The first cleavage line 61 cooling step may be performed after the first cleavage line 61 heating step. The first cleavage line 61 cooling step may be performed at the same time as the first cleavage line 61 heating step.

The 4H—SiC crystal structure body 1 is cleaved along the first cleavage lines 61 ([1-100] direction) by the compressive stress generated in the first cleavage line 61 heating step and the tensile stress generated in the first cleavage line 61 cooling step.

The 4H—SiC crystal structure body 1 is thereby divided into a plurality of strip portions extending along the [1-100] direction as shown in FIG. 25B. Each of the strip portions includes a plurality of device regions 53 aligned in a single column along the [1-100] direction.

Next, referring to FIG. 25C, the 4H—SiC crystal structure body 1 is cleaved along a nearest neighbor direction. That is, the 4H—SiC crystal structure body 1 is cleaved along the second cleavage lines 62 ([11-20] direction). More specifically, the 4H—SiC crystal structure body 1 is cleaved in order along arbitrary second cleavage lines 62 selected from the plurality of second cleavage lines 62.

The 4H—SiC crystal structure body 1 may be cleaved by applying stress to each second cleavage line 62. In this step, a step of applying thermal stress to the second cleavage line 62 by heating and cooling is performed.

A second cleavage line 62 heating step may be performed by the laser irradiation method. The laser irradiation method may be performed by an infrared laser (for example, a CO₂ laser). By the second cleavage line 62 heating step, a compressive stress with the second cleavage line 62 as a starting point is thermally induced. The laser energy, laser pulse duty ratio and laser irradiation speed are respectively set to arbitrary values in accordance with a magnitude of the stress to be applied to the second cleavage line 62.

A second cleavage line 62 cooling step may include a step of supplying a cooling fluid to the second cleavage line 62. The cooling fluid may include water or air or a mixture of water and air (aerosol). By the second cleavage line 62 cooling step, a tensile stress with the second cleavage line 62 as a starting point is thermally induced.

The supplying of the cooling fluid may be performed by emission (jetting) of the cooling fluid by the coolant jetting method or the cooling gas supplying method. The second cleavage line 62 cooling step may be performed after the second cleavage line 62 heating step. The second cleavage line 62 cooling step may be performed at the same time as the second cleavage line 62 heating step.

The 4H—SiC crystal structure body 1 is cleaved along the second cleavage lines 62 ([11-20] direction) by the compressive stress generated in the second cleavage line 62 heating step and the tensile stress generated in the second cleavage line 62 cooling step.

The plurality of SiC semiconductor devices 21 are thereby cut out from the plurality of strip portions extending along the [1-100] direction as shown in FIG. 25D. The SiC semiconductor devices 21 are manufactured through steps including the above.

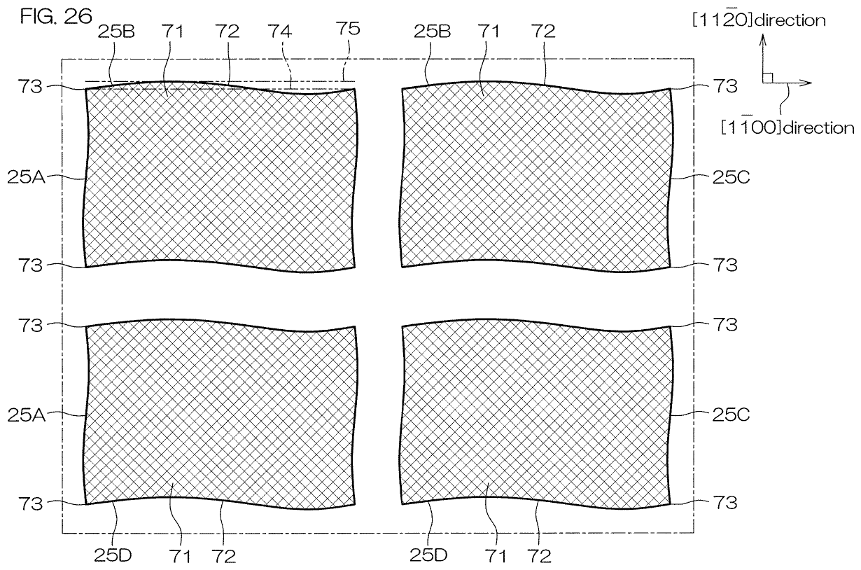

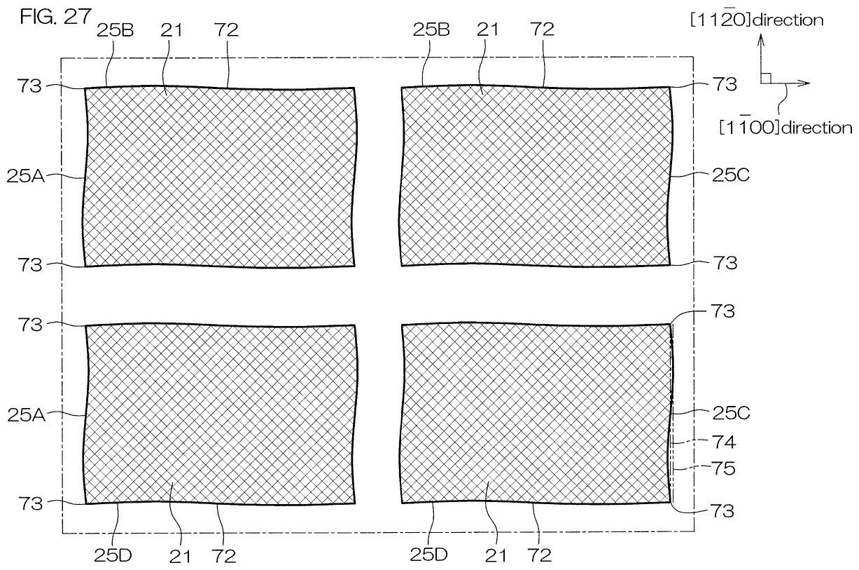

FIG. 26 is a plan view for describing planar shapes of SiC semiconductor devices 71 diced through a method for manufacturing the SiC semiconductor devices 71 according to a reference example. FIG. 27 is a plan view for describing planar shapes of the SiC semiconductor devices 21, shown in FIG. 17 and diced through the manufacturing method of FIG. 25A to FIG. 25D.

With the method for manufacturing the SiC semiconductor devices 71 according to the reference example, the 4H—SiC crystal structure body 1 is cleaved (thermally split) along the second cleavage lines 62 ([11-20] direction) and thereafter the 4H—SiC crystal structure body 1 is cleaved (thermally split) along the first cleavage lines 61 ([1-100] direction). That is, with the method for manufacturing the SiC semiconductor devices 71 according to the reference example, a nearest neighbor direction intersecting direction cleaving step is performed after a nearest neighbor direction cleaving step.

Referring to FIG. 26, in the SiC semiconductor devices 71 according to the reference example, the side surfaces 25A and 25C oriented along the [11-20] direction are formed comparatively flatly. In the [11-20] direction cleaving step, the 4H—SiC crystal structure body 1 is cleaved along the nearest neighbor direction and, at the same time, the stress (thermal stress) generated in the 4H—SiC crystal structure body 1 continues continuously. Forming of a bulge at a cleavage portion is thus suppressed.

On the other hand, on the side surfaces 25B and 25D oriented along the [1-100] direction, tortuosities 72 that bulge comparatively largely along the [11-20] direction are formed. In particular among the side surfaces 25A to 25D, the in-plane variations of the side surfaces 25B and 25D oriented along the [1-100] direction exceed 20 μm.

In the [1-100] direction cleaving step, the 4H—SiC crystal structure body 1, that is, the side surfaces 25A and 25C are cleaved in the nearest neighbor direction intersecting direction. Moreover, the 4H—SiC crystal structure body 1 is already cleaved along the [11-20] direction and therefore the stress (thermal stress) applied to the 4H—SiC crystal structure body 1 cannot be made to continue continuously.

Consequently, a force that holds the Si atomic arrangement (a force along the [11-20] direction) acts from the side surfaces 25A and 25C and the comparatively largely bulging tortuosities 72 are formed in the side surfaces 25B and 25D. Such tortuosities 72 have a tendency of forming from connection points 73 of the side surfaces 25A and 25C formed in the first cleaving step and the side surfaces 25B and 25D formed in the second cleaving step, as starting points in particular. With the SiC semiconductor devices 71 according to the reference example, the in-plane variations of the side surfaces 25B and 25D are worsened by the tortuosities 72.

The in-plane variation is defined by a maximum value of distances between a reference virtual line 74 and measurement virtual lines 75 set in one of the side surfaces 25A to 25D selected from the side surfaces 25A to 25D. The reference virtual line 74 is a straight line joining two corner portions of the SiC semiconductor 22 in plan view and is set in the selected one of the side surfaces 25A to 25D. The measurement virtual line 75 is a straight line extending in parallel to the reference virtual line 74 in plan view and is set to be tangent to a top portion or a base portion of a bulge (tortuosity 72) present on the selected one of the side surfaces 25A to 25D.

For example, the distance between the reference virtual line 74 and the measurement virtual line 75 tangent to the top portion of a bulge (tortuosity 72) and the distance between the reference virtual line 74 and the measurement virtual line tangent 75 to the base portion of the bulge (tortuosity 72) are measured. The in-plane variation of the selected one of the side surfaces 25A to 25D is defined by the maximum value of the measured distances between the reference virtual line 74 and the measured virtual lines 75.

A distance between the plurality of device regions 53 that are mutually adjacent in the [11-20] direction and the [1-100] direction is set in consideration of the tortuosities 72 (in-plane variations). Therefore, if a comparatively large tortuosity 72 (in-plane variation) is formed, the distance between the plurality of device regions 53 must be widened to suppress contact of neighboring SiC semiconductor devices 71. Therefore, a number of obtained SiC semiconductor devices 71 that can be acquired from a single 4H—SiC crystal structure body 1 is restricted by the tortuosities 72 (in-plane variations).

On the other hand, referring to FIG. 27, with the method for manufacturing the SiC semiconductor devices 21, the 4H—SiC crystal structure body 1 is cleaved (thermally split) along the first cleavage lines 61 ([1-100] direction) and thereafter the 4H—SiC crystal structure body 1 is cleaved (thermally split) along the second cleavage lines 61 ([11-20]direction). That is, with the method for manufacturing the SiC semiconductor devices 21, the nearest neighbor direction cleaving step is performed after the nearest neighbor direction intersecting direction cleaving step.

Although in the [1-100] direction cleaving step, the 4H—SiC crystal structure body 1 is cleaved in the nearest neighbor direction intersecting direction, the stress (thermal stress) applied to the 4H—SiC crystal structure body 1 continues continuously and therefore the forming of a bulge at a cleavage portion is suppressed.

On the other hand, in the [11-20] direction cleaving step, the 4H—SiC crystal structure body 1 is already cleaved along the [1-100] direction and therefore the stress (thermal stress) applied to the 4H—SiC crystal structure body 1 becomes discontinuous. However, in this step, the stress (thermal stress) is applied to the 4H—SiC crystal structure body 1 along the nearest neighbor direction ([11-20] direction) and the 4H—SiC crystal structure body 1 is cleaved along the nearest neighbor direction ([11-20] direction). The forming of a bulge at a cleavage portion is thereby suppressed.

Especially according to this order of steps, the forming of tortuosities 72 having the connection points 73 of the side surfaces 25A and 25C and the side surfaces 25B and 25D as the starting points is suppressed. Consequently, in-plane variations of not more than 20 μm and more specifically not more than 10 μm can be achieved in the side surfaces 25A to 25D. Also according to this order of steps, in-plane variations of not more than 20 μm and more specifically not more than 10 μm can be achieved in the side surfaces 25B and 25D oriented along the [1-100] direction. Flatness of all of the side surfaces 25A to 25D can thus be improved.

Also, the distance between the plurality of device regions 53 that are mutually adjacent in the [11-20] direction and the [1-100] direction can be narrowed because the tortuosities 72 can be suppressed. The number of obtained SiC semiconductor devices 21 that can be acquired from a single 4H—SiC crystal structure body 1 can thus be increased.

Referring to FIG. 26 and FIG. 27, it can be understood that, regardless of crystal direction, rectilinearity of cleavage is stabilized when the stress (thermal stress) applied to the 4H—SiC crystal structure body 1 is continuous. On the other hand, it can be understood that when the stress (thermal stress) generated in the 4H—SiC crystal structure body 1 is discontinuous, the rectilinearity of cleavage in the nearest neighbor direction intersecting direction becomes unstable.

Such a phenomenon is seen prominently in semiconductor materials having a comparatively high thermal conductivity among the various semiconductor materials used in semiconductor devices. In particular, SiC has a comparatively high thermal conductivity with respect to the thermal conductivity of a silicon monocrystal (Si), the thermal conductivity of sapphire (Al₂O₃), the thermal conductivity of gallium nitride (GaN), etc.

The thermal conductivity of silicon carbide (SiC) is not less than 4.5 W/cmK and not more than 5.5 W/cmK (more specifically, approximately 4.9 W/cmK). The thermal conductivity of Si is approximately 1.5 W/cmK. The thermal conductivity of sapphire (Al₂O₃) is approximately 0.4 W/cmK. The thermal conductivity of gallium nitride (GaN) is approximately 2.0 W/cmK.

That is, in comparison to the silicon monocrystal (Si), sapphire (Al₂O₃), gallium nitride (GaN), etc., SiC has a property that stress (thermal stress) due to heat dissipation becomes discontinuous easily. Therefore with SiC, a risk of in-plane variation becomes high in the nearest neighbor direction intersecting direction cleaving step when the stress (thermal stress) is discontinuous. Therefore, the order of performing the nearest neighbor direction cleaving step after the nearest neighbor direction intersecting direction cleaving step is especially effective for SiC which has a comparatively high thermal conductivity.

From a comparison of FIG. 26 and FIG. 27, a case where the SiC semiconductor layer 22 has, in plan view, the side surfaces 25A and 25C that form short sides of a rectangle and the side surfaces 25B and 25D that form long sides of the rectangle shall now be considered. In this case, the side surfaces 25B and 25D have areas exceeding the areas of the side surfaces 25A and 25C.

Therefore, in a case where side surfaces having comparatively large areas are present, it is preferable to set orientations of the plurality of device regions 53 with respect to crystal directions in advance such that stress (thermal stress) is transmitted continuously in a second cutting step. That is, it is preferable for the side surface 25A and the side surface 25C that form the short sides of the rectangle to be formed along the [1-100] direction and for the side surface 25B and the side surface 25D that form the long sides of the rectangle to be formed along the [11-20] direction.

In this case, first, the 4H—SiC crystal structure body 1 is cut along the [1-100] direction to form the side surface 25A and the side surface 25C that form the short sides of the rectangle. Thereafter, the 4H—SiC crystal structure body 1 is cut along the [11-20] direction to form the side surface 25B and the side surface 25D that form the long sides of the rectangle.

According to this order of steps, the continuity of the stress (thermal stress) can be improved in the second cutting step and therefore the flatness of the side surface 25B and the side surface 25D that have the comparatively large areas can be improved. Thus in a case of cutting the device regions 53 of rectangular shape, it is preferable to set the short sides of the device regions 53 in the [1-100] direction and the long sides of the device regions 53 in the [11-20] direction.

As described above, according to the present preferred embodiment, a crystal cutting method that enables the 4H—SiC crystal structure body 1 constituted of a hexagonal crystal to be cut appropriately from two different directions can be provided. Also, according to the present preferred embodiment, a method for manufacturing an SiC semiconductor device using the crystal cutting method can be provided. Also, the SiC semiconductor device 21 can be manufactured and provided by such a method for manufacturing an SiC semiconductor device.

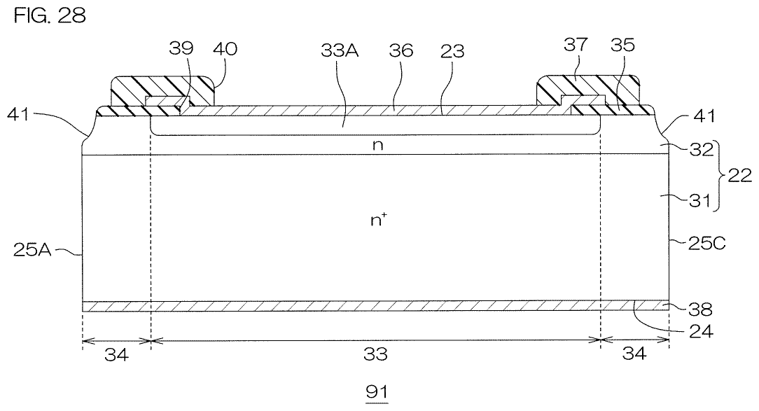

FIG. 28 is a sectional view of a region corresponding to FIG. 19 and is a sectional view of the general arrangement of an SiC semiconductor device 91 according to a twelfth preferred embodiment of the present invention. In the following, structures corresponding to structures described with the SiC semiconductor device 21 shall be provided with the same reference symbols and description thereof shall be omitted.

Referring to FIG. 28, the SiC semiconductor device 91 is manufactured by a manufacturing method with which the technical ideas described with FIG. 10A to FIG. 10D above are incorporated in the steps of FIG. 24A to FIG. 24L described above. More specifically, the SiC semiconductor device 91 does not have the modified layer 42. With the SiC semiconductor device 91, just the inclining portion 41 is formed at the corner portions of the SiC semiconductor layer 22.

Even in the case of manufacturing the SiC semiconductor device 91 described above, the same effects as the effects described for the eleventh preferred embodiment can be exhibited.

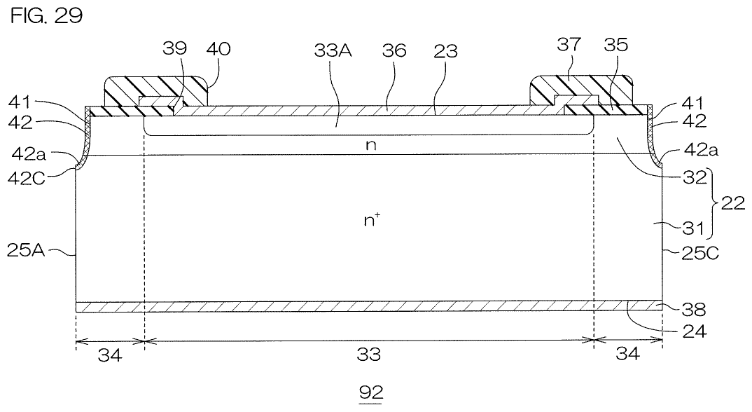

FIG. 29 is a sectional view of a region corresponding to FIG. 19 and is a sectional view of the general arrangement of an SiC semiconductor device 92 according to a thirteenth preferred embodiment of the present invention. In the following, structures corresponding to structures described with the SiC semiconductor device 21 shall be provided with the same reference symbols and description thereof shall be omitted.

Referring to FIG. 29, the SiC semiconductor device 92 is manufactured by a manufacturing method with which the technical ideas described with FIG. 11A to FIG. 11D above are incorporated in the steps of FIG. 24A to FIG. 24L described above. Among the steps of FIG. 24A to FIG. 24L, the step of FIG. 24K does not necessarily have to be performed.

More specifically, the SiC semiconductor device 92 includes the inclining portion 41 and the modified layer 42 that reach the SiC semiconductor substrate 31. The inclining portion 41 reaches the SiC semiconductor substrate 31 upon crossing the boundary region between the SiC semiconductor substrate 31 and the SiC epitaxial layer 32. The SiC semiconductor substrate 31, the SiC epitaxial layer 32 and the insulating layer 35 are exposed from the inclining portion 41. The lower side end portion 41b of the inclining portion 41 is positioned in the SiC semiconductor substrate 31. The lower side end portion 41b of the inclining portion 41 may be formed in a shape curved toward the second main surface 24.

The modified layer 42 is formed as a film along the inclining portion 41 of the SiC semiconductor layer 22. The modified layer 42 reaches the SiC semiconductor substrate 31 upon crossing the boundary region between the SiC semiconductor substrate 31 and the SiC epitaxial layer 32. The modified layer 42 is in contact with the SiC semiconductor substrate 31, the SiC epitaxial layer 32 and the insulating layer 35.

The lower side covering portion 42b of the modified layer 42 covers the SiC semiconductor substrate 31. The lower side covering portion 42b of the modified layer 42 includes the connection portion 42c connected to the side surfaces 25A to 25D. The connection portion 42c of the modified layer 42 may be a cleavage portion of the modified layer 42. The connection portion 42c of the modified layer 42 may be formed flush with the side surfaces 25A to 25D.

Even in the case of manufacturing the SiC semiconductor device 92 described above, the same effects as the effects described for the eleventh preferred embodiment can be exhibited.

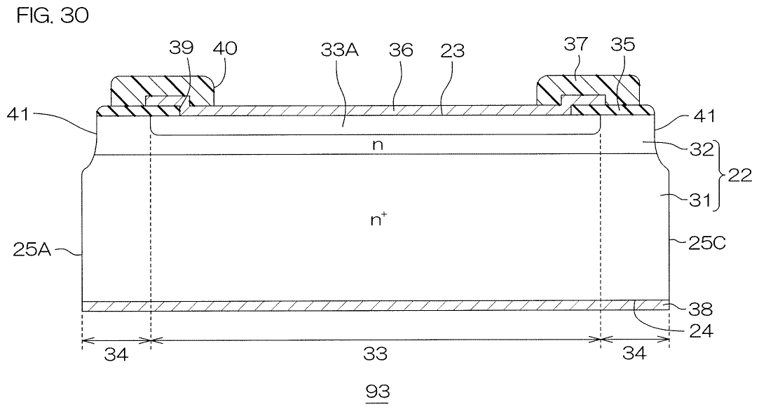

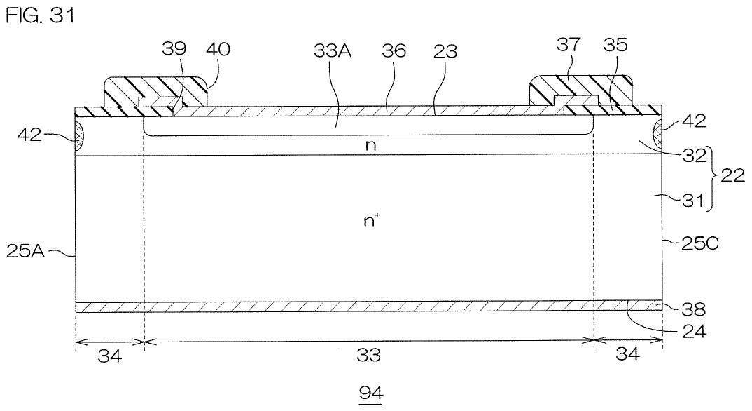

FIG. 30 is a sectional view of a region corresponding to FIG. 19 and is a sectional view of the general arrangement of an SiC semiconductor device 93 according to a fourteenth preferred embodiment of the present invention. In the following, structures corresponding to structures described with the SiC semiconductor device 21 shall be provided with the same reference symbols and description thereof shall be omitted.

Referring to FIG. 30, the SiC semiconductor device 93 is manufactured by a manufacturing method with which the technical ideas described with FIG. 12A to FIG. 12D above are incorporated in the steps of FIG. 24A to FIG. 24L described above.

More specifically, the SiC semiconductor device 93 does not have the modified layer 42. With the SiC semiconductor device 93, just the inclining portion 41 is formed at the corner portions of the SiC semiconductor layer 22. The inclining portion 41 reaches the SiC semiconductor substrate 31 upon crossing the boundary region between the SiC semiconductor substrate 31 and the SiC epitaxial layer 32.

The lower side end portion 41b of the inclining portion 41 is positioned inside the SiC semiconductor substrate 31. The lower side end portion 41b of the inclining portion 41 may be formed in a shape curved toward the second main surface 24. The SiC semiconductor substrate 31, the SiC epitaxial layer 32 and the insulating layer 35 are exposed from the inclining portion 41.

Even in the case of manufacturing the SiC semiconductor device 93 described above, the same effects as the effects described for the eleventh preferred embodiment can be exhibited.

FIG. 31 is a sectional view of a region corresponding to FIG. 19 and is a sectional view of the general arrangement of an SiC semiconductor device 94 according to a fifteenth preferred embodiment of the present invention. In the following, structures corresponding to structures described with the SiC semiconductor device 21 shall be provided with the same reference symbols and description thereof shall be omitted.

Referring to FIG. 31, the SiC semiconductor device 94 does not have the inclining portion 41 at the corner portions of the SiC semiconductor layer 22. The SiC semiconductor device 94 includes the modified layer 42 formed in a thickness direction intermediate portion of the SiC semiconductor layer 22 at the side surfaces 25A to 25D.

More specifically, the modified layer 42 is formed in a thickness direction intermediate portion of the SiC epitaxial layer 32 at the side surfaces 25A to 25D. The modified layer 42 is formed in the SiC epitaxial layer 32 at an interval toward the second main surface 24 side from the first main surface 23. The modified layer 42 is formed in the SiC epitaxial layer 32 at an interval toward the first main surface 23 side from the boundary region between the SiC semiconductor substrate 31 and the SiC epitaxial layer 32.

Such a modified layer 42 is formed by adjusting a light converging point of the laser light in the steps of FIG. 24J and FIG. 24I described above. In this case, the modified layer 42 is heated and cooled from the second main surface 3 side of the 4H—SiC crystal structure body 1 and the 4H—SiC crystal structure body 1 is cleaved. The step of FIG. 24K does not necessarily have to be performed.

Even in the case of manufacturing the SiC semiconductor device 94 described above, the same effects as the effects described for the eleventh preferred embodiment can be exhibited.

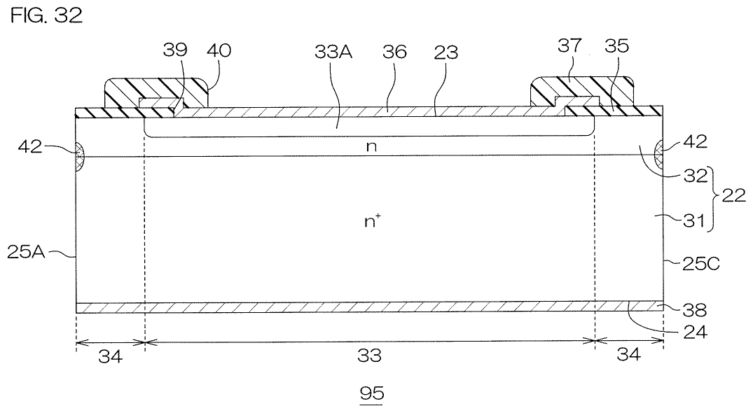

FIG. 32 is a sectional view of a region corresponding to FIG. 19 and is a sectional view of the general arrangement of an SiC semiconductor device 95 according to a sixteenth preferred embodiment of the present invention. In the following, structures corresponding to structures described with the SiC semiconductor device 21 shall be provided with the same reference symbols and description thereof shall be omitted.

Referring to FIG. 32, the SiC semiconductor device 95 does not have the inclining portion 41 at the corner portions of the SiC semiconductor layer 22. The SiC semiconductor device 95 includes the modified layer 42 formed in a thickness direction intermediate portion of the SiC semiconductor layer 22 at the side surfaces 25A to 25D.

The modified layer 42 has an upper end portion at the first main surface 23 side and a lower end portion at the second main surface 24 side. The upper end portion of the modified layer 42 is formed in the SiC epitaxial layer 32 at an interval toward the second main surface 24 side from the first main surface 23. The lower end portion of the modified layer 42 crosses the boundary region between the SiC semiconductor substrate 31 and the SiC epitaxial layer 32 and is formed in the SiC semiconductor substrate 31.

Such a modified layer 42 is formed by adjusting the light converging point of the laser light in the steps of FIG. 24J and FIG. 24I described above. In this case, the modified layer 42 is heated and cooled from the second main surface 3 side of the 4H—SiC crystal structure body 1 and the 4H—SiC crystal structure body 1 is cleaved. The step of FIG. 24K does not necessarily have to be performed.

Even in the case of manufacturing the SiC semiconductor device 95 described above, the same effects as the effects described for the eleventh preferred embodiment can be exhibited.

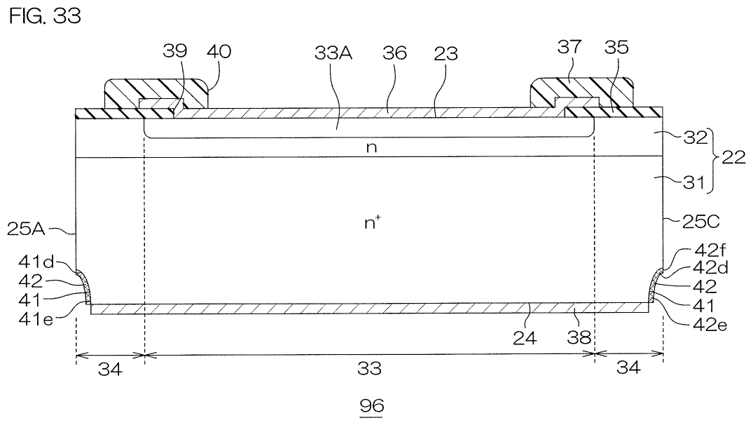

FIG. 33 is a sectional view of a region corresponding to FIG. 19 and is a sectional view of the general arrangement of an SiC semiconductor device 96 according to a seventeenth preferred embodiment of the present invention. In the following, structures corresponding to structures described with the SiC semiconductor device 21 shall be provided with the same reference symbols and description thereof shall be omitted.

Referring to FIG. 33, the SiC semiconductor device 96 is manufactured by a manufacturing method with which the technical ideas described with FIG. 13A to FIG. 13D above are incorporated in the steps of FIG. 24A to FIG. 24L described above. Among the steps of FIG. 24A to FIG. 24L, the step of FIG. 24K does not necessarily have to be performed.

More specifically, the SiC semiconductor device 96 includes the inclining portion 41 and the modified layer 42 that are formed in regions of the side surfaces 25A to 25D at the second main surface side 24 of the SiC semiconductor layer 22.

The inclining portion 41 is formed at corner portions connecting the second main surface 24 and the side surfaces 25A to 25D. The corner portions of the SiC semiconductor layer 22 include corner portions connecting the second main surface 24 and the side surfaces 25A and 25C and extending along the [11-20] direction. The corner portions of the SiC semiconductor layer 22 include corner portions connecting the second main surface 24 and the side surfaces 25B and 25D and extending along the [1-100] direction. The inclining portion 41 is inclined downwardly from the second main surface 24 toward the side surfaces 25A to 25D.

The inclining portion 41 is formed by an inner wall of a depression recessed from the second main surface 24 toward the first main surface 23 at the corner portions of the SiC semiconductor layer 22. The inclining portion 41 is formed in the SiC semiconductor substrate 31. More specifically, the inclining portion 41 is formed in a region at the second main surface 24 side with respect to the boundary region between the SiC semiconductor substrate 31 and the SiC epitaxial layer 32.

The inclining portion 41 has an upper side end portion 41d and a lower side end portion 41e. The upper side end portion 41d of the inclining portion 41 is positioned at the first main surface 23 side of the SiC semiconductor layer 22. The upper side end portion 41d of the inclining portion 41 is continuous to the side surfaces 25A to 25D. The upper side end portion 41d of the inclining portion 41 may be formed in a shape curved toward the first main surface 23. The lower side end portion 41e of the inclining portion 41 is positioned at the second main surface 24 side of the SiC semiconductor layer 22. The lower side end portion 41e of the inclining portion 41 is connected to the second main surface 24 of the SiC semiconductor layer 22.

The width WI of the inclining portion 41 may be not more than the in-plane variations of the side surfaces 25A to 25D. The width WI of the inclining portion 41 may be less than the in-plane variations of the side surfaces 25A to 25D. The width WI of the inclining portion 41 is the width in the direction orthogonal to the direction in which the inclining portion 41 extends in plan view.

The width WI of the inclining portion 41 may exceed 0 μm and be not more than 10 μm. The width WI of the inclining portion 41 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the SiC semiconductor layer 22 is not more than 150 μm, the width WI of the inclining portion 41 preferably exceeds 0 μm and is not more than 5 μm. More preferably, the width WI of the inclining portion 41 exceeds 0 μm and is not more than 2.5 μm.

The depth D of the inclining portion 41 may exceed 0 μm and be not more than 30 μm. The depth D of the inclining portion 41 is the distance in the normal direction N from the first main surface 23 to the lower side end portion of the inclining portion 41. The depth D of the inclining portion 41 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 22 is not more than 150 μm, the depth D of the inclining portion 41 preferably exceeds 0 μm and is not more than 15 μm.

The modified layer 42 is formed in the SiC semiconductor substrate 31. More specifically, the modified layer 42 is formed in a region of the SiC semiconductor layer 22 at the second main surface 24 side with respect to the boundary region between the SiC semiconductor substrate 31 and the SiC epitaxial layer 32. The modified layer 42 is formed along the corner portions connecting the second main surface 24 and the side surfaces 25A to 25D. The modified layer 42 is formed at the corner portions connecting the second main surface 24 and the side surfaces 25A and 25C and extending along the [11-20] direction. Also, the modified layer 42 is formed at the corner portions connecting the second main surface 24 and the side surfaces 25B and 25D and extending along the [1-100] direction.

In this embodiment, the modified layer 42 extends as a band on the side surfaces 25A to 25D along directions parallel to the second main surface 24. That is, the modified layer 42 extends as a band along the [1-100] direction and the [11-20] direction. At the side surfaces 25A to 25D, the modified layer 42 is formed in an annular shape (for example, an endless shape) surrounding the active region 33.

The modified layer 42 is formed as a film along the inclining portion 41 of the SiC semiconductor layer 22. The thickness of the portion of the modified layer 42 covering the bottom wall of the inclining portion 41 may be greater than the thickness of the portion of the modified layer 42 covering the side wall of the inclining portion 41. The modified layer 42 may be formed in a uniform thickness along the inner wall of the inclining portion 41.

The modified layer 42 includes an upper side covering portion 42d and a lower side covering portion 42e. The upper side covering portion 42d of the modified layer 42 covers the upper side end portion 41d of the inclining portion 41. The lower side covering portion 42e of the modified layer 42 covers the lower side end portion 41e of the inclining portion 41.

The upper side covering portion 42d of the modified layer 42 includes a connection portion 42f connected to the side surfaces 25A to 25D. The connection portion 42f of the modified layer 42 may be a cleavage portion of the modified layer 42. The connection portion 42f of the modified layer 42 may be formed flush with the side surfaces 25A to 25D.

The width WM of the modified layer 42 may be not more than the in-plane variations of the side surfaces 25A to 25D. The width WM of the modified layer 42 may be less than the in-plane variations of the side surfaces 25A to 25D. The width WM of the modified layer 42 is the width in the direction orthogonal to the direction in which the modified layer 42 extends in plan view.

The width WM of the modified layer 42 may exceed 0 μm and be not more than 10 μm. The width WM of the modified layer 42 may exceed 0 μm and be not more than 2 μm, be not less than 2 μm and not more than 4 μm, be not less than 4 μm and not more than 6 μm, be not less than 6 μm and not more than 8 μm, or be not less than 8 μm and not more than 10 μm. If the thickness of the SiC semiconductor layer 22 is not more than 150 μm, the width WM of the modified layer 42 preferably exceeds 0 μm and is not more than 5 μm. More preferably, the width WM of the modified layer 42 exceeds 0 μm and is not more than 2.5 μm.

The thickness T of the modified layer 42 may exceed 0 μm and be not more than 30 μm. The thickness T of the modified layer 42 is the thickness of the modified layer 42 along the normal direction N. The thickness T of the modified layer 42 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 22 is not more than 150 μm, the thickness T of the modified layer 42 preferably exceeds 0 μm and is not more than 15 μm.

The second electrode layer 38 exposes the modified layer 42 at the second main surface 24 of the SiC semiconductor layer 22. That is, a peripheral edge portion of the second electrode layer 38 is formed at an inner region of the SiC semiconductor layer 22 with respect to the side surfaces 25A to 25D. The modified layer 42 may have a covering portion extending from the inclining portion 41 toward the second electrode layer 38 and covering the second electrode layer 38.

Even in the case of manufacturing the SiC semiconductor device 96 described above, the same effects as the effects described for the eleventh preferred embodiment can be exhibited.

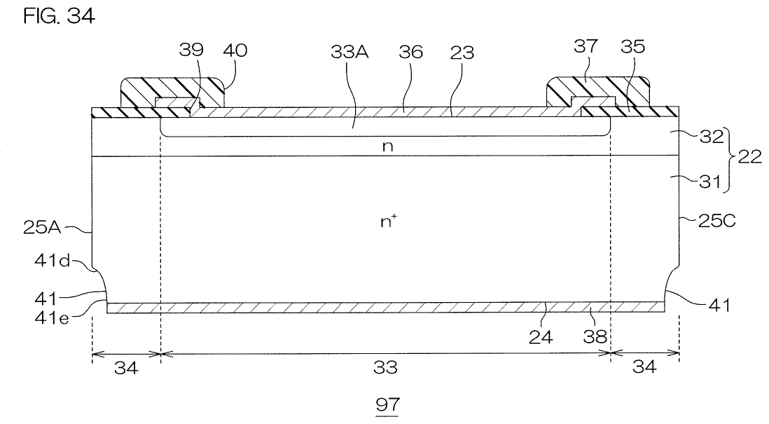

FIG. 34 is a sectional view of a region corresponding to FIG. 19 and is a sectional view of the general arrangement of an SiC semiconductor device 97 according to an eighteenth preferred embodiment of the present invention. In the following, structures corresponding to structures described with the SiC semiconductor device 21 shall be provided with the same reference symbols and description thereof shall be omitted.

Referring to FIG. 34, the SiC semiconductor device 97 is manufactured by a manufacturing method with which the technical ideas described with FIG. 14A to FIG. 14D above are incorporated in the steps of FIG. 24A to FIG. 24L described above.

More specifically, the SiC semiconductor device 97 does not have the modified layer 42. The SiC semiconductor device 97 includes the inclining portion 41 that is formed in regions of the side surfaces 25A to 25D at the second main surface side 24 of the SiC semiconductor layer 22.

The inclining portion 41 is formed at the corner portions connecting the second main surface 24 and the side surfaces 25A to 25D. The corner portions of the SiC semiconductor layer 22 include the corner portions connecting the second main surface 24 and the side surfaces 25A and 25C and extending along the [11-20] direction. The corner portions of the SiC semiconductor layer 22 include the corner portions connecting the second main surface 24 and the side surfaces 25B and 25D and extending along the [1-100] direction.

The inclining portion 41 is inclined downwardly from the second main surface 24 toward the side surfaces 25A to 25D. The inclining portion 41 is formed by an inner wall of a depression recessed from the second main surface 24 toward the first main surface 23 at the corner portions of the SiC semiconductor layer 22.

The inclining portion 41 is formed in the SiC semiconductor substrate 31. More specifically, the inclining portion 41 is formed in a region at the second main surface 24 side with respect to the boundary region between the SiC semiconductor substrate 31 and the SiC epitaxial layer 32.

The inclining portion 41 has the upper side end portion 41d and the lower side end portion 41e. The upper side end portion 41d of the inclining portion 41 is positioned at the first main surface 23 side. The lower side end portion 41e of the inclining portion 41 is positioned at the second main surface 24 side. The upper side end portion 41d of the inclining portion 41 is continuous to the side surfaces 25A to 25D. The upper side end portion 41d of the inclining portion 41 may be formed in a shape curved toward the first main surface 23. The lower side end portion 41e of the inclining portion 41 is connected to the second main surface 24.

The width WI of the inclining portion 41 may be not more than the in-plane variations of the side surfaces 25A to 25D. The width WI of the inclining portion 41 may be less than the in-plane variations of the side surfaces 25A to 25D. The width WI of the inclining portion 41 is the width in the direction orthogonal to the direction in which the inclining portion 41 extends in plan view.

The width WI of the inclining portion 41 may exceed 0 μm and be not more than 10 μm. The width WI of the inclining portion 41 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the SiC semiconductor layer 22 is not more than 150 μm, the width WI of the inclining portion 41 preferably exceeds 0 μm and is not more than 5 μm. More preferably, the width WI of the inclining portion 41 exceeds 0 μm and is not more than 2.5 μm.

The depth D of the inclining portion 41 may exceed 0 μm and be not more than 30 μm. The depth D of the inclining portion 41 is the distance in the normal direction N from the first main surface 23 to the lower side end portion of the inclining portion 41. The depth D of the inclining portion 41 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 22 is not more than 150 μm, the depth D of the inclining portion 41 preferably exceeds 0 μm and is not more than 15 μm.

The second electrode layer 38 exposes the inclining portion 41 at the second main surface 24. That is, the peripheral edge portion of the second electrode layer 38 is formed at the inner region of the SiC semiconductor layer 22 with respect to the side surfaces 25A to 25D.

Even in the case of manufacturing the SiC semiconductor device 97 described above, the same effects as the effects described for the eleventh preferred embodiment can be exhibited.

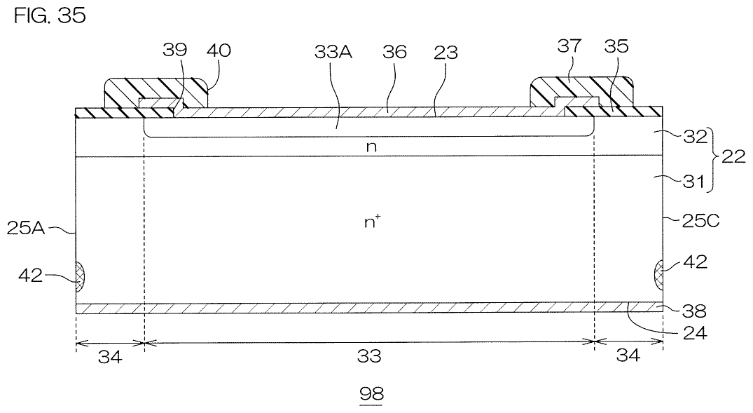

FIG. 35 is a sectional view of a region corresponding to FIG. 19 and is a sectional view of the general arrangement of an SiC semiconductor device 98 according to a nineteenth preferred embodiment of the present invention. In the following, structures corresponding to structures described with the SiC semiconductor device 21 shall be provided with the same reference symbols and description thereof shall be omitted.

Referring to FIG. 35, the SiC semiconductor device 98 does not have the inclining portion 41 at the corner portions at the first main surface 23 side and the corner portions at the second main surface 24 side. The SiC semiconductor device 98 includes the modified layer 42 formed in a thickness direction intermediate portion of the SiC semiconductor layer 22 at the side surfaces 25A to 25D.

More specifically, the modified layer 42 is formed in a thickness direction intermediate portion of the SiC semiconductor substrate 31. The modified layer 42 is formed at an interval toward the second main surface 24 side with respect to the boundary region between the SiC semiconductor substrate 31 and the SiC epitaxial layer 32. Also, the modified layer 42 is formed at an interval toward the SiC epitaxial layer 32 side with respect to the second main surface 24.

Such a modified layer 42 is formed by adjusting the light converging point of the laser light when irradiating the laser light onto the second main surface 24. In this case, the modified layer 42 is heated and cooled from the second main surface 3 side of the 4H—SiC crystal structure body 1 and the 4H—SiC crystal structure body 1 is cleaved. The step of FIG. 24K does not necessarily have to be performed.

Even in the case of manufacturing the SiC semiconductor device 98 described above, the same effects as the effects described for the eleventh preferred embodiment can be exhibited.

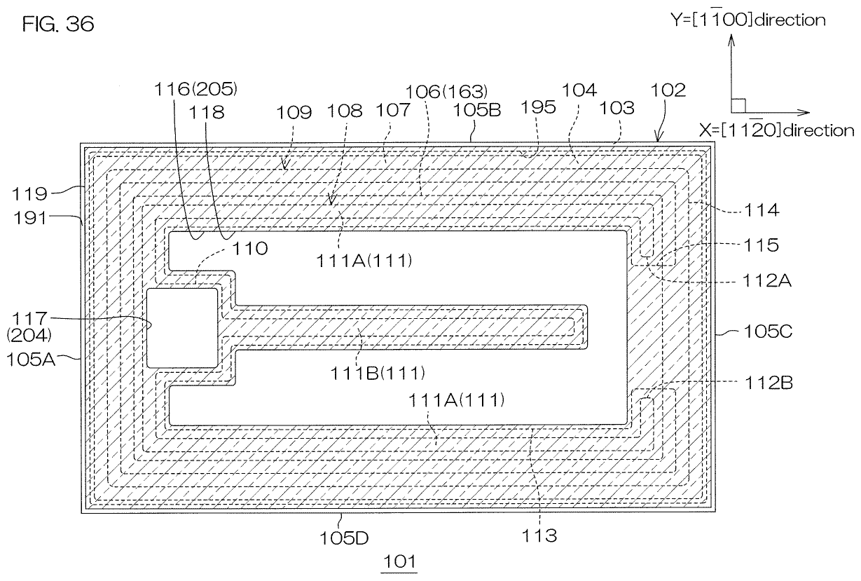

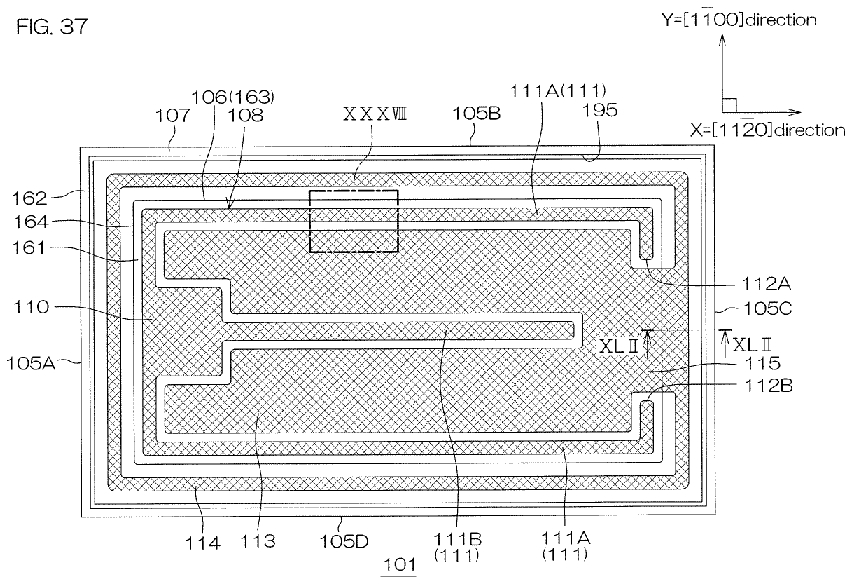

FIG. 36 is a top view of an SiC semiconductor device 101 according to a twentieth preferred embodiment of the present invention. FIG. 37 is a top view of the SiC semiconductor device 101 shown in FIG. 36 and is a top view with a resin layer 116 being removed. The SiC semiconductor device 101 is a device manufactured using the 4H—SiC crystal structure body 1 described above. The SiC semiconductor device 101 is also a configuration example that represents a specific structure of the SiC semiconductor device 21 described above.

Referring to FIG. 36 and FIG. 37, the SiC semiconductor device 101 includes an SiC semiconductor layer 102. A thickness of the SiC semiconductor layer 102 may be not less than 1 μm and less than 1000 μm. The thickness of the SiC semiconductor layer 102 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The SiC semiconductor layer 102 has a first main surface 103 at one side, a second main surface 104 at another side, and side surfaces 105A, 105B, 105C and 105D connecting the first main surface 103 and the second main surface 104. In this embodiment, the side surfaces 105A to 105D are all constituted of cut surfaces. More specifically, the side surfaces 105A to 105D are constituted of cleavage surfaces.

The first main surface 103 and the second main surface 104 are formed in quadrilateral shapes (rectangular shapes in this embodiment) in a plan view as viewed in a normal direction N to the surfaces (hereinafter referred to simply as “plan view”). The side surface 105A opposes the side surface 105C. The side surface 105B opposes the side surface 105D.

The SiC semiconductor layer 102 includes a 4H—SiC monocrystal. The first main surface 103 and the second main surface 104 face the c planes of the 4H—SiC monocrystal. The first main surface 103 faces the (0001) plane and the second main surface 104 faces the (000-1) plane.

The first main surface 103 and the second main surface 104 have an off angle θ inclined at an angle of not more than 10° in the [11-20] direction with respect to the (0001) plane. The off angle θ may be not less than 0° and not more than 2°, not less than 2° and not more than 4°, not less than 4° and not more than 6°, not less than 6° and not more than 8°, or not less than 8° and not more than 10⁰. The off angle θ is preferably not less than 0° and not more than 4⁰.

A state where the off angle θ is 0° is that in which the normal direction N and the c axis are matched. The off angle θ may exceed 0° and be less than 4⁰. The off angle θ is typically 2° or 4° and more specifically is set in a range of 2°±10% or a range of 4°±10%.

The side surfaces 105A to 105D respectively extend as planes along the normal direction N. A length of each of the side surfaces 105A to 105D may be not less than 1 mm and not more than 10 mm. The length of the side surfaces 105A to 105D may be not less than 1 mm and not more than 2.5 mm, not less than 2.5 mm and not more than 5 mm, not less than 5 mm and not more than 7.5 mm, or not less than 7.5 mm and not more than 10 mm. The length of the side surfaces 105A to 105D is preferably not less than 2 mm and not more than 5 mm.

The side surfaces 105A to 105D extend in a nearest neighbor direction and a nearest neighbor direction intersecting direction. More specifically, the nearest neighbor direction intersecting direction is an orthogonal direction orthogonal to the nearest neighbor direction. In this embodiment, the side surfaces 105A to 105D extend in the [11-20] direction and the [1-100] direction.

The side surface 105A and the side surface 105C that form short sides of a rectangle are formed along the nearest neighbor direction intersecting direction (that is, the [1-100] direction). The side surface 105B and the side surface 105D that form long sides of the rectangle are formed along the nearest neighbor direction (that is, the [11-20] direction). The side surface 105A and the side surface 105C may be formed along the [11-20] direction and the side surface 105B and the side surface 105D may be formed along the [1-100] direction instead.

In-plane variations of the side surfaces 105A to 105D are not more than 20 μm. The in-plane variations along the [11-20] direction of the side surfaces 105A and 105C that extend along the [1-100] direction are not more than 20 μm. More specifically, the in-plane variations of the side surfaces 105A and 105C are not more than 10 μm.

The in-plane variations along the [1-100] direction of the side surfaces 105B and 105D that extend along the [11-20] direction are not more than 20 μm. More specifically the in-plane variations of the side surfaces 105B and 105D are not more than 10 μm.

An in-plane variation is defined by a maximum value of distances between a reference virtual line and measurement virtual lines set in one of the side surfaces 105A to 105D selected from the side surfaces 105A to 105D. The reference virtual line is a straight line joining two corner portions of the SiC semiconductor 102 in plan view and is set in the selected one of the side surfaces 105A to 105D. A measurement virtual line is a straight line extending in parallel to the reference virtual line in plan view and is set to be tangent to a top portion or a base portion of a bulge (tortuosity) present on the selected one of the side surfaces 105A to 105D.

For example, the distance between the reference virtual line and the measurement virtual line tangent to the top portion of a bulge (tortuosity) and the distance between the reference virtual line and the measurement virtual line tangent to the base portion of the bulge (tortuosity) are measured. The in-plane variation of the selected one of the side surfaces 105A to 105D is defined by the maximum value of the measured distances between the reference virtual line and the measured virtual lines.

The SiC semiconductor layer 102 includes an active region 106 and an outer region 107. The active region 106 is a region in which a vertical MISFET (metal insulator semiconductor field effect transistor) is formed as an example of a field effect transistor. The outer region 107 is a region at an outer side of the active region 106.

The active region 106 may be set in a central portion of the SiC semiconductor layer 102 at intervals toward an inner region from the side surfaces 105A to 105D in plan view. The active region 106 may be set to a quadrilateral shape (a rectangular shape in this embodiment) having four sides parallel to the four side surfaces 105A to 105D in plan view.

The outer region 107 is set in a region between the side surfaces 105A to 105D and the active region 106. The outer region 107 may be set to an annular shape (for example, an endless shape) surrounding the active region 106 in plan view.

The SiC semiconductor device 101 includes a gate terminal electrode layer 108 and a source terminal electrode layer 109 that are formed on the first main surface 103. In this embodiment, the gate terminal electrode layer 108 includes a gate pad 110 and a gate finger 111. The gate pad 110 and the gate finger 111 are disposed in the active region 106.

The gate pad 110 is formed in a region oriented along the side surface 105A in plan view. The gate pad 110 is formed in a region oriented along a central portion of the side surface 105A in plan view. The gate pad 110 may be formed in a region oriented along a corner portion connecting any two of the side surfaces 105A to 105D in plan view. The gate pad 110 is formed in a quadrilateral shape in plan view.

The gate finger 111 includes an outer gate finger 111A and an inner gate finger 111B. The outer gate finger 111A is led out from the gate pad 110 and extends as a band along peripheral edges of the active region 106. In this embodiment, the outer gate finger 111A is formed along the three side surfaces 105A, 105B and 105D and defines an inner region of the active region 106 from three directions.

The outer gate finger 111A has a pair of open end portions 112A and 112B. The pair of open end portions 112A and 112B of the outer gate finger 111A are formed in a region opposing the gate pad 110 across the inner region of the active region 106. In this embodiment, the pair of open end portions 112A and 112B of the outer gate finger 111A are formed in a region oriented along the side surface 105C.

The inner gate finger 111B is led out from the gate pad 110 to the inner region of the active region 106. The inner gate finger 111B extends as a band in the inner region of the active region 106. The inner gate finger 111B extends from the side surface 105A side toward the side surface 105C side.

In this embodiment, the source terminal electrode layer 109 includes a source pad 113, a source routing wiring 114 and a source connection portion 115. The source pad 113 is formed in the active region 106 at intervals from the gate pad 110 and the gate finger 111. The source pad 113 covers a region of C shape (inverted C shape in FIG. 36 and FIG. 37) defined by the gate pad 110 and the gate finger 111. The source pad 113 is formed in a C shape (an inverted C shape in FIG. 36 and FIG. 37) in plan view.

The source routing wiring 114 is formed in the outer region 107. The source routing wiring 114 extends as a band along the active region 106. In this embodiment, the source routing wiring 114 is formed in an annular shape (for example, an endless shape) surrounding the active region 106 in plan view. The source routing wiring 114 is electrically connected to the SiC semiconductor layer 102 in the outer region 107.

The source connection portion 115 connects the source pad 113 and the source routing wiring 114. The source connection portion 115 is formed in a region between the pair of open end portions 112A and 112B of the outer gate finger 111A. The source connection portion 115 crosses a boundary region between the active region 106 and the outer region 107 from the source pad 113 and is connected to the source routing wiring 114.

Due to its structure, the MISFET formed in the active region 106 includes an npn type parasitic bipolar transistor. When an avalanche current generated in the outer region 107 flows into the active region 106, the parasitic bipolar transistor is switched to an on state. In this case, control of the MISFET may become unstable, for example, due to latchup.

Therefore, with the SiC semiconductor device 101, the structure of the source terminal electrode layer 109 is used to form an avalanche current absorbing structure that absorbs an avalanche current generated in a region outside the active region 106.

More specifically, the avalanche current generated in the outer region 107 is absorbed by the source routing wiring 114. The avalanche current is thereby made to reach the source pad 113 via the source connection portion 115. If a lead wire (for example, a bonding wire) for external connection is connected to the source pad 113, the avalanche current is taken out by this lead wire.

Switching of the parasitic bipolar transistor to the on state by an undesirable current generated in the outer region 107 can thereby be suppressed. Latchup can thus be suppressed and therefore stability of control of the MISFET can be improved.

A gate voltage is applied to the gate pad 110 and the gate finger 111. The gate voltage may be not less than 10 V and not more than 50 V (for example, approximately 30 V). A source voltage is applied to the source pad 113. The source voltage may be a reference voltage (for example, a GND voltage).

The SiC semiconductor device 101 includes the resin layer 116 formed on the first main surface 103 (more specifically, on an interlayer insulating layer 191 to be described below). In FIG. 36, the resin layer 116 is shown with hatching for clarity. The resin layer 116 covers the gate pad 110, the gate finger 111 and the source pad 113.

The resin layer 116 may include a negative type or positive type photosensitive resin. In this embodiment, the resin layer 116 includes a polybenzoxazole as an example of a positive type photosensitive resin. The resin layer 116 may include a polyimide as an example of a negative type photosensitive resin instead.

The resin layer 116 includes a gate pad opening 117 and a source pad opening 118. The gate pad opening 117 exposes the gate pad 110. The source pad opening 118 exposes the source pad 113.

A peripheral edge portion 119 of the resin layer 116 is formed at intervals in an inner region from the side surfaces 105A to 105D. The resin layer 116 thereby exposes a peripheral edge portion (more specifically, the interlayer insulating layer 191 to be described below) of the SiC semiconductor layer 102.

The peripheral edge portion 119 of the resin layer 116 is a portion in which dicing streets were formed in a process of cutting out the SiC semiconductor device 101 from the 4H—SiC crystal structure body 1. By exposing the peripheral edge portion of the SiC semiconductor layer 102 from the resin layer 116, it becomes unnecessary to physically cut the resin layer 116. The SiC semiconductor device 101 can thus be cut out smoothly from the 4H—SiC crystal structure body 1.

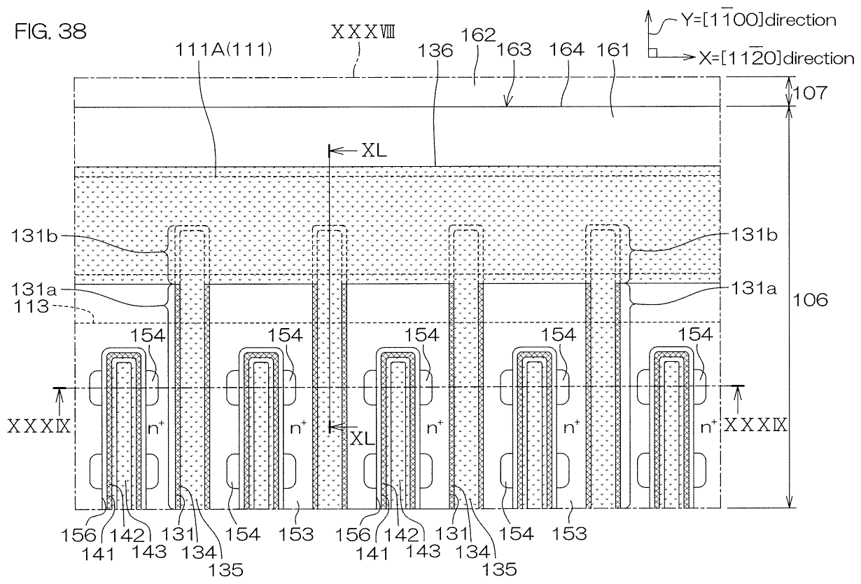

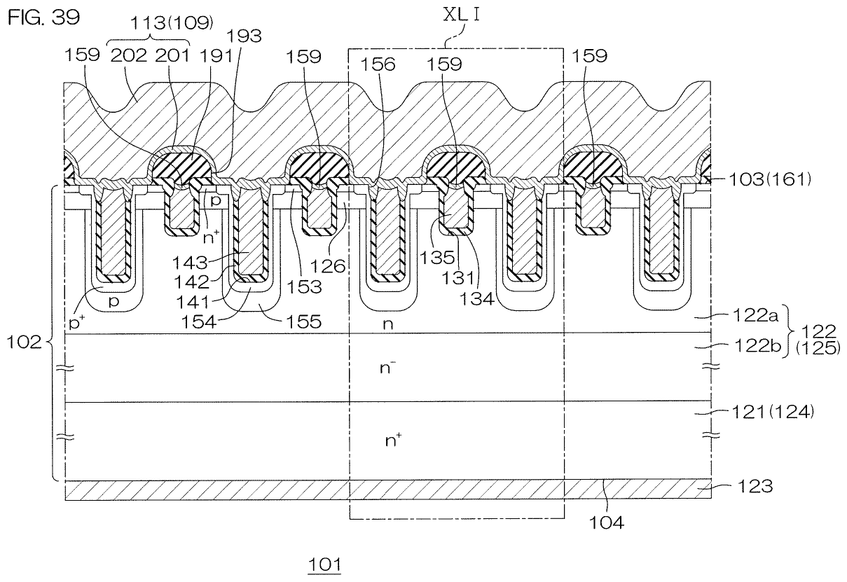

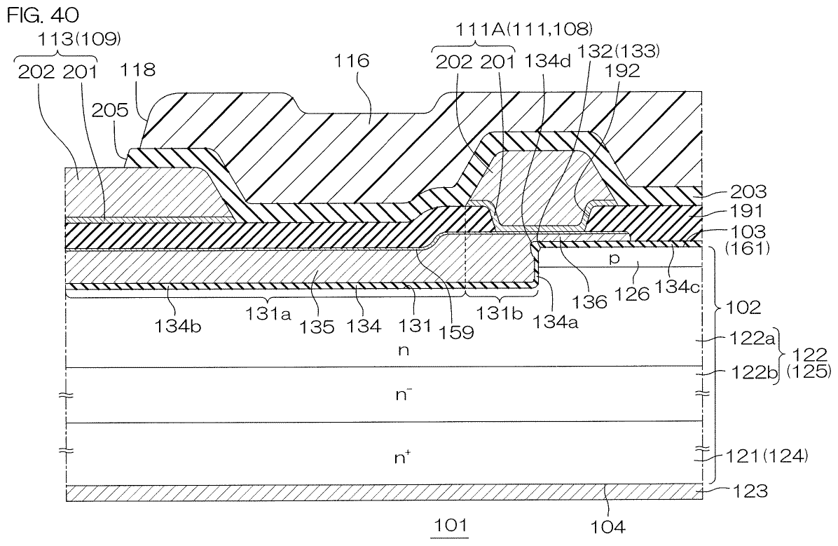

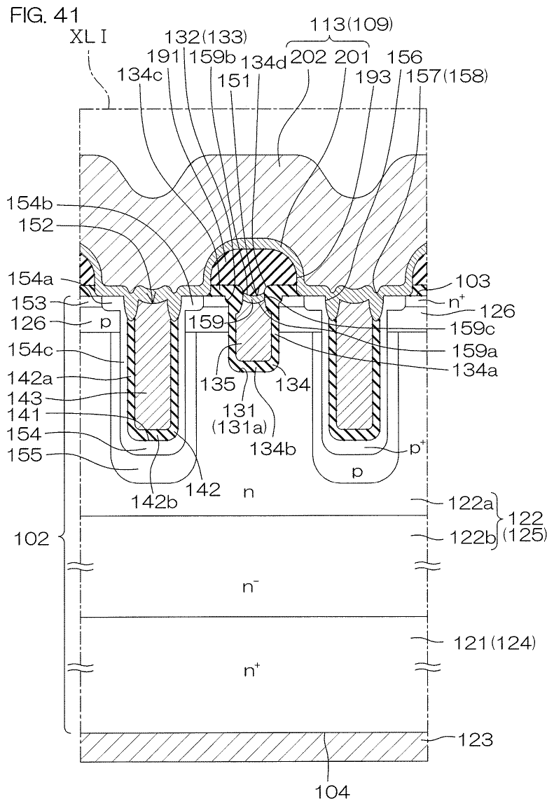

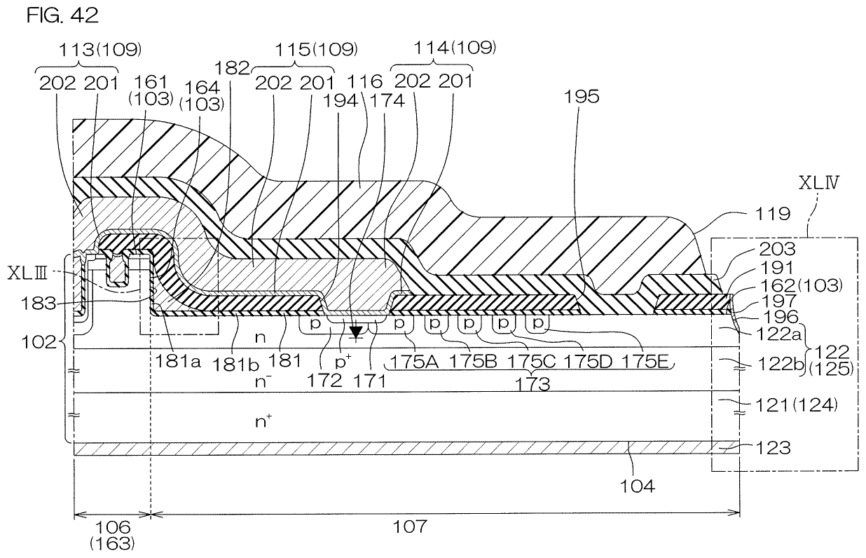

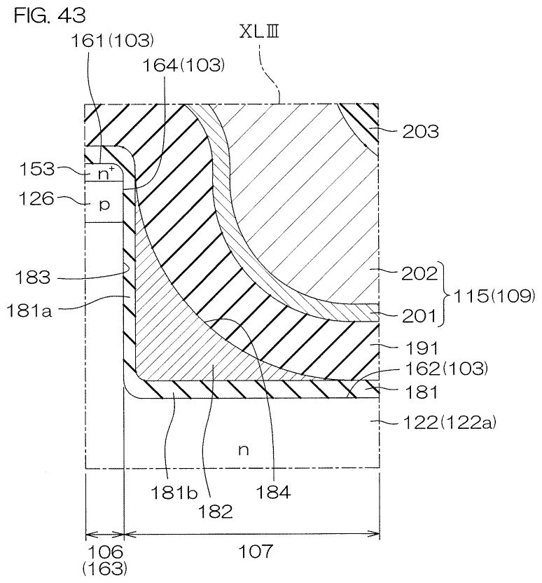

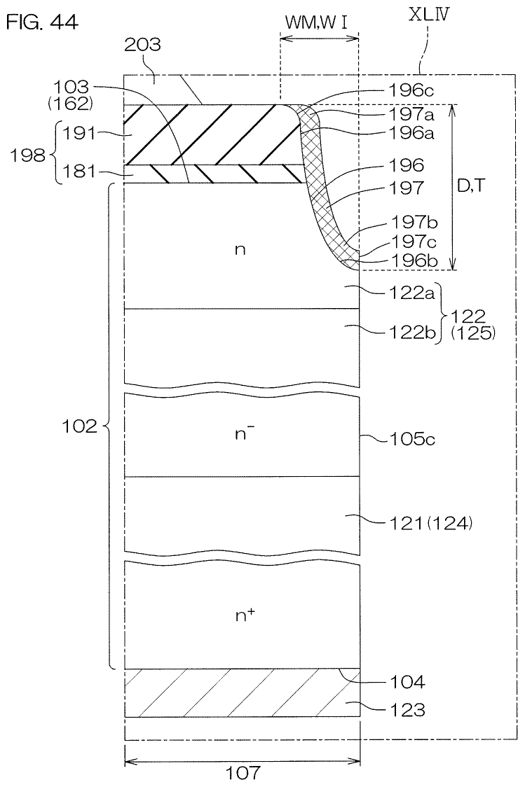

FIG. 38 is an enlarged view of a region XXXVIII shown in FIG. 37 and is a diagram for describing the structure of the first main surface 103 of the SiC semiconductor layer 102. FIG. 39 is a sectional view taken along line XXXIX-XXXIX shown in FIG. 38. FIG. 40 is a sectional view taken along line XL-XL shown in FIG. 38. FIG. 41 is an enlarged view of a region XLI shown in FIG. 39. FIG. 42 is a sectional view taken along line XLII-XLII shown in FIG. 37. FIG. 43 is an enlarged view of a region XLIII shown in FIG. 42. FIG. 44 is an enlarged view of a region XLIV shown in FIG. 42.

Referring to FIG. 38 to FIG. 44, the SiC semiconductor layer 102 has, in this embodiment, a laminated structure including an n+ type SiC semiconductor substrate 121 and an n type SiC epitaxial layer 122.

The second main surface 104 of the SiC semiconductor layer 102 is formed by the SiC semiconductor substrate 121. The first main surface 103 of the SiC semiconductor layer 102 is formed by the SiC epitaxial layer 122. The side surfaces 105A to 105D of the SiC semiconductor layer 102 are formed by the SiC semiconductor substrate 121 and the SiC epitaxial layer 122. The second main surface 104 may be a ground surface having grinding processing marks.

A thickness of the SiC epitaxial layer 122 is less than a thickness of the SiC semiconductor substrate 121. The thickness of the SiC semiconductor substrate 121 may be not less than 1 μm and less than 1000 μm. The thickness of the SiC semiconductor substrate 121 may be not less than 1 μm and not more than 50 μm, not less than 50 μm and not more than 150 μm, not less than 150 μm and not more than 250 μm, not less than 250 μm and not more than 400 μm, not less than 400 μm and not more than 600 μm, not less than 600 μm and not more than 800 μm, or not less than 800 μm and not more than 1000 μm.

The thickness of the SiC semiconductor substrate 121 is preferably not more than 150 μm. By making the thickness of the SiC semiconductor substrate 121 small, reduction of resistance value can be achieved by shortening of a current path.

The thickness of the SiC epitaxial layer 122 may be not less than 1 μm and not more than 100 μm. The thickness of the SiC epitaxial layer 122 may be not less than 1 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 75 μm, or not less than 75 μm and not more than 100 μm. The thickness of the SiC epitaxial layer 122 is preferably not less than 5 μm and not more than 20 μm.

An n type impurity concentration of the SiC epitaxial layer 122 is not more than an n type impurity concentration of the SiC semiconductor substrate 121. The n type impurity concentration of the SiC semiconductor substrate 121 may be not less than 1.0×10¹⁸ cm⁻³ and not more than 1.0×10²¹ cm⁻³. The n type impurity concentration of the SiC epitaxial layer 122 may be not less than 1.0×10¹⁵ cm⁻³ and not more than 1.0×10¹⁸ cm⁻³.

In this embodiment, the SiC epitaxial layer 122 has a plurality of regions having different n type impurity concentrations along the normal direction N. More specifically, the SiC epitaxial layer 122 includes a high concentration region 122a of comparatively high n type impurity concentration and a low concentration region 122b of lower n type impurity concentration than the high concentration region 122a.

The high concentration region 122a is formed in a region at the first main surface 103 side. The low concentration region 122b is formed in a region at the second main surface 104 side with respect to the high concentration region 122a. The n type impurity concentration of the high concentration region 122a may be not less than 1×10¹⁶ cm⁻³ and not more than 1×10¹⁸ cm⁻³. The n type impurity concentration of the low concentration region 122b may be not less than 1×10¹⁵ cm⁻³ and not more than 1×10¹⁶ cm⁻³.

A thickness of the high concentration region 122a is not more than a thickness of the low concentration region 122b. More specifically, the thickness of the high concentration region 122a is less than the thickness of the low concentration region 122b. That is, the thickness of the high concentration region 122a is less than half the total thickness of the SiC epitaxial layer 122.

The SiC epitaxial layer 122 is formed, for example, by changing an introduced amount (added amount) of the n type impurity along an SiC growth direction when epitaxially growing SiC from the SiC semiconductor wafer 51 in the step of preparing the 4H—SiC crystal structure body 1 (see FIG. 23 and FIG. 24A).

The SiC semiconductor device 101 includes a drain pad 123 connected to the second main surface 104 of the SiC semiconductor layer 102. That is, the SiC semiconductor substrate 121 is formed as a drain region 124 of the MISFET. The SiC epitaxial layer 122 is formed as a drift region 125 of the MISFET. A maximum voltage that can be applied across the source pad 113 and the drain pad 123 in an off state may be not less than 1000 V and not more than 10000 V.

The drain pad 123 may include at least one layer among an Al layer, a Ti layer, an Ni layer, an Au layer and an Ag layer. The drain pad 123 may have a laminated structure in which at least two layers among an Al layer, a Ti layer, an Ni layer, an Au layer and an Ag layer are laminated in any mode. The drain pad 123 may have a single layer structure constituted of an Al layer, a Ti layer, an Ni layer, an Au layer, or an Ag layer. The drain pad 123 may have a four-layer structure that includes a Ti layer, an Ni layer, an Au layer and an Ag layer that are laminated in that order from the second main surface 104.

The SiC semiconductor device 101 includes a p type body region 126 formed in a surface layer portion of the first main surface 103 of the SiC semiconductor layer 102 in the active region 106. A p type impurity concentration of the body region 126 may be not less than 1×10¹⁷ cm⁻³ and not more than 1×10²⁰ cm⁻³. The body region 126 defines the active region 106.

The SiC semiconductor device 101 includes a plurality of gate trenches 131 in the surface layer portion of the first main surface 103 in the active region 106. The plurality of gate trenches 131 are formed at intervals along an arbitrary first direction X. The plurality of gate trenches 131 are formed as bands extending along a second direction Y intersecting the first direction X. The second direction Y is a direction orthogonal to the first direction X. The plurality of gate trenches 131 are thereby formed as stripes extending along the second direction Y as a whole in plan view.

Preferably, the first direction X is set to the [11-20] direction and the second direction Y is set to the [1-100] direction. That is, the plurality of gate trenches 131 are preferably formed as bands formed at intervals in the [11-20] direction and extending along the [1-100] direction.

The first direction X may be set to the [1-100] direction and the second direction Y may be set to the [11-20] direction instead. That is, the plurality of gate trenches 131 may be formed as bands formed at intervals in the [1-100] direction and extending along the [11-20] direction.

Each gate trench 131 extends as a band from a peripheral edge portion at one side (the side surface 105B side) toward a peripheral edge portion at another side (the side surface 105D side) of the active region 106. Each gate trench 131 crosses an intermediate portion between the peripheral edge portion at the one side and the peripheral edge portion at the other side of the active region 106. One end portion of each gate trench 131 is positioned at the peripheral edge portion at the one side of the active region 106. Another end portion of each gate trench 131 is positioned at the peripheral edge portion at the other side of the active region 106.

Each gate trench 131 has a length of the millimeter order (a length not less than 1 mm). The length of each gate trench 131 may be not less than 1 mm and not more than 10 mm. The length of each gate trench 131 may be not less than 1 mm and not more than 2 mm, not less than 2 mm and not more than 4 mm, not less than 4 mm and not more than 6 mm, not less than 6 mm and not more than 8 mm, or not less than 8 mm and not more than 10 mm. The length of each gate trench 131 is preferably not less than 2 mm and not more than 5 mm. Also, a total extension of one or a plurality of the gate trenches 131 per unit area is preferably not less than 0.5 μm/μm² and not more than 0.75 μm/μm².

Each gate trench 131 includes an active trench portion 131a and a contact trench portion 131b. The active trench portion 131a is a portion in the active region 106 along a channel region of the MISFET. The contact trench portion 131b is a portion of the gate trench 131 that mainly serves as a contact with the gate finger 111.

The contact trench portion 131b is led out from the active trench portion 131a to a peripheral edge portion of the active region 106. The contact trench portion 131b is formed in a region directly below the gate finger 111. A lead-out amount of the contact trench portion 131b is arbitrary.

Each gate trench 131 penetrates through the body region 126 and reaches the SiC epitaxial layer 122. A bottom wall of each gate trench 131 is positioned inside the SiC epitaxial layer 122.

More specifically, the bottom wall of each gate trench 131 is positioned in the high concentration region 122a of the SiC epitaxial layer 122. The bottom wall of the gate trench 131 may be formed parallel to the first main surface 103. The bottom wall of the gate trench 131 may be formed in a shape curved toward the second main surface 104.

Side wall of the gate trench 131 may extend along the normal direction N. The side wall of the gate trench 131 may be formed substantially perpendicular to the first main surface 103 of the SiC semiconductor layer 102. The gate trench 131 may be formed in a tapered shape with a bottom area being less than an opening area.

A depth of the gate trench 131 along the normal direction N may be not less than 0.5 μm and not more than 3 μm. The depth of the gate trench 131 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The depth of the gate trench 131 is preferably not less than 0.5 μm and not more than 1.0 μm.

A width of the gate trench 131 along the first direction X may be not less than 0.1 μm and not more than 2 μm. The width of the gate trench 131 may be not less than 0.1 μm and not more than 0.5 μm, not less than 0.5 μm and not more than 1 μm, not less than 1 μm and not more than 1.5 μm, or not less than 1.5 μm and not more than 2 μm. The width of the gate trench 131 is preferably not less than 0.1 μm and not more than 0.5 μm.

Referring to FIG. 41, an opening edge portion 132 of each gate trench 131 includes an inclining portion 133 that inclines downwardly from the first main surface 103 toward the gate trench 131. The opening edge portion 132 of the gate trench 131 is a corner portion connecting the first main surface 103 and the side wall of the gate trench 131.

In this embodiment, the inclining portion 133 is formed in a curved shape recessed toward the SiC semiconductor layer 102. The inclining portion 133 may instead be formed in a curved shape protruding toward an inner side of the gate trench 131. An electric field with respect to the opening edge portion 132 is relaxed by the inclining portion 133.

The SiC semiconductor device 101 includes a gate insulating layer 134 and a gate electrode layer 135 formed inside each gate trench 131. In FIG. 38, the gate insulating layer 134 and the gate electrode layer 135 are shown with hatching.

The gate insulating layer 134 includes silicon oxide. The gate insulating layer 134 may include another insulating film of silicon nitride, etc. The gate insulating layer 134 is formed as a film along inner wall surfaces of the gate trench 131. The gate insulating layer 134 defines a recess space inside the gate trench 131.

The gate insulating layer 134 includes a first region 134a, a second region 134b and a third region 134c. The first region 134a is formed along the side wall of the gate trench 131. The second region 134b is formed along the bottom wall of the gate trench 131. The third region 134c is led out from the first region 134a onto the first main surface 103 and formed on the first main surface 103.

A thickness T1 of the first region 134a is less than a thickness T2 of the second region 134b and a thickness T3 of the third region 134c. A ratio T2/T1 of the thickness T2 of the second region 134b with respect to the thickness T1 of the first region 134a may be not less than 2 and not more than 5. A ratio T3/T1 of the thickness T3 of the third region 134c with respect to the thickness T1 of the first region 134a may be not less than 2 and not more than 5.

The thickness T1 of the first region 134a may be not less than 0.01 μm and not more than 0.2 μm. The thickness T2 of the second region 134b may be not less than 0.05 μm and not more than 0.5 μm. The thickness T3 of the third region 134c may be not less than 0.05 μm and not more than 0.5 μm.

By thinning of the first region 134a, increase in carriers induced in regions of the body region 126 in vicinities of the side wall of the gate trench 131 can be suppressed. Increase in channel resistance can thereby be suppressed. By thickening of the second region 134b, concentration of electric field with respect to the bottom wall of the gate trench 131 can be relaxed.

By thickening of the third region 134c, a withstand voltage of the gate insulating layer 134 in a vicinity of the opening edge portion 132 can be improved. Also, by the thickening of the third region 134c, loss of the third region 134c due to an etching method can be suppressed. The first region 134a can thereby be protected by the third region 134c.

For example, removal of the first region 134a by the etching method due to the loss of the third region 134c can be suppressed. The gate electrode layer 135 can thereby be made to oppose the SiC semiconductor layer 102 (body region 126) appropriately across the gate insulating layer 134.

The gate insulating layer 134 further includes a bulging portion 134d which bulges toward an interior of the gate trench 131 at the opening edge portion 132. The bulging portion 134d is formed at a portion connecting the first region 134a and the third region 134c of the gate insulating layer 134. The bulging portion 134d bulges curvingly toward the inner side of the gate trench 131. The bulging portion 134d narrows an opening of the gate trench 131 at the opening edge portion 132.

Improvement of the dielectric withstand voltage of the gate insulating layer 134 at the opening edge portion 132 is achieved by the bulging portion 134d. A gate insulating layer 134 not having the bulging portion 134d may be formed instead. A gate insulating layer 134 having a uniform thickness may be formed instead.

The gate electrode layer 135 is embedded in the gate trench 131 across the gate insulating layer 134. More specifically, the gate electrode layer 135 is embedded in the recess space defined by the gate insulating layer 134. The gate electrode layer 135 is controlled by the gate voltage.

The gate electrode layer 135 is formed as a wall extending along the normal direction N in sectional view. The gate electrode layer 135 has an upper end portion positioned at the opening side of the gate trench 131. The upper end portion of the gate electrode layer 135 is formed in a curved shape recessed toward the bottom wall of the gate trench 131. The upper end portion of the gate electrode layer 135 has a constricted portion that is constricted along the bulging portion 134d of the gate insulating layer 134.

A cross-sectional area of the gate electrode layer 135 in a direction (first direction X) orthogonal to the direction in which the gate trench 131 extends may be not less than 0.05 μm² and not more than 0.5 μm². The cross-sectional area of the gate electrode layer 135 is defined as a product of a thickness of the gate electrode layer 135 along the normal direction N and a width of the gate electrode layer 135 along the first direction X.

The thickness of the gate electrode layer 135 is a distance from the upper end portion to a lower end portion of the gate electrode layer 135. The width of the gate electrode layer 135 is a width of the gate electrode layer 135 at an intermediate position between the upper end portion and the lower end portion of the gate electrode layer 135. When the upper end portion is a curved surface (a curved shape recessed toward the lower side in this embodiment), an intermediate position of the upper end portion of the gate electrode layer 135 is deemed to be the position of the upper end portion of the gate electrode layer 135.

The cross-sectional area of the gate electrode layer 135 may be not less than 0.05 μm² and not more than 0.1 μm², not less than 0.1 μm² and not more than 0.2 μm², not less than 0.2 μm² and not more than 0.3 μm², not less than 0.3 μm² and not more than 0.4 μm², or not less than 0.4 μm² and not more than 0.5 μm².

The gate electrode layer 135 may include at least one type of material among a conductive polysilicon, tungsten, aluminum, copper, an aluminum alloy and a copper alloy. In this embodiment, the gate electrode layer 135 includes a p type polysilicon doped with a p type impurity. The p type impurity of the gate electrode layer 135 may include at least one type of material among boron (B), aluminum (Al), indium (In) and gallium (Ga).

A p type impurity concentration of the gate electrode layer 135 is not less than the p type impurity concentration of the body region 126. More specifically, the p type impurity concentration of the gate electrode layer 135 exceeds the p type impurity concentration of the body region 126. The p type impurity concentration of the gate electrode layer 135 may be not less than 1×10¹⁸ cm⁻³ and not more than 1×10²² cm⁻³. A sheet resistance of the gate electrode layer 135 may be not less than 10Ω/□ and not more than 500Ω/□ (approximately 200Ω/□ in this embodiment).

Referring to FIG. 38 and FIG. 40, the SiC semiconductor device 101 further includes a gate wiring layer 136 formed in the active region 106. In FIG. 40, the gate wiring layer 136 is shown with hatching. The gate wiring layer 136 electrically connects the gate pad 110 (gate finger 111) and the gate electrode layer 135.

In this embodiment, the gate wiring layer 136 is formed on the first main surface 103. More specifically, the gate wiring layer 136 is formed on the third region 134c of the gate insulating layer 134.

In this embodiment, the gate wiring layer 136 is formed along the gate finger 111. More specifically, the gate wiring layer 136 is formed along the three side surfaces 105A, 105B and 105D of the SiC semiconductor layer 102 and defines the inner region of the active region 106 from three directions.

The gate wiring layer 136 is connected to the gate electrode layer 135 exposed from the contact trench portion 131b of each gate trench 131. In this embodiment, the gate wiring layer 136 is formed by lead-out portions of the gate electrode layers 135 that are led out from the respective gate trenches 131 onto the first main surface 103. An upper end portion of the gate wiring layer 136 is connected to the upper end portions of the gate electrode layers 135.

Referring to FIG. 38, FIG. 39 and FIG. 41, the SiC semiconductor device 101 includes a plurality of source trenches 141 formed in the first main surface 103 in the active region 106. Each source trench 141 is formed in a region between two mutually adjacent gate trenches 131.

Each source trench 141 is formed as a band extending along the second direction Y. The plurality of source trenches 141 are formed as stripes extending along the second direction Y as a whole in plan view. The plurality of gate trenches 131 and the plurality of source trenches 141 are thereby formed as stripes formed alternately in the first direction X and extending along the second direction Y.

A pitch between central portions of two mutually adjacent source trenches 141 that are mutually adjacent in the first direction X may be not less than 1.5 μm and not more than 3 μm. The pitch of the source trenches 141 may be not less than 1.5 μm and not more than 2 μm, not less than 2 μm and not more than 2.5 μm, or not less than 2.5 μm and not more than 3 μm.

Each source trench 141 penetrates through the body region 126 and reaches the SiC epitaxial layer 122. A bottom wall of each source trench 141 is positioned inside the SiC epitaxial layer 122. More specifically, the bottom wall of each source trench 141 is positioned in the high concentration region 122a.

In this embodiment, a depth of the source trench 141 in the normal direction N is not less than the depth of the gate trench 131. More specifically, the depth of the source trench 141 exceeds the depth of the gate trench 131. The bottom wall of the source trench 141 is positioned at the second main surface 104 side with respect to the bottom wall of the gate trench 131.

In the normal direction N, the bottom wall of the source trench 141 is positioned in a region between the bottom wall of the gate trench 131 and the low concentration region 122b. The bottom wall of the source trench 141 may be formed parallel to the first main surface 103. The bottom wall of the source trench 141 may be formed in a shape curved toward the second main surface 104.

Side wall of the source trench 141 may extend along the normal direction N. The side wall of the source trench 141 may be formed substantially perpendicular to the first main surface 103. The source trench 141 may be formed in a tapered shape with a bottom area being less than an opening area.

A ratio of the depth of the source trench 141 with respect to the depth of the gate trench 131 may be not less than 1.5. The ratio of the depth of the source trench 141 with respect to the depth of the gate trench 131 is preferably not less than 2.

The depth of the source trench 141 may be not less than 0.5 μm and not more than 10 μm. The depth of the source trench 141 may be not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, or not less than 8 μm and not more than 10 μm. The depth of the source trench 141 is preferably not less than 1 μm and not more than 6 μm.

A width of the source trench 141 may be not less than 0.1 μm and not more than 2 μm. The width of the source trench 141 may be not less than 0.1 μm and not more than 0.5 μm, not less than 0.5 μm and not more than 1 μm, not less than 1 μm and not more than 1.5 μm, or not less than 1.5 μm and not more than 2 μm. The width of the source trench 141 is preferably not less than 0.1 μm and not more than 0.5 μm. The width of the source trench 141 along the first direction X may be substantially equal to the width of the gate trench 131 along the first direction X. The width of the source trench 141 along the first direction X may be not less than the width of the gate trench 131 along the first direction X.

The SiC semiconductor device 101 includes a source insulating layer 142 and a source electrode layer 143 formed inside each source trench 141. In FIG. 38, each source insulating layer 142 and each source electrode layer 143 are shown with hatching.

The source insulating layer 142 may include silicon oxide. The source insulating layer 142 may include another insulating film of silicon nitride, etc. The source insulating layer 142 is formed as a film along inner wall surfaces of the source trench 141 and defines a recess space inside the source trench 141.

The source insulating layer 142 includes a first region 142a and a second region 142b. The first region 142a is formed along the side wall of the source trench 141. The second region 142b is formed along the bottom wall of the source trench 141. A thickness T11 of the first region 142a is less than a thickness T12 of the second region 142b.

A ratio T12/T11 of the thickness T12 of the second region 142b with respect to the thickness T11 of the first region 142a may be not less than 2 and not more than 5. The thickness T11 of the first region 142a may be not less than 0.01 μm and not more than 0.2 μm. The thickness T12 of the second region 142b may be not less than 0.05 μm and not more than 0.5 μm.

The thickness T11 of the first region 142a may be substantially equal to the thickness T1 of the first region 134a of the gate insulating layer 134. The thickness T12 of the second region 142b may be substantially equal to the thickness T2 of the second region 134b of the gate insulating layer 134. Also, a source insulating layer 142 having a uniform thickness may be formed.

The source electrode layer 143 is embedded in the source trench 141 across the source insulating layer 142. More specifically, the source electrode layer 143 is embedded in the recess space defined by the source insulating layer 142. The source electrode layer 143 is controlled by the source voltage.

The source electrode layer 143 has an upper end portion positioned at an opening side of the source trench 141. The upper end portion of the source electrode layer 143 is formed at the bottom wall side of the source trench 141 with respect to the first main surface 103. The upper end portion of the source electrode layer 143 is formed in a curved shape recessed toward the bottom wall of the source trench 141. The upper end portion of the source electrode layer 143 may be formed parallel to the first main surface 103.

The upper end portion of the source electrode layer 143 may be positioned higher than the first main surface 103. The upper end portion of the source electrode layer 143 may project higher than an upper end portion of the source insulating layer 142. The upper end portion of the source electrode layer 143 may be positioned lower than the upper end portion of the source insulating layer 142.

A thickness along the normal direction N of the source electrode layer 143 may be not less than 0.5 μm and not more than 10 μm (for example, approximately 1 μm). The thickness of the source electrode layer 143 may be not less than 0.5 μm and not more than 1 μm, not less than 1 μm and not more than 2 μm, not less than 2 μm and not more than 4 μm, not less than 4 μm and not more than 6 μm, not less than 6 μm and not more than 8 μm, or not less than 8 μm and not more than 10 μm. The thickness of the source electrode layer 143 is preferably not less than 1 μm and not more than 6 μm.

The source electrode layer 143 preferably includes a polysilicon having properties close to SiC in terms of material properties. Stress generated in the SiC semiconductor layer 102 due to the source electrode layer 143 can thereby be reduced. The source electrode layer 143 may preferably include the same conductive material type as the gate electrode layer 135.

The source electrode layer 143 may include a conductive polysilicon. The source electrode layer 143 may include an n type polysilicon or a p type polysilicon as an example of a conductive polysilicon. In place of a conductive polysilicon, the source electrode layer 143 may include at least one type of material among tungsten, aluminum, copper, an aluminum alloy and a copper alloy.

If the gate electrode layer 135 includes a p type polysilicon doped with a p type impurity, the source electrode layer 143 preferably includes a p type polysilicon doped with a p type impurity. The source electrode layer 143 can thereby be formed at the same time as the gate electrode layer 135.

In this case, the p type impurity of the source electrode layer 143 may include at least one type of material among boron (B), aluminum (Al), indium (In) and gallium (Ga). A p type impurity concentration of the source electrode layer 143 is not less than the p type impurity concentration of the body region 126. More specifically, the p type impurity concentration of the source electrode layer 143 exceeds the p type impurity concentration of the body region 126.

The p type impurity concentration of the source electrode layer 143 may be not less than 1×10¹⁸ cm⁻³ and not more than 1×10²² cm⁻³. A sheet resistance of the source electrode layer 143 may be not less than 10Ω/□ and not more than 500Ω/□ (approximately 200Ω/□ in this embodiment).

The p type impurity concentration of the source electrode layer 143 may be substantially equal to the p type impurity concentration of the gate electrode layer 135. The sheet resistance of the source electrode layer 143 may be substantially equal to the sheet resistance of the gate electrode layer 135.

The SiC semiconductor device 101 thus has trench gate structures 151 and trench source structures 152. Each trench gate structure 151 includes the gate trench 131, the gate insulating layer 134 and the gate electrode layer 135. Each trench source structure 152 includes the source trench 141, the source insulating layer 142 and the source electrode layer 143.

The SiC semiconductor device 101 includes n⁺ type source regions 153 formed in regions of a surface layer portion of the body region 126 along the side wall of each gate trench 131. An n type impurity concentration of the source regions 153 may be not less than 1.0×10¹⁸ cm⁻³ and not more than 1.0×10²¹ cm⁻³. A plurality of the source regions 153 are formed along the side wall at one side and the side wall at another side of the gate trenches 131 in the first direction X.

The plurality of source regions 153 are respectively formed as bands extending along the second direction Y. The plurality of source regions 153 are formed as stripes as a whole in plan view. The respective source regions 153 are exposed from the side wall of the gate trenches 131 and the side wall of the source trenches 141.

The SiC semiconductor device 101 includes a plurality of p⁺ type contact regions 154 formed in the surface layer portion of the first main surface 103. A p type impurity concentration of the contact regions 154 is greater than the p type impurity concentration of the body region 126. The p type impurity concentration of the contact regions 154 may be not less than 1.0×10¹⁸ cm⁻³ and not more than 1.0×10²¹ cm⁻³.

The plurality of p⁺ type contact regions 154 are respectively formed along the side wall of the plurality of source trenches 141. In this embodiment, a plurality of contact regions 154 are formed per one source trench 141. The plurality of contact regions 154 are formed at intervals in the second direction Y such as to be oriented along the source trench 141 for one source trench 141.

The plurality of contact regions 154 are formed at intervals in the first direction X from the gate trenches 131. Thereby, each contact region 154 opposes a gate trench 131 across a source region 153 in plan view.

Each contact region 154 covers the side wall and the bottom wall of a source trench 141. A bottom portion of each contact region 154 may be formed parallel to the bottom wall of a source trench 141. More specifically, each contact region 154 integrally includes a first surface layer region 154a, a second surface layer region 154b and an inner wall region 154c.

Each first surface layer region 154a is formed along a side wall at one side of a source trench 141 in the surface layer portion of the first main surface 103. The first surface layer region 154a extends from the side wall at one side of the source trench 141 toward the adjacent gate trench 131. The first surface layer region 154a may extend to an intermediate region between the source trench 141 and the gate trench 131.

The second surface layer region 154b is formed along the side wall at the other side of the source trench 141 in the surface layer portion of the first main surface 103. The second surface layer region 154b extends from the side surface at the other side of the source trench 141 toward the adjacent gate trench 131. The second surface layer region 154b may extend to an intermediate region between the source trench 141 and the gate trench 131.

The inner wall region 154c is formed in a region of the SiC semiconductor layer 102 along the inner wall of the source trench 141. The inner wall region 154c is formed along the side wall of the source trench 141. The inner wall region 154c covers corner portions connecting the side wall and the bottom wall of the source trench 141. The inner wall region 154c covers the bottom wall of the source trench 141 from the side wall of the source trench 141 via the corner portions. The bottom portion of each contact region 154 is formed by the inner wall region 154c.

The SiC semiconductor device 101 includes a plurality of p type deep well regions 155 formed in the surface layer portion of the first main surface 103. The deep well regions 155 are also referred to as withstand voltage adjusting regions (withstand voltage holding regions) that adjust the withstand voltage of the SiC semiconductor layer 102 in the active region 106.

The plurality of deep well regions 155 are formed in one-to-one correspondence with the plurality of source trenches 141. Each deep well region 155 covers the inner wall of the corresponding source trench 141 across the contact region 154. The deep well region 155 is formed as a band extending along the source trench 141 in plan view. The deep well region 155 is formed along the side wall of the source trench 141.

The deep well region 155 covers the corner portions connecting the side wall and the bottom wall of the source trench 141. The deep well region 155 covers the bottom wall of the source trench 141 from the side wall of the source trench 141 via the corner portions. The deep well region 155 is continuous to the body region 126 at the side wall of the source trench 141.

The deep well region 155 is formed in the high concentration region 122a of the SiC epitaxial layer 122. The deep well region 155 has a bottom portion positioned at the second main surface 104 side with respect to the bottom wall of the gate trench 131. The bottom portion of the deep well region 155 may be formed parallel to the bottom wall of the source trench 141.

A p type impurity concentration of the deep well region 155 may be substantially equal to the p type impurity concentration of the body region 126. The p type impurity concentration of the deep well region 155 may exceed the p type impurity concentration of the body region 126. The p type impurity concentration of the deep well region 155 may be less than the p type impurity concentration of the body region 126.

The p type impurity concentration of the deep well region 155 may be not more than the p type impurity concentration of the contact region 154. The p type impurity concentration of the deep well region 155 may be less than the p type impurity concentration of the contact region 154. The p type impurity concentration of the deep well region 155 may be not less than 1.0×10¹⁷ cm⁻³ and not more than 1.0×10¹⁹ cm⁻³.

The deep well regions 155 form pn junction portions with the SiC semiconductor layer 102 (high concentration region 122a of the SiC epitaxial layer 122). Depletion layers spread toward the plurality of gate trenches 131 from the pn junction portions. The depletion layers spreading from the deep well regions 155 spread toward regions at the second main surface 104 side with respect to the bottom walls of the gate trenches 131.

The depletion layers spreading from the deep well regions 155 may overlap with the bottom walls of the gate trenches 131. The depletion layers spreading from the bottom portions of the deep well regions 155 may overlap with the bottom walls of the gate trenches 131.

With an SiC semiconductor device that includes just a pn junction diode a problem of concentration of electric field inside the SiC semiconductor layer 102 does not occur frequently, due to the structure of not including trenches. The deep well regions 155 make the trench gate type MISFET approach the structure of a pn junction diode.

The electric field inside the SiC semiconductor layer 102 can thereby be relaxed in the trench gate type MISFET. Narrowing a pitch between the plurality of mutually adjacent deep well regions 155 is thus effective in terms of relaxing the concentration of electric field. With the deep well regions 155 having the bottom portions at the second main surface 104 side with respect to the bottom walls of the gate trenches 131, concentration of electric field with respect to the gate trenches 131 can be relaxed appropriately by the depletion layers.

The bottom portions of the plurality of deep well regions 155 are preferably formed at a substantially fixed interval from the second main surface 104. Occurrence of variation in distance between the bottom portion of each deep well region 155 and the second main surface 104 can thereby be suppressed. In this case, the withstand voltage (for example, an electrostatic breakdown strength) of the SiC semiconductor layer 102 can be suppressed from being restricted by the deep well regions 155 and therefore improvement of the withstand voltage can be achieved appropriately.

Also in this embodiment, the high concentration region 122a of the SiC epitaxial layer 122 is interposed in the regions between the plurality of mutually adjacent deep well regions 155. A JFET (junction field effect transistor) resistance can thereby be reduced in the regions between the plurality of deep well regions 155.

Further, in this embodiment, the bottom portions of the deep well regions 155 are positioned inside the high concentration region 122a of the SiC epitaxial layer 122. Current paths can thereby be expanded in a lateral direction parallel to the first main surface 103 by using the high concentration region 122a positioned directly below the deep well regions 155. Consequently, a current spread resistance can be reduced. The low concentration region 122b of the SiC epitaxial layer 122 increases the withstand voltage of the SiC semiconductor layer 102 in such a structure.

The deep well regions 155 are formed using the source trenches 141. That is, the deep well regions 155 are formed conformally to the inner wall of the source trenches 141. Occurrence of variation among the depths of the respective deep well regions 155 can thereby be suppressed appropriately. Also, by using the source trenches 141, the deep well regions 155 can be formed appropriately in comparatively deep regions of the SiC semiconductor layer 102.

The SiC semiconductor device 101 includes a plurality of source sub-trenches 156 formed in regions of the first main surface 103 along the upper end portions of the source electrode layers 143. The plurality of source sub-trenches 156 are each in communication with the corresponding source trench 141 and form a portion of the side wall of the source trench 141.

In this embodiment, the source sub-trench 156 is formed in an annular shape (for example, an endless shape) surrounding the upper end portion of the source electrode layer 143 in plan view. That is, the source sub-trench 156 borders the upper end portion of the source electrode layer 143.

The source sub-trench 156 is formed by digging into a portion of the source insulating layer 142. More specifically, the source sub-trench 156 is formed by digging into the upper end portion of the source insulating layer 142 and the upper end portion of the source electrode layer 143 from the first main surface 103.

The upper end portion of the source electrode layer 143 has a shape that is constricted with respect to a lower end portion of the source electrode layer 143. The lower end portion of the source electrode layer 143 is a portion of the source electrode layer 143 that is positioned at the bottom wall side of the source trench 141. A width along the first direction X of the upper end portion of the source electrode layer 143 may be less than a width along the first direction X of the lower end portion of the source electrode layer 143.

The source sub-trench 156 is formed to a convergent shape with a bottom area being less than an opening area in sectional view. A bottom wall of the source sub-trench 156 may be formed in a shape curved toward the second main surface 104.

The source region 153, the contact region 154, the source insulating region 142 and the source electrode layer 143 are exposed from inner wall of the source sub-trench 156. At least the first region 142a of the source insulating layer 142 is exposed from the bottom wall of the source sub-trench 156. An upper end portion of the first region 142a of the source insulating layer 142 is positioned lower than the first main surface 103.

An opening edge portion 157 of each source trench 141 includes an inclining portion 158 that inclines downwardly from the first main surface 103 toward an inner side of the source trench 141. The opening edge portion 157 of the source trench 141 is a corner portion connecting the first main surface 103 and the side wall of the source trench 141. The inclining portion 158 of the source trench 141 is formed by the source sub-trench 156.

In this embodiment, the inclining portion 158 is formed in a curved shape recessed toward the SiC semiconductor layer 102. The inclining portion 158 may instead be formed in a curved shape protruding toward the source sub-trench 156. An electric field with respect to the opening edge portion 157 is relaxed by the inclining portion 156.

The SiC semiconductor device 101 includes a low resistance electrode layer 159 formed on the gate electrode layer 135. Inside the gate trench 131, the low resistance electrode layer 159 covers the upper end portion of the gate electrode layer 135. That is, the trench gate structure 151 includes the low resistance electrode layer 159.

The low resistance electrode layer 159 includes a conductive material having a sheet resistance less than the sheet resistance of the gate electrode layer 135. A sheet resistance of the low resistance electrode layer 159 may be not less than 0.01Ω/□ and not more than 10Ω/□. The sheet resistance of the low resistance electrode layer 159 may be not less than 0.01Ω/□ and not more than 0.1Ω/□, not less than 0.1Ω/□ and not more than 1Ω/□, not less than 1Ω/□ and not more than 2Ω/□, not less than 2Ω/□ and not more than 4Ω/□, not less than 4Ω/□ and not more than 6Ω/□, not less than 6Ω/□ and not more than 8Ω/□, or not less than 8Ω/□ and not more than 10Ω/□.

A current supplied into the gate trenches 131 flows through the low resistance electrode layer 159, having the comparatively low sheet resistance, and is transmitted to entireties of the gate electrode layers 135. The entireties of the gate electrode layers 135 can thereby be made to transition rapidly from an on state to an off state and therefore delay of switching response can be suppressed.

In particular, although time is required for transmission of current in a case of gate trenches 131 having a length of the millimeter order, the delay of the switching response can be suppressed appropriately by the low resistance electrode layer 159. That is, the low resistance electrode layer 159 is formed as a current diffusing electrode layer that diffuses the current into the gate trenches 131.

The low resistance electrode layer 159 is formed as a film. The low resistance electrode layer 159 has a connection portion 159a in contact with the upper end portion of the gate electrode layer 135 and a non-connection portion 159b opposite thereof. The connection portion 159a and the non-connection portion 159b of the low resistance electrode layer 159 may be formed in curved shapes conforming to the upper end portion of the gate electrode layer 135. The connection portion 159a and the non-connection portion 159b of the low resistance electrode layer 159 may take on any of various configurations.

An entirety of the connection portion 159a of the low resistance electrode layer 159 may be positioned higher than the first main surface 103. The entirety of the connection portion 159a of the low resistance electrode layer 159 may be positioned lower than the first main surface 103.

The connection portion 159a of the low resistance electrode layer 159 may include a portion positioned higher than the first main surface 103. The connection portion 159a of the low resistance electrode layer 159 may include a portion positioned lower than the first main surface 103. For example, a central portion of the connection portion 159a of the low resistance electrode layer 159 may be positioned lower than the first main surface 103 and a peripheral edge portion of the connection portion 159a of the low resistance electrode layer 159 may be positioned higher than the first main surface 103.

An entirety of the non-connection portion 159b of the low resistance electrode layer 159 may be positioned higher than the first main surface 103. The entirety of the non-connection portion 159b of the low resistance electrode layer 159 may be positioned lower than the first main surface 103.

The non-connection portion 159b of the low resistance electrode layer 159 may include a portion positioned higher than the first main surface 103. The non-connection portion 159b of the low resistance electrode layer 159 may include a portion positioned lower than the first main surface 103. For example, a central portion of the non-connection portion 159b of the low resistance electrode layer 159 may be positioned lower than the first main surface 103 and a peripheral edge portion of the non-connection portion 159b of the low resistance electrode layer 159 may be positioned higher than the first main surface 103.

The low resistance electrode layer 159 has an edge portion 159c contacting the gate insulating layer 134. The edge portion 159c of the low resistance electrode layer 159 contacts a corner portion (the bulging portion 134d in this embodiment) which connects the first region 134a and the second region 134b at the gate insulating layer 134.

The edge portion 159c of the low resistance electrode layer 159 is formed in a region at the first main surface 103 side with respect to bottom portions of the source regions 153. That is, the edge portion 159c of the low resistance electrode layer 159 is formed in a region further to the first main surface 103 side than boundary regions between the body region 126 and the source regions 153.

The edge portion 159c of the low resistance electrode layer 159 thus opposes the source regions 153 across the gate insulating layer 134. The edge portion 159c of the low resistance electrode layer 159 does not oppose the body region 126 across the gate insulating layer 134. Formation of a leakage current path in a region of the gate insulating layer 134 between the low resistance electrode layer 159 and the body region 126 can thereby be suppressed.

A leakage current path may be formed by undesired diffusion of an electrode material of the low resistance electrode layer 159 into the gate insulating layer 134. Formation of a leakage current path can be suppressed appropriately by connecting the edge portion 159c of the low resistance electrode layer 159 to the comparatively thick third region 134c (the bulging portion 134d) of the gate insulating layer 134.

In regard to the normal direction N, a thickness TR of the low resistance electrode layer 159 is not more than a thickness TG of the gate electrode layer 135 (TR≤TG). More specifically, the thickness TR of the low resistance electrode layer 159 is not more than one-half the thickness TG of the gate electrode layer 135 (TR≤TG/2).

A ratio TR/TG of the thickness TR of the low resistance electrode layer 159 with respect to the thickness TG of the gate electrode layer 135 may be not less than 0.01 and not more than 1. The ratio TR/TG may be not less than 0.01 and not more than 0.1, not less than 0.1 and not more than 0.2, not less than 0.2 and not more than 0.4, not less than 0.4 and not more than 0.6, not less than 0.6 and not more than 0.8, or not less than 0.8 and not more than 1.

The thickness TG of the gate electrode layer 135 may be not less than 0.5 μm and not more than 3 μm. The thickness TG of the gate electrode layer 135 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm.

The thickness TR of the low resistance electrode layer 159 may be not less than 0.01 μm and not more than 3 μm. The thickness TR of the low resistance electrode layer 159 may be not less than 0.01 μm and not more than 0.1 μm, not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm.

In this embodiment, the low resistance electrode layer 159 also covers the upper end portion of the gate wiring layer 136. A portion of the low resistance electrode layer 159 that covers the upper end portion of the gate wiring layer 136 is formed integral to portions of the low resistance electrode layer 159 covering the upper end portions of the gate electrode layers 135. The low resistance electrode layer 159 thereby covers entire areas of the gate electrode layers 135 and an entire area of the gate wiring layer 136.

A current supplied from the gate pad 110 (gate finger 111) to the gate wiring layer 136 thus flows through the low resistance electrode layer 159 of comparatively low sheet resistance and is transmitted to the entireties of the gate electrode layers 135 and the gate wiring layer 136. The entireties of the gate electrode layers 135 can thereby be made to transition rapidly from the on state to the off state via the gate wiring layer 136 and therefore the delay of the switching response can be suppressed.

In particular, in the case of the gate trenches 131 having the length of the millimeter order, the delay of the switching response can be suppressed appropriately by the low resistance electrode layer 159 covering the upper end portion of the gate wiring layer 136.

The low resistance electrode layer 159 includes a polycide layer. More specifically, the low resistance electrode layer 159 is constituted of a p type polycide layer that includes the p type impurity doped in the gate electrode layer 135 (p type polysilicon). The polycide layer is formed by a surface layer portion of the gate electrode layer 135, which includes the p type polysilicon, being silicided by a metal material. The siliciding of the p type polysilicon is performed by a heat treatment. The heat treatment may be that by an RTA (rapid thermal annealing) method.

In this embodiment, the low resistance electrode layer 159 has a specific resistance of not less than 10 μΩ·cm and not more than 110 μΩ·cm. The specific resistance of the low resistance electrode layer 159 may be not less than 10 μΩ·cm and not more than 20 μΩ·cm, not less than 20 μΩ·cm and not more than 40 μΩ·cm, not less than 40 μΩ·cm and not more than 60 μΩ·cm, not less than 60 μΩ·cm and not more than 80 μΩ·cm, or not less than 80 μΩ·cm and not more than 110 μΩ·cm.

More specifically, the low resistance electrode layer 159 includes at least one type of material among TiSi, TiSi₂, NiSi, CoSi, CoSi₂, MoSi₂ and WSi₂ as a polycide. Among these types of materials, NiSi, CoSi₂ and TiSi₂ are suitable as the polycide layer forming the low resistance electrode layer 159 due to being comparatively low in specific resistance value and temperature dependence.

A sheet resistance inside the gate trench 131 embedded with the gate electrode layer 135 (p type polysilicon) and the low resistance electrode layer 159 (p type polycide) is not more than a sheet resistance of the gate electrode layer 135 (p type polysilicon) alone. The sheet resistance inside the gate trench 131 is preferably not more than a sheet resistance of an n type polysilicon doped with an n type impurity.

The sheet resistance inside the gate trench 131 is approximated by the sheet resistance of the low resistance electrode layer 159. That is, the sheet resistance inside the gate trench 131 may be not less than 0.01Ω/□ and not more than 10Ω/□. The sheet resistance inside the gate trench 131 may be not less than 0.01Ω/□ and not more than 0.1Ω/□, not less than 0.1Ω/□ and not more than 1Ω/□, not less than 1Ω/□ and not more than 2Ω/□, not less than 2Ω/□ and not more than 4Ω/□, not less than 4Ω/□ and not more than 6Ω/□, not less than 6Ω/□ and not more than 8Ω/□, or not less than 8Ω/□ and not more than 10Ω/□. The sheet resistance inside the gate trench 131 is preferably less than 10Ω/□.

Referring to FIG. 42 and FIG. 43, the active region 106 has an active main surface 161 forming a portion of the first main surface 103. The outer region 107 has an outer main surface 162 forming a portion of the first main surface 103. The outer main surface 162 is connected to the side surfaces 105A to 105D.

The outer main surface 162 is positioned at the second main surface 104 side with respect to the active main surface 161. In this embodiment, the outer region 107 is formed by digging into the first main surface 103 toward the second main surface 104 side. The outer region 107 is thus formed in a region that is recessed toward the second main surface 104 side with respect to the active main surface 161.

The outer main surface 162 may be positioned at the second main surface 104 side with respect to the bottom walls of the gate trenches 131. The outer main surface 162 may be formed at a depth position substantially equal to the bottom walls of the source trenches 141. That is, the outer main surface 162 may be positioned on substantially the same plane as the bottom walls of the source trenches 141. A distance between the outer main surface 162 and the second main surface 104 may be substantially equal to a distance between the bottom wall of each source trench 141 and the second main surface 104.

The outer main surface 162 may be positioned at the second main surface 104 side with respect to the bottom walls of the source trenches 141. The outer main surface 162 may be positioned in a range of exceeding 0 μm and being not more than 1 μm to the second main surface 104 side with respect to the bottom walls of the source trenches 141.

The SiC epitaxial layer 122 is exposed from the outer main surface 162. More specifically, the high concentration region 122a of the SiC epitaxial layer 122 is exposed from the outer main surface 162. The outer main surface 162 opposes the low concentration region 122b of the SiC epitaxial layer 122 across the high concentration region 122a of the SiC epitaxial layer 122.

In this embodiment, the active region 106 is defined as a mesa by the outer region 107. That is, the active region 106 is formed as an active mesa 163 of mesa shape projecting further upward than the outer region 107.

The active mesa 163 includes active side wall 164 connecting the active main surface 161 and the outer main surface 162. The first main surface 103 of the SiC semiconductor layer 102 is formed by the active main surface 161, the outer main surface 162 and the active side wall 164.

In this embodiment, the active side wall 164 extend in a direction substantially perpendicular to the active main surface 161 (outer main surface 162). The active side wall 164 may be inclined downward from the active main surface 161 toward the outer main surface 162. The active side wall 164 defines a boundary region between the active region 106 and the outer region 107.

The SiC epitaxial layer 122 is exposed from the active side wall 164. More specifically, the high concentration region 122a of the SiC epitaxial layer 122 is exposed from the active side wall 164. A main structure of the MISFET can thereby be formed appropriately in the high concentration region 122a defined by the active mesa 163.

At least the body region 126 is exposed from a region of the active side wall 164 at the active main surface 161 side. In FIG. 42 and FIG. 43, a configuration example where the body region 126 and the source regions 153 are exposed from the active side wall 164 is shown.

The SiC semiconductor device 101 includes a p⁺ type diode region 171, a p type outer deep well region 172 and a p type field limit structure 173 formed in a surface layer portion of the outer main surface 162 (first main surface 103) in the outer region 107.

The diode region 171 is formed in a region of the outer region 107 between the active side wall 164 and the side surfaces 105A to 105D. The diode region 171 is formed at intervals from the active side wall 164 and the side surfaces 105A to 105D.

The diode region 171 extends as a band along the active region 106 in plan view. In this embodiment, the diode region 171 is formed in an annular shape (for example, an endless shape) surrounding the active region 106 in plan view.

The diode region 171 overlaps with the source routing wiring 114 in plan view. The diode region 171 is electrically connected to the source routing wiring 114. The diode region 171 forms a portion of the avalanche current absorbing structure.

The diode region 171 forms a pn junction portion with the SiC semiconductor layer 102. More specifically, the diode region 171 is positioned inside the SiC epitaxial layer 122. The diode region 171 thus forms the pn junction portion with the SiC epitaxial layer 122.

Even more specifically, the diode region 171 is positioned inside the high concentration region 122a of the SiC epitaxial layer 122. The diode region 171 thus forms the pn junction portion with the high concentration region 122a of the SiC epitaxial layer 122. A pn junction diode 174 having the diode region 171 as an anode and the SiC semiconductor layer 102 as a cathode is thereby formed.

An entirety of the diode region 171 is positioned at the second main surface 104 side with respect to the bottom walls of the gate trenches 131. A bottom portion of the diode region 171 is positioned at the second main surface 104 side with respect to the bottom walls of the source trenches 141. The bottom portion of the diode region 171 may be formed at a depth position substantially equal to the bottom portions of the contact regions 154. That is, the bottom portion of the diode region 171 may be positioned on substantially the same plane as the bottom portions of the contact regions 154.

A distance between the bottom portion of the diode region 171 and the second main surface 104 may be substantially equal to a distance between the bottom portion of each contact region 154 and the second main surface 104. The bottom portion of the diode region 171 may be positioned at the second main surface 104 side with respect to the bottom portions of the contact regions 154. The bottom portion of the diode region 171 may be positioned in a range of exceeding 0 μm and being not more than 1 μm to the second main surface 104 side with respect to the bottom portions of the contact regions 154.

A p type impurity concentration of the diode region 171 is substantially equal to the p type impurity concentration of the contact regions 154. The p type impurity concentration of the diode region 171 exceeds the p type impurity concentration of the body region 126. The p type impurity concentration of the diode region 171 may be not less than 1.0×10¹⁸ cm⁻³ and not more than 1.0×10²¹ cm⁻³.

The outer deep well region 172 is formed in a region between the active side wall 164 and the diode region 171 in plan view. In this embodiment, the outer deep well region 172 is formed at intervals toward the diode region 171 side from the active side wall 164. The outer deep well region 172 is also referred to as a withstand voltage adjusting region (withstand voltage holding region) that adjusts the withstand voltage of the SiC semiconductor layer 102 in the outer region 107.

The outer deep well region 172 extends along the active region 106 in plan view. In this embodiment, the outer deep well region 172 is formed in an annular shape (for example, an endless shape) surrounding the active region 106 in plan view.

A bottom portion of the outer deep well region 172 is positioned at the second main surface 104 side with respect to the bottom portion of the diode region 171. In this embodiment, the outer deep well region 172 covers the diode region 171 from the second main surface 104 side. The outer deep well region 172 may overlap with the source routing wiring 114 in plan view.

The outer deep well region 172 is electrically connected to the source routing wiring 114 via the diode region 171. The outer deep well region 172 may form a portion of the pn junction diode 174. The outer deep well region 172 may form a portion of the avalanche current absorbing structure.

An entirety of the outer deep well region 172 is positioned at the second main surface 104 side with respect to the bottom walls of the gate trenches 131. The bottom portion of the outer deep well region 172 is positioned at the second main surface 104 side with respect to the bottom walls of the source trenches 141.

The bottom portion of the outer deep well region 172 may be formed at a depth position substantially equal to the bottom portions of the deep well regions 155. That is, the bottom portion of the outer deep well region 172 may be positioned on substantially the same plane as the bottom portions of the deep well regions 155. A distance between the bottom portion of the outer deep well region 172 and the outer main surface 162 may be substantially equal to a distance between the bottom portion of each deep well region 155 and the bottom wall of the source trench 141.

A distance between the bottom portion of the outer deep well region 172 and the second main surface 104 may be substantially equal to a distance between the bottom portion of each deep well region 155 and the second main surface 104. Variation can thereby be suppressed from occurring between the distance between the bottom portion of the outer deep well region 172 and the second main surface 104 and the distance between the bottom portion of each deep well region 155 and the second main surface 104.

In this case, the withstand voltage (for example, the electrostatic breakdown strength) of the SiC semiconductor layer 102 can be suppressed from being restricted by the outer deep well region 172 and the deep well region 155 and therefore improvement of the withstand voltage can be achieved appropriately.

The bottom portion of the outer deep well region 172 may be positioned at the second main surface 104 side with respect to the bottom portions of the deep well regions 155. The bottom portion of the outer deep well region 172 may be positioned in a range of exceeding 0 μm and being not more than 1 μm to the second main surface 104 side with respect to the bottom portions of the deep well regions 155.

A p type impurity concentration of the outer deep well region 172 may be not more than the p type impurity concentration of the diode region 171. The p type impurity concentration of the outer deep well region 172 may be less than the p type impurity concentration of the diode region 171.

The p type impurity concentration of the outer deep well region 172 may be substantially equal to the p type impurity concentration of the deep well regions 155. The p type impurity concentration of the outer deep well region 172 may be substantially equal to the p type impurity concentration of the body region 126.

The p type impurity concentration of the outer deep well region 172 may exceed the p type impurity concentration of the body region 126. The p type impurity concentration of the outer deep well region 172 may be less than the p type impurity concentration of the body region 126.

The p type impurity concentration of the outer deep well region 172 may be not more than the p type impurity concentration of the contact regions 154. The p type impurity concentration of the outer deep well region 172 may be less than the p type impurity concentration of the contact regions 154. The p type impurity concentration of the outer deep well region 172 may be not less than 1.0×10¹⁷ cm⁻³ and not more than 1.0×10¹⁹ cm⁻³.

The field limit structure 173 is formed in a region between the diode region 171 and the side surfaces 105A to 105D in plan view. In this embodiment, the field limit structure 173 is formed at intervals toward the side surfaces 105A to 105D sides from the diode region 171.

The field limit structure 173 includes one or a plurality of (for example, not less than two and not more than twenty) field limit regions. In this embodiment, the field limit structure 173 includes a field limit region group having a plurality of (five) field limit regions 175A, 175B, 175C, 175D and 175E.

The field limit regions 175A to 175E are formed in that order at intervals along a direction away from the diode region 171. The field limit regions 175A to 175E respectively extend as bands along the peripheral edge of the active region 106 in plan view.

More specifically, the field limit regions 175A to 175E are respectively formed as annular shapes (for example, an endless shapes) surrounding the active region 106 in plan view. Each of the field limit regions 175A to 175E is also referred to as an FLR (field limiting ring) region.

In this embodiment, bottom portions of the field limit regions 175A to 175E are positioned at the second main surface 104 side with respect to the bottom portion of the diode region 171. In this embodiment, the field limit region 175A at an innermost side among the field limit regions 175A to 175E covers the diode region 171 from the second main surface 104 side.

The field limit region 175A may be overlapped in plan view with the source routing wiring 114 described above. The field limit region 175A may be electrically connected to the source routing wiring 114 via the diode region 171. The field limit region 175A may form a portion of the pn junction diode 174. The field limit region 175A may form a portion of the avalanche current absorbing structure.

Entireties of the field limit regions 175A to 175E are positioned at the second main surface 104 side with respect to the bottom walls of the gate trenches 131. The bottom portions of the field limit regions 175A to 175E are positioned at the second main surface 104 side with respect to the bottom walls of the source trenches 141.

The field limit regions 175A to 175E may be formed at a depth position substantially equal to the deep well regions 155 (outer deep well region 172). That is, the bottom portions of the field limit regions 175A to 175E may be positioned on substantially the same plane as the bottom portions of the deep well regions 155 (outer deep well region 172).

The bottom portions of the field limit regions 175A to 175E may be positioned at the outer main surface 162 side with respect to the bottom portions of the deep well regions 155 (outer deep well region 172). The bottom portions of the field limit regions 175A to 175E may be positioned at the second main surface 104 side with respect to the bottom portions of the deep well regions 155 (outer deep well region 172).

Widths between mutually adjacent field limit regions 175A to 175E may differ from each other. The widths between mutually adjacent field limit regions 175A to 175E may increase in a direction away from the active region 106. The widths between mutually adjacent field limit regions 175A to 175E may decrease in the direction away from the active region 106.

Depths of the field limit regions 175A to 175E may differ from each other. The depths of the field limit regions 175A to 175E may decrease in the direction away from the active region 106. The depths of the field limit regions 175A to 175E may increase in the direction away from the active region 106.

A p type impurity concentration of the field limit regions 175A to 175E may be not more than the p type impurity concentration of the diode region 171. The p type impurity concentration of the field limit regions 175A to 175E may be less than the p type impurity concentration of the diode region 171.

The p type impurity concentration of the field limit regions 175A to 175E may be not more than the p type impurity concentration of the outer deep well region 172. The p type impurity concentration of the field limit regions 175A to 175E may be less than the p type impurity concentration of the outer deep well region 172.

The p type impurity concentration of the field limit regions 175A to 175E may be not less than the p type impurity concentration of the outer deep well region 172. The p type impurity concentration of the field limit regions 175A to 175E may be greater than the p type impurity concentration of the outer deep well region 172.

The p type impurity concentration of the field limit regions 175A to 175E may be not less than 1.0×10¹⁵ cm⁻³ and not more than 1.0×10¹⁸ cm⁻³. Preferably, the p type impurity concentration of the field limit regions 175A to 175E< the p type impurity concentration of the outer deep well region 172< the p type impurity concentration of the diode region 171.

The field limit structure 173 relaxes concentration of electric field in the outer region 107. The number, widths, depths, p type impurity concentration, etc., of the field limit regions may take on any of various values in accordance with the electric field to be relaxed.

The SiC semiconductor device 101 includes an outer insulating layer 181 formed on the outer main surface 162 (first main surface 103) in the outer region 107. The outer insulating layer 181 selectively covers the diode region 171, the outer deep well region 172 and the field limit structure 173 in the outer region 107.

The outer insulating layer 181 is formed as a film along the active side wall 164 and the outer main surface 162. On the active main surface 161, the outer insulating layer 181 is continuous to the gate insulating layer 134. More specifically, the outer insulating layer 181 is continuous to the third region 134c of the gate insulating layer 134.

The outer insulating layer 181 may include silicon oxide. The outer insulating layer 181 may include another insulating film of silicon nitride, etc. In this embodiment, the outer insulating layer 181 is formed of the same insulating material type as the gate insulating layer 134.

The outer insulating layer 181 includes a first region 181a and a second region 181b. The first region 181a of the outer insulating layer 181 covers the active side wall 164. The second region 181b of the outer insulating layer 181 covers the outer main surface 162.

A thickness of the second region 181b of the outer insulating layer 181 may be not more than a thickness of the first region 181a of the outer insulating layer 181. The thickness of the second region 181b of the outer insulating layer 181 may be less than the thickness of the first region 181a of the outer insulating layer 181.

The thickness of the first region 181a of the outer insulating layer 181 may be substantially equal to the thickness of the first region 134a of the gate insulating layer 134. The thickness of the second region 181b of the outer insulating layer 181 may be substantially equal to the thickness of the third region 134c of the gate insulating layers 134. An outer insulating layer 181 having a uniform thickness may be formed instead.

Referring to FIG. 42 and FIG. 43, the SiC semiconductor device 101 further includes a side wall structure 182 covering the active side wall 164. The side wall structure 182 protects and reinforces the active mesa 163 from the outer region 107 side.

The side wall structure 182 forms a level difference moderating structure that moderates a level difference 183 formed between the active main surface 161 and the outer main surface 162. If an upper layer structure covering the boundary region between the active region 106 and the outer region 107 is formed, the upper layer structure covers the side wall structure 182. The side wall structure 182 improves flatness of the upper layer structure.

The side wall structure 182 may have an inclining portion 184 that inclines downwardly from the active main surface 161 toward the outer main surface 162. The level difference 183 can be moderated appropriately by the inclining portion 184. The inclining portion 184 may be formed in a curved shape recessed toward the SiC semiconductor layer 102 side. The inclining portion 184 may be formed in a curved shape protruding outside the SiC semiconductor layer 102.

The side wall structure 182 is formed self-aligningly with respect to the active main surface 161. More specifically, the side wall structure 182 is formed along the active side wall 164. In this embodiment, the side wall structure 182 is formed in an annular shape (for example, an endless shape) surrounding the active region 106 in plan view.

The side wall structure 182 may include an insulating material. In this case, an insulating property of the active region 106 with respect to the outer region 107 can be improved by the side wall structure 182. The side wall structure 182 may include a conductive material.

The side wall structure 182 may include the same conductive material type as the gate electrode layers 135. The side wall structure 182 may include the same conductive material type as the source electrode layers 143. The side wall structure 182 can thereby be formed at the same time as the gate electrode layers 135 and/or the source electrode layers 143.

In this embodiment, the side wall structure 182 includes a polysilicon. The side wall structure 182 may include an n type polysilicon or a p type polysilicon. If the gate electrode layer 135 includes a p type polysilicon doped with a p type impurity, the side wall structure 182 preferably includes a p type polysilicon doped with a p type impurity. The p type impurity of the side wall structure 182 may include at least one type of material among boron (B), aluminum (Al), indium (In) and gallium (Ga).

A p type impurity concentration of the side wall structure 182 is not less than the p type impurity concentration of the body region 126. More specifically, the p type impurity concentration of the side wall structure 182 exceeds the p type impurity concentration of the body region 126. The p type impurity concentration of the side wall structure 182 may be substantially equal to the p type impurity concentration of the gate electrode layer 135. A sheet resistance of the source electrode layer 143 may be substantially equal to the sheet resistance of the gate electrode layer 135.

The p type impurity concentration of the side wall structure 182 may be not less than 1×10¹⁸ cm⁻³ and not more than 1×10²² cm⁻³. The sheet resistance of the side wall structure 182 may be not less than 10Ω/□ and not more than 500Ω/□ (approximately 200Ω/□ in this embodiment).

Referring to FIG. 39 to FIG. 43, the SiC semiconductor device 101 includes the interlayer insulating layer 191 formed on the first main surface 103. The interlayer insulating layer 191 selectively covers the active region 106 and the outer region 107. The interlayer insulating layer 191 is formed as a film along the active main surface 161 and the outer main surface 162.

In the active region 106, the interlayer insulating layer 191 selectively covers the trench gate structures 151, the gate wiring layer 136 and the trench source structures 152. In the outer region 107, the interlayer insulating layer 191 selectively covers the diode region 171, the outer deep well region 172 and the field limit structure 173.

In the boundary region between the active region 106 and the outer region 107, the interlayer insulating layer 191 is formed along an outer surface (inclining portion 184) of the side wall structure 182. A peripheral edge portion of the interlayer insulating layer 191 may be formed flush with the side surfaces 105A to 105D.

The interlayer insulating layer 191 may include silicon oxide or silicon nitride. The interlayer insulating layer 191 may include PSG (phosphor silicate glass) and/or BPSG (boron phosphor silicate glass) as an example of silicon oxide.

The interlayer insulating layer 191 may have a single layer structure constituted of a PSG layer or a BPSG layer. The interlayer insulating layer 191 may have a laminated structure including a PSG layer or a BPSG layer laminated in that order from the first main surface 103 side. The interlayer insulating layer 191 may have a laminated structure including a BPSG layer or a PSG layer laminated in that order from the first main surface 103 side.

A gate contact hole 192, source contact holes 193, a diode contact hole 194 and an anchor hole 195 are formed in the interlayer insulating layer 191. The gate contact hole 192 exposes the gate wiring layer 136 in the active region 106. The gate contact hole 192 may be formed as a band oriented along the gate wiring layer 136.

An opening edge portion of the gate contact hole 192 is formed in a shape curved toward an interior of the gate contact hole 192. The opening edge portion of the gate contact hole 192 may be formed in a curved shape recessed toward the interlayer insulating layer 191.

The source contact holes 193 expose the source regions 153, the contact regions 154 and the trench source structures 152 in the active region 106. The source contact holes 193 may be formed as bands oriented along the trench source structures 152, etc.

An opening edge portion of each source contact hole 193 is formed in a shape curved toward an interior of the source contact hole 193. The opening edge portion of the source contact hole 193 may be formed in a curved shape recessed toward an interior of the interlayer insulating layer 191.

The diode contact hole 194 exposes the diode region 171 in the outer region 107. The diode contact hole 194 may be formed as a band (more specifically, an endless shape (annular shape)) extending along the diode region 171.

The diode contact hole 194 may expose the outer deep well region 172 and/or the field limit structure 173. An opening edge portion of the diode contact hole 194 is formed in a shape curved toward an interior of the diode contact hole 194. The opening edge portion of the diode contact hole 194 may be formed in a curved shape recessed toward the interior of the interlayer insulating layer 191.

The anchor hole 195 is formed by digging into the interlayer insulating layer 191 in the outer region 107. The anchor hole 195 exposes the first main surface 103 (outer main surface 162). The anchor hole 195 is formed in a region between the field limit structure 173 and the side surfaces 105A to 105D in plan view.

Referring to FIG. 37, the anchor hole 195 extends as a band along the active region 106 in plan view. In this embodiment, the anchor hole 195 is formed in an annular shape (for example, an endless shape) surrounding the active region 106 in plan view.

An opening edge portion of the anchor hole 195 is formed in a shape curved toward an interior of the anchor hole 195. The opening edge portion of the anchor hole 195 may be formed in a curved shape recessed toward an interior of the interlayer insulating layer 191.

Referring to FIG. 42 and FIG. 44, an inclining portion 196 and a modified layer 197 are formed in the outer region 107. The modified layer 197 is formed by SiC being modified to a different property. The inclining portion 196 and the modified layer 197 respectively correspond to the inclining portion 41 and the modified layer 42 according to the SiC semiconductor device 21 described above. The description related to the components of the modified layer 42 applies to the description of the components of the modified layer 197 (see also FIG. 21 and FIG. 22).

The inclining portion 196 is formed at corner portions connecting the outer main surface 162 (first main surface 103) and the side surfaces 105A to 105D. The corner portions of the SiC semiconductor layer 102 include corner portions connecting the outer main surface 162 and the side surfaces 105A and 105C and extending along the [1-100] direction. The corner portions of the SiC semiconductor layer 102 include corner portions connecting the outer main surface 162 and the side surfaces 105B and 105D and extending along the [11-20] direction.

The inclining portion 196 inclines downwardly from the outer main surface 162 toward the side surfaces 105A to 105D. The inclining portion 196 is formed by an inner wall of a depression recessed from the outer main surface 162 toward the second main surface 104 at the corner portions of the SiC semiconductor layer 102.

In this embodiment, the inclining portion 196 is formed in the SiC epitaxial layer 122. The inclining portion 196 is formed in a region at the outer main surface 162 side with respect to a boundary region between the SiC semiconductor substrate 121 and the SiC epitaxial layer 122. The SiC epitaxial layer 122 is thus exposed from the inclining portion 196.

More specifically, the inclining portion 196 is formed in a region of the SiC epitaxial layer 122 at the outer main surface 162 side with respect to a boundary region between the high concentration region 122a and the low concentration region 122b. That is, the high concentration region 122a is exposed from the inclining portion 196.

The inclining portion 196 has an upper side end portion 196a and a lower side end portion 196b. The upper side end portion 196a of the inclining portion 196 is positioned at the outer main surface 162 side. The lower side end portion 196b of the inclining portion 196 is positioned at the second main surface 104 side.

In this embodiment, the upper side end portion 196a of the inclining portion 196 extends from the SiC epitaxial layer 122 toward an insulating laminated structure 198, which includes the outer insulating layer 181 and the interlayer insulating layer 191, and is continuous to the insulating laminated structure 198. That is, the SiC epitaxial layer 32 and the insulating laminated structure 198 are exposed from the inclining portion 41. A peripheral edge portion of the insulating laminated structure 198 is formed at an inner region of the SiC semiconductor layer 102 with respect to the side surfaces 105A to 105D. The insulating laminated structure 198 corresponds to the insulating layer 35 of the SiC semiconductor device 21 described above.

The upper side end portion 196a of the inclining portion 196 is connected to an upper surface of the interlayer insulating layer 191. An upper side connection portion 196c of the inclining portion 196 that connects the upper side end portion 196a of the inclining portion 196 and the upper surface of the insulating laminated structure 198 may be formed in a shape curved toward an outer side of the SiC semiconductor layer 102.

The lower side end portion 196b of the inclining portion 196 exposes the SiC epitaxial layer 32. More specifically, the lower side end portion 196b of the inclining portion 196 exposes the high concentration region 122a of the SiC epitaxial layer 32. The lower side end portion 196b of the inclining portion 196 is connected to the side surfaces 105A to 105D. The lower side end portion 196b of the inclining portion 196 may be formed in a shape curved toward the second main surface 104.

Referring to FIG. 44, a width WI of the inclining portion 196 may be not more than the in-plane variations of the side surfaces 105A to 105D. The width WI of the inclining portion 196 may be less than the in-plane variations of the side surfaces 105A to 105D. The width WI of the inclining portion 196 is a width in a direction orthogonal to a direction in which the inclining portion 196 extends in plan view.

The width WI of the inclining portion 196 may exceed 0 μm and be not more than 10 μm. The width WI of the inclining portion 196 may exceed 0 μm and be not more than 2 μm, be not less than 2 μm and not more than 4 μm, be not less than 4 μm and not more than 6 μm, be not less than 6 μm and not more than 8 μm, or be not less than 8 μm and not more than 10 μm. If the thickness of the SiC semiconductor layer 102 is not more than 150 μm, the width WI of the inclining portion 196 preferably exceeds 0 μm and is not more than 5 μm. More preferably, the width WI of the inclining portion 196 exceeds 0 μm and is not more than 2.5 μm.

A depth D of the inclining portion 196 may exceed 0 μm and be not more than 30 μm. The depth D of the inclining portion 196 is a distance in the normal direction N from the outer main surface 162 (first main surface 103) to the lower side end portion 196b of the inclining portion 196. The depth D of the inclining portion 196 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 102 is not more than 150 μm, the depth D of the inclining portion 196 preferably exceeds 0 μm and is not more than 15 μm.

The modified layer 197 is formed in regions of the side surfaces 105A to 105D at the outer main surface 103 side. More specifically, the modified layer 197 is formed along the corner portions connecting the outer main surface 162 and the side surfaces 105A to 105D. Even more specifically, the modified layer 197 is formed at the corner portions connecting the outer main surface 162 and the side surfaces 105A and 105C and extending along the [1-100] direction. The modified layer 197 is formed at the corner portions connecting the outer main surface 162 and the side surfaces 105B and 105D and extending along the [11-20] direction.

In this embodiment, the modified layer 197 is formed in the SiC epitaxial layer 122. More specifically, the modified layer 197 is formed in a region at the outer main surface 162 side with respect to the boundary region between the SiC semiconductor substrate 121 and the SiC epitaxial layer 122. Even more specifically, the modified layer 197 is formed in the high concentration region 122a of the SiC epitaxial layer 122. In this embodiment, the modified layer 197 is formed in a region at the outer main surface 162 side with respect to the boundary region between the high concentration region 122a and the low concentration region 122b.

In this embodiment, the modified layer 197 extends as a band on the side surfaces 105A to 105D along directions parallel to the outer main surface 162. That is, the modified layer 197 extends as a band along the [1-100] direction and the [11-20] direction. At the side surfaces 105A to 105D, the modified layer 197 is formed in an annular shape (for example, an endless shape) surrounding the outer region 107.

Referring to FIG. 44, a width WM of the modified layer 197 may be not more than the in-plane variations of the side surfaces 105A to 105D. The width WM of the modified layer 197 may be less than the in-plane variations of the side surfaces 105A to 105D. The width WM of the modified layer 197 is a width in a direction orthogonal to a direction in which the modified layer 197 extends in plan view.

The width WM of the modified layer 197 may exceed 0 μm and be not more than 10 μm. The width WM of the modified layer 197 may exceed 0 μm and be not more than 2 μm, be not less than 2 μm and not more than 4 μm, be not less than 4 μm and not more than 6 μm, be not less than 6 μm and not more than 8 μm, or be not less than 8 μm and not more than 10 μm. If the thickness of the SiC semiconductor layer 102 is not more than 150 μm, the width WM of the modified layer 197 preferably exceeds 0 μm and is not more than 5 μm. More preferably, the width WM of the modified layer 197 exceeds 0 μm and is not more than 2.5 μm.

A thickness T of the modified layer 197 may exceed 0 μm and be not more than 30 μm. The thickness T of the modified layer 197 is a thickness of the modified layer 197 along the normal direction N. The thickness T of the modified layer 197 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 102 is not more than 150 μm, the thickness T of the modified layer 197 preferably exceeds 0 μm and is not more than 15 μm.

The modified layer 197 is formed as a film along the inclining portion 196 of the SiC semiconductor layer 102. A thickness of a portion of the modified layer 197 covering a bottom wall of the inclining portion 196 may be greater than a thickness of a portion of the modified layer 197 covering a side wall of the inclining portion 196. The modified layer 197 may be formed in a uniform thickness along inner wall of the inclining portion 196.

The modified layer 197 includes an upper side covering portion 197a and a lower side covering portion 197b. The upper side covering portion 197a of the modified layer 197 covers the upper side end portion 196a of the inclining portion 196. The lower side covering portion 197b of the modified layer 197 covers the lower side end portion 196b of the inclining portion 196.

The upper side covering portion 197a of the modified layer 197 covers the SiC epitaxial layer 122. More specifically, the upper side covering portion 197a of the modified layer 197 covers the high concentration region 122a. The modified layer 197 extends from the SiC epitaxial layer 122 toward the insulating laminated structure 198 and covers the insulating laminated structure 198. The upper side covering portion 197a of the modified layer 197 may be formed in a shape curved toward the outer side of the SiC semiconductor layer 102.

The lower side covering portion 197b of the modified layer 197 covers the SiC epitaxial layer 122. More specifically, the lower side covering portion 197b of the modified layer 197 covers the high concentration region 122a. The lower side covering portion 197b of the modified layer 197 includes a connection portion 197c connected to the side surfaces 105A to 105D. The connection portion 197c of the modified layer 197 may be a cleavage portion of the modified layer 197. The connection portion 197c of the modified layer 197 may be formed flush with the side surfaces 105A to 105D.

The gate terminal electrode layer 108 and the source terminal electrode layer 109 are formed on the interlayer insulating layer 191. Each of the gate terminal electrode layer 108 and the source terminal electrode layer 109 has a laminated structure that includes a barrier electrode layer 201 and a main electrode layer 202 laminated in that order from the first main surface 103 side.

The barrier electrode layer 201 may have a single layer structure constituted of a titanium layer or a titanium nitride layer. The barrier electrode layer 201 may have a laminated structure including a titanium layer and a titanium nitride layer that are laminated in that order from the first main surface 103 side.

A thickness of the main electrode layer 202 exceeds a thickness of the barrier electrode layer 201. The main electrode layer 202 includes a conductive material having a lower resistance value than a resistance value of the barrier electrode layer 201. The main electrode layer 202 may include at least one type of material among aluminum, copper, an aluminum alloy and a copper alloy. The main electrode layer 202 may include at least one type of material among an aluminum-silicon alloy, an aluminum-silicon-copper alloy and an aluminum-copper alloy. In this embodiment, the main electrode layer 202 includes an aluminum-silicon-copper alloy.

The gate finger 111 which is included in the gate terminal electrode layer 108 enters into the gate contact hole 192 from above the interlayer insulating layer 191. The gate finger 111 is electrically connected to the gate wiring layer 136 inside the gate contact hole 192. An electrical signal from the gate pad 110 is thereby transmitted to the gate electrode layer 135 via the gate finger 111.

The source pad 113 included in the source terminal electrode layer 109 enters into the source contact holes 193 and the source sub-trenches 156 from above the interlayer insulating layer 191. The source pad 113 is electrically connected to the source regions 153, the contact regions 154 and the source electrode layers 143 inside the source contact holes 193 and the source sub-trenches 156.

The source electrode layers 143 may be formed using partial regions of the source pad 113. That is, the source electrode layers 143 may be formed by portions of the source pad 113 entering into the source trenches 141.

The source routing wiring 114 included in the source terminal electrode layer 109 enters into the diode contact hole 194 from above the interlayer insulating layer 191. The source routing wiring 114 is electrically connected to the diode region 171 inside the diode contact hole 194.

The source connection portion 115 included in the source terminal electrode layer 109 crosses the side wall structure 182 from the active region 106 and is led out to the outer region 107. The source connection portion 115 forms a portion of the upper layer structure covering the side wall structure 182.

The SiC semiconductor device 101 includes a passivation layer 203 formed on the interlayer insulating layer 191. The passivation layer 203 may include silicon oxide and/or silicon nitride. In this embodiment, the passivation layer 203 has a single layer structure constituted of a silicon nitride layer.

The passivation layer 203 is formed as a film along the interlayer insulating layer 191. The passivation layer 203 selectively covers the active region 106 and the outer region 107 via the interlayer insulating layer 191.

The passivation layer 203 crosses the side wall structure 182 from the active region 106 and is led out to the outer region 107. The passivation layer 203 forms a portion of the upper layer structure covering the side wall structure 182.

A gate sub-pad opening 204 and a source sub-pad opening 205 (see also FIG. 37) are formed in the passivation layer 203. The gate sub-pad opening 204 exposes the gate pad 110. The source sub-pad opening 205 exposes the source pad 113.

Referring to FIG. 42, in the outer region 107, the passivation layer 203 enters into the anchor hole 195 from above the interlayer insulating layer 191. Inside the anchor hole 195, the passivation layer 203 is connected to the outer main surface 162 (first main surface 103). A recess, recessed in conformance to the anchor hole 195 is formed in a region of an outer surface of the passivation layer 203 positioned above the anchor hole 195.

A peripheral edge portion of the passivation layer 203 may be formed flush with the side surfaces 105A to 105D. The peripheral edge portion of the passivation layer 203 may be formed in an inner region across intervals from the side surfaces 105A to 105D. That is, the peripheral edge portion of the passivation layer 203 may expose the interlayer insulating layer 191.

The peripheral edge portion of the passivation layer 203 may be portions forming portions of dicing streets in a process of cutting out the SiC semiconductor device 101 from the 4H—SiC crystal structure body 1. By exposing the outer main surface 162 (first main surface 103) from the peripheral edge portion of the passivation layer 203, it becomes unnecessary to physically cut the passivation layer 203. The semiconductor device 101 can thus be cut out smoothly from the 4H—SiC crystal structure body 1.

The resin layer 116 described above is formed on the passivation layer 203. The resin layer 116 is formed as a film along the passivation layer 203. The resin layer 116 selectively covers the active region 106 and the outer region 107 across the passivation layer 203 and the interlayer insulating layer 191.

The resin layer 116 crosses the side wall structure 182 from the active region 106 and is led out to the outer region 107. The resin layer 116 forms a portion of the upper layer structure covering the side wall structure 182.

The gate pad opening 117 of the resin layer 116 is in communication with the gate sub-pad opening 204 of the passivation layer 203. In this embodiment, inner wall of the gate pad opening 117 are positioned at outer sides of inner wall of the gate sub-pad opening 204.

The inner wall of the gate pad opening 117 may be formed flush with the inner wall of the gate sub-pad opening 204. The inner wall of the gate pad opening 117 may be positioned at inner sides of the inner wall of the gate sub-pad opening 204. That is, the resin layer 116 may cover the inner wall of the gate sub-pad opening 204.

The source pad opening 118 of the resin layer 116 is in communication with the source sub-pad opening 205 of the passivation layer 203. In this embodiment, the inner wall of the source pad opening 118 are positioned at outer sides of the inner wall of the source sub-pad opening 205.

The inner wall of the source pad opening 118 may be formed flush with the inner wall of the source sub-pad opening 205. The inner wall of the source pad opening 118 may be positioned at inner sides of the inner wall of the source sub-pad opening 205. That is, the resin layer 116 may cover the inner wall of the source sub-pad opening 205.

Referring to FIG. 42, the resin layer 116 has an anchor portion entering into the recess of the passivation layer 203 in the outer region 107. An anchor structure, arranged to improve a connection strength of the resin layer 116, is thus formed in the outer region 107.

The anchor structure includes an uneven structure formed in the first main surface 103 in the outer region 107. More specifically, the uneven structure (anchor structure) includes unevenness formed using the interlayer insulating layer 191 covering the outer main surface 162. Even more specifically, the uneven structure (anchor structure) includes the anchor hole 195 formed in the interlayer insulating layer 191.

The resin layer 116 is engaged with the anchor hole 195. In this embodiment, the resin layer 116 is engaged with the anchor hole 195 via the passivation layer 203. The connection strength of the resin layer 116 with respect to the first main surface 103 can thereby be improved and therefore, peeling of the resin layer 116 can be suppressed.

Also, the resin layer 116 exposes the modified layer 197. By exposing the modified layer 197 from the resin layer 116, it becomes unnecessary to physically cut the resin layer 116. The SiC semiconductor device 101 can thus be cut out smoothly from the 4H—SiC crystal structure body 1 while achieving appropriate protection of the active region 106 and the outer region 107 by the resin layer 116.

Even in the case of manufacturing the SiC semiconductor device 101 described above, the same effects as the effects described for the eleventh preferred embodiment can be exhibited.

Also, with the SiC semiconductor device 101, depletion layers can be spread from boundary regions (pn junction portions) between the SiC semiconductor layer 102 and the deep well regions 155. Consequently, current paths of a short-circuit current flowing between the source pad 113 and the drain pad 123 can be narrowed.

Also, a feedback capacitance Crss can be reduced inverse-proportionately by the depletion layers spreading from the boundary regions between the SiC semiconductor layer 102 and the deep well regions 155. The feedback capacitance Crss is a static capacitance across the gate electrode layers 135 and the drain pad 123. The SiC semiconductor device 101 can thus be provided with which the short-circuit capacity can be improved and the feedback capacitance can be reduced.

Preferably, the depletion layers spreading from the boundary regions (pn junction portions) between the SiC semiconductor layer 102 and the deep well regions 155 spread toward regions to the second main surface 104 side with respect to the bottom walls of the gate trenches 131. Regions of the SiC semiconductor layer 102 occupied by the depletion layers can thereby be increased and the feedback capacitance Crss can thus be reduced appropriately. In this case, the depletion layers spreading from the bottom portions of the deep well regions 155 may overlap with the bottom walls of the gate trenches 131.

Also, with the SiC semiconductor device 101, the bottom portions of the plurality of deep well regions 155 are formed at a substantially fixed interval from the second main surface 104. Occurrence of variation in the distance between the bottom portion of each deep well region 155 and the second main surface 104 can thereby be suppressed. Consequently, the withstand voltage (for example, the electrostatic breakdown strength) of the SiC semiconductor layer 102 can be suppressed from being restricted by the deep well regions 155 and therefore improvement of the withstand voltage can be achieved appropriately.

Also, with the SiC semiconductor device 101, the diode region 171 is formed in the outer region 107. The diode region 171 is electrically connected to the source terminal electrode layer 109. An avalanche current generated in the outer region 107 can thereby be made to flow into the source terminal electrode layer 109 via the diode region 171. Consequently, the avalanche current generated in the outer region 107 can be absorbed by the diode region 171 and the source terminal electrode layer 109 and stability of operation of the MISFET can thus be improved.

Also, with the SiC semiconductor device 101, the outer deep well region 172 is formed in the outer region 107. The withstand voltage of the SiC semiconductor layer 102 can thereby be adjusted in the outer region 107.

In this case, the outer deep well region 172 is preferably formed at substantially the same depth position as the deep well regions 155. The bottom portion of the outer deep well region 172 is preferably positioned on substantially the same plane as the bottom portions of the deep well regions 155. The distance between the bottom portion of the outer deep well region 172 and the second main surface 104 is preferably substantially equal to the distance between the bottom portion of each deep well regions 155 and the second main surface 104.

With these structures, variation can be suppressed from occurring between the distance between the bottom portion of the outer deep well region 172 and the second main surface 104 and the distance between the bottom portion of each deep well region 155 and the second main surface 104. The withstand voltage (for example, the electrostatic breakdown strength) of the SiC semiconductor layer 102 can thereby be suppressed from being restricted by the outer deep well region 172 and the deep well regions 155. Consequently, improvement of the withstand voltage can be achieved appropriately.

Also, with the SiC semiconductor device 101, the outer region 107 is formed at the second main surface 104 side with respect to the active region 106. The position of the bottom portion of the outer deep well region 172 can thereby be made to approach the positions of the bottom portions of the deep well regions 155 appropriately.

That is, by the outer region 107 positioned at the second main surface 104 side with respect to the active region 106, a need to introduce the p type impurity to a comparatively deep position of the surface layer portion of the first main surface 103 during the forming of the outer deep well region 172 is eliminated. The position of the bottom portion of the outer deep well region 172 can thus be suppressed appropriately from deviating greatly with respect to the positions of the bottom portions of the deep well regions 155.

Also, with the SiC semiconductor device 101, the outer main surface 162 of the outer region 107 is positioned on substantially the same plane as the bottom walls of the source trenches 141. Thereby, the deep well regions 155 and the outer deep well region 172 can be formed at substantially equal depth positions by introducing the p type impurity into the bottom walls of the source trenches 141 and the outer main surface 162 of the outer region 107 at an equal energy. Consequently, the position of the bottom portion of the outer deep well region 172 can be suppressed even more appropriately from deviating greatly with respect to the positions of the bottom portions of the deep well regions 155.

Also, with the SiC semiconductor device 101, the field limit structure 173 is formed in the outer region 107. An electric field relaxation effect by the field limit structure 173 can thereby be obtained in the outer region 107. The electrostatic breakdown strength of the SiC semiconductor layer 102 can thus be improved appropriately.

Also, with the SiC semiconductor device 101, the active region 106 is formed as the active mesa 163 of mesa shape. The active mesa 163 includes the active side wall 164 connecting the active main surface 161 of the active region 106 and the outer main surface 162 of the outer region 107.

The level difference moderating structure that moderates the level difference 183 between the active main surface 161 and the outer main surface 162 is formed in the region between the active main surface 161 and the outer main surface 162. The level difference moderating structure includes the side wall structure 182.

The level difference 183 between the active main surface 161 and the outer main surface 162 can thereby be moderated appropriately. The flatness of the upper layer structure formed on the side wall structure 182 can thus be improved appropriately. With the SiC semiconductor device 101, the interlayer insulating layer 191, the source terminal electrode layer 109, the passivation layer 203 and the resin layer 116 are formed as an example of the upper layer structure.

Also, with the SiC semiconductor device 101, the anchor structure, arranged to improve the connection strength of the resin layer 116 is formed in the outer region 107. The anchor structure includes the uneven structure formed in the first main surface 103 of the SiC semiconductor layer 102 in the outer region 107.

More specifically, the uneven structure (anchor structure) includes the unevenness formed using the interlayer insulating layer 191 formed on the first main surface 103 in the outer region 107. Even more specifically, the uneven structure (anchor structure) includes the anchor hole 195 formed in the interlayer insulating layer 191.

The resin layer 116 is engaged with the anchor hole 195. In this embodiment, the resin layer 116 is engaged with the anchor hole 195 via the passivation layer 203. The connection strength of the resin layer 116 with respect to the first main surface 103 can thereby be improved and therefore, peeling of the resin layer 116 can be suppressed appropriately.

Also, with the SiC semiconductor device 101, the trench gate structures 151, with each of which the gate electrode layer 135 is embedded across the gate insulating layer 134 in the gate trench 131, are formed. With the trench gate structure 151, the gate electrode layer 135 is covered by the low resistance electrode layer 159 in the limited space of the gate trench 151.

The gate electrode layer 135 includes the p type polysilicon. The gate threshold voltage Vth can thereby be increased (for example, increased by approximately 1V). Also, the low resistance electrode layer 159 includes the conductive material having the sheet resistance less than the sheet resistance of the p type polysilicon. Reduction of the gate resistance can thereby be achieved. Consequently, a current can be diffused efficiently along the trench gate structures 151 and reduction of switching delay can thus be achieved.

Especially, with the structure where the gate electrode layer 135 is covered by the low resistance electrode layer 159, the p type impurity concentration of the body region 126 does not have to be increased. The gate threshold voltage Vth can thus be increased while preventing the increase in channel resistance.

Also, with the SiC semiconductor device 101, the gate wiring layer 136 is covered by the low resistance electrode layer 159 in the outer region 107. Reduction of gate resistance of the gate wiring layer 136 can also be achieved thereby. Especially, with the structure where the gate electrode layers 135 and the gate wiring layer 136 are covered by the low resistance electrode layer 159, the current can be diffused efficiently along the trench gate structures 151. The reduction of switching delay can thus be achieved appropriately.

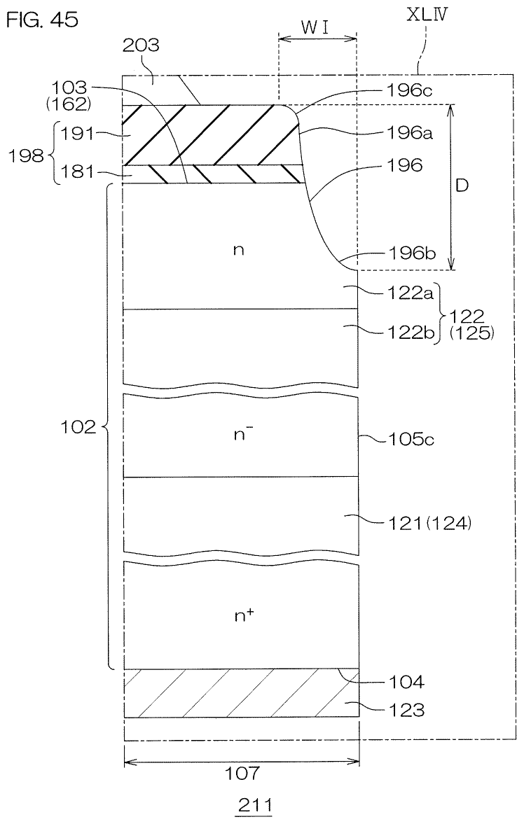

Features of the SiC semiconductor devices 91 to 98 according to the twelfth to nineteenth preferred embodiments (see also FIG. 28 to FIG. 35) may be combined in the SiC semiconductor device 101. Configurations in which the features of the SiC semiconductor devices 91 to 98 according to the twelfth to nineteenth preferred embodiments are incorporated in the SiC semiconductor device 101 shall now be described with reference to FIG. 45 to FIG. 54.

FIG. 45 is an enlarged view of a region corresponding to FIG. 44 and is an enlarged view of an SiC semiconductor device 211 according to a twenty-first preferred embodiment of the present invention. In the following, structures corresponding to structures described with the SiC semiconductor device 101 shall be provided with the same reference symbols and description thereof shall be omitted.

Referring to FIG. 45, the SiC semiconductor device 211 does not have the modified layer 197. With the SiC semiconductor device 211, just the inclining portion 196 is formed at the corner portions of the SiC semiconductor layer 102.

Even in the case of manufacturing the SiC semiconductor device 211 described above, the same effects as the effects described for the twentieth preferred embodiment can be exhibited.

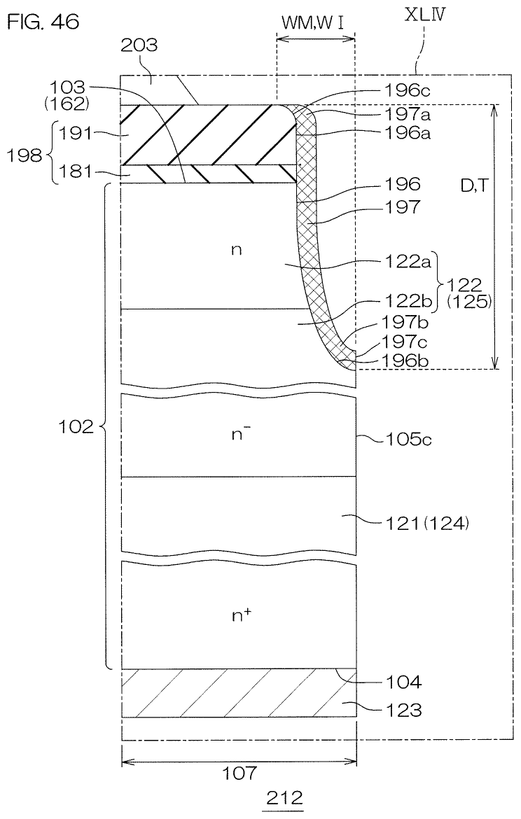

FIG. 46 is an enlarged view of a region corresponding to FIG. 44 and is an enlarged view of an SiC semiconductor device 212 according to a twenty-second preferred embodiment of the present invention. In the following, structures corresponding to structures described with the SiC semiconductor device 101 shall be provided with the same reference symbols and description thereof shall be omitted.

Referring to FIG. 46, in this embodiment, the inclining portion 196 crosses the boundary region between the high concentration region 122a and the low concentration region 122b and reaches the low concentration region 122b in the SiC epitaxial layer 122. The high concentration region 122a and the low concentration region 122b are exposed from the inclining portion 196.

The lower side end portion 196b of the inclining portion 196 is positioned in the low concentration region 122b. In the low concentration region 122b, the lower side end portion 196b of the inclining portion 196 is connected to the side surfaces 105A to 105D. The lower side end portion 196b of the inclining portion 196 may be formed in a shape curved toward the second main surface 104.

In this embodiment, the modified layer 197 crosses the boundary region between the high concentration region 122a and the low concentration region 122b and reaches the low concentration region 122b in the SiC epitaxial layer 122. The modified layer 197 covers the high concentration region 122a and the low concentration region 122b. The upper side covering portion 197a of the modified layer 197 covers the high concentration region 122a. The lower side covering portion 197b of the modified layer 197 covers the low concentration region 122b.

Even in the case of manufacturing the SiC semiconductor device 212 described above, the same effects as the effects described for the twentieth preferred embodiment can be exhibited.

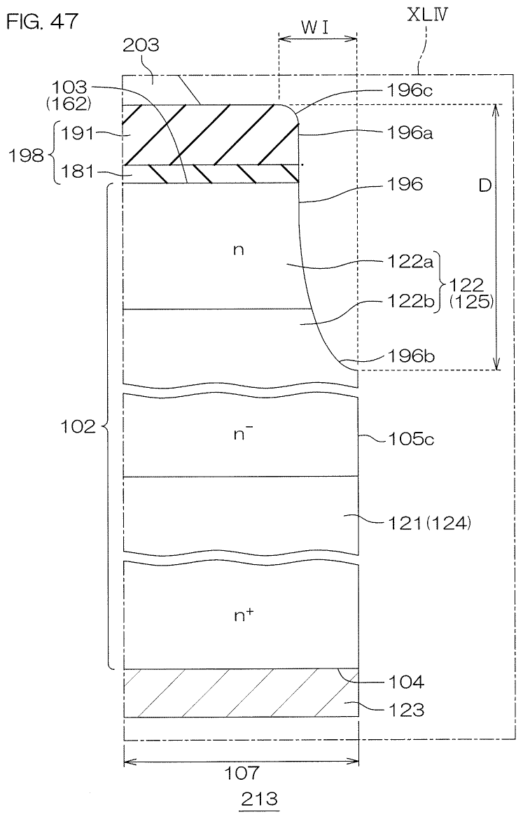

FIG. 47 is an enlarged view of a region corresponding to FIG. 44 and is an enlarged view of an SiC semiconductor device 213 according to a twenty-third preferred embodiment of the present invention. In the following, structures corresponding to structures described with the SiC semiconductor device 101 shall be provided with the same reference symbols and description thereof shall be omitted.

Referring to FIG. 47, the SiC semiconductor device 213 does not have the modified layer 197. With the SiC semiconductor device 213, just the inclining portion 196 is formed at the corner portions of the SiC semiconductor layer 102.

In this embodiment, the inclining portion 196 crosses the boundary region between the high concentration region 122a and the low concentration region 122b and reaches the low concentration region 122b in the SiC epitaxial layer 122. The high concentration region 122a and the low concentration region 122b are exposed from the inclining portion 196.

The lower side end portion 196b of the inclining portion 196 is positioned in the low concentration region 122b. In the low concentration region 122b, the lower side end portion 196b of the inclining portion 196 is connected to the side surfaces 105A to 105D. The lower side end portion 196b of the inclining portion 196 may be formed in a shape curved toward the second main surface 104.

Even in the case of manufacturing the SiC semiconductor device 213 described above, the same effects as the effects described for the twentieth preferred embodiment can be exhibited.

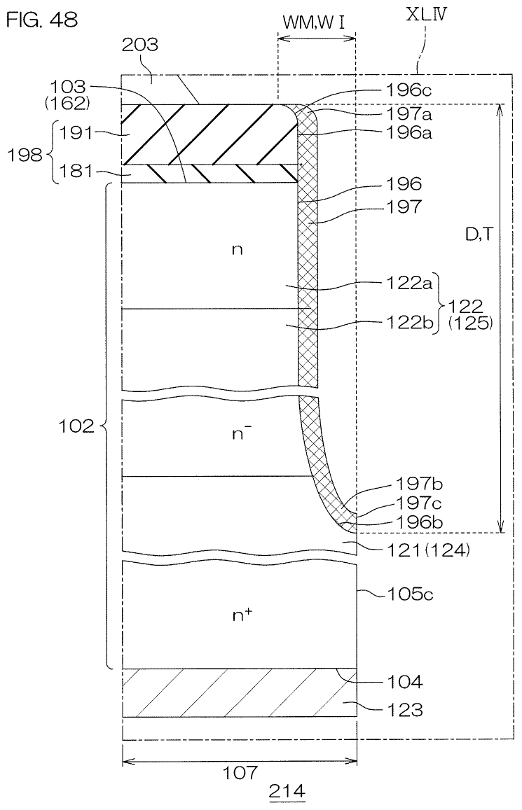

FIG. 48 is an enlarged view of a region corresponding to FIG. 44 and is an enlarged view of an SiC semiconductor device 214 according to a twenty-fourth preferred embodiment of the present invention. In the following, structures corresponding to structures described with the SiC semiconductor device 101 shall be provided with the same reference symbols and description thereof shall be omitted.

Referring to FIG. 48, in this embodiment, the inclining portion 196 crosses the boundary region between the SiC semiconductor substrate 121 and the SiC epitaxial layer 122 and reaches the SiC semiconductor substrate 121. The SiC semiconductor substrate 121 and the SiC epitaxial layer 122 are exposed from the inclining portion 196.

The lower side end portion 196b of the inclining portion 196 exposes the SiC semiconductor substrate 121. In the SiC semiconductor substrate 121, the lower side end portion 196b of the inclining portion 196 is connected to the side surfaces 105A to 105D. The lower side end portion 196b of the inclining portion 196 may be formed in a shape curved toward the second main surface 104.

In this embodiment, the modified layer 197 crosses the boundary region between the SiC semiconductor substrate 121 and the SiC epitaxial layer 122 and reaches the SiC semiconductor substrate 121. The modified layer 197 covers the SiC semiconductor substrate 121 and the SiC epitaxial layer 122. The upper side covering portion 197a of the modified layer 197 covers the SiC epitaxial layer 122. The lower side covering portion 197b of the modified layer 197 covers the SiC semiconductor substrate 121.

Even in the case of manufacturing the SiC semiconductor device 214 described above, the same effects as the effects described for the twentieth preferred embodiment can be exhibited.

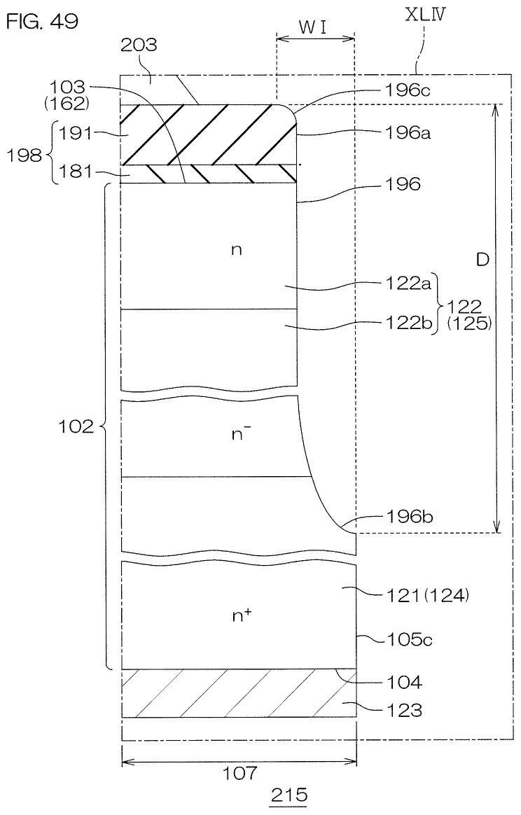

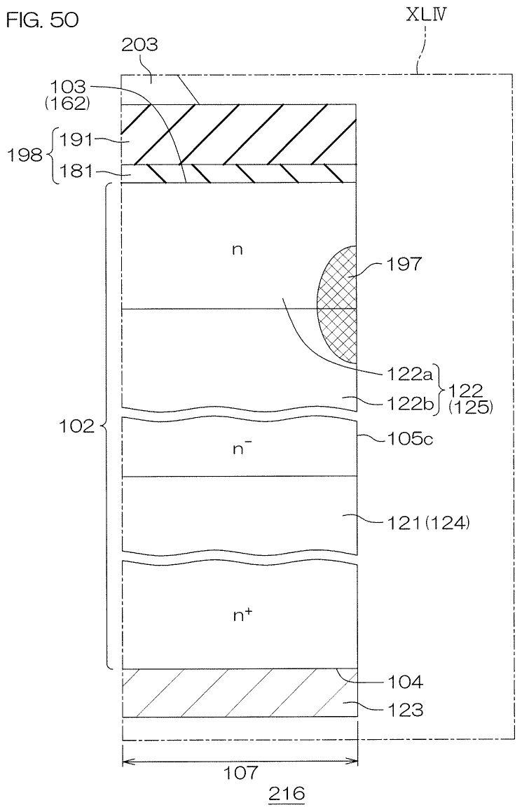

FIG. 49 is an enlarged view of a region corresponding to FIG. 44 and is an enlarged view of an SiC semiconductor device 215 according to a twenty-fifth preferred embodiment of the present invention. In the following, structures corresponding to structures described with the SiC semiconductor device 101 shall be provided with the same reference symbols and description thereof shall be omitted.

Referring to FIG. 49, the SiC semiconductor device 215 does not have the modified layer 197. With the SiC semiconductor device 215, just the inclining portion 196 is formed at the corner portions of the SiC semiconductor layer 102.

In this embodiment, the inclining portion 196 crosses the boundary region between the SiC semiconductor substrate 121 and the SiC epitaxial layer 122 and reaches the SiC semiconductor substrate 121. The SiC semiconductor substrate 121 and the SiC epitaxial layer 122 are exposed from the inclining portion 196.

The lower side end portion 196b of the inclining portion 196 exposes the SiC semiconductor substrate 121. In the SiC semiconductor substrate 121, the lower side end portion 196b of the inclining portion 196 is connected to the side surfaces 105A to 105D. The lower side end portion 196b of the inclining portion 196 may be formed in a shape curved toward the second main surface 104.

Even in the case of manufacturing the SiC semiconductor device 215 described above, the same effects as the effects described for the twentieth preferred embodiment can be exhibited.

FIG. 50 is an enlarged view of a region corresponding to FIG. 44 and is an enlarged view of an SiC semiconductor device 216 according to a twenty-sixth preferred embodiment of the present invention. In the following, structures corresponding to structures described with the SiC semiconductor device 101 shall be provided with the same reference symbols and description thereof shall be omitted.

Referring to FIG. 50, the SiC semiconductor device 216 does not have the inclining portion 196 at the corner portions of the SiC semiconductor layer 102. The SiC semiconductor device 216 includes the modified layer 197 formed in thickness direction intermediate portions of the side surfaces 105A to 105D.

More specifically, the modified layer 197 is formed in a thickness direction intermediate portion of the SiC epitaxial layer 122 at the side surfaces 105A to 105D. The modified layer 197 is formed in the SiC epitaxial layer 122 at an interval toward the second main surface 104 side from the outer main surface 162. The modified layer 197 is formed in the SiC epitaxial layer 122 at an interval toward the outer main surface 162 side from the boundary region between the SiC semiconductor substrate 121 and the SiC epitaxial layer 122.

The modified layer 197 may be positioned in the high concentration region 122a. The modified layer 197 may be positioned in the high concentration region 122a at intervals from the outer main surface 162 and the low concentration region 122b. The modified layer 197 may be positioned in the low concentration region 122b. The modified layer 197 may be positioned in the low concentration region 122b at intervals from the SiC semiconductor substrate 121 and the high concentration region 122a.

The modified layer 197 may be formed in the high concentration region 122a and the low concentration region 122b. The modified layer 197 may be formed such as to cross the boundary region between the high concentration region 122a and the low concentration region 122b.

Even in the case of manufacturing the SiC semiconductor device 216 described above, the same effects as the effects described for the twentieth preferred embodiment can be exhibited.

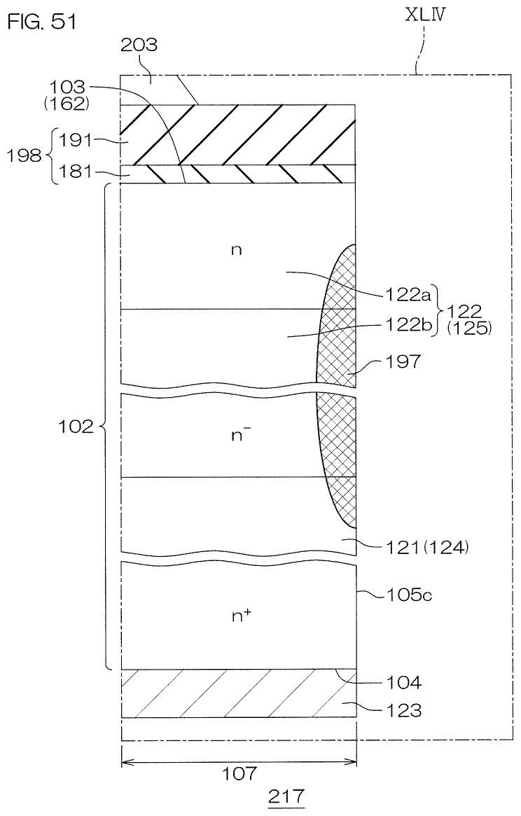

FIG. 51 is an enlarged view of a region corresponding to FIG. 44 and is an enlarged view of an SiC semiconductor device 217 according to a twenty-seventh preferred embodiment of the present invention. In the following, structures corresponding to structures described with the SiC semiconductor device 101 shall be provided with the same reference symbols and description thereof shall be omitted.

Referring to FIG. 51, the SiC semiconductor device 217 does not have the inclining portion 196 at the corner portions of the SiC semiconductor layer 102. The SiC semiconductor device 217 includes the modified layer 197 formed in thickness direction intermediate portions of the side surfaces 105A to 105D.

More specifically, the modified layer 197 is formed in the SiC semiconductor substrate 121 and the SiC epitaxial layer 122 at the side surfaces 105A to 105D. The modified layer 197 is formed such as to cross the boundary region between the SiC semiconductor substrate 121 and the SiC epitaxial layer 122.

The modified layer 197 is formed in the side surfaces 105A to 105D at intervals to the second main surface 104 side from the outer main surface 162. The modified layer 197 is formed in the side surfaces 105A to 105D at intervals to the outer main surface 162 side from the second main surface 104.

The modified layer 197 has an upper end portion positioned at the outer main surface 162 side and a lower end portion positioned at the second main surface 104 side. The upper end portion of the modified layer 197 is positioned in the SiC epitaxial layer 122. The upper end portion of the modified layer 197 may be positioned in the low concentration region 122b. The upper end portion of the modified layer 197 may cross the boundary region between the high concentration region 122a and the low concentration region 122b and be positioned in the high concentration region 122a. The lower end portion of the modified layer 197 is positioned in the SiC semiconductor substrate 121.

Even in the case of manufacturing the SiC semiconductor device 217 described above, the same effects as the effects described for the twentieth preferred embodiment can be exhibited.

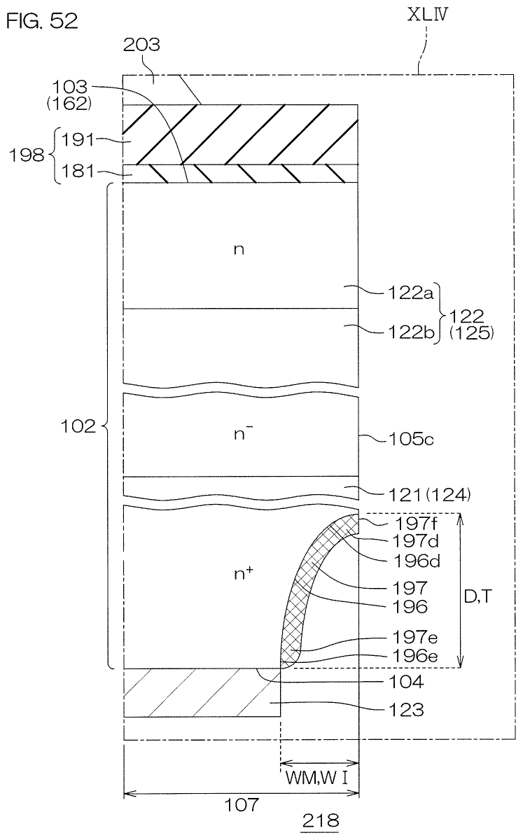

FIG. 52 is a sectional view of a region corresponding to FIG. 44 and is a sectional view of an SiC semiconductor device 218 according to a twenty-eighth preferred embodiment of the present invention. In the following, structures corresponding to structures described with the SiC semiconductor device 101 shall be provided with the same reference symbols and description thereof shall be omitted.

Referring to FIG. 52, the inclining portion 196 and the modified layer 197 that are formed in the second main surface 104 in the outer region 107 are included.

The inclining portion 196 is formed at corner portions connecting the second main surface 104 and the side surfaces 105A to 105D. The corner portions of the SiC semiconductor layer 102 include corner portions connecting the second main surface 104 and the side surfaces 105A and 105C. Also, the corner portions of the SiC semiconductor layer 102 include corner portions connecting the second main surface 104 and the side surfaces 105B and 105D.

The inclining portion 196 is inclined downwardly from the second main surface 104 toward the side surfaces 105A to 105D. The inclining portion 196 is formed by an inner wall of a depression recessed from the second main surface 104 toward the second main surface 104 at the corner portions of the SiC semiconductor layer 102.

The inclining portion 196 is formed in the SiC semiconductor substrate 121. More specifically, the inclining portion 196 is formed at an interval toward the second main surface 104 side with respect to the boundary region between the SiC semiconductor substrate 121 and the SiC epitaxial layer 122.

The inclining portion 196 has an upper side end portion 196d and a lower side end portion 196e. The upper side end portion 196d of the inclining portion 196 is positioned at the outer main surface 162 side. The lower side end portion 196e of the inclining portion 196 is positioned at the second main surface 104 side. The upper side end portion 196d of the inclining portion 196 is continuous to the side surfaces 105A to 105D. The upper side end portion 196d of the inclining portion 196 may be formed in a shape curved toward the outer main surface 162. The lower side end portion 196e of the inclining portion 196 is connected to the second main surface 104.

The width WI of the inclining portion 196 may be not more than the in-plane variations of the side surfaces 105A to 105D. The width WI of the inclining portion 196 may be less than the in-plane variations of the side surfaces 105A to 105D. The width WI of the inclining portion 196 is the width in the direction orthogonal to the direction in which the inclining portion 196 extends in plan view.

The width WI of the inclining portion 196 may exceed 0 μm and be not more than 10 μm. The width WI of the inclining portion 196 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the SiC semiconductor layer 102 is not more than 150 μm, the width WI of the inclining portion 196 preferably exceeds 0 μm and is not more than 5 μm. More preferably, the width WI of the inclining portion 196 exceeds 0 μm and is not more than 2.5 μm.

The depth D of the inclining portion 196 may exceed 0 μm and be not more than 30 μm. The depth D of the inclining portion 196 is the distance in the normal direction N from the second main surface 104 to the upper side end portion 196d of the inclining portion 196. The depth D of the inclining portion 196 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 102 is not more than 150 μm, the depth D of the inclining portion 196 preferably exceeds 0 μm and is not more than 15 μm.

The modified layer 197 is formed along the corner portions connecting the second main surface 104 and the side surfaces 105A to 105D. The modified layer 197 is formed in the SiC semiconductor substrate 121. More specifically, the modified layer 197 is formed at the second main surface 104 side with respect to the boundary region between the SiC semiconductor substrate 121 and the SiC epitaxial layer 122.

The modified layer 197 is formed along the corner portions connecting the second main surface 104 and the side surfaces 105A and 105C. The modified layer 197 is formed along the corner portions connecting the second main surface 104 and the side surfaces 105B and 105D. That is, the modified layer 197 extends as a band along the [1-100] direction and the [11-20] direction.

In this embodiment, the modified layer 197 extends as a band on the side surfaces 105A to 105D along directions parallel to the second main surface 104. At the side surfaces 105A to 105D, the modified layer 197 is formed in an annular shape (for example, an endless shape) surrounding the outer region 107.

The width WM of the modified layer 197 may be not more than the in-plane variations of the side surfaces 105A to 105D. The width WM of the modified layer 197 may be less than the in-plane variations of the side surfaces 105A to 105D. The width WM of the modified layer 197 is the width in the direction orthogonal to the direction in which the modified layer 197 extends in plan view.

The width WM of the modified layer 197 may exceed 0 μm and be not more than 10 μm. The width WM of the modified layer 197 may exceed 0 μm and be not more than 2 μm, be not less than 2 μm and not more than 4 μm, be not less than 4 μm and not more than 6 μm, be not less than 6 μm and not more than 8 μm, or be not less than 8 μm and not more than 10 μm. If the thickness of the SiC semiconductor layer 102 is not more than 150 μm, the width WM of the modified layer 197 preferably exceeds 0 μm and is not more than 5 μm. More preferably, the width WM of the modified layer 197 exceeds 0 μm and is not more than 2.5 μm.

The thickness T of the modified layer 197 may exceed 0 μm and be not more than 30 μm. The thickness T of the modified layer 197 is the thickness of the modified layer 197 along the normal direction N. The thickness T of the modified layer 197 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 102 is not more than 150 μm, the thickness T of the modified layer 197 preferably exceeds 0 μm and is not more than 15 μm.

The modified layer 197 is formed as a film along the inclining portion 196 of the SiC semiconductor layer 102. The thickness of the portion of the modified layer 197 covering the bottom wall of the inclining portion 196 may be greater than the thickness of the portion of the modified layer 197 covering the side wall of the inclining portion 196. The modified layer 197 may be formed in a uniform thickness along the inner wall of the inclining portion 196.

The modified layer 197 includes an upper side covering portion 197d and a lower side covering portion 197e. The upper side covering portion 197d of the modified layer 197 covers the upper side end portion 196d of the inclining portion 196. The lower side covering portion 197e of the modified layer 197 covers the lower side end portion 196e of the inclining portion 196.

The upper side covering portion 197d of the modified layer 197 includes a connection portion 197f connected to the side surfaces 105A to 105D. The connection portion 197f of the modified layer 197 may be a cleavage portion of the modified layer 197. The connection portion 197f of the modified layer 197 may be formed flush with the side surfaces 105A to 105D.

Even in the case of manufacturing the SiC semiconductor device 218 described above, the same effects as the effects described for the twentieth preferred embodiment can be exhibited.

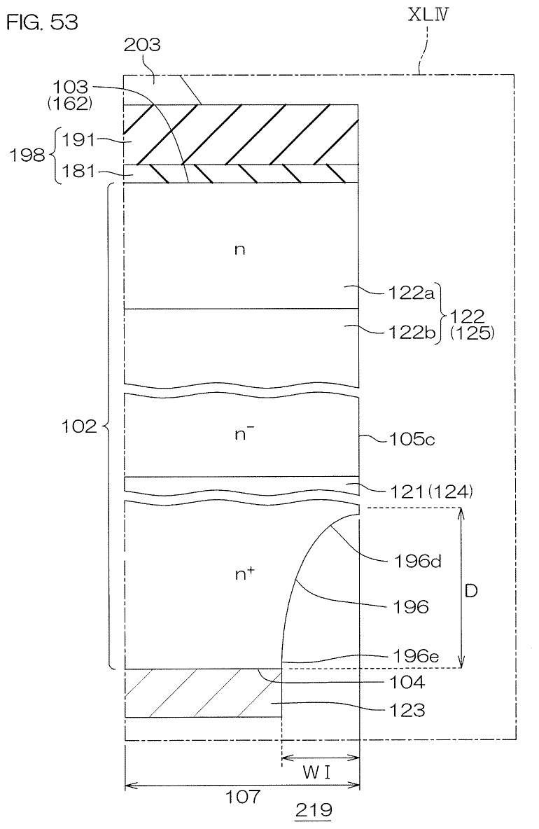

FIG. 53 is a sectional view of a region corresponding to FIG. 44 and is a sectional view of an SiC semiconductor device 219 according to a twenty-ninth preferred embodiment of the present invention. In the following, structures corresponding to structures described with the SiC semiconductor device 101 shall be provided with the same reference symbols and description thereof shall be omitted.

The SiC semiconductor device 219 does not have the modified layer 197. The SiC semiconductor device 219 includes the inclining portion 196 that is formed in regions of the side surfaces 105A to 105D at the second main surface 104 side. The inclining portion 196 is formed at the corner portions connecting the second main surface 104 and the side surfaces 105A to 105D.

The corner portions of the SiC semiconductor layer 102 include the corner portions connecting the second main surface 104 and the side surfaces 105A and 105C. Also, the corner portions of the SiC semiconductor layer 102 include the corner portions connecting the second main surface 104 and the side surfaces 105B and 105D.

The inclining portion 196 is inclined downwardly from the second main surface 104 toward the side surfaces 105A to 105D. The inclining portion 196 is formed by an inner wall of a depression recessed from the second main surface 104 toward the second main surface 104 at the corner portions of the SiC semiconductor layer 102.

The inclining portion 196 is formed in the SiC semiconductor substrate 121. More specifically, the inclining portion 196 is formed at an interval toward the second main surface 104 side with respect to the boundary region between the SiC semiconductor substrate 121 and the SiC epitaxial layer 122.

The inclining portion 196 has the upper side end portion 196d and the lower side end portion 196e. The upper side end portion 196d of the inclining portion 196 is positioned at the outer main surface 162 side. The lower side end portion 196e of the inclining portion 196 is positioned at the second main surface 104 side. The upper side end portion 196d of the inclining portion 196 is continuous to the side surfaces 105A to 105D. The upper side end portion 196d of the inclining portion 196 may be formed in a shape curved toward the outer main surface 162. The lower side end portion 196e of the inclining portion 196 is connected to the second main surface 104.

The width WI of the inclining portion 196 may be not more than the in-plane variations of the side surfaces 105A to 105D. The width WI of the inclining portion 196 may be less than the in-plane variations of the side surfaces 105A to 105D. The width WI of the inclining portion 196 is the width in the direction orthogonal to the direction in which the inclining portion 196 extends in plan view.

The width WI of the inclining portion 196 may exceed 0 μm and be not more than 10 μm. The width WI of the inclining portion 196 may exceed 0 μm and be not more than 2.5 μm, be not less than 2.5 μm and not more than 5 μm, be not less than 5 μm and not more than 7.5 μm, or be not less than 7.5 μm and not more than 10 μm. If the thickness of the SiC semiconductor layer 102 is not more than 150 μm, the width WI of the inclining portion 196 preferably exceeds 0 μm and is not more than 5 μm. More preferably, the width WI of the inclining portion 196 exceeds 0 μm and is not more than 2.5 μm.

The thickness T of the modified layer 197 may exceed 0 μm and be not more than 30 μm. The thickness T of the modified layer 197 is the thickness of the modified layer 197 along the normal direction N. The thickness T of the modified layer 197 may exceed 0 μm and be not more than 5 μm, be not less than 5 μm and not more than 10 μm, be not less than 10 μm and not more than 15 μm, be not less than 15 μm and not more than 20 μm, be not less than 20 μm and not more than 25 μm, or be not less than 25 μm and not more than 30 μm. If the thickness of the SiC semiconductor layer 102 is not more than 150 μm, the thickness T of the modified layer 197 preferably exceeds 0 μm and is not more than 15 μm.

Even in the case of manufacturing the SiC semiconductor device 219 described above, the same effects as the effects described for the twentieth preferred embodiment can be exhibited.

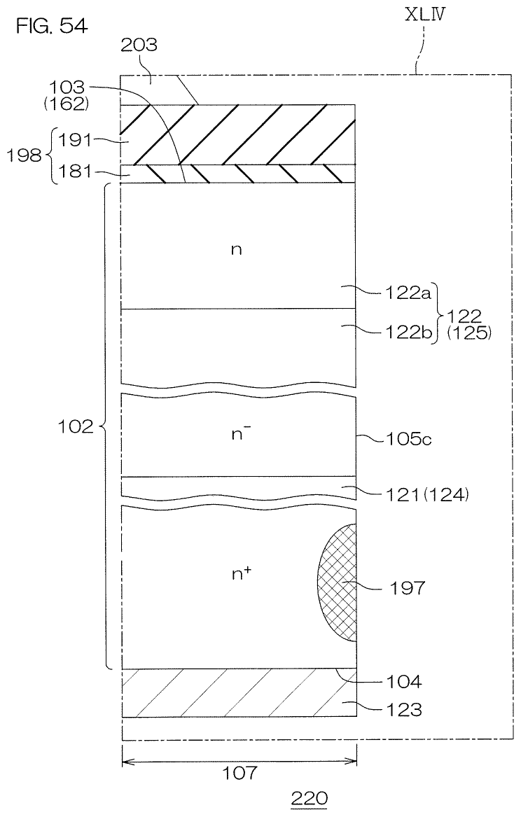

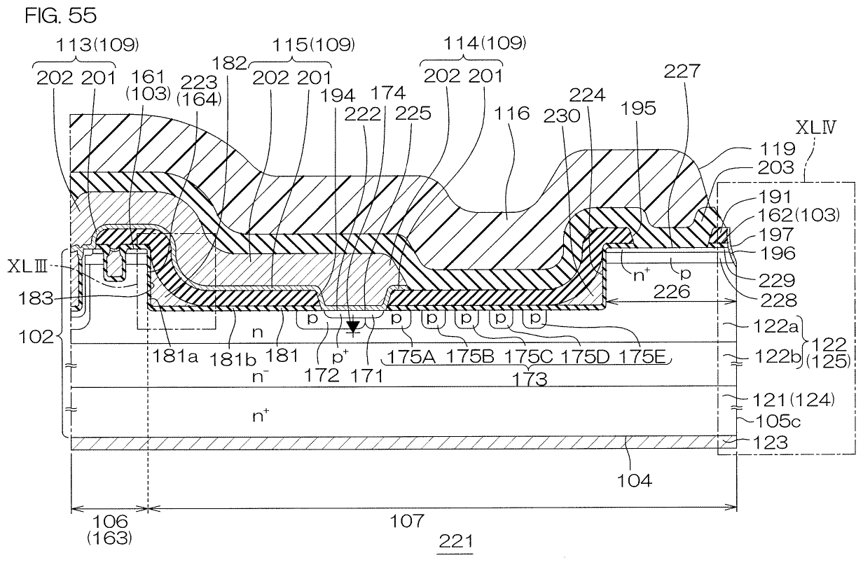

FIG. 54 is a sectional view of a region corresponding to FIG. 44 and is a sectional view of the general arrangement of an SiC semiconductor device 220 according to a thirtieth preferred embodiment of the present invention. In the following, structures corresponding to structures described with the SiC semiconductor device 101 shall be provided with the same reference symbols and description thereof shall be omitted.

Referring to FIG. 54, the SiC semiconductor device 211 does not have the inclining portion 196 at the corner portions at the first main surface 103 side and the corner portions at the second main surface 104 side of the SiC semiconductor layer 102. The SiC semiconductor device 211 includes the modified layer 197 formed in thickness direction intermediate portions of the side surfaces 105A to 105D.

More specifically, the modified layer 197 is formed in a thickness direction intermediate portion of the SiC semiconductor substrate 121 at the side surfaces 105A to 105D. The modified layer 197 is formed in the SiC semiconductor substrate 121 at an interval toward the second main surface 104 side from the boundary region between the SiC semiconductor substrate 121 and the SiC epitaxial layer 122. Also, the modified layer 197 is formed at an interval toward the SiC epitaxial layer 122 side with respect to the second main surface 104.

Such a modified layer 197 is formed by adjusting a light converging point of laser light when irradiating the laser light onto the second main surface 3 of the 4H—SiC crystal structure body 1 (second main surface 104 of the SiC semiconductor layer 102). In this case, the modified layer 197 is heated and cooled from the second main surface 3 side of the 4H—SiC crystal structure body 1 and the 4H—SiC crystal structure body 1 is cleaved. The step of FIG. 24K does not necessarily have to be performed.

Even in the case of manufacturing the SiC semiconductor device 220 described above, the same effects as the effects described for the twentieth preferred embodiment can be exhibited.

FIG. 55 is a sectional view of a region corresponding to FIG. 42 and is a sectional view of an SiC semiconductor device 221 according to a thirty-first preferred embodiment of the present invention. In the following, structures corresponding to structures described with the SiC semiconductor device 101 shall be provided with the same reference symbols and description thereof shall be omitted.

Referring to FIG. 55, in this embodiment, in the outer region 107, a groove 222 oriented along the active region 106 is formed in the first main surface 103 of the SiC semiconductor layer 102. The groove 222 is formed by digging into the first main surface 103 toward the second main surface 104 side.

The groove 222 is formed as a band extending along the active region 106 in plan view. In this embodiment, the groove 222 is formed in an annular shape (for example, an endless shape) surrounding the active region 106 in plan view.

The groove 222 includes an inner wall 223, an outer wall 224 and a bottom wall 225. The inner wall 223 of the groove 222 is positioned at the active region 106 side. The inner wall 223 of the groove 222 forms the active side wall 164. The outer wall 224 of the groove 222 is positioned at the side surface 105A to 105D sides. The bottom wall 225 of the groove 222 connects the inner wall 223 and the outer wall 224.

The bottom wall 225 of the groove 222 may be positioned at the second main surface 104 side with respect to the bottom walls of the gate trenches 131. The groove 222 may be formed at a depth position substantially equal to the source trenches 141. That is, the bottom wall 225 of the groove 222 may be positioned on substantially the same plane as the bottom walls of the source trenches 141.

A distance between the bottom wall 225 of the groove 222 and the second main surface 104 may be substantially equal to the distance between the bottom walls of the source trenches 141 and the second main surface 104. The bottom wall 225 of the groove 222 may be positioned at the second main surface 104 side with respect to the bottom walls of the source trenches 141. The bottom wall 225 of the groove 222 may be positioned in a range of exceeding 0 μm and being not more than 1 μm to the second main surface 104 side with respect to the bottom walls of the source trenches 141.

The bottom wall 225 of the groove 222 exposes the SiC epitaxial layer 122. More specifically, the bottom wall 225 of the groove 222 exposes the high concentration region 122a of the SiC epitaxial layer 122. The bottom wall 225 of the groove 222 opposes the low concentration region 122b across the high concentration region 122a.

The inner wall 223 of the groove 222 defines the active mesa 163. Together with the side surfaces 105A to 105D, the outer wall 224 at the outer region 107 defines an outer mesa 226 projecting higher than the bottom wall 225 of the groove 222. In a configuration where the groove 222 is formed in an annular shape (for example, an endless shape), the outer mesa 226 is formed in an annular shape (for example, an endless shape) surrounding the groove 222 in plan view.

The outer mesa 226 includes a mesa main surface 227. The mesa main surface 227 forms a portion of the first main surface 103. The mesa main surface 227 is positioned on substantially the same plane as the active main surface 161 of the active region 106. The mesa main surface 227 extends parallel to the bottom wall 225 of the groove 222.

In this embodiment, a p type impurity region 228 is formed in a surface layer portion of the mesa main surface 227 of the outer mesa 226. The p type impurity region 228 is formed in an electrically floating state. The p type impurity region 228 may have a p type impurity concentration substantially equal to the p type impurity concentration of the body region 126.

In this embodiment, in the outer mesa 226, an n type impurity region 229 is formed in a surface layer portion of the p type impurity region 228. The n type impurity region 229 is formed in an electrically floating state. The n type impurity region 229 may have an n type impurity concentration substantially equal to the n type impurity concentration of the source regions 153.

With the exception of the point of being formed along the bottom wall 225 of the groove 222, the diode region 171, the outer deep well region 172 and the field limit structure 173 described above respectively have substantially the same structures as the diode region 171, the outer deep well region 172 and the field limit structure 173 of the semiconductor device 101.

The outer insulating layer 181 is formed as a film along the inner wall of the groove 222 and the mesa main surface 227 of the outer mesa 226. In the groove 222, an outer wall side wall 230 is formed in addition to the side wall structure 182.

With the exception of the point of covering the outer wall 224 of the groove 222, the outer wall side wall 230 has substantially the same structure as the side wall structure 182. The descriptions of the active side wall 164 and the side wall structure 182 apply to the descriptions of the outer wall 224 of the groove 222 and the outer wall side wall 230.

In this embodiment, the anchor structure arranged to improve the connection strength of the resin layer 116 is formed in the mesa main surface 227. The anchor structure includes an uneven structure formed in a portion of the interlayer insulating layer 191 covering the mesa main surface 227. The uneven structure has the anchor hole 195 formed in the interlayer insulating layer 191. The passivation layer 203 contacts the mesa main surface 227 in the anchor hole 195.

The resin layer 116 is engaged with the anchor hole 195. In this embodiment, the resin layer 116 is engaged with the anchor hole 195 via the passivation layer 203. The connection strength of the resin layer 116 with respect to the first main surface 103 can thereby be improved and therefore, peeling of the resin layer 116 can be suppressed appropriately. The anchor structure for the resin layer 116 may be formed in the bottom wall 225 of the groove 222 instead.

In this embodiment, the inclined portion 196 and the modified layer 197 are formed along corner portions connecting the side surfaces 105A to 105D and the mesa main surface 227. In regard to the inclined portion 196 and the modified layer 197, at least one configuration among those of the nineteenth to thirtieth preferred embodiments is applied. Specific description of the inclined portion 196 and the modified layer 197 shall be omitted.

Even in the case of manufacturing the SiC semiconductor device 221 described above, the same effects as the effects described for the twentieth preferred embodiment can be exhibited.

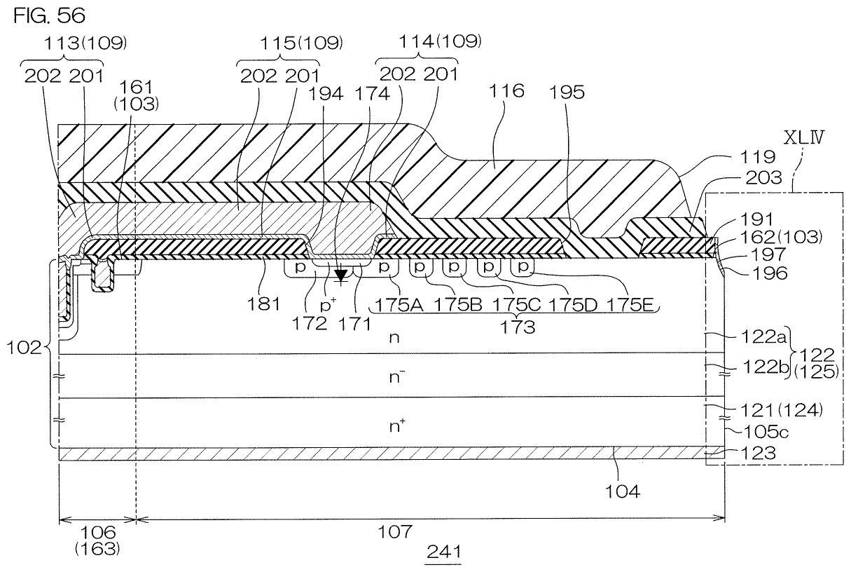

FIG. 56 is a sectional view of a region corresponding to FIG. 42 and is a sectional view of an SiC semiconductor device 241 according to a thirty-second preferred embodiment of the present invention. In the following, structures corresponding to structures described with the semiconductor device 101 shall be provided with the same reference symbols and description thereof shall be omitted.

Referring to FIG. 56, in this embodiment, the active main surface 161 of the active region 106 and the outer main surface 162 of the outer region 107 are formed flush. In this embodiment, the active region 106 is defined by the body region 126.

In this embodiment, a distance between the outer main surface 162 and the bottom portion of the diode region 171 is substantially equal to a distance between the bottom walls of the source trenches 144 and the bottom portions of the contact regions 154.

In this embodiment, a distance between the outer main surface 162 and the bottom portion of the outer deep well region 172 is substantially equal to a distance between the bottom walls of the source trenches 144 and the bottom portions of the deep well regions 155.

In this embodiment, a distance between the outer main surface 162 and a bottom portion of the field limit structure 173 is substantially equal to the distance between the outer main surface 162 and the bottom portion of the outer deep well region 172.

Even in the case of manufacturing the SiC semiconductor device 241 described above, the same effects as the effects described for the twentieth preferred embodiment can be exhibited.

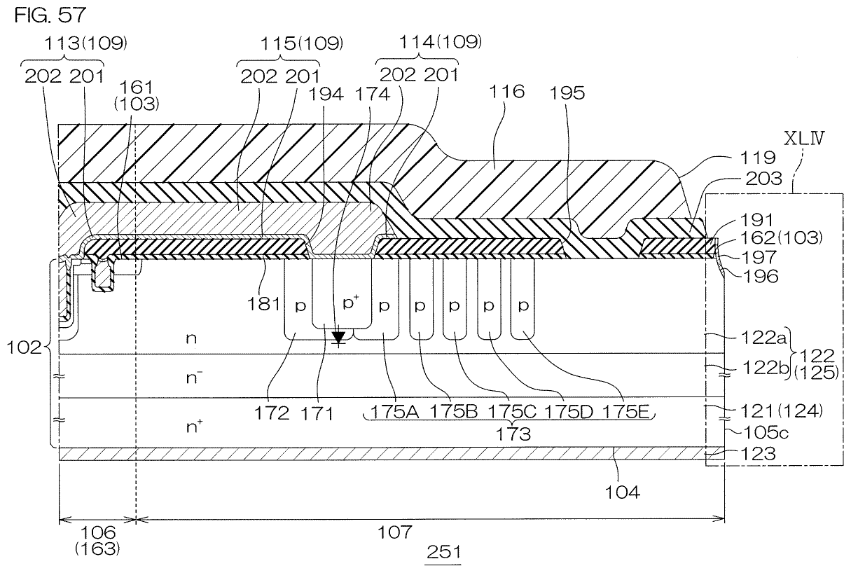

FIG. 57 is a sectional view of a region corresponding to FIG. 42 and is a sectional view of an SiC semiconductor device 251 according to a thirty-third preferred embodiment of the present invention. In the following, structures corresponding to structures described with the semiconductor device 101 shall be provided with the same reference symbols and description thereof shall be omitted.

Referring to FIG. 57, in this embodiment, the active main surface 161 of the active region 106 and the outer main surface 162 of the outer region 107 are formed flush. In this embodiment, the active region 106 is defined by the body region 126.

The bottom portion of the diode region 171 may be formed at substantially the same depth position as the bottom portions of the contact regions 154. That is, the bottom portion of the diode region 171 may be positioned on the same plane as the bottom portions of the contact regions 154.

The bottom portion of the outer deep well region 172 may be formed at substantially the same depth position as the bottom portions of the deep well regions 155. That is, the bottom portion of the outer deep well region 172 may be positioned on the same plane as the bottom portions of the deep well regions 155.

The bottom portion of the field limit structure 173 may be formed at substantially the same depth position as the bottom portion of the outer deep well region 172. That is, the bottom portion of the field limit structure 173 may be positioned on the same plane as the bottom portion of the outer deep well region 172.

Even in the case of manufacturing the SiC semiconductor device 251 described above, the same effects as the effects described for the twentieth preferred embodiment can be exhibited.

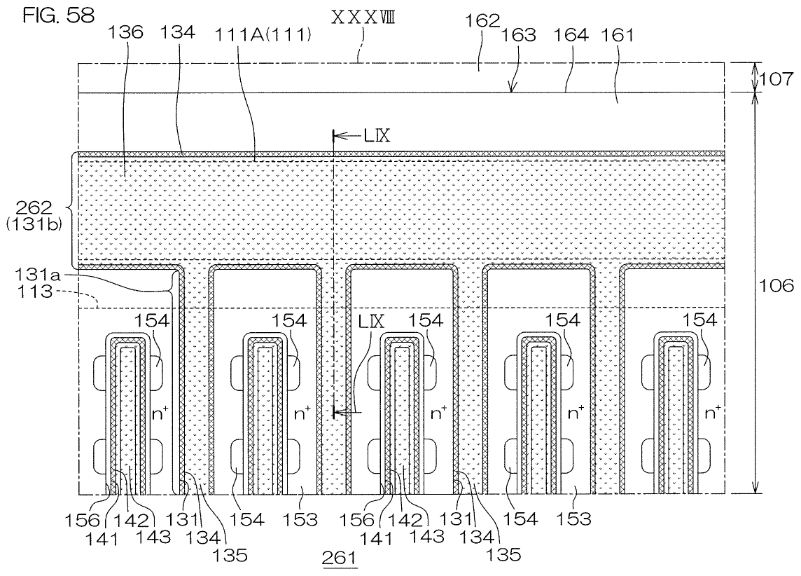

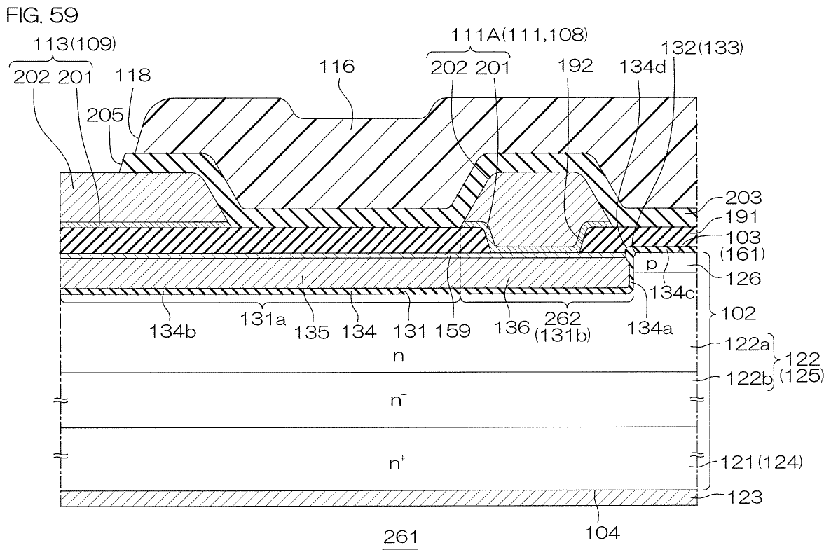

FIG. 58 is an enlarged view of a region corresponding to FIG. 38 and is an enlarged view of an SiC semiconductor device 261 according to a thirty-fourth preferred embodiment of the present invention. FIG. 59 is a sectional view taken along line LIX-LIX shown in FIG. 58. In the following, structures corresponding to structures described with the semiconductor device 101 shall be provided with the same reference symbols and description thereof shall be omitted.

Referring to FIG. 58 and FIG. 59, the semiconductor device 261 includes an outer gate trench 262 formed in the first main surface 103 (active main surface 161) in the active region 106. The outer gate trench 262 extends as a band along the peripheral edge portions of the active region 106 (active side wall 164).

The outer gate trench 262 is formed in a region of the first main surface 103 of directly below the gate finger 111 (outer gate finger 111A). The outer gate trench 262 extends along the gate finger 111 (outer gate finger 111A).

More specifically, the outer gate trench 262 is formed along the three side surfaces 105A, 105B and 105D of the SiC semiconductor layer 102 and defines the inner region of the active region 106 from three directions. The outer gate trench 262 may be formed in an annular shape (for example, an endless shape) that surrounds the inner region of the active region 106.

The outer gate trench 262 is in communication with the contact trench portion 131b of each gate trench 131. The outer gate trench 262 and the gate trenches 131 are thereby formed by a single trench.

The gate wiring layer 136 is embedded in the outer gate trench 262 across the gate insulating layer 134. The gate wiring layer 136 is connected to the gate electrode layers 135 at communication portions of the gate trenches 131 and the outer gate trench 262.

The low resistance electrode layer 159, covering the upper surface of the gate wiring layer 136, may be formed in the outer gate trench 262. In this case, the low resistance electrode layer 159 covering the gate electrode layers 135 and the low resistance electrode layer 159 covering the gate wiring layer 136 are formed inside a single trench.

Even in the case of manufacturing the SiC semiconductor device 261 described above, the same effects as the effects described for the twentieth preferred embodiment can be exhibited. Also, with the semiconductor device 261, the gate wiring layer 136 is not required to be led out to above the first main surface 103.

The gate wiring layer 136 can thereby be suppressed from opposing the SiC semiconductor layer 102 across the gate insulating layer 134 at the opening edge portions of the gate trenches 131 and the outer gate trench 262. Consequently, the concentration of electric field at the opening edge portions of the gate trenches 131 can be suppressed.

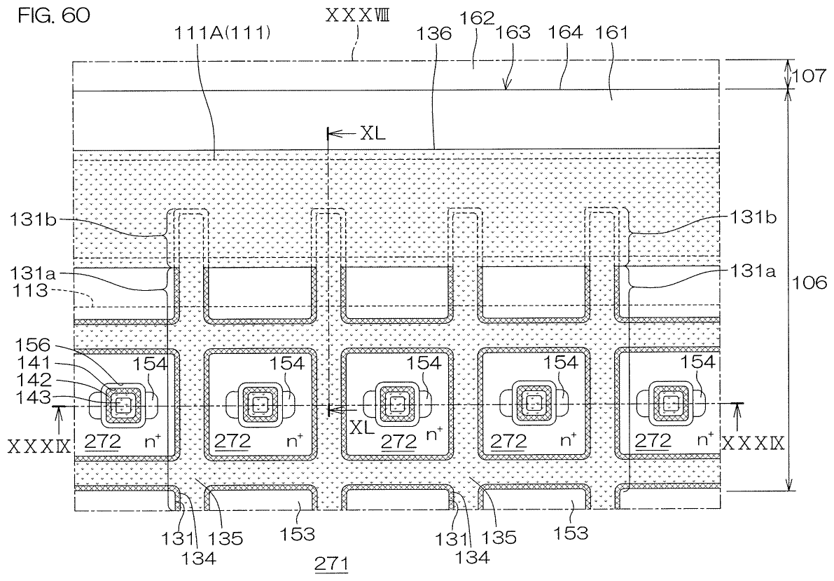

FIG. 60 is an enlarged view of a region corresponding to FIG. 38 and is an enlarged view of an SiC semiconductor device 271 according to a thirty-fifth preferred embodiment of the present invention. In the following, structures corresponding to structures described with the semiconductor device 101 shall be provided with the same reference symbols and description thereof shall be omitted.

Referring to FIG. 60, in this embodiment, the gate trenches 131 are formed in a lattice shape that integrally includes a plurality of gate trenches 131 extending along the first direction X and a plurality of gate trenches 131 extending along the second direction Y in plan view.

A plurality of cell regions 272 are defined in a matrix by the gate trenches 131 in the first main surface 103. Each cell region 272 is formed in a quadrilateral shape in plan view. The source trenches 411 are formed respectively in the plurality of cell regions 272. Each source trench 411 may be formed in a quadrilateral shape in plan view.

A sectional view taken along line XXXIX-XXXIX of FIG. 60 corresponds to the sectional view of FIG. 39. A sectional view taken along line XL-XL of FIG. 60 corresponds to the sectional view of FIG. 40.

Even in the case of manufacturing the SiC semiconductor device 271 described above, the same effects as the effects described for the twentieth preferred embodiment can be exhibited.

Although the preferred embodiments of the present invention have been described above, the present invention may also be implemented in other configurations.

With each of the eleventh to thirty-fifth preferred embodiments described above, an example where the side surfaces 25A to 25D or 105A to 105D of the SiC semiconductor layer 22 or 102 are formed along the [11-20] direction and the [1-100] direction was described. However, the side surfaces 25A to 25D or 105A to 105D may be formed along a crystal direction equivalent to the [11-20] direction and a crystal direction equivalent to the [1-100] direction instead of the [11-20] direction and the [1-100] direction.

That is, the side surfaces 25A to 25D or 105A to 105D may be formed along the [−12-10] direction, the [−2110] direction, the [−1-120] direction, the [1-210] direction, or the [2-1-10] direction instead of the [11-20] direction. Also, the side surfaces 25A to 25D or 105A to 105D may be formed along the [01-10] direction, the [−1100] direction, the [−1010] direction, the [0-110] direction, or the [10-10] direction instead of the [1-100] direction.

When the SiC semiconductor layer 22 or 102 is formed in a rectangular shape in plan view, side surfaces among the side surfaces 25A to 25D or 105A to 105D that form the long sides are preferably formed along a nearest neighbor direction.

With each of the twentieth to thirty-fifth preferred embodiments described above, an example where the gate electrode layers 135 and the gate wiring layer 136 that include the p type polysilicon doped with the p type impurity are formed was described. However, if increase of the gate threshold voltage Vth is not emphasized, the gate electrode layers 135 and the gate wiring layer 136 may include an n type polysilicon doped with an n type impurity instead of the p type polysilicon.

In this case, the low resistance electrode layer 159 may include an n type polycide, with which the gate electrode layer 135 (n type polysilicon) is silicided. With such a structure, reduction of gate resistance can be achieved.

With each of the twentieth to thirty-fifth preferred embodiments described above, an example where the SiC semiconductor layer 102 has the laminated structure that includes the SiC semiconductor substrate 121 and the SiC epitaxial layer 122 was described. However, the SiC semiconductor layer 102 may instead have a single layer structure constituted of the SiC semiconductor substrate 121 or the SiC epitaxial layer 122. An n⁺ type drain region may be formed by implantation of an n type impurity into the second main surface 104.

With each of the twentieth to thirty-fifth preferred embodiments described above, an example where the SiC epitaxial layer 122, having the high concentration region 122a and the low concentration region 122b is formed by the epitaxial growth method was described. However, the SiC epitaxial layer 122 may instead be formed by steps such as the following.

First, the SiC epitaxial layer 122, having a comparatively low n type impurity concentration is formed by an epitaxial growth method. Next, the n type impurity is introduced into a surface layer portion of the SiC epitaxial layer 122 by an ion implantation method. The SiC epitaxial layer 112, having the high concentration region 122a and the low concentration region 122b, is thereby formed.

With each of the twentieth to thirty-fifth preferred embodiments described above, if the source electrode layers 143 include a polysilicon (n type polysilicon or p type polysilicon), a low resistance electrode layer (159) covering the source electrode layers 143 inside the source trenches 141 may be formed.

With each of the twentieth to thirty-fifth preferred embodiments, a p⁺ type SiC semiconductor substrate (121) may be adopted in place of the n⁺ type SiC semiconductor substrate 121. With this structure, an IGBT (insulated gate bipolar transistor) can be provided in place of a MISFET.

In this case, the “source” of the MISFET is replaced by an “emitter” of the IGBT. Also, the “drain” of the MISFET is replaced by a “collector” of the IGBT. Even when an IGBT is adopted in place of a MISFET, the same effects as the effects described above for the twentieth to thirty-fifth preferred embodiments can be exhibited.

With each of the preferred embodiments described above, a structure with which the conductivity types of the respective semiconductor portions are inverted may be adopted. That is, a p type portion may be formed to be of an n type and an n type portion may be formed to be of a p type.

With each of the preferred embodiments described above, an example where the 4H—SiC crystal structure body 1 is cleaved was described. However, the 4H—SiC crystal structure body 1 may instead be cut by a dicing blade, etc. Even in this case, the 4H—SiC crystal structure body 1 can be cut appropriately from two different directions. However, in this case, there is concern for wear of the dicing blade and elongation of cutting time and therefore cleaving is more preferable.

The ideas and technical ideas of the respective preferred embodiments described above can also be applied to a semiconductor device besides a SiC semiconductor device. For example, the ideas and technical ideas of the respective preferred embodiments described above can also be applied to a semiconductor laser device that includes a crystal structure body constituted of a hexagonal crystal or to a semiconductor light emitting device that includes a crystal structure body constituted of a hexagonal crystal.

The present specification does not restrict any combined configuration of features illustrated with the first to thirty-fifth preferred embodiments. The first to thirty-fifth preferred embodiments may be combined among each other in any mode or any configuration.

Examples of features extracted from the present specification and drawings are indicated below.

[A1] A crystal cutting method including a step of preparing a crystal structure body constituted of a hexagonal crystal, a first cutting step of cutting the crystal structure body along an intersecting direction intersecting a nearest atom direction of the crystal structure body and forming a first cut portion in the crystal structure body, and a second cutting step of cutting the crystal structure body along the nearest neighbor direction and forming a second cut portion crossing the first cut portion, in the crystal structure body.

According to this crystal cutting method, the crystal structure body is cut along the nearest neighbor direction intersecting direction in the first cutting step. The crystal structure body is cut along the nearest neighbor direction in the second cutting step.

In the first cutting step, the uncut crystal structure body is cut and therefore stress to the crystal structure body does not become discontinuous. Forming of a bulging portion in the first cut portion can thereby be suppressed. On the other hand, in the second cutting step, stress to the crystal structure body becomes discontinuous because the crystal structure body has been cut in the nearest neighbor direction intersecting direction. However, in the second cutting step, stress is applied to the crystal structure body along the nearest neighbor direction and the crystal structure body is cut along the nearest neighbor direction.

Forming of a bulging portion in the second cut portion can thereby be suppressed and flatness of the first cut portion and the second cut portion can thus be improved. A crystal cutting method that enables a crystal structure body constituted of a hexagonal crystal to be cut appropriately from two different directions can thus be provided.

[A2] The crystal cutting method according to A1, wherein the first cutting step includes a first cleaving step of cleaving the crystal structure body along the intersecting direction and the second cutting step includes a second cleaving step of cleaving the crystal structure body along the nearest neighbor direction.

[A3] The crystal cutting method according to A2, further including a step of forming a first cleavage line oriented along the intersecting direction by heating a region of the crystal structure body to be cleaved along the intersecting direction in advance of the first cutting step, and a step of forming a second cleavage line oriented along the nearest neighbor direction by heating a region of the crystal structure body to be cleaved along the nearest neighbor direction in advance of the second cutting step, wherein the first cutting step includes the first cleaving step of cleaving the crystal structure body with the first cleavage line as a starting point and the second cutting step includes the second cleaving step of cleaving the crystal structure body with the second cleavage line as a starting point.

[A4] The crystal cutting method according to A3, wherein the step of forming the first cleavage line includes a step of forming a first modified layer in which a crystal structure is modified to a different property by heating, in the crystal structure body, and the step of forming the second cleavage line includes a step of forming a second modified layer in which a crystal structure is modified to a different property by heating, in the crystal structure body.

[A5] The crystal cutting method according to A3 or A4, wherein the first cleaving step includes a step of cleaving the crystal structure body with the first cleavage line as the starting point by heating and cooling the first cleavage line, and the second cleaving step includes a step of cleaving the crystal structure body with the second cleavage line as the starting point by heating and cooling the second cleavage line.

[A6] The crystal cutting method according to any one of A1 to A5, wherein the nearest neighbor direction is a [11-20] direction, a [−12-10] direction, or a [−2110] direction of the hexagonal crystal.

[A7] The crystal cutting method according to any one of A1 to A6, wherein the crystal structure body is constituted of an SiC crystal structure body having a silicon plane and a carbon plane as crystal planes and the nearest neighbor direction is an arrangement direction of nearest neighboring Si atoms in a plan view viewed from a normal direction of the silicon plane.

[B1] A crystal cutting method including a step of preparing an SiC crystal structure body constituted of a hexagonal crystal having a silicon plane and a carbon plane as crystal planes, a first cleaving step of cleaving the SiC crystal structure body along an intersecting direction intersecting an arrangement direction of nearest neighboring Si atoms in a plan view viewed from a normal direction of the silicon plane and forming a first cleavage portion in the SiC crystal structure body, and a second cleaving step of cleaving the SiC crystal structure body along the arrangement direction and forming a second cleavage portion crossing the first cleavage portion in the SiC crystal structure body.

According to this crystal cutting method, the SiC crystal structure body is cleaved along the nearest neighbor direction intersecting direction in the first cleaving step. The SiC crystal structure body is cleaved along the nearest neighbor direction in the second cleaving step.

In the first cleaving step, the uncut SiC crystal structure body is cleaved and therefore stress to the SiC crystal structure body does not become discontinuous. Forming of a bulging portion in the first cleavage portion can thereby be suppressed. On the other hand, in the second cleaving step, stress to the SiC crystal structure body becomes discontinuous because the SiC crystal structure body has been cleaved in the nearest neighbor direction intersecting direction. However, in the second cleaving step, stress is applied to the SiC crystal structure body along the nearest neighbor direction and the SiC crystal structure body is cleaved along the nearest neighbor direction.

Forming of a bulging portion in the second cleavage portion can thereby be suppressed and flatness of the first cleavage portion and the second cleavage portion can thus be improved. A crystal cutting method that enables an SiC crystal structure body constituted of a hexagonal crystal to be cut appropriately from two different directions can thus be provided.

[B2] The crystal cutting method according to B1, further including a step of forming a first cleavage line oriented along the intersecting direction by heating a region of the SiC crystal structure body to be cleaved along the intersecting direction in advance of the first cleaving step, and a step of forming a second cleavage line oriented along the arrangement direction by heating a region of the SiC crystal structure body to be cleaved along the arrangement direction in advance of the second cleaving step, wherein the first cleaving step includes a step of cleaving the SiC crystal structure body with the first cleavage line as a starting point and the second cleaving step includes a step of cleaving the SiC crystal structure body with the second cleavage line as a starting point.

[B3] The crystal cutting method according to B2, wherein the step of forming the first cleavage line includes a step of forming a first modified layer in which a crystal structure is modified to a different property by heating in the SiC crystal structure body, and the step of forming the second cleavage line includes a step of forming a second modified layer in which a crystal structure is modified to a different property by heating in the SiC crystal structure body.

[B4] The crystal cutting method according to B3, wherein the SiC crystal structure body includes an SiC semiconductor substrate, the first modified layer is formed in an outer surface of the SiC semiconductor substrate in the step of forming the first cleavage line, and the second modified layer is formed in the outer surface of the SiC semiconductor substrate in the step of forming the second cleavage line.

[B5] The crystal cutting method according to B3, wherein the SiC crystal structure body includes an SiC laminated structure that includes an SiC semiconductor substrate and an SiC epitaxial layer, the first modified layer is formed in an outer surface of the SiC epitaxial layer in the step of forming the first cleavage line, and the second modified layer is formed in the outer surface of the SiC epitaxial layer in the step of forming the second cleavage line.

[B6] The crystal cutting method according to B5, wherein the first modified layer is formed to reach a boundary region between the SiC semiconductor substrate and the SiC epitaxial layer in the step of forming the first cleavage line and the second modified layer is formed to reach the boundary region between the SiC semiconductor substrate and the SiC epitaxial layer in the step of forming the second cleavage line.

[B7] The crystal cutting method according to any one of B2 to B6, wherein the first cleaving step includes a step of cleaving the SiC crystal structure body with the first cleavage line as the starting point by heating and cooling the first cleavage line and the second cleaving step includes a step of cleaving the SiC crystal structure body with the second cleavage line as the starting point by heating and cooling the second cleavage line.

[B8] The crystal cutting method according to any one of B1 to B7, wherein the SiC crystal structure body includes 2H—SiC, 4H—SiC, or 6H—SiC.

[B9] The crystal cutting method according to any one of B1 to B8, wherein the arrangement direction is a [11-20] direction, a [−12-10] direction, or a [−2110] direction of the hexagonal crystal.

[C1] A method for manufacturing an SiC semiconductor device including a step of preparing an SiC crystal structure body constituted of a hexagonal crystal having a silicon plane and a carbon plane as crystal planes, a step of setting, in the SiC crystal structure body, a device region of quadrilateral shape having an arrangement direction side oriented along an arrangement direction of nearest neighboring Si atoms in a plan view viewed from a normal direction of the silicon plane and an intersecting direction side oriented along an intersecting direction intersecting the arrangement direction, and forming a functional device in the device region, a first cleaving step of cleaving the SiC crystal structure body along the intersecting direction side of the device region and forming a first cleavage portion in the SiC crystal structure body, and a second cleaving step of cleaving the SiC crystal structure body along the arrangement direction side of the device region and forming a second cleavage portion crossing the first cleavage portion in the SiC crystal structure body.

According to this method for manufacturing the SiC semiconductor device, the SiC crystal structure body is cleaved along the nearest neighbor direction intersecting direction in the first cleaving step. The SiC crystal structure body is cleaved along the nearest neighbor direction in the second cleaving step.

In the first cleaving step, the SiC crystal structure body has not been cleaved and therefore stress to the SiC crystal structure body does not become discontinuous. Forming of a bulging portion in the first cleavage portion can thereby be suppressed. On the other hand, in the second cleaving step, stress to the SiC crystal structure body becomes discontinuous because the SiC crystal structure body has been cleaved in the nearest neighbor direction intersecting direction. However, in the second cleaving step, stress is applied to the SiC crystal structure body along the nearest neighbor direction and the SiC crystal structure body is cleaved along the nearest neighbor direction.

Forming of a bulging portion in the second cleavage portion can thereby be suppressed and flatness of the first cleavage portion and the second cleavage portion can thus be improved. A method for manufacturing an SiC semiconductor device that enables an SiC crystal structure body constituted of a hexagonal crystal to be cut appropriately from two different directions can thus be provided.

[C2] The method for manufacturing the SiC semiconductor device according to C1, wherein the step of forming the functional device includes a step of setting, in the SiC crystal structure body, a plurality of the device regions in a matrix array oriented along the arrangement direction and the intersecting direction and forming the functional devices respectively in the plurality of device regions, the first cleaving step includes a step of cleaving the SiC crystal structure body along the intersecting direction sides of the plurality of device regions, and the second cleaving step includes a step of cleaving the SiC crystal structure body along the arrangement direction sides of the plurality of device regions.

[C3] The method for manufacturing the SiC semiconductor device according to C1 or C2, further including a step of forming a first cleavage line oriented along the intersecting direction side of the device region by heating a region of the SiC crystal structure body oriented along the intersecting direction side of the device region in advance of the first cleaving step, and a step of forming a second cleavage line oriented along the arrangement direction side of the device region by heating a region of the SiC crystal structure body oriented along the arrangement direction side of the device region in advance of the second cleaving step, wherein the first cleaving step includes a step of cleaving the SiC crystal structure body with the first cleavage line as a starting point and the second cleaving step includes a step of cleaving the SiC crystal structure body with the second cleavage line as a starting point.

[C4] The method for manufacturing the SiC semiconductor device according to C3, wherein the step of forming the first cleavage line includes a step of forming, in the SiC crystal structure body, a first modified layer in which a crystal structure is modified to a different property by heating, and the step of forming the second cleavage line includes a step of forming, in the SiC crystal structure body, a second modified layer in which a crystal structure is modified to a different property by heating.

[C5] The method for manufacturing the SiC semiconductor device according to C4, wherein the SiC crystal structure body includes an SiC laminated structure that includes an SiC semiconductor substrate and an SiC epitaxial layer, the device region is set in an outer surface of the SiC epitaxial layer, the first modified layer is formed in the outer surface of the SiC epitaxial layer, and the second modified layer is formed in the outer surface of the SiC epitaxial layer.

[C6] The method for manufacturing the SiC semiconductor device according to C5, wherein the first modified layer is formed to reach a boundary region between the SiC semiconductor substrate and the SiC epitaxial layer, and the second modified layer is formed to reach the boundary region between the SiC semiconductor substrate and the SiC epitaxial layer.

[C7] The method for manufacturing the SiC semiconductor device according to any one of C3 to C6, wherein the first cleaving step includes a step of cleaving the SiC crystal structure body with the first cleavage line as the starting point by heating and cooling the first cleavage line and the second cleaving step includes a step of cleaving the SiC crystal structure body with the second cleavage line as the starting point by heating and cooling the second cleavage line.

[C8] The method for manufacturing the SiC semiconductor device according to any one of C1 to C7, wherein the SiC crystal structure body includes 2H—SiC, 4H—SiC, or 6H—SiC.

[C9] The method for manufacturing the SiC semiconductor device according to any one of C1 to C8, wherein the arrangement direction is a [11-20] direction, a [−12-10] direction, or a [−2110] direction of the hexagonal crystal.

[D1] An SiC semiconductor device including an SiC semiconductor layer that is constituted of a hexagonal crystal, having a silicon plane and a carbon plane as crystal planes, and includes a first main surface at one side, a second main surface at another side, a first side surface connecting the first main surface and the second main surface and extending along an arrangement direction of nearest neighboring Si atoms in a plan view viewed from a normal direction of the silicon plane, and a second side surface connecting the first main surface and the second main surface, extending along an intersecting direction intersecting the arrangement direction in the plan view and being not more than 20 μm in an in-plane variation along the arrangement direction.

[D2] The SiC semiconductor device according to D1, further including a first modified layer which is formed in a region of the first side surface at the first main surface side and in which a crystal structure is modified to a different property, and a second modified layer which is formed in a region of the second side surface at the first main surface side and in which a crystal structure is modified to a different property.

[D3] The SiC semiconductor device according to D2, wherein the first modified layer is exposed from the first main surface and the second modified layer is exposed from the first main surface.

[D4] The SiC semiconductor device according to D2, wherein the first modified layer is formed at an interval toward the second main surface side with respect to the first main surface and the second modified layer is formed at an interval toward the second main surface side with respect to the first main surface.

[D5] The SiC semiconductor device according to D2, wherein the SiC semiconductor layer has an SiC laminated structure that includes an SiC semiconductor substrate and an SiC epitaxial layer, the first main surface of the SiC semiconductor layer is formed by the SiC epitaxial layer, the second main surface of the SiC semiconductor layer is formed by the SiC semiconductor substrate, the first modified layer crosses a boundary region between the SiC semiconductor substrate and the SiC epitaxial layer, and the second modified layer crosses the boundary region between the SiC semiconductor substrate and the SiC epitaxial layer.

[D6] The SiC semiconductor device according to D1, further including a first modified layer which is formed in a region of the first side surface at the second main surface side and in which a crystal structure is modified to a different property, and a second modified layer which is formed in a region of the second side surface at the second main surface side and in which a crystal structure is modified to a different property.

[D7] The SiC semiconductor device according to D6, wherein the first modified layer is exposed from the second main surface and the second modified layer is exposed from the second main surface.

[D8] The SiC semiconductor device according to D6, wherein the first modified layer is formed at an interval toward the first main surface side with respect to the second main surface and the second modified layer is formed at an interval toward the first main surface side with respect to the second main surface.

[D9] The SiC semiconductor device according to any one of D6 to D8, wherein the SiC semiconductor layer has an SiC laminated structure that includes an SiC semiconductor substrate and an SiC epitaxial layer, the first main surface of the SiC semiconductor layer is formed by the SiC epitaxial layer, the second main surface of the SiC semiconductor layer is formed by the SiC semiconductor substrate, the first modified layer is formed in the SiC semiconductor substrate, and the second modified layer is formed in the SiC semiconductor substrate.

[D10] The SiC semiconductor device according to any one of D1 to D9, wherein the arrangement direction is a [11-20] direction, a [−12-10] direction, or a [−2110] direction of the hexagonal crystal.

[E1] An SiC processing method including a step of preparing an SiC processing object that includes SiC, a step of selectively heating an outer surface of the SiC processing object and forming a modified layer in which the SiC is modified to a different property in the outer surface of the SiC processing object, and a step of removing a portion or an entirety of the modified layer while letting the SiC processing object remain.

According to this SiC processing method, the outer surface of the SiC processing object of high hardness can be processed by the modified layer forming step and the modified layer removing step.

[E2] The SiC processing method according to E1, wherein the modified layer has a carbon density that differs along a thickness direction.

[E3] The SiC semiconductor device according to E1 or E2, wherein the modified layer has a silicon density that is higher than a carbon density.

[E4] The SiC processing method according to any one of E1 to E3, wherein the modified layer includes an Si modified layer, in which the SiC of the SiC processing object is modified to Si.

[E5] The SiC processing method according to any one of E1 to E4, wherein the SiC processing object is heated to a temperature at which a C atom is eliminated from the SiC.

[E5] The SiC processing method according to any one of E1 to E5, wherein the SiC processing object is heated to a temperature at which a C atom is sublimated from the SiC.

[E7] The SiC processing method according to any one of E1 to E6, wherein a portion or an entirety of the modified layer is removed by an etching method.

[E8] The SiC processing method according to any one of E1 to E7, wherein the SiC processing object includes an SiC semiconductor substrate and the modified layer is formed in an outer surface of the SiC semiconductor substrate.

[E9] The SiC processing method according to any one of E1 to E7, wherein the SiC processing object includes an SiC laminated structure that includes an SiC semiconductor substrate and an SiC epitaxial layer and the modified layer is formed in an outer surface of the SiC semiconductor layer.

[E10] The SiC processing method according to any one of E1 to E7, wherein the SiC processing object includes an SiC laminated structure that includes an SiC semiconductor substrate and an SiC epitaxial layer and the modified layer is formed in an outer surface of the SiC semiconductor substrate.

[E11] The SiC processing method according to any one of E1 to E10, further including a step of cleaving the SiC processing object with a removed portion of the modified layer as a starting point.

[E12] The SiC processing method according to any one of E1 to E11, wherein the SiC processing object includes an SiC monocrystal constituted of a hexagonal crystal.

[E13] A method for manufacturing an SiC semiconductor device that includes the SiC processing method according to any one of E1 to E12.

[F1] An SiC crystal cutting method including a step of preparing an SiC crystal structure body that includes 4H—SiC, a first cutting step of cutting the SiC crystal structure body along a [1-100] direction of the 4H—SiC and forming a first cut portion in the SiC crystal structure body, and a second cutting step of cutting the crystal structure body along a [11-20] direction of the 4H—SiC and forming a second cut portion crossing the first cut portion in the SiC crystal structure body.

According to this SiC crystal cutting method, the SiC crystal structure body is cut along the [1-100] direction which is a nearest neighbor direction intersecting direction, in the first cutting step. The SiC crystal structure body is cut along the [11-20] direction which is a nearest neighbor direction, in the second cutting step.

In the first cutting step, the uncut SiC crystal structure body is cut and therefore stress to the SiC crystal structure body does not become discontinuous. Forming of a bulging portion in the first cut portion can thereby be suppressed. On the other hand, in the second cutting step, stress to the SiC crystal structure body becomes discontinuous because the SiC crystal structure body has been cut in the nearest neighbor direction intersecting direction. However, in the second cutting step, stress is applied to the SiC crystal structure body along the nearest neighbor direction and the SiC crystal structure body is cut along the nearest neighbor direction.

Forming of a bulging portion in the second cut portion can thereby be suppressed and flatness of the first cut portion and the second cut portion can thus be improved. An SiC crystal cutting method that enables an SiC crystal structure body constituted of a hexagonal crystal to be cut appropriately from two different directions can thus be provided.

[F2] The SiC crystal cutting method according to F1, wherein the first cutting step includes a first cleaving step of cleaving the SiC crystal structure body along the [1-100] direction and the second cutting step includes a second cleaving step of cleaving the SiC crystal structure body along the [11-20] direction.

[F3] The SiC crystal cutting method according to F2, further including a step of forming oriented along the [1-100] direction by heating a region of the SiC crystal structure body to be cleaved along the [1-100] direction in advance of the first cleaving step, a first cleavage line, and a step of forming a second cleavage line oriented along the [11-20] direction by heating a region of the SiC crystal structure body to be cleaved along the [11-20] direction in advance of the second cleaving step, wherein the first cleaving step includes a step of cleaving the SiC crystal structure body along the [1-100] direction with the first cleavage line as a starting point and the second cleaving step includes a step of cleaving the SiC crystal structure body along the [11-20] direction with the second cleavage line as a starting point.

[F4] The SiC crystal cutting method according to F3, wherein the step of forming the first cleavage line includes a step of forming, in the SiC crystal structure body, a first modified layer in which a crystal structure is modified to a different property by heating, and the step of forming the second cleavage line includes a step of forming, in the SiC crystal structure body, a second modified layer in which a crystal structure is modified to a different property by heating.

[F5] The SiC crystal cutting method according to F4, wherein the SiC crystal structure body has an SiC semiconductor substrate that includes 4H—SiC, the first modified layer is formed in an outer surface of the SiC semiconductor substrate in the step of forming the first cleavage line, and the second modified layer is formed in the outer surface of the SiC semiconductor substrate in the step of forming the second cleavage line.

[F6] The SiC crystal cutting method according to F4, wherein the SiC crystal structure body has an SiC laminated structure that includes an SiC semiconductor substrate that includes 4H—SiC and an SiC epitaxial layer that includes 4H—SiC, the first modified layer is formed in an outer surface of the SiC epitaxial layer in the step of forming the first cleavage line, and the second modified layer is formed in the outer surface of the SiC epitaxial layer in the step of forming the second cleavage line.

[F7] The SiC crystal cutting method according to F6, wherein the first modified layer is formed to reach a boundary region between the SiC semiconductor substrate and the SiC epitaxial layer in the step of forming the first cleavage line, and the second modified layer is formed to reach the boundary region between the SiC semiconductor substrate and the SiC epitaxial layer in the step of forming the second cleavage line.

[F8] The SiC crystal cutting method according to any one of F3 to F7, wherein the first cleaving step includes a step of cleaving the SiC crystal structure body along the [1-100] direction with the first cleavage line as the starting point by heating and cooling the first cleavage line and the second cleaving step includes a step of cleaving the SiC crystal structure body along the [11-20] direction with the second cleavage line as the starting point by heating and cooling the second cleavage line.

[F9] The SiC crystal cutting method according to any one of F1 to F8, wherein the SiC crystal structure body is formed in a plate shape or discoid shape.

[G1] A method for manufacturing an SiC semiconductor device including a step of preparing an SiC crystal structure body constituted of a hexagonal crystal, a step of setting, in the SiC crystal structure body, a device region of quadrilateral shape having a [1-100] direction side oriented along a [1-100] direction of the SiC crystal structure body and an [11-20] direction side oriented along an [11-20] direction of the SiC crystal structure body, and forming a functional device in the device region, a first cutting step of cutting the SiC crystal structure body along the [1-100] direction side and forming a first cut portion oriented along the [1-100] direction, and a second cutting step of cutting the SiC crystal structure body along the [11-20] direction side and forming a second cut portion crossing the first cut portion and oriented along the [11-20] direction.

According to this method for manufacturing the SiC semiconductor device, forming of a bulging portion with a connection point connecting the first cut portion and the second portion as a starting point can be suppressed in the second cutting step. Flatness of the first cut portion and the second cut portion can thereby be improved. A method for manufacturing an SiC semiconductor device that enables a crystal structure body constituted of a hexagonal crystal to be cut appropriately from two different directions can thus be provided.

[G2] The method for manufacturing the SiC semiconductor device according to G1, wherein, the first cut portion with which an in-plane variation along the [11-20] direction is not more than 20 μm is formed in the first cutting step.

[G3] The method for manufacturing the SiC semiconductor device according to G1 or G2, wherein the step of forming the functional device includes a step of setting, in the SiC crystal structure body, a plurality of the device regions in a matrix array oriented along the [11-20] direction and the [1-100] direction and forming the functional devices respectively in the plurality of device regions, the first cutting step includes a step of cutting the SiC crystal structure body along the [1-100] direction sides of the plurality of device regions, and the second cutting step includes a step of cutting the SiC crystal structure body along the [11-20] direction sides of the plurality of device regions.

[G4] The method for manufacturing the SiC semiconductor device according to any one of G1 to G3, wherein the first cutting step includes a first cleaving step of cleaving the SiC crystal structure body along the [1-100] direction side and the second cutting step includes a second cleaving step of cleaving the SiC crystal structure body along the [11-20] direction side.

[G5] The method for manufacturing the SiC semiconductor device according to G4, further including a step of forming a first cleavage line oriented along the [1-100] direction side of the device region by heating a region of the SiC crystal structure body oriented along the [1-100] direction side of the device region in advance of the first cleaving step, and a step of forming oriented along the [11-20] direction side of the device region by heating a region of the SiC crystal structure body oriented along the [11-20] direction side of the device region in advance of the second cleaving step, a second cleavage line, wherein the first cleaving step includes a step of cleaving the SiC crystal structure body with the first cleavage line as a starting point and the second cleaving step includes a step of cleaving the SiC crystal structure body with the second cleavage line as a starting point.

[G6] The method for manufacturing the SiC semiconductor device according to G5, wherein the step of forming the first cleavage line includes a step of forming, in the SiC crystal structure body, a first modified layer in which a crystal structure is modified to a different property by heating, and the step of forming the second cleavage line includes a step of forming, in the SiC crystal structure body, a second modified layer in which a crystal structure is modified to a different property by heating.

[G7] The method for manufacturing the SiC semiconductor device according to G6, wherein the SiC crystal structure body includes an SiC laminated structure that includes an SiC semiconductor substrate and an SiC epitaxial layer, the device region is set in an outer surface of the SiC epitaxial layer, the first modified layer is formed in the outer surface of the SiC epitaxial layer, and the second modified layer is formed in the outer surface of the SiC epitaxial layer.

[G8] The method for manufacturing the SiC semiconductor device according to G7, wherein the first modified layer is formed to reach a boundary region between the SiC semiconductor substrate and the SiC epitaxial layer and the second modified layer is formed to reach the boundary region between the SiC semiconductor substrate and the SiC epitaxial layer.

[G9] The method for manufacturing the SiC semiconductor device according to any one of G5 to G8, wherein the first cleaving step includes a step of cleaving the SiC crystal structure body along the [1-100] direction with the first cleavage line as the starting point by heating and cooling the first cleavage line and the second cleaving step includes a step of cleaving the SiC crystal structure body along the [11-20] direction with the second cleavage line as the starting point by heating and cooling the second cleavage line.

[G10] The method for manufacturing the SiC semiconductor device according to any one of G1 to G9, wherein the SiC crystal structure body is formed in a plate shape or discoid shape.

[G11] The method for manufacturing the SiC semiconductor device according to any one of G1 to G10, wherein the SiC crystal structure body includes 2H—SiC, 4H—SiC, or 6H—SiC.

[H1] A semiconductor device including a semiconductor layer that is constituted of a hexagonal crystal and includes a first main surface at one side, a second main surface at another side, a first side surface connecting the first main surface and the second main surface and extending along a nearest neighbor direction of the hexagonal crystal and a second side surface connecting the first main surface and the second main surface, extending along an intersecting direction intersecting the nearest neighbor direction and being not more than 20 μm in an in-plane variation along the nearest neighbor direction.

[H2] The semiconductor device according to H1, further including a first modified layer which is formed in a region of the first side surface at the first main surface side and in which a crystal structure is modified to a different property, and a second modified layer which is formed in a region of the second side surface at the first main surface side and in which a crystal structure is modified to a different property.

[H3] The semiconductor device according to H2, wherein the first modified layer is exposed from the first main surface and the second modified layer is exposed from the first main surface.

[H4] The semiconductor device according to H3, wherein the first modified layer is formed at an interval toward the second main surface side with respect to the first main surface, and the second modified layer is formed at an interval toward the second main surface side with respect to the first main surface.

[H5] The semiconductor device according to H3, wherein the semiconductor layer has a laminated structure that includes a semiconductor substrate and an epitaxial layer, the first main surface of the semiconductor layer is formed by the epitaxial layer, the second main surface of the semiconductor layer is formed by the semiconductor substrate, the first modified layer crosses a boundary region between the semiconductor substrate and the epitaxial layer, and the second modified layer crosses the boundary region between the semiconductor substrate and the epitaxial layer.

[H6] The semiconductor device according to H1, further including a first modified layer which is formed in a region of the first side surface at the second main surface side and in which a crystal structure is modified to a different property, and a second modified layer which is formed in a region of the second side surface at the second main surface side and in which a crystal structure is modified to a different property.

[H7] The semiconductor device according to H6, wherein the first modified layer is exposed from the second main surface, and the second modified layer is exposed from the second main surface.

[H8] The semiconductor device according to H6, wherein the first modified layer is formed at an interval toward the first main surface side with respect to the second main surface, and the second modified layer is formed at an interval toward the first main surface side with respect to the second main surface.

[H9] The semiconductor device according to any one of H6 to H8, wherein the semiconductor layer has a laminated structure that includes a semiconductor substrate and an epitaxial layer, the first main surface of the semiconductor layer is formed by the epitaxial layer, the second main surface of the semiconductor layer is formed by the semiconductor substrate, the first modified layer is formed in the semiconductor substrate, and the second modified layer is formed in the semiconductor substrate.

[H10] The semiconductor device according to any one of H1 to H9, wherein the intersecting direction is a direction orthogonal to the nearest neighbor direction.

[H11] The semiconductor device according to any one of H1 to H10, wherein the nearest neighbor direction is a [11-20] direction, a [−12-10] direction, or a [−2110] direction of the hexagonal crystal.

[H12] The semiconductor device according to any one of H1 to H11, wherein the intersecting direction is a [01-10] direction, a [−1-100] direction, or a [−1010] direction of the hexagonal crystal.

[I1] An SiC semiconductor device including an SiC semiconductor layer that is constituted of a hexagonal crystal having a silicon plane and a carbon plane as crystal planes and includes a first main surface at one side, a second main surface at another side and a side surface connecting the first main surface and the second main surface and extending along an arrangement direction of nearest neighboring Si atoms in a plan view viewed from a normal direction of the silicon plane and an intersecting direction intersecting the arrangement direction, and a modified layer which is formed in the side surface of the SiC semiconductor layer and has a carbon density that differs along a thickness direction of the semiconductor layer and in which a crystal structure is modified to a different property.

[I2] The SiC semiconductor device according to I1, wherein the modified layer has a silicon density that is higher than the carbon density.

[I3] The SiC semiconductor device according to I1 or I2, wherein the modified layer includes an Si modified layer in which SiC of the SiC semiconductor layer is modified to Si.

[I4] The SiC semiconductor device according to any one of I1 or I3, wherein the modified layer includes an Si amorphous layer.

[I5] The SiC semiconductor device according to any one of I1 or I4, wherein the modified layer is formed in a region of the side surface at the first main surface side.

[I6] The SiC semiconductor device according to any one of I1 or I5, wherein the modified layer is exposed from the first main surface.

[I7] The SiC semiconductor device according to any one of I1 to I5, wherein the modified layer is formed at an interval toward the second main surface side with respect to the first main surface.

[I8] The SiC semiconductor device according to any one of I1 to I7, wherein the SiC semiconductor layer has an SiC laminated structure that includes an SiC semiconductor substrate and an SiC epitaxial layer, the first main surface of the SiC semiconductor layer is formed by the SiC epitaxial layer, the second main surface of the SiC semiconductor layer is formed by the SiC semiconductor substrate, and the modified layer crosses a boundary region between the SiC semiconductor substrate and the SiC epitaxial layer.

[I9] The SiC semiconductor device according to any one of I1 to I4, wherein the modified layer is formed in a region of the side surface at the second main surface side.

[I10] The SiC semiconductor device according to I9, wherein the modified layer is exposed from the second main surface.

[I11] The SiC semiconductor device according to I9, wherein the modified layer is formed at an interval toward the first main surface side with respect to the second main surface.

[I12] The SiC semiconductor device according to any one of I9 to I11, wherein the SiC semiconductor layer has an SiC laminated structure that includes an SiC semiconductor substrate and an SiC epitaxial layer, the first main surface of the SiC semiconductor layer is formed by the SiC epitaxial layer, the second main surface of the SiC semiconductor layer is formed by the SiC semiconductor substrate, and the modified layer is formed in the SiC semiconductor substrate.

[I13] The SiC semiconductor device according to any one of I1 to I12, wherein the intersecting direction is a direction orthogonal to the nearest neighbor direction.

[I14] The SiC semiconductor device according to any one of I1 to I13, wherein the arrangement direction is a [11-20] direction, a [−12-10] direction, or a [−2110] direction of the hexagonal crystal.

[I15] The SiC semiconductor device according to any one of I1 to I14, wherein the intersecting direction is a [01-10] direction, a [−1-100] direction, or a [−1010] direction of the hexagonal crystal.

[I16] The SiC semiconductor device according to any one of I1 to I15, wherein an in-plane variation along the arrangement direction of a plane extending along the intersecting direction in the side surface of the SiC semiconductor layer is not more than 20 μm.

The present application corresponds to Japanese Patent Application No. 2018-086472 filed on Apr. 27, 2018 in the Japan Patent Office, and the entire disclosure of this application is incorporated herein by reference.

While preferred embodiments of the present invention have been described in detail, these are merely specific examples used to clarify the technical contents of the present invention and the present invention should not be interpreted as being limited to these specific examples and the scope of the present invention is to be limited only by the appended claims.

### REFERENCE SIGNS LIST

1 . . . 4H—SiC crystal structure body
2 . . . first main surface of 4H—SiC crystal structure body
3 . . . second main surface of 4H—SiC crystal structure body
4 . . . side surface of 4H—SiC crystal structure body
10 . . . processed region of 4H—SiC crystal structure body
11 . . . modified layer
16 . . . SiC semiconductor wafer
17 . . . SiC epitaxial layer
21 . . . SiC semiconductor device
22 . . . SiC semiconductor layer
23 . . . first main surface of SiC semiconductor layer
24 . . . second main surface of SiC semiconductor layer
25A . . . side surface of SiC semiconductor layer
25B . . . side surface of SiC semiconductor layer
25C . . . side surface of SiC semiconductor layer
25D . . . side surface of SiC semiconductor layer
31 . . . SiC semiconductor substrate
32 . . . SiC epitaxial layer
42 . . . modified layer
51 . . . SiC semiconductor wafer
52 . . . SiC epitaxial layer
53 . . . device region
61 . . . first cleavage line
62 . . . second cleavage line
73 . . . connection portion
91 . . . SiC semiconductor device
92 . . . SiC semiconductor device
93 . . . SiC semiconductor device
94 . . . SiC semiconductor device
95 . . . SiC semiconductor device
96 . . . SiC semiconductor device
97 . . . SiC semiconductor device
101 . . . SiC semiconductor device
102 . . . SiC semiconductor layer
103 . . . first main surface of SiC semiconductor layer
104 . . . second main surface of SiC semiconductor layer
105A . . . side surface of SiC semiconductor layer
105B . . . side surface of SiC semiconductor layer
105C . . . side surface of SiC semiconductor layer
105D . . . side surface of SiC semiconductor layer
121 . . . SiC semiconductor substrate
122 . . . SiC epitaxial layer
197 . . . modified layer
211 . . . SiC semiconductor device
212 . . . SiC semiconductor device
213 . . . SiC semiconductor device
214 . . . SiC semiconductor device
215 . . . SiC semiconductor device
216 . . . SiC semiconductor device
217 . . . SiC semiconductor device
218 . . . SiC semiconductor device
219 . . . SiC semiconductor device
N . . . normal direction

1. A method for manufacturing a semiconductor device comprising:
a step of preparing a semiconductor wafer of a crystal structure body which has a first main surface at one side and a second main surface at another side;
a step of forming a first depression which towards a thickness direction of the semiconductor wafer and a first modified layer along side walls of the first depression on the first main surface or the second main surface of the semiconductor wafer;
a step of forming a second depression which towards a thickness direction of the semiconductor wafer and a second modified layer along side walls of the second depression on the first main surface or the second main surface of the semiconductor wafer, the second depression is made a crossing direction to the first depression;
a cutting step of cleaving or cutting the semiconductor wafer along the first depression and the second depression.

2. The method for manufacturing a semiconductor device according to claim 1, further comprising:
a step of forming an insulating layer on the first main surface of the semiconductor wafer; wherein
the first depression and the second depression are made within the insulating layer and a semiconductor layer of the semiconductor wafer continuously.

3. The method for manufacturing a semiconductor device according to claim 1, wherein
the crystal structure body is constituted of a hexagonal crystal,
the first depression extends n-axis direction of the hexagonal crystal, and
the second depression extends a-axis direction of the hexagonal crystal.

4. The method for manufacturing a semiconductor device according to claim 1, wherein
the step of forming a first depression includes heating by laser light along the m-axis direction for forming the first depression, and
the step of forming a second depression includes heating by laser light along the a-axis direction for forming the second depression.

5. The method for manufacturing a semiconductor device according to claim 1, wherein
the step of forming a first depression and the step of forming a second depression serve as simultaneously forming the first modified layer and the second modified layer respectively.

6. The method for manufacturing a semiconductor device according to claim 1, wherein
the first depression and the second depression each forms declining shape to an inside of the crystal structure body from the first main surface or the second main surface.

7. The method for manufacturing a semiconductor device according to claim 1, wherein
the first modified layer includes a bottom portion which covers a bottom of the first depression and side portions which cover side walls of the first depression, a thickness of the bottom portion is greater than a thickness of the side portions,
the second modified layer includes a bottom portion which covers a bottom of the second depression and side portions which cover side walls of the second depression, a thickness of the bottom portion is greater than a thickness of the side portions.

8. The method for manufacturing a semiconductor device according to claim 1, wherein
the cutting step is cleaving the semiconductor wafer along the first depression and the second depression,
the cutting step includes the first cleaving step of cleaving the crystal structure body with a most deeper point of the first depressions as a starting point, and
the second cleaving step of cleaving the crystal structure body with a deepest point of the second depression as a starting point.

9. The method for manufacturing a semiconductor device according to claim 8, wherein
the first cleaving step includes heating process of the crystal structure body by irradiating laser light along with the first depression and cooling process of the crystal structure body,
the second cleaving step includes heating process of the crystal structure body by irradiating laser light along with the second depression and cooling process of the crystal structure body.

10. The method for manufacturing a semiconductor device according to claim 1, further comprising:
a step of forming a functional device in a device forming region on the first main surface of the semiconductor wafer before the step of forming a first depression and the step of forming a second depression.

11. The method for manufacturing a semiconductor device according to claim 10, wherein
the step of forming a functional device includes a step of forming a plurality of functional devices in a plurality of functional device forming regions respectively, and
a step of forming electrode layers for each electrically connecting an electrode of the functional device.

12. The method for manufacturing a semiconductor device according to claim 1, wherein
the crystal structure body includes a laminated structure with a crystal substrate and an epitaxial layer on the crystal substrate, and
the first depression and the second depression are formed in the epitaxial layer.

13. The method for manufacturing a semiconductor device according to claim 12, wherein
the crystal substrate has a first impurity concentration, and
the epitaxial layer has a second impurity concentration which is less than the first impurity concentration.

14. The method for manufacturing a semiconductor device according to claim 12, wherein
the first depression and the second depression each has a portion formed in the crystal substrate and a portion formed in the epitaxial layer.

15. The method for manufacturing a semiconductor device according to claim 1, wherein,
the crystal structure body includes a SiC monocrystal.

16. A semiconductor device comprising:
a semiconductor layer which has a first main surface at one side, a second main surface at another side, a first side surface for connecting the first main surface and the second main surface and extends a first direction which crosses to the first main surface, and a second side surface for connecting the first main surface and the second main surface and extends a second direction which crosses to the first main surface and the first direction,
an inclining portion or inclining portions which form(s) at a connecting portion between the first main surface and the first side surface, and/or, form(s) at a connecting portion between the second main surface and the second side surface,
a modified layer formed on the inclining portion,
a functional device formed on the first main surface of the semiconductor layer, and
a cleavage surface which is continuous to the inclining portion at one of the first side surface and the second side surface or at both of the first side surface and the second side surface.

17. The semiconductor device according to claim 16, wherein
the inclining portion forms indent shape with the semiconductor layer and an insulating layer formed on the semiconductor layer are indented altogether.

18. The semiconductor device according to claim 17, wherein
the insulating layer is flush with the semiconductor layer in the inclining portion.

19. The semiconductor device according to claim 16, wherein
the first side surface and the second side surface are tortuosities in plane view,
an in-plane variations oriented along the second direction of the first side surface is not more than 20 μm,
an in-plane variations oriented along the first direction of the second side surface is not more than 20 μm.

20. The semiconductor device according to claim 16, wherein
the semiconductor layer includes a crystal structure body constituted of a hexagonal crystal,
the first direction is a-axis direction of the hexagonal crystal, and
the second direction is m-axis direction of the hexagonal crystal.

21. The semiconductor device according to claim 16, wherein
the semiconductor layer has a laminated structure with a crystal substrate and an epitaxial layer on the crystal substrate,
the first main surface is located at the epitaxial layer and the second main surface is located at the crystal substrate, and
the inclining portion(s) are formed on the epitaxial layer.

22. The semiconductor device according to claim 20, wherein
the inclining portion has a portion formed in the crystal substrate and a portion formed in the epitaxial layer.

23. The semiconductor device according to claim 16, wherein.
the modified layer forms on the inclining portion.

24. The semiconductor device according to claim 23, wherein
the modified layer exposes at the first main surface or the second main surface as flush with the first main surface or the second main surface.

25. The semiconductor device according to claim 16, wherein
the functional device includes an insulated gate transistor,
a first electrode and a gate pad is formed on the first main surface, and
a second electrode is formed on the second main surface.

26. The semiconductor device according to claim 25, wherein
the insulated gate transistor includes a gate trench.

27. The semiconductor device according to claim 16, wherein
the functional device includes an diode,
a first electrode serves as an anode is formed on the first main surface, and
a second electrode serves as a cathode is formed on the second main surface.

28. The semiconductor device according to claim 16, wherein
the semiconductor layer includes a SiC monocrystal.
